(19) United States
(12) Patent Application Publication
(10) Pub. No.: US 2024/0380418 A1
(43) Pub. Date: Nov. 14, 2024

(54) TRANSMISSION DEVICE, TRANSMISSION METHOD, RECEPTION DEVICE, AND RECEPTION METHOD

(71) Applicant: Sony Group Corporation, Tokyo (JP)

(72) Inventors: Yuji SHINOHARA, Tokyo (JP); Makiko YAMAMOTO, Tokyo (JP)

(73) Assignee: Sony Group Corporation, Tokyo (JP)

(21) Appl. No.: 18/576,756

(22) PCT Filed: Feb. 24, 2022
(86) PCT No.: PCT/JP2022/007468

§ 371 Date: Jan. 5, 2024

(30) Foreign Application Priority Data
Jul. 12, 2021 (JP) 2021-114822

(51) Int. Cl. H03M 13/27; H04L 1/00

(52) U.S. Cl. CPC H03M 13/2721; H04L 1/0058; H04L 1/0071

(57) ABSTRACT

The present technology relates to a transmission device, a transmission method, a reception device, and a reception method capable of ensuring good communication quality in data transmission using an LDPC code.

In group-wise interleaving in which an LDPC code with a code length N of 69120 bits is interleaved in units of bit groups of 360 bits, an (i+1)th bit group from a head of the LDPC code is set as a bit group i, and a sequence of bit groups 0 to 191 of the 69120 bit LDPC code is interleaved into a predetermined sequence. In the group-wise deinterleaving, the sequence of the LDPC code after the group-wise interleaving is returned to the original sequence. The present technology can be applied to, for example, a case of performing data transmission or the like using an LDPC code.

### TECHNICAL FIELD

The present technology relates to a transmission device, a transmission method, a reception device, and a reception method, and more particularly, to a transmission device, a transmission method, a reception device, and a reception method capable of ensuring good communication quality in data transmission using, for example, an LDPC code.

### BACKGROUND ART

Low density parity check (LDPC) codes have high error correction capability, and in recent years, for example, have been widely adopted in transmission systems of digital broadcasting and the like such as digital video broadcasting (DVB)-S.2, DVB-T.2, and DVB-C.2 in Europe and the like, and advanced television systems committee (ATSC)3.0 in the United States and the like (See, for example, Non-Patent Document 1.).

Recent researches have revealed that the LDPC codes achieve performance close to the Shannon limit as the code length is increased, similarly to turbo codes and the like. Furthermore, since the LDPC codes have a property that the minimum distance is proportional to the code length, the LDPC codes have a good block error probability characteristic, and further, a so-called error floor phenomenon observed in decoding characteristics of the turbo codes and the like hardly occurs as an advantage.

### CITATION LIST

### Non Patent Document

Non-Patent Document 1: ATSC Standard: Physical Layer Protocol(A/322), 7 Sep. 2016

### SUMMARY OF THE INVENTION

### Problems to be Solved by the Invention

In data transmission using the LDPC code, for example, the LDPC code is used as a symbol of quadrature modulation (digital modulation) such as quadrature phase shift keying (QPSK) (symbolized), and the symbol is mapped to a signal point of the quadrature modulation and transmitted.

Data transmission using the LDPC code as described above is spreading worldwide, and it is required to ensure good communication (transmission) quality.

The present technology has been made in view of such a situation, and aims to ensure good communication quality in data transmission using the LDPC code.

### Solutions to Problems

A transmission device/method of the present technology including: an encoding unit that performs/step of performing LDPC coding on the basis of a parity check matrix of an LDPC code with a code length N of 69120 bits and a coding rate r of 4/16; a group-wise interleaving unit that performs/step of performing group-wise interleaving that interleaves the LDPC code in units of bit groups of 360 bits; and a mapping unit that maps/step of mapping the LDPC code to any one of 16 signal points of a 16QAM 2D-non-uniform constellation (NUC) in units of 4 bits, in which in the group-wise interleaving, an (i+1)th bit group from a head of the LDPC code is set as a bit group i, and a sequence of bit groups 0 to 191 of the LDPC code with the 69210 bits is interleaved into a sequence of bit groups below,
154, 83, 159, 153, 136, 6, 19, 73, 122, 40, 97, 144, 101, 106, 130, 174, 48, 176, 14, 27, 52, 152, 173, 63, 39, 92, 114, 98, 190, 149, 103, 160, 118, 13, 29, 51, 66, 168, 180, 23, 170, 24, 5, 157, 28, 45, 53, 68, 25, 191, 148, 139, 15, 67, 77, 100, 58, 91, 50, 131, 65, 17, 11, 123, 86, 135, 115, 120, 59, 162, 9, 189, 21, 12, 179, 178, 110, 35, 137, 3, 84, 177, 124, 186, 143, 26, 96, 80, 31, 169, 119, 33, 87, 140, 88, 171, 133, 150, 151, 72, 85, 89, 112, 126, 167, 56, 49, 187, 138, 145, 18, 32, 90, 158, 54, 104, 62, 165, 79, 1, 81, 102, 44, 61, 10, 166, 2, 116, 161, 60, 108, 142, 30, 78, 127, 111, 46, 43, 184, 163, 64, 22, 41, 156, 70, 20, 42, 182, 55, 95, 105, 132, 38, 69, 134, 74, 155, 141, 172, 57, 7, 175, 128, 75, 107, 109, 99, 147, 146, 117, 125, 185, 0, 76, 82, 129, 36, 34, 93, 188, 113, 71, 183, 121, 47, 16, 164, 4, 181, 94, 37, 8
the parity check matrix includes: an A matrix on an upper left of the parity check matrix, with M1 rows and K columns represented by a predetermined value M1 and an information length K=N×r of the LDPC code; a B matrix of M1 rows and M1 columns, the B matrix having a staircase structure adjacent to a right side of the A matrix; a Z matrix of M1 rows and N−K−M1 columns, the Z matrix being a zero matrix adjacent to a right side of the B matrix; a C matrix of N−K−M1 rows and K+M1 columns, the C matrix being adjacent under the A matrix and the B matrix; and a D matrix of N−K−M1 rows and N−K−M1 columns, the D matrix being an identity matrix adjacent to a right side of the C matrix, the predetermined value M1 is 1800, the A matrix and the C matrix are represented by a parity check matrix initial value table, and the parity check matrix initial value table is a table representing positions of elements of 1 in the A matrix and the C matrix for every 360 columns, and is
561 825 1718 4745 7515 13041 13466 18039 19065 21821 32596 32708 35323 36399 36450 41124 43036 43218 43363 44875 49948
56 102 1779 2427 5381 8768 15336 26473 35717 38748 39066 45002 50720
694 1150 1533 2177 5801 6610 7601 16657 18949 33472 47746 49581 50668
90 1122 1472 2085 2593 4986 8200 9175 15502 44084 46057 48546 50487
521 619 708 6915 8978 14211 17426 23058 23463 27440 29822 33443 42871
449 912 1471 8058 9344 11928 20533 20600 20737 26557 26970 27616 33791
355 700 1528 6478 9588 10790 20992 33122 34283 41295 43439 46249 47763
997 1543 1679 5874 7973 7975 11113 28275 28812 29864 35070 36864 50676
85 326 1392 4186 10855 11005 12913 19263 22984 31733 33787 37567 48173
986 1144 1508 19864 28918 29117 33609 36452 47975 48432 48842 49274 51533
437 1190 1413 3814 6695 17541 22060 25845 28431 37453 38912 44170 49231
327 1171 1204 6952 11880 16469 25058 28956 31523 36770 40189 43422 46481
123 605 619 8118 8455 19550 20529 21762 21950 28485 30946 34755 34765
113 896 971 6400 27059 33383 34537 35827 38796 40582 42594 43098 48525
162 854 1015 2938 10659 12085 13040 32772 33023 35878 49674 51060 51333
100 452 1703 1932 4208 5127 12086 14549 16084 17890 20870 41364 48498
1569 1633 1666 12957 18611 22499 38418 38719 42135 46815 48274 50947 51387
119 691 1190 2457 3865 7468 12512 30782 31811 33508 36586 41789 47426
867 1117 1666 4376 13263 13466 33524 37440 38136 39800 41454 41620 42510
378 900 1754 16303 25369 27103 28360 30958 35316 44165 46682 47016 50004
1321 1549 1570 16276 17284 19431 23482 23920 27386 27517 46253 48617 50118
37 383 1418 15792 22551 28843 36532 36718 38805 39226 45671 47712 51769
150 787 1441 17828 19396 21576 21805 24048 31868 32891 42486 43020 45492
1095 1214 1744 2445 5773 10209 11526 29604 30121 36526 45786 47376 49366
412 448 1281 11164 14501 15538 15773 23305 31960 32721 40744 45731 50269
183 626 837 4491 12237 13705 15177 15973 21266 25374 41232 44147 50529
618 1550 1594 5474 9260 16552 18122 26061 30420 30922 32661 34390 43236
135 496 757 9327 15659 20738 24327 26688 29063 38993 46155 49532 50001
64 126 1714 5561 8921 11300 12688 14454 16857 19585 20528 24107 27252
528 687 1730 9735 11737 16396 19200 33712 34271 38241 42027 44471 45581
69 646 1447 8603 19706 22153 22398 23840 24638 27254 29107 30368 41419
673 845 1285 9100 11064 14804 15425 17357 27248 31223 32410 35444 48018
124 1531 1677 3672 3673 3786 8886 9557 10003 11053 13053 22458 25413
102 1154 1758 5721 6034 14567 17772 28670 33380 34284 35356 47480 48123
48 351 760 2078 9797 22956 26120 34119 39658 41039 45237 47861 49022
254 445 841 6835 18340 19021 20053 22874 32639 36679 42004 45696 49530
16 802 903 6218 16206 22068 23049 28201 30377 33947 44358 44739 49303
153 1542 1629 7992 29900 34931 36927 38651 39981 41085 41327 50185 51484
525 1291 1765 9425 20271 31229 37444 38996 39145 41711 43188 45203 51255
2 244 1648 12321 14991 17426 18456 20126 29915 32581 38880 39516 49013
23 452 705 9414 11862 13764 18179 35458 37892 40471 46041 46494 48746
509 1201 1328 8921 9867 10947 19476 22693 32636 34301 38356 39238 51797
246 249 1390 12438 13266 24060 33628 37130 42923 43298 43709 43721 45413
117 257 748 9419 9461 11350 12790 16724 33147 34168 34683 37884 42699
619 646 740 7468 7604 8152 16296 19120 27614 27748 40170 40289 49366
914 1360 1716 10817 17672 18919 26146 29631 40903 46716 49502 51576 51657
68 702 1552 10431 10925 12856 24516 26440 30834 31179 32277 35019 44108
588 880 1524 6641 9453 9653 13679 14488 20714 25865 42217 42637 48312
6380 12240 12558 12816 21460 24206 26129 28555 41616 51767
8889 16221 21629 23476 33954 40572 43494 44666 44885 49813
16938 17727 17913 18898 21754 32515 35686 36920 39898 43560
9170 11747 14681 22874 24537 24685 26989 28947 33592 34621
2427 10241 29649 30522 37700 37789 41656 44020 49801 51268.

A reception device/method of the present technology including a group-wise deinterleaving unit that returns/step of returning a sequence of an LDPC code after group-wise interleaving to an original sequence, the sequence of the LDPC code after group-wise interleaving being obtained from data transmitted by a transmission method including: an encoding step of performing LDPC coding on the basis of a parity check matrix of an LDPC code with a code length N of 69120 bits and a coding rate r of 4/16; a group-wise interleaving step of performing group-wise interleaving that interleaves the LDPC code in units of bit groups of 360 bits; and a mapping step of mapping the LDPC code to any one of 16 signal points of a 16QAM 2D-non-uniform constellation (NUC) in units of 4 bits, in which in the group-wise interleaving, an (i+1)th bit group from a head of the LDPC code is set as a bit group i, and a sequence of bit groups 0 to 191 of the LDPC code with the 69120 bits is interleaved into a sequence of bit groups below,
154, 83, 159, 153, 136, 6, 19, 73, 122, 40, 97, 144, 101, 106, 130, 174, 48, 176, 14, 27, 52, 152, 173, 63, 39, 92, 114, 98, 190, 149, 103, 160, 118, 13, 29, 51, 66, 168, 180, 23, 170, 24, 5, 157, 28, 45, 53, 68, 25, 191, 148, 139, 15, 67, 77, 100, 58, 91, 50, 131, 65, 17, 11, 123, 86, 135, 115, 120, 59, 162, 9, 189, 21, 12, 179, 178, 110, 35, 137, 3, 84, 177, 124, 186, 143, 26, 96, 80, 31, 169, 119, 33, 87, 140, 88, 171, 133, 150, 151, 72, 85, 89, 112, 126, 167, 56, 49, 187, 138, 145, 18, 32, 90, 158, 54, 104, 62, 165, 79, 1, 81, 102, 44, 61, 10, 166, 2, 116, 161, 60, 108, 142, 30, 78, 127, 111, 46, 43, 184, 163, 64, 22, 41, 156, 70, 20, 42, 182, 55, 95, 105, 132, 38, 69, 134, 74, 155, 141, 172, 57, 7, 175, 128, 75, 107, 109, 99, 147, 146, 117, 125, 185, 0, 76, 82, 129, 36, 34, 93, 188, 113, 71, 183, 121, 47, 16, 164, 4, 181, 94, 37, 8
the parity check matrix includes: an A matrix on an upper left of the parity check matrix, with M1 rows and K columns represented by a predetermined value M1 and an information length K=N×r of the LDPC code; a B matrix of M1 rows and M1 columns, the B matrix having a staircase structure adjacent to a right side of the A matrix; a Z matrix of M1 rows and N−K−M1 columns, the Z matrix being a zero matrix adjacent to a right side of the B matrix; a C matrix of N−K−M1 rows and K+M1 columns, the C matrix being adjacent under the A matrix and the B matrix; and a D matrix of N−K−M1 rows and N−K−M1 columns, the D matrix being an identity matrix adjacent to a right side of the C matrix, the predetermined value M1 is 1800, the A matrix and the C matrix are represented by a parity check matrix initial value table, and the parity check matrix initial value table is a table representing positions of elements of 1 in the A matrix and the C matrix for every 360 columns, and is
561 825 1718 4745 7515 13041 13466 18039 19065 21821 32596 32708 35323 36399 36450 41124 43036 43218 43363 44875 49948
56 102 1779 2427 5381 8768 15336 26473 35717 38748 39066 45002 50720
694 1150 1533 2177 5801 6610 7601 16657 18949 33472 47746 49581 50668
90 1122 1472 2085 2593 4986 8200 9175 15502 44084 46057 48546 50487
521 619 708 6915 8978 14211 17426 23058 23463 27440 29822 33443 42871
449 912 1471 8058 9344 11928 20533 20600 20737 26557 26970 27616 33791
355 700 1528 6478 9588 10790 20992 33122 34283 41295 43439 46249 47763
997 1543 1679 5874 7973 7975 11113 28275 28812 29864 35070 36864 50676
85 326 1392 4186 10855 11005 12913 19263 22984 31733 33787 37567 48173
986 1144 1508 19864 28918 29117 33609 36452 47975 48432 48842 49274 51533
437 1190 1413 3814 6695 17541 22060 25845 28431 37453 38912 44170 49231
327 1171 1204 6952 11880 16469 25058 28956 31523 36770 40189 43422 46481
123 605 619 8118 8455 19550 20529 21762 21950 28485 30946 34755 34765
113 896 971 6400 27059 33383 34537 35827 38796 40582 42594 43098 48525
162 854 1015 2938 10659 12085 13040 32772 33023 35878 49674 51060 51333
100 452 1703 1932 4208 5127 12086 14549 16084 17890 20870 41364 48498
1569 1633 1666 12957 18611 22499 38418 38719 42135 46815 48274 50947 51387
119 691 1190 2457 3865 7468 12512 30782 31811 33508 36586 41789 47426
867 1117 1666 4376 13263 13466 33524 37440 38136 39800 41454 41620 42510
378 900 1754 16303 25369 27103 28360 30958 35316 44165 46682 47016 50004
1321 1549 1570 16276 17284 19431 23482 23920 27386 27517 46253 48617 50118
37 383 1418 15792 22551 28843 36532 36718 38805 39226 45671 47712 51769
150 787 1441 17828 19396 21576 21805 24048 31868 32891 42486 43020 45492
1095 1214 1744 2445 5773 10209 11526 29604 30121 36526 45786 47376 49366
412 448 1281 11164 14501 15538 15773 23305 31960 32721 40744 45731 50269
183 626 837 4491 12237 13705 15177 15973 21266 25374 41232 44147 50529
618 1550 1594 5474 9260 16552 18122 26061 30420 30922 32661 34390 43236
135 496 757 9327 15659 20738 24327 26688 29063 38993 46155 49532 50001
64 126 1714 5561 8921 11300 12688 14454 16857 19585 20528 24107 27252
528 687 1730 9735 11737 16396 19200 33712 34271 38241 42027 44471 45581
69 646 1447 8603 19706 22153 22398 23840 24638 27254 29107 30368 41419
673 845 1285 9100 11064 14804 15425 17357 27248 31223 32410 35444 48018
124 1531 1677 3672 3673 3786 8886 9557 10003 11053 13053 22458 25413
102 1154 1758 5721 6034 14567 17772 28670 33380 34284 35356 47480 48123
48 351 760 2078 9797 22956 26120 34119 39658 41039 45237 47861 49022
254 445 841 6835 18340 19021 20053 22874 32639 36679 42004 45696 49530
16 802 903 6218 16206 22068 23049 28201 30377 33947 44358 44739 49303
153 1542 1629 7992 29900 34931 36927 38651 39981 41085 41327 50185 51484
525 1291 1765 9425 20271 31229 37444 38996 39145 41711 43188 45203 51255
2 244 1648 12321 14991 17426 18456 20126 29915 32581 38880 39516 49013
23 452 705 9414 11862 13764 18179 35458 37892 40471 46041 46494 48746
509 1201 1328 8921 9867 10947 19476 22693 32636 34301 38356 39238 51797
246 249 1390 12438 13266 24060 33628 37130 42923 43298 43709 43721 45413
117 257 748 9419 9461 11350 12790 16724 33147 34168 34683 37884 42699
619 646 740 7468 7604 8152 16296 19120 27614 27748 40170 40289 49366
914 1360 1716 10817 17672 18919 26146 29631 40903 46716 49502 51576 51657
68 702 1552 10431 10925 12856 24516 26440 30834 31179 32277 35019 44108
588 880 1524 6641 9453 9653 13679 14488 20714 25865 42217 42637 48312
6380 12240 12558 12816 21460 24206 26129 28555 41616 51767
8889 16221 21629 23476 33954 40572 43494 44666 44885 49813
16938 17727 17913 18898 21754 32515 35686 36920 39898 43560
9170 11747 14681 22874 24537 24685 26989 28947 33592 34621
2427 10241 29649 30522 37700 37789 41656 44020 49801 51268.

In the transmission device/method according to the present technology, the LDPC coding is performed on the basis of the parity check matrix of the LDPC code with the code length N of 69120 bits and the coding rate r of 4/16, and the group-wise interleaving that interleaves the LDPC code in units of bit groups of 360 bits is performed. Then, the LDPC code is mapped to any one of 16 signal points of the 16QAM 2D-non-uniform constellation (NUC) in units of 4 bits. In the group-wise interleaving, an (i+1)th bit group from a head of the LDPC code is set as a bit group i, a sequence of bit groups 0 to 191 of the LDPC code with the 69120 bits is interleaved into a sequence of bit groups below.
154, 83, 159, 153, 136, 6, 19, 73, 122, 40, 97, 144, 101, 106, 130, 174, 48, 176, 14, 27, 52, 152, 173, 63, 39, 92, 114, 98, 190, 149, 103, 160, 118, 13, 29, 51, 66, 168, 180, 23, 170, 24, 5, 157, 28, 45, 53, 68, 25, 191, 148, 139, 15, 67, 77, 100, 58, 91, 50, 131, 65, 17, 11, 123, 86, 135, 115, 120, 59, 162, 9, 189, 21, 12, 179, 178, 110, 35, 137, 3, 84, 177, 124, 186, 143, 26, 96, 80, 31, 169, 119, 33, 87, 140, 88, 171, 133, 150, 151, 72, 85, 89, 112, 126, 167, 56, 49, 187, 138, 145, 18, 32, 90, 158, 54, 104, 62, 165, 79, 1, 81, 102, 44, 61, 10, 166, 2, 116, 161, 60, 108, 142, 30, 78, 127, 111, 46, 43, 184, 163, 64, 22, 41, 156, 70, 20, 42, 182, 55, 95, 105, 132, 38, 69, 134, 74, 155, 141, 172, 57, 7, 175, 128, 75, 107, 109, 99, 147, 146, 117, 125, 185, 0, 76, 82, 129, 36, 34, 93, 188, 113, 71, 183, 121, 47, 16, 164, 4, 181, 94, 37, 8

The parity check matrix initial value table that defines the parity check matrix is as described above.

In the reception device/method of the present technology, the sequence of the LDPC code after group-wise interleaving obtained from the data transmitted by the transmission method of the present technology is returned to the original sequence.

Note that each of the reception device and the transmission device may be an independent device or may be an internal block constituting one device.

### BRIEF DESCRIPTION OF DRAWINGS

FIG. 1 is a diagram for explaining a parity check matrix H of an LDPC code.

FIG. 2 is a flowchart illustrating an LDPC code decoding procedure.

FIG. 3 is a diagram illustrating an example of a parity check matrix of an LDPC code.

FIG. 4 is a diagram illustrating an example of a Tanner graph of a parity check matrix.

FIG. 5 is a diagram illustrating an example of a variable node.

FIG. 6 is a diagram illustrating an example of a check node.

FIG. 7 is a diagram illustrating a configuration example of an embodiment of a transmission system to which the present technology is applied.

FIG. 8 is a block diagram illustrating a configuration example of a transmission device 11.

FIG. 9 is a block diagram illustrating a configuration example of a bit interleaver 116.

FIG. 10 is a diagram illustrating an example of a parity check matrix.

FIG. 11 is a diagram illustrating an example of a parity matrix.

FIG. 12 is a diagram illustrating a parity check matrix of an LDPC code defined in the DVB-T.2 standard.

FIG. 13 is a diagram illustrating a parity check matrix of an LDPC code defined in the DVB-T.2 standard.

FIG. 14 is a diagram illustrating an example of a Tanner graph for decoding an LDPC code.

FIG. 15 is a diagram illustrating an example of a parity matrix H_{T} having a staircase structure and a Tanner graph corresponding to the parity matrix H_{T}.

FIG. 16 is a diagram illustrating an example of a parity matrix H_{T} of a parity check matrix H corresponding to an LDPC code after parity interleaving.

FIG. 17 is a flowchart illustrating an example of processing performed by a bit interleaver 116 and a mapper 117.

FIG. 18 is a block diagram illustrating a configuration example of an LDPC encoder 115.

FIG. 19 is a flowchart illustrating an example of processing of an LDPC encoder 115.

FIG. 20 is a diagram illustrating an example of a parity check matrix initial value table of a code rate of 1/4 and a code length of 16200.

FIG. 21 is a diagram for explaining a method of obtaining a parity check matrix H from a parity check matrix initial value table.

FIG. 22 is a diagram illustrating a structure of a parity check matrix.

FIG. 23 is a diagram illustrating an example of a parity check matrix initial value table.

FIG. 24 is a diagram for explaining an A matrix generated from a parity check matrix initial value table.

FIG. 25 is a diagram for explaining parity interleaving for a B matrix.

FIG. 26 is a diagram for explaining a C matrix generated from a parity check matrix initial value table.

FIG. 27 is a diagram for explaining parity interleaving of a D matrix.

FIG. 28 is a diagram illustrating a parity check matrix on which column permutation as parity deinterleaving for restoring parity interleaving is performed.

FIG. 29 is a diagram illustrating a transformed parity check matrix obtained by performing row permutation for a parity check matrix.

FIG. 30 is a diagram illustrating an example of a parity check matrix initial value table of a type A code with N=69120 bits and r=2/16.

FIG. 31 is a diagram illustrating an example of a parity check matrix initial value table of a type A code with N=69120 bits and r=3/16.

FIG. 32 is a diagram illustrating an example of a parity check matrix initial value table of a type A code with N=69120 bits and r=3/16.

FIG. 33 is a diagram illustrating an example of a parity check matrix initial value table of a type A code with N=69120 bits and r=4/16.

FIG. 34 is a diagram illustrating an example of a parity check matrix initial value table of a type A code with N=69120 bits and r=5/16.

FIG. 35 is a diagram illustrating an example of a parity check matrix initial value table of a type A code with N=69120 bits and r=5/16.

FIG. 36 is a diagram illustrating an example of a parity check matrix initial value table of a type A code with N=69120 bits and r=6/16.

FIG. 37 is a diagram illustrating an example of a parity check matrix initial value table of a type A code with N=69120 bits and r=6/16.

FIG. 38 is a diagram illustrating an example of a parity check matrix initial value table of a type A code with N=69120 bits and r=7/16.

FIG. 39 is a diagram illustrating an example of a parity check matrix initial value table of a type A code with N=69120 bits and r=7/16.

FIG. 40 is a diagram illustrating an example of a parity check matrix initial value table of a type A code with N=69120 bits and r=8/16.

FIG. 41 is a diagram illustrating an example of a parity check matrix initial value table of a type A code with N=69120 bits and r=8/16.

FIG. 42 is a diagram illustrating an example of a parity check matrix initial value table of a type B code with N=69120 bits and r=7/16.

FIG. 43 is a diagram illustrating an example of a parity check matrix initial value table of a type B code with N=69120 bits and r=7/16.

FIG. 44 is a diagram illustrating another example of a parity check matrix initial value table of a type B code with N=69120 bits and r=7/16.

FIG. 45 is a diagram illustrating another example of a parity check matrix initial value table of a type B code with N=69120 bits and r=7/16.

FIG. 46 is a diagram illustrating an example of a parity check matrix initial value table of a type B code with N=69120 bits and r=8/16.

FIG. 47 is a diagram illustrating an example of a parity check matrix initial value table of a type B code with N=69120 bits and r=8/16.

FIG. 48 is a diagram illustrating another example of a parity check matrix initial value table of a type B code with N=69120 bits and r=8/16.

FIG. 49 is a diagram illustrating another example of a parity check matrix initial value table of a type B code with N=69120 bits and r=8/16.

FIG. 50 is a diagram illustrating an example of a parity check matrix initial value table of a type B code with N=69120 bits and r=9/16.

FIG. 51 is a diagram illustrating an example of a parity check matrix initial value table of a type B code with N=69120 bits and r=9/16.

FIG. 52 is a diagram illustrating an example of a parity check matrix initial value table of a type B code with N=69120 bits and r=9/16.

FIG. 53 is a diagram illustrating another example of a parity check matrix initial value table of a type B code with N=69120 bits and r=9/16.

FIG. 54 is a diagram illustrating another example of a parity check matrix initial value table of a type B code with N=69120 bits and r=9/16.

FIG. 55 is a diagram illustrating another example of a parity check matrix initial value table of a type B code with N=69120 bits and r=9/16.

FIG. 56 is a diagram illustrating an example of a parity check matrix initial value table of a type B code with N=69120 bits and r=10/16.

FIG. 57 is a diagram illustrating an example of a parity check matrix initial value table of a type B code with N=69120 bits and r=10/16.

FIG. 58 is a diagram illustrating an example of a parity check matrix initial value table of a type B code with N=69120 bits and r=10/16.

FIG. 59 is a diagram illustrating another example of a parity check matrix initial value table of a type B code with N=69120 bits and r=10/16.

FIG. 60 is a diagram illustrating another example of a parity check matrix initial value table of a type B code with N=69120 bits and r=10/16.

FIG. 61 is a diagram illustrating another example of a parity check matrix initial value table of a type B code with N=69120 bits and r=10/16.

FIG. 62 is a diagram illustrating an example of a parity check matrix initial value table of a type B code with N=69120 bits and r=11/16.

FIG. 63 is a diagram illustrating an example of a parity check matrix initial value table of a type B code with N=69120 bits and r=11/16.

FIG. 64 is a diagram illustrating an example of a parity check matrix initial value table of a type B code with N=69120 bits and r=11/16.

FIG. 65 is a diagram illustrating another example of a parity check matrix initial value table of a type B code with N=69120 bits and r=11/16.

FIG. 66 is a diagram illustrating another example of a parity check matrix initial value table of a type B code with N=69120 bits and r=11/16.

FIG. 67 is a diagram illustrating another example of a parity check matrix initial value table of a type B code with N=69120 bits and r=11/16.

FIG. 68 is a diagram illustrating an example of a parity check matrix initial value table of a type B code with N=69120 bits and r=12/16.

FIG. 69 is a diagram illustrating an example of a parity check matrix initial value table of a type B code with N=69120 bits and r=12/16.

FIG. 70 is a diagram illustrating an example of a parity check matrix initial value table of a type B code with N=69120 bits and r=12/16.

FIG. 71 is a diagram illustrating another example of a parity check matrix initial value table of a type B code with N=69120 bits and r=12/16.

FIG. 72 is a diagram illustrating another example of a parity check matrix initial value table of a type B code with N=69120 bits and r=12/16.

FIG. 73 is a diagram illustrating another example of a parity check matrix initial value table of a type B code with N=69120 bits and r=12/16.

FIG. 74 is a diagram illustrating an example of a parity check matrix initial value table of a type B code with N=69120 bits and r=13/16.

FIG. 75 is a diagram illustrating an example of a parity check matrix initial value table of a type B code with N=69120 bits and r=13/16.

FIG. 76 is a diagram illustrating an example of a parity check matrix initial value table of a type B code with N=69120 bits and r=13/16.

FIG. 77 is a diagram illustrating another example of a parity check matrix initial value table of a type B code with N=69120 bits and r=13/16.

FIG. 78 is a diagram illustrating another example of a parity check matrix initial value table of a type B code with N=69120 bits and r=13/16.

FIG. 79 is a diagram illustrating another example of a parity check matrix initial value table of a type B code with N=69120 bits and r=13/16.

FIG. 80 is a diagram illustrating an example of a parity check matrix initial value table of a type B code with N=69120 bits and r=14/16.

FIG. 81 is a diagram illustrating an example of a parity check matrix initial value table of a type B code with N=69120 bits and r=14/16.

FIG. 82 is a diagram illustrating an example of a parity check matrix initial value table of a type B code with N=69120 bits and r=14/16.

FIG. 83 is a diagram illustrating another example of a parity check matrix initial value table of a type B code with N=69120 bits and r=14/16.

FIG. 84 is a diagram illustrating another example of a parity check matrix initial value table of a type B code with N=69120 bits and r=14/16.

FIG. 85 is a diagram illustrating another example of a parity check matrix initial value table of a type B code with N=69120 bits and r=14/16.

FIG. 86 is a diagram illustrating an example of a Tanner graph of an ensemble of degree sequence having a column weight of 3 and a row weight of 6.

FIG. 87 is a diagram illustrating an example of a Tanner graph of a multi-edge type ensemble.

FIG. 88 is a diagram for explaining a parity check matrix by a type A method.

FIG. 89 is a diagram for explaining a parity check matrix by a type A method.

FIG. 90 is a diagram for explaining a parity check matrix by a type B method.

FIG. 91 is a diagram for explaining a parity check matrix by a type B method.

FIG. 92 is a diagram illustrating an example of coordinates of signal points of UC in a case where a modulation method is QPSK.

FIG. 93 is a diagram illustrating an example of coordinates of signal points of a 2D-NUC in a case where a modulation method is 16QAM.

FIG. 94 is a diagram illustrating an example of coordinates of signal points of 1D-NUC in a case where a modulation method is 1024QAM.

FIG. 95 is a diagram illustrating a relationship between a symbol y of 1024QAM and a position vector u.

FIG. 96 is a diagram illustrating examples of coordinates z_{q} of a signal point of QPSK-UC.

FIG. 97 is a diagram illustrating examples of coordinates z_{q} of a signal point of QPSK-UC.

FIG. 98 is a diagram illustrating examples of coordinates z_{q} of a signal point of 16QAM-UC.

FIG. 99 is a diagram illustrating examples of coordinates z_{q} of a signal point of 16QAM-UC.

FIG. 100 is a diagram illustrating examples of coordinates z_{q} of signal points of 64QAM-UC.

FIG. 101 is a diagram illustrating examples of coordinates z_{q} of signal points of 64QAM-UC.

FIG. 102 is a diagram illustrating examples of coordinates z_{q} of signal points of 256QAM-UC.

FIG. 103 is a diagram illustrating examples of coordinates z_{q} of signal points of 256QAM-UC.

FIG. 104 is a diagram illustrating examples of coordinates z_{q} of signal points of 1024QAM-UC.

FIG. 105 is a diagram illustrating examples of coordinates z_{q} of signal points of 1024QAM-UC.

FIG. 106 is a diagram illustrating examples of coordinates z_{q} of signal points of 4096QAM-UC.

FIG. 107 is a diagram illustrating examples of coordinates z_{q} of signal points of 4096QAM-UC.

FIG. 108 is a diagram illustrating examples of coordinates zₛ of signal points of 16QAM-2D-NUC.

FIG. 109 is a diagram illustrating examples of coordinates zₛ of signal points of 64QAM-2D-NUC.

FIG. 110 is a diagram illustrating examples of coordinates zₛ of signal points of 256QAM-2D-NUC.

FIG. 111 is a diagram illustrating examples of coordinates zₛ of signal points of 256QAM-2D-NUC.

FIG. 112 is a diagram illustrating examples of coordinates zₛ of signal points of 1024QAM-1D-NUC.

FIG. 113 is a diagram illustrating a relationship between a symbol y of 1024QAM and a position vector u.

FIG. 114 is a diagram illustrating examples of coordinates zₛ of signal points of 4096QAM-1D-NUC.

FIG. 115 is a diagram illustrating a relationship between a symbol y of 4096QAM and a position vector u.

FIG. 116 is a diagram illustrating a relationship between a symbol y of 4096QAM and a position vector u.

FIG. 117 is a diagram for explaining block interleaving performed by a block interleaver 25.

FIG. 118 is a diagram for explaining block interleaving performed by the block interleaver 25.

FIG. 119 is a diagram for explaining group-wise interleaving performed by a group-wise interleaver 24.

FIG. 120 is a diagram illustrating a first example of a GW pattern for an LDPC code with a code length N of 69120 bits.

FIG. 121 is a diagram illustrating a second example of the GW pattern for the LDPC code with a code length N of 69120 bits.

FIG. 122 is a diagram illustrating a third example of the GW pattern for the LDPC code with a code length N of 69120 bits.

FIG. 123 is a diagram illustrating a fourth example of the GW pattern for the LDPC code with a code length N of 69120 bits.

FIG. 124 is a diagram illustrating a fifth example of the GW pattern for the LDPC code with a code length N of 69120 bits.

FIG. 125 is a diagram illustrating a sixth example of the GW pattern for the LDPC code with a code length N of 69120 bits.

FIG. 126 is a diagram illustrating a seventh example of the GW pattern for the LDPC code with a code length N of 69120 bits.

FIG. 127 is a diagram illustrating an eighth example of the GW pattern for the LDPC code with a code length N of 69120 bits.

FIG. 128 is a diagram illustrating a ninth example of the GW pattern for the LDPC code with a code length N of 69120 bits.

FIG. 129 is a diagram illustrating a tenth example of the GW pattern for the LDPC code with a code length N of 69120 bits.

FIG. 130 is a diagram illustrating an eleventh example of the GW pattern for the LDPC code with a code length N of 69120 bits.

FIG. 131 is a diagram illustrating a twelfth example of the GW pattern for the LDPC code with a code length N of 69120 bits.

FIG. 132 is a diagram illustrating a thirteenth example of the GW pattern for the LDPC code with a code length N of 69120 bits.

FIG. 133 is a diagram illustrating a fourteenth example of the GW pattern for the LDPC code with a code length N of 69120 bits.

FIG. 134 is a diagram illustrating a fifteenth example of the GW pattern for the LDPC code with a code length N of 69120 bits.

FIG. 135 is a diagram illustrating a sixteenth example of the GW pattern for the LDPC code with a code length N of 69120 bits.

FIG. 136 is a diagram illustrating a seventeenth example of the GW pattern for the LDPC code with a code length N of 69120 bits.

FIG. 137 is a diagram illustrating an eighteenth example of the GW pattern for the LDPC code with a code length N of 69120 bits.

FIG. 138 is a diagram illustrating a nineteenth example of the GW pattern for the LDPC code with a code length N of 69120 bits.

FIG. 139 is a diagram illustrating a twentieth example of the GW pattern for the LDPC code with a code length N of 69120 bits.

FIG. 140 is a diagram illustrating a twenty first example of the GW pattern for the LDPC code with a code length N of 69120 bits.

FIG. 141 is a diagram illustrating a twenty second example of the GW pattern for the LDPC code with a code length N of 69120 bits.

FIG. 142 is a diagram illustrating a twenty third example of the GW pattern for the LDPC code with a code length N of 69120 bits.

FIG. 143 is a diagram illustrating a twenty fourth example of the GW pattern for the LDPC code with a code length N of 69120 bits.

FIG. 144 is a diagram illustrating a twenty fifth example of the GW pattern for the LDPC code with a code length N of 69120 bits.

FIG. 145 is a diagram illustrating a twenty sixth example of the GW pattern for the LDPC code with a code length N of 69120 bits.

FIG. 146 is a diagram illustrating a twenty seventh example of the GW pattern for the LDPC code with a code length N of 69120 bits.

FIG. 147 is a diagram illustrating a twenty eighth example of the GW pattern for the LDPC code with a code length N of 69120 bits.

FIG. 148 is a diagram illustrating a twenty ninth example of the GW pattern for the LDPC code with a code length N of 69120 bits.

FIG. 149 is a diagram illustrating a thirtieth example of the GW pattern for the LDPC code with a code length N of 69120 bits.

FIG. 150 is a diagram illustrating a thirty first example of the GW pattern for the LDPC code with a code length N of 69120 bits.

FIG. 151 is a diagram illustrating a thirty second example of the GW pattern for the LDPC code with a code length N of 69120 bits.

FIG. 152 is a diagram illustrating a thirty third example of the GW pattern for the LDPC code with a code length N of 69120 bits.

FIG. 153 is a diagram illustrating a thirty fourth example of the GW pattern for the LDPC code with a code length N of 69120 bits.

FIG. 154 is a diagram illustrating a thirty fifth example of the GW pattern for the LDPC code with a code length N of 69120 bits.

FIG. 155 is a diagram illustrating a thirty sixth example of the GW pattern for the LDPC code with a code length N of 69120 bits.

FIG. 156 is a diagram illustrating a thirty seventh example of the GW pattern for the LDPC code with a code length N of 69120 bits.

FIG. 157 is a diagram illustrating a thirty eighth example of the GW pattern for the LDPC code with a code length N of 69120 bits.

FIG. 158 is a diagram illustrating a thirty ninth example of the GW pattern for the LDPC code with a code length N of 69120 bits.

FIG. 159 is a diagram illustrating a fortieth example of the GW pattern for the LDPC code with a code length N of 69120 bits.

FIG. 160 is a diagram illustrating a forty first example of the GW pattern for the LDPC code with a code length N of 69120 bits.

FIG. 161 is a diagram illustrating a forty second example of the GW pattern for the LDPC code with a code length N of 69120 bits.

FIG. 162 is a diagram illustrating a forty third example of the GW pattern for the LDPC code with a code length N of 69120 bits.

FIG. 163 is a diagram illustrating a forty fourth example of the GW pattern for the LDPC code with a code length N of 69120 bits.

FIG. 164 is a diagram illustrating a forty fifth example of the GW pattern for the LDPC code with a code length N of 69120 bits.

FIG. 165 is a diagram illustrating a forty sixth example of the GW pattern for the LDPC code with a code length N of 69120 bits.

FIG. 166 is a diagram illustrating a forty seventh example of the GW pattern for the LDPC code with a code length N of 69120 bits.

FIG. 167 is a diagram illustrating a forty eighth example of the GW pattern for the LDPC code with a code length N of 69120 bits.

FIG. 168 is a diagram illustrating a forty ninth example of the GW pattern for the LDPC code with a code length N of 69120 bits.

FIG. 169 is a diagram illustrating a fiftieth example of the GW pattern for the LDPC code with a code length N of 69120 bits.

FIG. 170 is a diagram illustrating a fifty first example of the GW pattern for the LDPC code with a code length N of 69120 bits.

FIG. 171 is a diagram illustrating a fifty second example of the GW pattern for the LDPC code with a code length N of 69120 bits.

FIG. 172 is a diagram illustrating a fifty third example of the GW pattern for the LDPC code with a code length N of 69120 bits.

FIG. 173 is a diagram illustrating a fifty fourth example of the GW pattern for the LDPC code with a code length N of 69120 bits.

FIG. 174 is a diagram illustrating a fifty fifth example of the GW pattern for the LDPC code with a code length N of 69120 bits.

FIG. 175 is a diagram illustrating a fifty sixth example of the GW pattern for the LDPC code with a code length N of 69120 bits.

FIG. 176 is a diagram illustrating a fifty seventh example of the GW pattern for the LDPC code with a code length N of 69120 bits.

FIG. 177 is a diagram illustrating a fifty eighth example of the GW pattern for the LDPC code with a code length N of 69120 bits.

FIG. 178 is a diagram illustrating a fifty ninth example of the GW pattern for the LDPC code with a code length N of 69120 bits.

FIG. 179 is a diagram illustrating a sixtieth example of the GW pattern for the LDPC code with a code length N of 69120 bits.

FIG. 180 is a diagram illustrating a sixty first example of the GW pattern for the LDPC code with a code length N of 69120 bits.

FIG. 181 is a diagram illustrating a sixty second example of the GW pattern for the LDPC code with a code length N of 69120 bits.

FIG. 182 is a diagram illustrating a sixty third example of the GW pattern for the LDPC code with a code length N of 69120 bits.

FIG. 183 is a diagram illustrating a sixty fourth example of the GW pattern for the LDPC code with a code length N of 69120 bits.

FIG. 184 is a diagram illustrating a sixty fifth example of the GW pattern for the LDPC code with a code length N of 69120 bits.

FIG. 185 is a diagram illustrating a sixty sixth example of the GW pattern for the LDPC code with a code length N of 69120 bits.

FIG. 186 is a diagram illustrating a sixty seventh example of the GW pattern for an LDPC code with a code length N of 69120 bits.

FIG. 187 is a diagram illustrating a sixty eighth example of the GW pattern for the LDPC code with a code length N of 69120 bits.

FIG. 188 is a diagram illustrating a sixty ninth example of the GW pattern for the LDPC code with a code length N of 69120 bits.

FIG. 189 is a diagram illustrating a seventieth example of the GW pattern for the LDPC code with a code length N of 69120 bits.

FIG. 190 is a diagram illustrating a seventy first example of the GW pattern for the LDPC code with a code length N of 69120 bits.

FIG. 191 is a diagram illustrating a seventy second example of the GW pattern for the LDPC code with a code length N of 69120 bits.

FIG. 192 is a diagram illustrating a seventy third example of the GW pattern for the LDPC code with a code length N of 69120 bits.

FIG. 193 is a diagram illustrating a seventy fourth example of the GW pattern for the LDPC code with a code length N of 69120 bits.

FIG. 194 is a diagram illustrating a seventy fifth example of the GW pattern for the LDPC code with a code length N of 69120 bits.

FIG. 195 is a diagram illustrating a seventy sixth example of the GW pattern for the LDPC code with a code length N of 69120 bits.

FIG. 196 is a diagram illustrating a seventy seventh example of the GW pattern for the LDPC code with a code length N of 69120 bits.

FIG. 197 is a diagram illustrating a seventy eighth example of the GW pattern for the LDPC code with a code length N of 69120 bits.

FIG. 198 is a diagram illustrating examples of coordinates of signal points of another 16QAM-2D-NUC that can be used for a new LDPC code.

FIG. 199 is a diagram illustrating a simulation result of BER of a type A code with a code length N of 69120 bits and r=4/16.

FIG. 200 is a diagram illustrating a simulation result of a required carrier-to-noise ratio (CNR) of a type A code with a code length N of 69120 bits and r=4/16.

FIG. 201 is a diagram illustrating a seventy ninth example of the GW pattern for the LDPC code with a code length N of 69120 bits.

FIG. 202 is a diagram illustrating a simulation result of BER of a combination of a type A code with a code length N of 69120 bits and r=4/16, 16QAM, new 16QAM-2D-NUC, and a new GW pattern.

FIG. 203 is a diagram illustrating a simulation result of required CNR of a combination of a type A code with a code length N of 69120 bits and r=4/16, 16QAM, new 16QAM-2D-NUC, and a new GW pattern.

FIG. 204 is a block diagram illustrating a configuration example of a reception device 12.

FIG. 205 is a block diagram illustrating a configuration example of a bit deinterleaver 165.

FIG. 206 is a flowchart illustrating an example of processing performed by a demapper 164, the bit deinterleaver 165, and an LDPC decoder 166.

FIG. 207 is a diagram illustrating an example of a parity check matrix of an LDPC code.

FIG. 208 is a diagram illustrating an example of a matrix (transformed parity check matrix) obtained by applying row permutation and column permutation to a parity check matrix.

FIG. 209 is a diagram illustrating an example of a transformed parity check matrix divided into 5×5 units.

FIG. 210 is a block diagram illustrating a configuration example of a decoding device that collectively performs P node operations.

FIG. 211 is a block diagram illustrating a configuration example of the LDPC decoder 166.

FIG. 212 is a diagram illustrating block deinterleaving performed by a block deinterleaver 54.

FIG. 213 is a block diagram illustrating another configuration example of the bit deinterleaver 165.

FIG. 214 is a block diagram illustrating a first configuration example of a reception system to which the reception device 12 is applicable.

FIG. 215 is a block diagram illustrating a second configuration example of a reception system to which the reception device 12 can be applied.

FIG. 216 is a block diagram illustrating a third configuration example of a reception system to which the reception device 12 is applicable.

FIG. 217 is a block diagram illustrating a configuration example of an embodiment of a computer to which the present technology is applied.

### MODE FOR CARRYING OUT THE INVENTION

Hereinafter, an embodiment of the present technology will be described, and before that, an LDPC code will be described.

### <Ldpc Code>

Note that the LDPC code is a linear code and does not necessarily have to be binary, but will be described here assuming that it is binary.

The largest feature of the LDPC code is that a parity check matrix defining the LDPC code is sparse. Here, the sparse matrix is a matrix in which the number of “1” elements of the matrix is very small (a matrix in which most elements are 0).

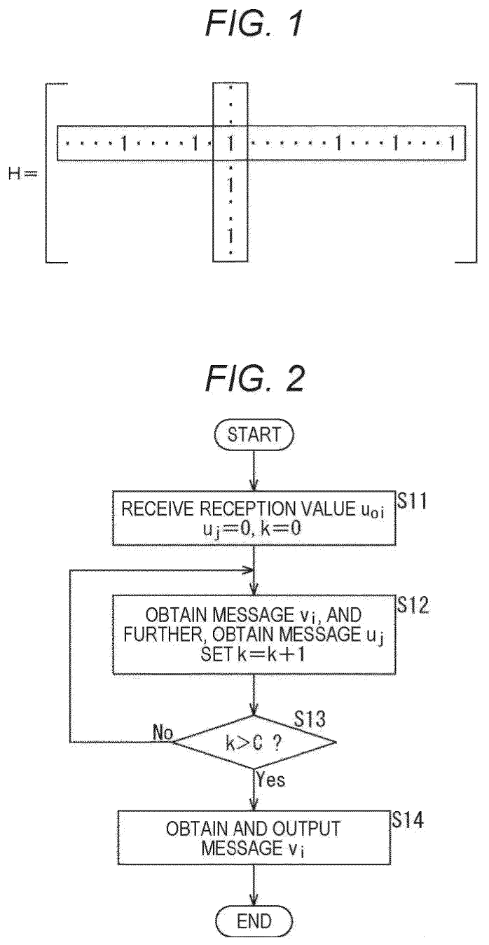

FIG. 1 is a diagram illustrating an example of a parity check matrix H of an LDPC code.

In the parity check matrix H in FIG. 1, the weight (column weight) (the number of “1”) (weight) of each column is “3”, and the weight (row weight) of each row is “6”.

In encoding with an LDPC code (LDPC encoding), for example, a code word (LDPC code) is generated by generating a generator matrix G on the basis of a parity check matrix H and multiplying binary information bits by the generator matrix G.

Specifically, the encoding device that performs LDPC encoding first calculates the generator matrix G in which the equation GH^{T}=0 holds between a transposed matrix H^{T} of the parity check matrix H and the generator matrix G. Here, in a case where the generator matrix G is a K×N matrix, the encoding device multiplies the generator matrix G by a bit string (vector u) of K-bit information bits to generate a code word c (=uG) of N bits. The code word (LDPC code) generated by the encoding device is received on a reception side via a predetermined communication path.

The LDPC code can be decoded by an algorithm called probabilistic decoding proposed by Gallager, that is, a message passing algorithm based on belief propagation on a so-called Tanner graph including a variable node (variable node (also referred to as a message node)) and a check node. Hereinafter, the variable node and the check node are also simply referred to as nodes as appropriate.

FIG. 2 is a flowchart illustrating a procedure of decoding the LDPC code.

Note that, hereinafter, a real value (reception LLR) obtained by expressing the “0” likeliness of the value of the i-th sign bit of the LDPC code (one code word) received on the reception side by a log likelihood ratio is also referred to as a reception value u₀₁ as appropriate. Furthermore, a message output from the check node is uⱼ, and a message output from the variable node is vᵢ.

First, in the decoding of the LDPC code, as illustrated in FIG. 2, in step S11, the LDPC code is received, a message (check node message) uⱼ is initialized to “0”, a variable k that takes an integer as a counter for the repetitive processing is initialized to “0”, and the process proceeds to step S12. In step S12, the message (variable node message) vᵢ is obtained by performing the operation (variable node operation) shown in Formula (1) on the basis of the reception value u₀₁ obtained by receiving the LDPC code, and further, the message uⱼ is obtained by performing the operation (check node operation) shown in Formula (2) on the basis of the message vᵢ.

$$\begin{matrix}[ Mathematical formula 1 ] & \\ {v}_{i} = {u}_{0 i} + {\sum }_{j = 1}^{{d}_{v} - 1} {u}_{j} & ( 1 )\end{matrix}$$

$$\begin{matrix}[ Mathematical formula 2 ] & \\ tanh ( \frac{{u}_{j}}{2} ) = {\prod }_{i = 1}^{{d}_{c} - 1} tanh ( \frac{{v}_{i}}{2} ) & ( 2 )\end{matrix}$$

Here, dᵥ and d_{c} in Formulas (1) and (2) are arbitrarily selectable parameters indicating the number of “1” in the vertical direction (column) and the horizontal direction (row) of the parity check matrix H, respectively. For example, in the case of the LDPC code ((3, 6) LDPC code) for the parity check matrix H with the column weight of 3 and the row weight of 6 as illustrated in FIG. 1, dᵥ=3 and d_{c}=6.

Note that, in each of the variable node calculation of Formula (1) and the check node calculation of Formula (2), a message input from an edge (line connecting the variable node and the check node) that is intended to output a message is not an object of calculation, and thus, the range of calculation is 1 to dᵥ−1 or 1 to d_{c}−1. Furthermore, the check node calculation of Formula (2) is actually performed by creating a table of the function R (v₁, v₂) shown in Formula (3) defined by one output for two inputs v₁ and v₂ in advance and continuously (recursively) using the table as shown in Formula (4).

$$\begin{matrix}[ Mathematical formula 3 ] & \\ x = 2 {tanh}^{- 1} \{ tanh ( {v}_{1} / 2 ) tanh ( {v}_{2} / 2 ) \} = R ( {v}_{1} , {v}_{2} ) & ( 3 )\end{matrix}$$

$$\begin{matrix}[ Mathematical formula 4 ] & \\ {u}_{j} = R ( {v}_{1} , R ( {v}_{2} , R ( {v}_{3} , … R ( {v}_{{d}_{c} - 2} , {v}_{{d}_{c} - 1} ) ) ) ) & ( 4 )\end{matrix}$$

In step S12, the variable k is further incremented by “1”, and the process proceeds to step S13. In step S13, it is determined whether or not the variable k is larger than a predetermined number of iterative decoding operations C. In a case where it is determined in step S13 that the variable k is not larger than C, the processing returns to step S12, and the similar processing is repeated thereafter.

Furthermore, in a case where it is determined in step S13 that the variable k is larger than C, the process proceeds to step S14, and the message vᵢ as the decoding result to be finally output is obtained and output by performing the operation shown in Formula (5), and the decoding processing of the LDPC code ends.

$$\begin{matrix}[ Mathematical formula 5 ] & \\ {v}_{i} = {u}_{0 i} + {\sum }_{j = 1}^{{d}_{v}} {u}_{j} & ( 5 )\end{matrix}$$

Here, unlike the variable node operation of Formula (1), the operation of Formula (5) is performed using messages uⱼ from all the edges connected to the variable node.

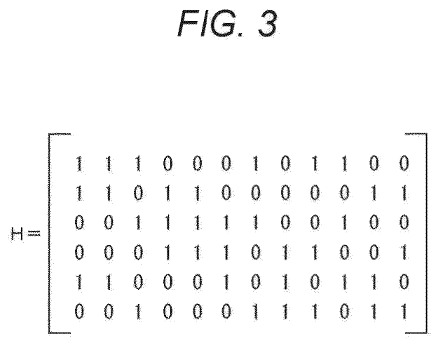

FIG. 3 is a diagram illustrating an example of a parity check matrix H of a (3, 6)LDPC code (coding rate 1/2, code length 12).

In the parity check matrix H in FIG. 3, similar to FIG. 1, the weight of the column is 3 and the weight of the row is 6.

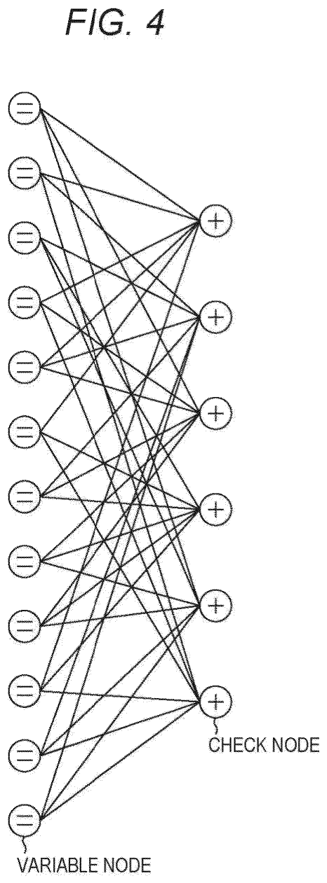

FIG. 4 is a diagram illustrating a Tanner graph of the parity check matrix H in FIG. 3.

Here, in FIG. 4, a check node is represented by plus “+”, and a variable node is represented by equal “=”. The check node and the variable node correspond to the rows and columns of the parity check matrix H, respectively. The connection between the check node and the variable node is an edge and corresponds to the “1” of the elements of the parity check matrix.

That is, in a case where the element of the j-th row and the i-th column of the parity check matrix is 1, the i-th variable node (node of “=”) from the top and the j-th check node (node of “+”) from the top are connected by the edge in FIG. 4. The edge indicates that the sign bit corresponding to the variable node has a constraint condition corresponding to the check node.

In a sum product algorithm which is a decoding method of an LDPC code, a variable node operation and a check node operation are repeatedly performed.

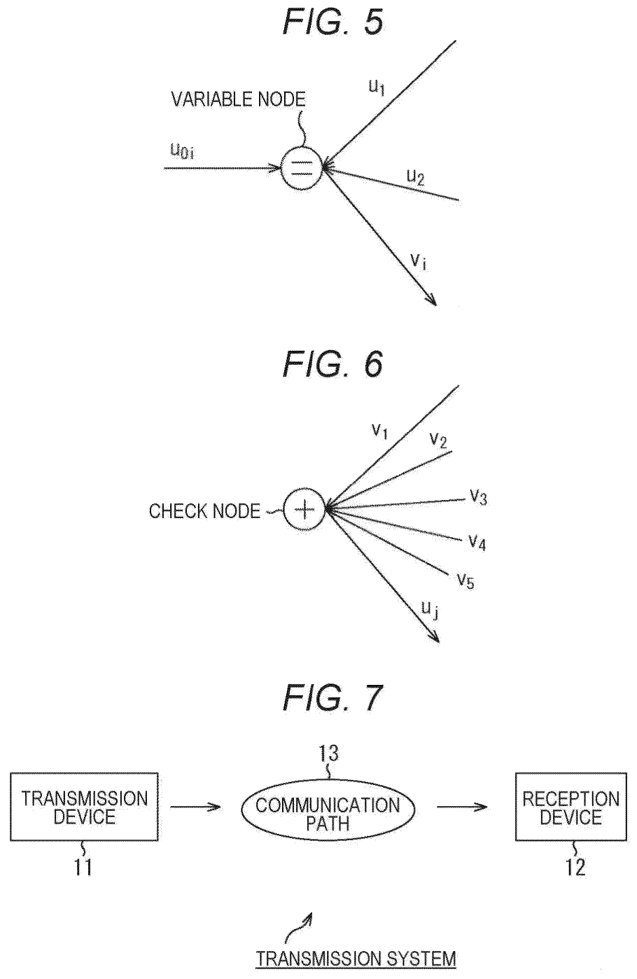

FIG. 5 is a diagram illustrating a variable node operation performed in a variable node.

In the variable node, the message vᵢ corresponding to the edge to be calculated is obtained by the variable node operation of Formula (1) using the messages u₁ and u₂ from the remaining edges connected to the variable node and the reception value u₀₁. Messages corresponding to other edges are similarly obtained.

FIG. 6 is a diagram illustrating a check node operation performed in the check node.

Here, the check node operation of Formula (2) can be rewritten into Formula (6) using a relationship of an equation a×b=exp{ln(|a|)+ln(|b|)}×sign(a)×sign(b). Note that sign(x) is 1 when x≥0, and is −1 when x<0.

$$\begin{matrix}[ Mathematical formula 6 ] & \\ \begin{matrix}{u}_{j} = 2 {tanh}^{- 1} ( {\prod }_{i = 1}^{{d}_{c} - 1} tanh ( \frac{{v}_{i}}{2} ) ) \\ = 2 {tanh}^{- 1} [ exp \{ {\sum }_{i = 1}^{{d}_{c} - 1} ln ( \vert tanh ( \frac{{v}_{i}}{2} ) \vert ) \} \times {\prod }_{i = 1}^{{d}_{c} - 1} sign ( tanh ( \frac{{v}_{i}}{2} ) ) ] \\ = 2 {tanh}^{- 1} [ exp \{ - ( {\sum }_{i = 1}^{{d}_{c} - 1} - ln ( tanh ( \frac{\vert {v}_{i} \vert}{2} ) ) ) \} ] \times {\prod }_{i = 1}^{{d}_{c} - 1} sign ( {v}_{i} )\end{matrix} & ( 6 )\end{matrix}$$

When the function φ(x) is defined as an equation φ(x)=ln(tanh(x/2)) in x≥0, an equation φ⁻¹(x)=2tanh⁻¹(e^{-x}) holds, and thus Formula (6) can be transformed into Formula (7).

$$\begin{matrix}[ Mathematical formula 7 ] & \\ {u}_{j} = {ϕ}^{- 1} ( {\sum }_{i = 1}^{{d}_{c} - 1} ϕ ( \vert {v}_{i} \vert ) ) \times {\prod }_{i = 1}^{{d}_{c} - 1} sign ( {v}_{i} ) & ( 7 )\end{matrix}$$

In the check node, the check node operation of Formula (2) is performed according to Formula (7).

That is, in the check node, as illustrated in FIG. 6, the message uⱼ corresponding to the edge to be calculated is obtained by the check node operation of Formula (7) using the messages v₁, v₂, v₃, v₄, and v₅ from the remaining edges connected to the check node. Messages corresponding to other edges are similarly obtained.

Note that the function φ(x) of Formula (7) can be expressed by an equation φ(x)=ln((e^{x}+1)/(e^{x}−1)), and when x>0, φ(x)=φ⁻¹(x). When the functions φ(x) and φ⁻¹(x) are implemented in hardware, there is a case where the functions φ(x) and φ⁻¹(x) are implemented using a look up table (LUT), and both functions φ(x) and φ⁻¹(x) are the same LUT.

<Configuration Example of Transmission System to which Present Technology is Applied>

FIG. 7 is a diagram illustrating a configuration example of an embodiment of a transmission system (The system refers to a logical assembly of a plurality of devices, and it does not matter whether or not the devices of each configuration are in the same housing.) to which the present technology is applied.

In FIG. 7, the transmission system includes a transmission device 11 and a reception device 12.

The transmission device 11 transmits (broadcasts) (transmits) a television broadcast program or the like, for example. That is, the transmission device 11 encodes target data to be transmitted, such as image data or audio data as a program, into an LDPC code, and transmits the LDPC code via the communication path 13 such as a satellite line, a ground wave, or a cable (wired line).

The reception device 12 receives the LDPC code transmitted from the transmission device 11 via the communication path 13, decodes the LDPC code into target data, and outputs the target data.

Here, it is known that the LDPC code used in the transmission system in FIG. 7 exhibits extremely high capability in an additive white Gaussian noise (AWGN) communication path.

On the other hand, in the communication path 13, a burst error or an erasure may occur. For example, particularly in a case where the communication path 13 is a terrestrial channel, in an orthogonal frequency division multiplexing (OFDM) system, in a multipath environment in which a desired to undesired ratio (D/U) is 0 dB (power of undesired=echo is equal to power of desired=main path), power of a specific symbol may become 0 (erasure) according to a delay of an echo (path other than the main path).

Furthermore, even in a flutter (a communication path in which a delay is 0 and an echo with a Doppler frequency is added), in a case where D/U is 0 dB, the power of the entire OFDM symbol at a specific time may become 0 (erasure) depending on the Doppler frequency.

Moreover, a burst error may occur due to a wiring condition from a reception unit (not illustrated) such as an antenna that receives a signal from the transmission device 11 on a side of the reception device 12 to the reception device 12 or instability of a power supply of the reception device 12.

On the other hand, in the decoding of the LDPC code, the variable node operation of Formula (1) involving the addition of (the reception value u₀₁ of) the sign bit of the LDPC code is performed in the column of the parity check matrix H, and thus, in the variable node corresponding to the sign bit of the LDPC code, as illustrated in FIG. 5. Therefore, if an error occurs in the sign bit used for the variable node operation, the accuracy of the obtained message decreases.

Then, in the decoding of the LDPC code, the check node calculation of Formula (7) is performed in the check node using the message obtained in the variable node connected to the check node. Therefore, if the number of check nodes in which (the sign bits of the LDPC code corresponding to) the plurality of connected variable nodes become errors (including erasures) at the same time increases, the performance of the decoding deteriorates.

That is, for example, when two or more of the variable nodes connected to the check node become erasures at the same time, the check node returns a message indicating that the probability of the value being 0 and the probability of the value being 1 are equal to each other to all the variable nodes. In this case, the check node that returns the message of equal probability does not contribute to one decoding process (one set of variable node operation and check node operation), and as a result, a large number of repetitions of the decoding process are required, so that the performance of decoding is deteriorated, and further, the power consumption of the reception device 12 that decodes the LDPC code is increased.

Therefore, in the transmission system in FIG. 7, it is possible to improve resistance to burst errors and erasures while maintaining performance in the AWGN communication path (AWGN channel).

### <Configuration Example of Transmission Device 11>

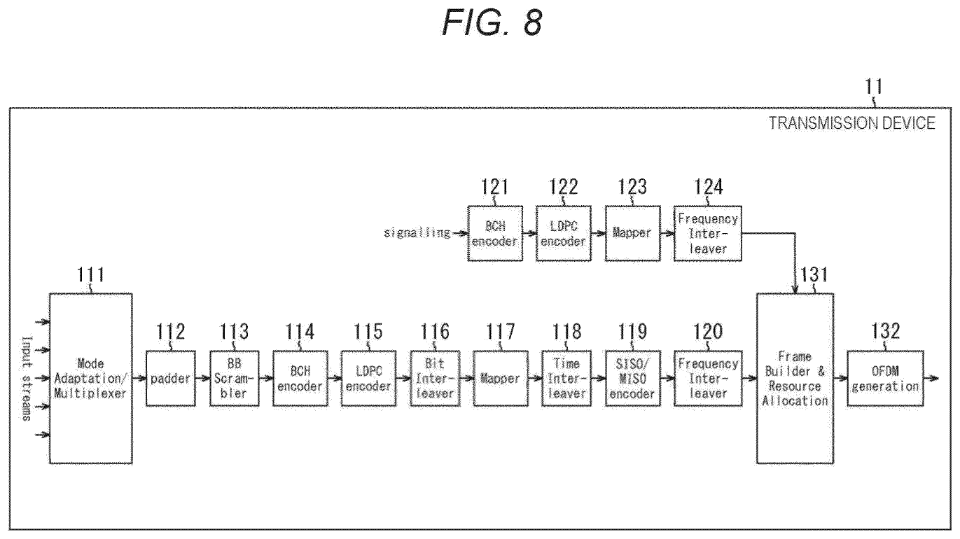

FIG. 8 is a block diagram illustrating a configuration example of the transmission device 11 in FIG. 7.

In the transmission device 11, one or more input streams as target data are supplied to a mode adaptation/multiplexer 111.

The mode adaptation/multiplexer 111 performs processing such as mode selection and multiplexing of one or more input streams supplied thereto as necessary, and supplies resulting data to a padder 112.

The padder 112 performs necessary 0 padding (insertion of Null) on the data from the mode adaptation/multiplexer 111, and supplies resulting data to a BB scrambler 113.

The BB scrambler 113 performs BB scrambling on the data from the padder 112, and supplies resulting data to a BCH encoder 114.

The BCH encoder 114 performs BCH encoding on the data from the BB scrambler 113, and supplies resulting data to an LDPC encoder 115 as LDPC target data to be subjected to LDPC encoding.

The LDPC encoder 115 performs, for the LDPC target data from the BCH encoder 114, LDPC coding for example according to a parity check matrix in which a parity matrix that is a portion corresponding to parity bits of the LDPC code has a staircase (dual diagonal) structure, and outputs an LDPC code having the LDPC target data as information bits.

That is, the LDPC encoder 115 performs LDPC coding for coding the LDPC target data into an LDPC code (corresponding to a parity check matrix) defined in a predetermined standard such as DVB-S.2, DVB-T.2, DVB-C.2, or ATSC3.0, or another LDPC code, and outputs a resulting LDPC code.

Here, the LDPC code defined in the DVB-S.2 or ATSC3.0 standard and the LDPC code to be adopted in ATSC3.0 are irregular repeat accumulate (IRA) codes, and (a part or all of) the parity matrix in the parity check matrix of the LDPC code has a staircase structure. The parity matrix and the staircase structure will be described later. Furthermore, the IRA code is described in, for example, “Irregular Repeat-Accumulate Codes”, H. Jin, A. Khandekar, and R. J. McEliece, in Proceedings of 2nd International Symposium on Turbo codes and Related Topics, pp. 1-8, September 2000.

The LDPC code output from the LDPC encoder 115 is supplied to a bit interleaver 116.

The bit interleaver 116 performs bit interleaving as described later on the LDPC code supplied from the LDPC encoder 115, and supplies the LDPC code after the bit interleaving to a mapper 117.

The mapper 117 performs orthogonal modulation (multi-level modulation) by mapping the LDPC code from the bit interleaver 116 to a signal point representing one symbol of orthogonal modulation in units of one or more sign bits (symbol units) of the LDPC code.

That is, the mapper 117 performs quadrature modulation by mapping the LDPC code from the bit interleaver 116 to a signal point determined by a modulation method for performing quadrature modulation of the LDPC code on a constellation that is an IQ plane defined by an I axis representing an I component in phase with the carrier wave and a Q axis representing a Q component orthogonal to the carrier wave.

In a case where the number of constellation signal points used in the modulation method of the quadrature modulation performed by the mapper 117 is 2^{m}, the mapper 117 maps the LDPC code from the bit interleaver 116 to a signal point representing a symbol among 2^{m} signal points in units of symbols, using the m-bit sign bit of the LDPC code as a symbol (1 symbol).

Here, examples of the modulation method of the quadrature modulation performed by the mapper 117 include modulation methods defined in the DVB-S.2 standard, the ATSC3.0 standard, and the like, and other modulation methods, that is, for example, binary phase shift keying (BPSK), quadrature phase shift keying (QPSK), 8 phase-shift keying (PSK), amplitude phase-shift keying (16APSK), 32APSK, 16 quadrature amplitude modulation (QAM), 16QAM, 64QAM, 256QAM, 1024QAM, 4096QAM, 4 pulse amplitude modulation (PAM), and the like. Which modulation scheme is used for quadrature modulation in the mapper 117 is set in advance according to, for example, an operation and the like of an operator of the transmission device 11.

Data (a mapping result obtained by mapping symbols to signal points) obtained by the processing in the mapper 117 is supplied to a time interleaver 118.

The time interleaver 118 performs time interleaving (interleaving in the time direction) in units of symbols for the data from the mapper 117, and supplies resulting data to a single input single output/multiple input single output (SISO/MISO) encoder 119.

The SISO/MISO encoder 119 performs space-time coding on the data from the time interleaver 118, and supplies the resultant data to a frequency interleaver 120.

The frequency interleaver 120 performs frequency interleaving (interleaving in the frequency direction) in units of symbols for the data from the SISO/MISO encoder 119, and supplies the data to a frame builder/resource allocation unit 131.

Meanwhile, control data (signalling) for transmission control such as base band (BB) signaling (BB header) is supplied to the BCH encoder 121, for example.

The BCH encoder 121 performs BCH encoding on the control data supplied thereto similarly to the BCH encoder 114, and supplies resulting data to the LDPC encoder 122.

The LDPC encoder 122 performs LDPC coding on the data from the BCH encoder 121 as an LDPC target data similarly to the LDPC encoder 115, and supplies the resulting LDPC code to the mapper 123.

Similarly to the mapper 117, the mapper 123 performs orthogonal modulation by mapping the LDPC code from the LDPC encoder 122 to a signal point representing one symbol of the orthogonal modulation in units of one or more sign bits (symbol units) of the LDPC code, and supplies resulting data to the frequency interleaver 124.

Similarly to the frequency interleaver 120, the frequency interleaver 124 performs frequency interleaving in units of symbols for the data from the mapper 123, and supplies the data to the frame builder/resource allocation unit 131.

The frame builder/resource allocation unit 131 inserts a pilot symbol at a necessary position of the data (symbol) from the frequency interleaver 120 and the frequency interleaver 124, configures a frame (for example, a physical layer (PL) frame, a T2 frame, a C2 frame, or the like.) including a predetermined number of symbols from the resultant data (symbol), and supplies the frame to the OFDM generation unit 132.

The OFDM generation unit 132 generates an OFDM signal corresponding to the frame from the frame builder/resource allocation unit 131, and transmits the OFDM signal via the communication path 13 (FIG. 7).

Note that the transmission device 11 can be configured without providing some of the blocks illustrated in FIG. 8, such as the time interleaver 118, the SISO/MISO encoder 119, the frequency interleaver 120, and the frequency interleaver 124.

### <Configuration Example of Bit Interleaver 116>

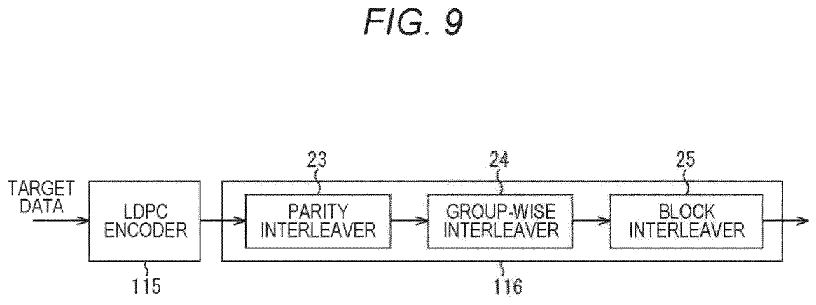

FIG. 9 is a block diagram illustrating a configuration example of the bit interleaver 116 in FIG. 8.

The bit interleaver 116 has a function of interleaving data, and includes a parity interleaver 23, a group-wise interleaver 24, and a block interleaver 25.

The parity interleaver 23 performs parity interleaving to interleave the parity bits of the LDPC code from the LDPC encoder 115 to the positions of the other parity bits, and supplies the LDPC code subjected to the parity interleaving to the group-wise interleaver 24.

The group-wise interleaver 24 performs group-wise interleaving for the LDPC code supplied from the parity interleaver 23, and supplies the LDPC code subjected to the group-wise interleaving to the block interleaver 25.

Here, in the group-wise interleaving, the LDPC code from the parity interleaver 23 is interleaved in units of bit groups, where 360 bits of one section obtained by dividing the LDPC code of one code into units of 360 bits equal to a unit size P as described later from the head thereof are set as bit groups.

In a case where group-wise interleaving is performed, an error rate can be improved as compared with a case where group-wise interleaving is not performed, and as a result, good communication quality can be ensured in data transmission.

The block interleaver 25 performs block interleaving for demultiplexing the LDPC code from the group-wise interleaver 24, thereby, for example, symbolizing the LDPC code corresponding to one code into an m-bit symbol which is a unit of mapping, and supplies the symbol to the mapper 117 (FIG. 8).

Here, in the block interleaving, for example, the LDPC code from the group-wise interleaver 24 is written in the column direction and read in the row direction in a storage area in which columns as storage areas for storing a predetermined bit length in the column (vertical) direction are arranged in the row (horizontal) direction by a length equal to the bit length m of the symbol, whereby the LDPC code is symbolized into an m-bit symbol.

### <Parity Check Matrix of LDPC Code>

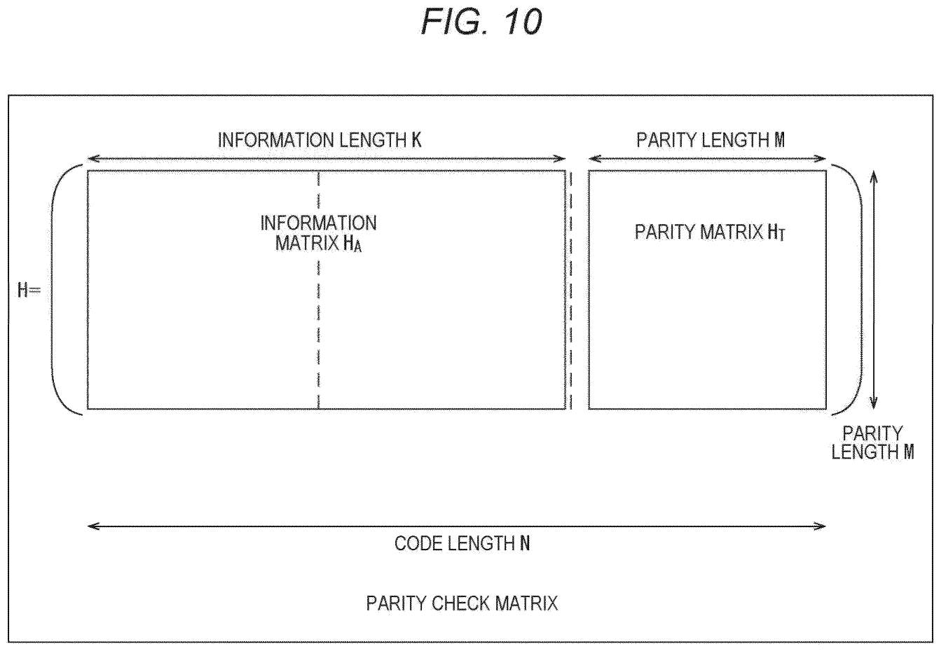

FIG. 10 is a diagram illustrating an example of a parity check matrix H used for LDPC coding in the LDPC encoder 115 in FIG. 8.

The parity check matrix H has a low-density generation matrix (LDGM) structure, and can be expressed by an equation H=[H_{A}|H_{T}] (A matrix in which elements of the information matrix H_{A} are elements on the left side and elements of the parity matrix H_{T} are elements on the right side.) by an information matrix H_{A} of a portion corresponding to the information bits and the parity matrix H_{T} corresponding to the parity bits among the sign bits of the LDPC code.

Here, the length of information bits and the length of parity bits among the sign bits of one LDPC code (one code word) are referred to as an information length K and a parity length M, respectively, and the length of sign bits of one (one code word) LDPC code is referred to as a code length N(=K+M).

An information length K and a parity length M of an LDPC code having a certain code length N are determined by a coding rate. Furthermore, the parity check matrix H is a matrix having M×N rows and columns (a matrix of M rows and N columns). Then, the information matrix H_{A} is an M×K matrix, and the parity matrix H_{T} is an M×M matrix.

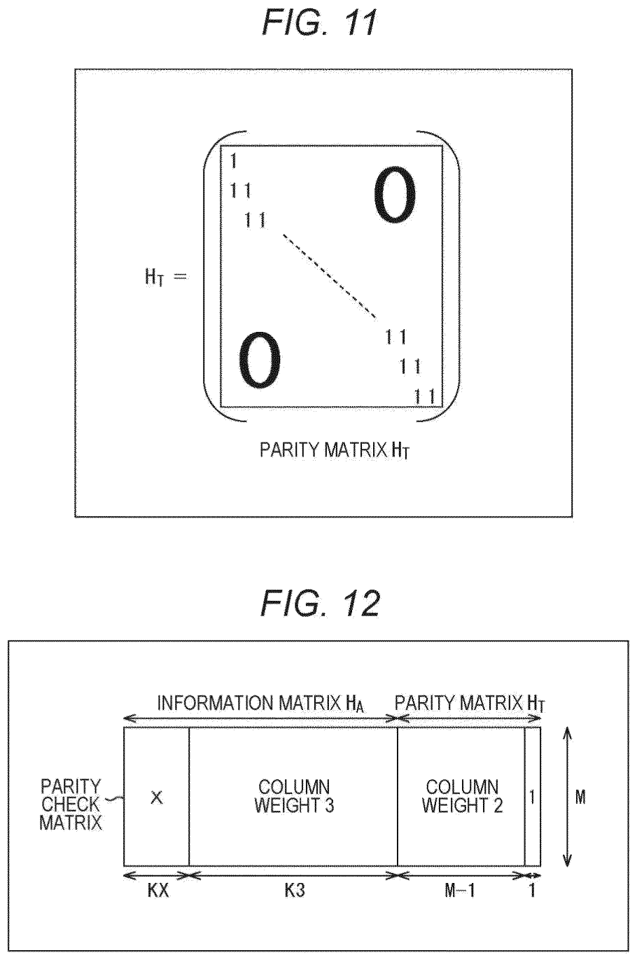

FIG. 11 is a diagram illustrating an example of the parity matrix H_{T} of the parity check matrix H used for LDPC coding in the LDPC encoder 115 in FIG. 8.

As the parity matrix H_{T} of the parity check matrix H used for the LDPC coding in the LDPC encoder 115, for example, a parity matrix H_{T} similar to the parity check matrix H of the LDPC code defined in the standard such as DVB-T.2 can be adopted.

The parity matrix H_{T} of the parity check matrix H of the LDPC code defined in the standard such as DVB-T.2 is, as illustrated in FIG. 11, a lower bidiagonal matrix having a staircase structure in which elements of 1 are arranged in a so-called step shape. The row weight of the parity matrix H_{T} is 1 for the first row and 2 for all the remaining rows. Furthermore, the column weight is 1 for the last one column and 2 for all the remaining columns.

As described above, the LDPC code of the parity check matrix H in which the parity matrix H_{T} has the staircase structure can be easily generated using the parity check matrix H.

That is, the LDPC code (one code word) is represented by a row vector c, and a column vector obtained by transposing the row vector is represented by c^{T}. Furthermore, a portion of information bits in the row vector c which is an LDPC code is represented by a row vector A, and a portion of parity bits is represented by a row vector T.

In this case, the row vector c can be expressed by an equation c=[A|T] (a row vector in which an element of the row vector A is a left element and an element of the row vector T is a right element) by the row vector A as the information bits and the row vector T as the parity bits.

the parity check matrix H and the row vector c=[A|T] as the LDPC code need to satisfy an equation Hc^{T}=0, and in a case where the parity matrix H_{T} of the parity check matrix H=[H_{A}|H_{T}] has the staircase structure illustrated in FIG. 11, the row vector T as the parity bits constituting the row vector c=[A|T] satisfying the equation Hc^{T}=0 can be sequentially (sequentially) obtained by setting the elements of each row to 0 in order from the element of the first row of the column vector Hc^{T} in the equation Hc^{T}=0.

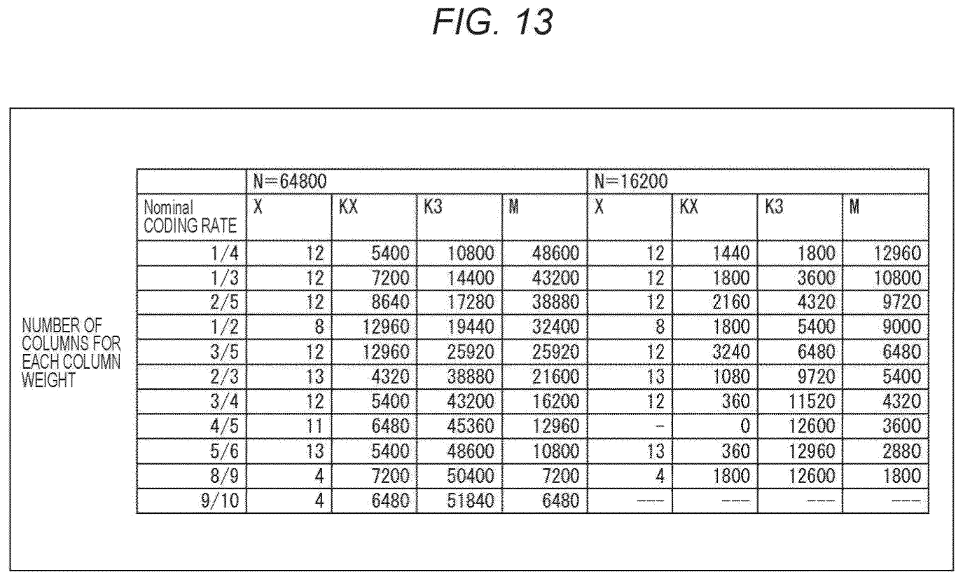

FIG. 12 is a diagram for describing a parity check matrix H of an LDPC code defined in a standard such as DVB-T.2.

For the KX columns from the 1st column of the parity check matrix H of the LDPC code defined in the standard such as DVB-T.2, the column weight is X, for the subsequent K3 columns, the column weight is 3, for the subsequent M−1 columns, the column weight is 2, and for the last one column, the column weight is 1.

Here, KX+K3+M−1+1 is equal to the code length N.

FIG. 13 is a diagram illustrating the numbers of columns KX, K3, and M and a column weight X for each coding rate r of the LDPC code defined in the standard such as DVB-T.2.

In the standard such as DVB-T.2, an LDPC code having a code length N of 64800 bits and 16200 bits is specified.

Then, 11 coding rates (nominal rates) 1/4, 1/3, 2/5, 1/2, 3/5, 2/3, 3/4, 4/5, 5/6, 8/9, and 9/10 are defined for the LDPC code with the code length N of 64800 bits, and 10 coding rates 1/4, 1/3, 2/5, 1/2, 3/5, 2/3, 3/4, 4/5, 5/6, and 8/9 are defined for the LDPC code with the code length N of 16200 bits.

Hereinafter, the code length N of 64800 bits is also referred to as 64 kbits, and the code length N of 16200 bits is also referred to as 16 kbits.

For the LDPC code, the error rate tends to be lower as the sign bit corresponds to a column having a larger column weight of the parity check matrix H.

In the parity check matrix H defined in the standard such as DVB-T.2 illustrated in FIGS. 12 and 13, the column weight tends to be larger as the column is closer to the head side (left side). Therefore, for the LDPC code corresponding to the parity check matrix H, the sign bit at the head tends to be more resistant to an error (more resistant to an error), and the sign bit at the end tends to be weaker to an error.

### <Parity Interleaving>

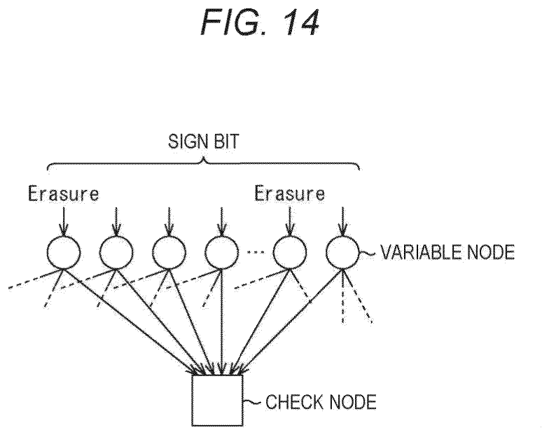

Parity interleaving by the parity interleaver 23 in FIG. 9 will be described with reference to FIGS. 14 to 16.

FIG. 14 is a diagram illustrating an example of (a part of) a Tanner graph of a parity check matrix of an LDPC code.

As illustrated in FIG. 14, when a plurality of (sign bits corresponding to) two or more variable nodes connected to the check node simultaneously becomes errors such as erasures, the check node returns a message indicating that the probability of the value being 0 and the probability of the value being 1 are equal to each other to all the variable nodes connected to the check node. Therefore, if a plurality of variable nodes connected to the same check node simultaneously becomes erasures or the like, decoding performance is degraded.

Meanwhile, the LDPC code output by the LDPC encoder 115 in FIG. 8 is an IRA code similarly to the LDPC code defined in the standard such as DVB-T.2, for example, and the parity matrix H_{T} of the parity check matrix H has a staircase structure as illustrated in FIG. 11.

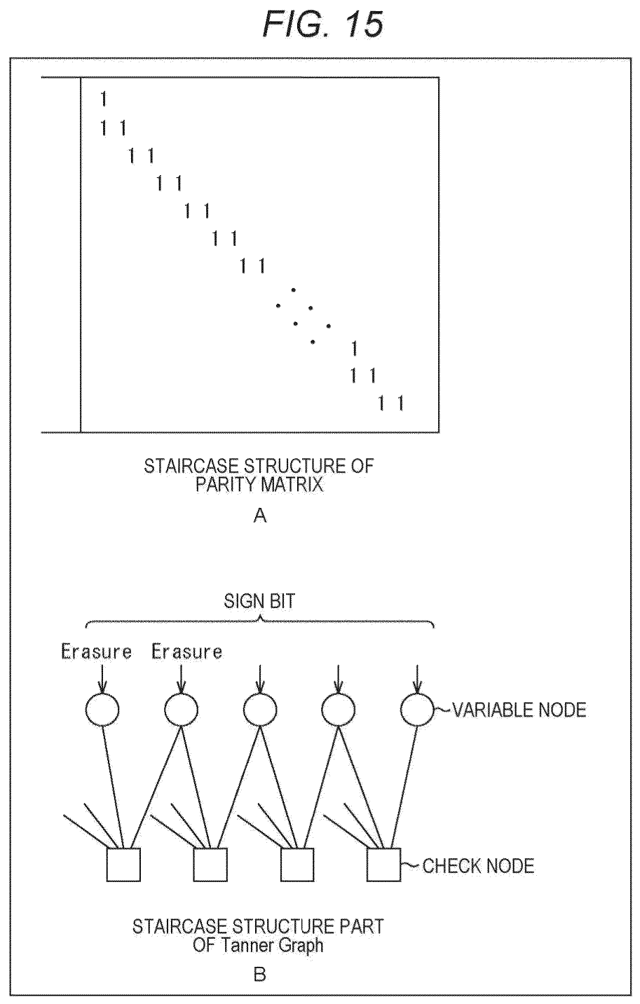

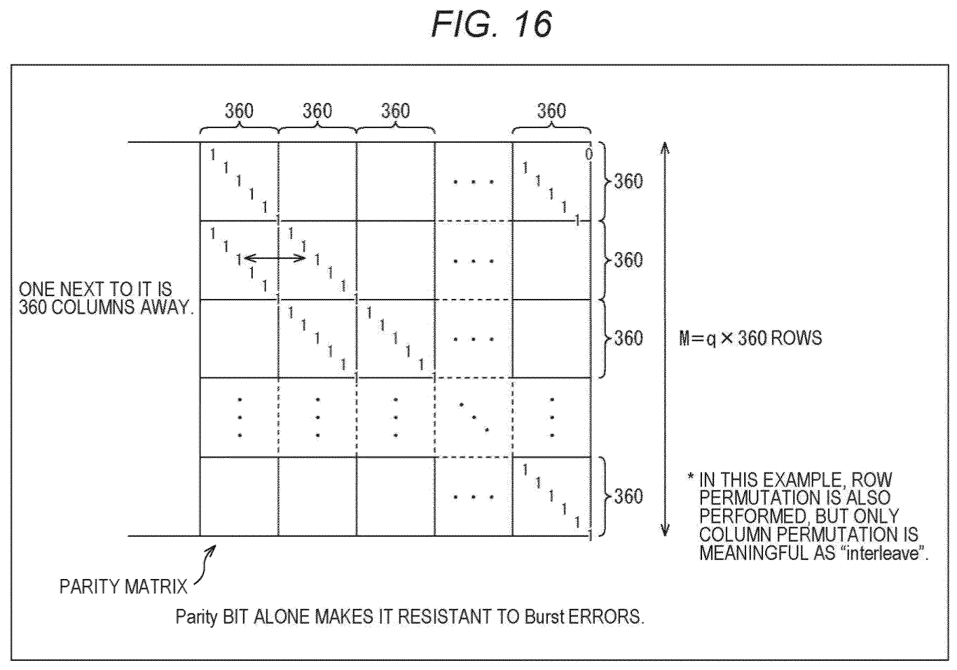

FIG. 15 is a diagram illustrating an example of the parity matrix H_{T} having a staircase structure and the Tanner graph corresponding to the parity matrix H_{T} as illustrated in FIG. 11.

A of FIG. 15 illustrates an example of the parity matrix H_{T} having a staircase structure, and B of FIG. 15 illustrates a Tanner graph corresponding to the parity matrix H_{T} in A of FIG. 15.

In the parity matrix H_{T} having a staircase structure, elements of 1 are adjacent in each row (excluding the first row). Therefore, in the Tanner graph of the parity matrix H_{T}, two adjacent variable nodes corresponding to columns of two adjacent elements in which the value of the parity matrix H_{T} is 1 are connected to the same check node.

Therefore, when the parity bits corresponding to the above-described two adjacent variable nodes become errors at the same time due to burst errors, erasures, or the like, the check node connected to the two variable nodes corresponding to the two parity bits that have become the errors (variable nodes for obtaining a message using the parity bits) returns a message in which the probability that the value is 0 and the probability that the value is 1 are equal to the variable node connected to the check node, and thus decoding performance deteriorates. Then, when the burst length (the but length of the parity bit that continuously becomes an error) becomes large, the number of check nodes returning the message of equal probability increases, and the performance of decoding further deteriorates.

Therefore, the parity interleaver 23 (FIG. 9) performs parity interleaving to interleave the parity bits of the LDPC code from the LDPC encoder 115 to the positions of the other parity bits in order to prevent degradation of the decoding performance described above.

FIG. 16 is a diagram illustrating the parity matrix H_{T} of the parity check matrix H corresponding to the LDPC code subjected to the parity interleaving performed by the parity interleaver 23 in FIG. 9.

Here, the information matrix H_{A} of the parity check matrix H corresponding to the LDPC code output by the LDPC encoder 115 has a cyclic structure, similarly to the information matrix of the parity check matrix H corresponding to the LDPC code defined in the standard such as DVB-T.2.

The cyclic structure refers to a structure in which a certain column coincides with that obtained by cyclically shifting another column, and includes, for example, a structure in which, for each P columns, the position of 1 in each row of the P columns is cyclically shifted in the column direction by a predetermined value such as a value proportional to a value q obtained by dividing the first column of the P columns by the parity length M. Hereinafter, the P columns in the cyclic structure will be appropriately referred to as a unit size.

As the LDPC code defined in the standard such as DVB-T.2, there are two types of LDPC codes with the code lengths N of 64800 bits and 16200 bits as described with reference to FIGS. 12 and 13, and for each of the two types of LDPC codes, the unit size P is defined as 360, which is one of the divisors of the parity length M except for 1 and M.

Furthermore, the parity length M is a value other than the prime number represented by an equation M=q×P=q×360 using a value q that differs depending on the coding rate. Therefore, similarly to the unit size P, the value q is another one of the divisors of the parity length M except 1 and M, and is obtained by dividing the parity length M by the unit size P (The product of P and q, which are divisors of the parity length M, becomes the parity length M.).

As described above, when the information length is K, an integer of 0 or more and less than P is x, and an integer of 0 or more and less than q is y, the parity interleaver 23 interleaves the (K+qx+y+1)th sign bit among the sign bits of the N-bit LDPC code to the position of the (K+Py+x+1)th sign bit as parity interleaving.

Since both the (K+qx+y+1)th sign bit and the (K+Py+x+1)th sign bit are the (K+1)th and subsequent sign bits, they are parity bits. Therefore, according to the parity interleaving, the positions of the parity bits of the LDPC code are moved.

According to such parity interleaving, (the parity bits corresponding to) the variable nodes connected to the same check node are separated by the unit size P, that is, 360 bits here. Therefore, in a case where the burst length is less than 360 bits, it is possible to avoid a situation where a plurality of variable nodes connected to the same check node becomes an error at the same time, and as a result, the resistance to burst errors can be improved.

Note that the LDPC code after parity interleaving for interleaving the (K+qx+y+1)th sign bit to the position of the (K+Py+x+1)th sign bit matches the LDPC code of the parity check matrix (Hereinafter, it is also referred to as a transformed parity check matrix.) obtained by performing column permutation for permutating the (K+qx+y+1)th column to the (K+Py+x+1)th column in the original check matrix H.

Furthermore, in the parity matrix of the transformed parity check matrix, as illustrated in FIG. 16, a pseudo cyclic structure having P columns (In FIG. 16, 360 columns) as a unit appears.

Here, the pseudo cyclic structure means a structure in which a part except for a part is a cyclic structure.

The transformed parity check matrix obtained by applying column permutation corresponding to parity interleaving to the parity check matrix of the LDPC code defined in the standard such as DVB-T.2 does not have only one element of 1 (it is an element of 0) in the portion of 360 rows×360 columns (shift matrix as described later) in the upper right corner portion of the transformed parity check matrix, and in that respect, the transformed parity check matrix has a so-called pseudo cyclic structure instead of a (complete) cyclic structure.

The transformed parity check matrix for the parity check matrix of the LDPC code output by the LDPC encoder 115 has a pseudo cyclic structure, for example, similarly to the transformed parity check matrix for the parity check matrix of the LDPC code defined in the standard such as DVB-T.2.

Note that the transformed parity check matrix in FIG. 16 is a matrix obtained by applying, to the original check matrix H, row permutation (row permutation) for causing the transformed parity check matrix to be configured by a configuration matrix to be described later, in addition to column permutation corresponding to parity interleaving.

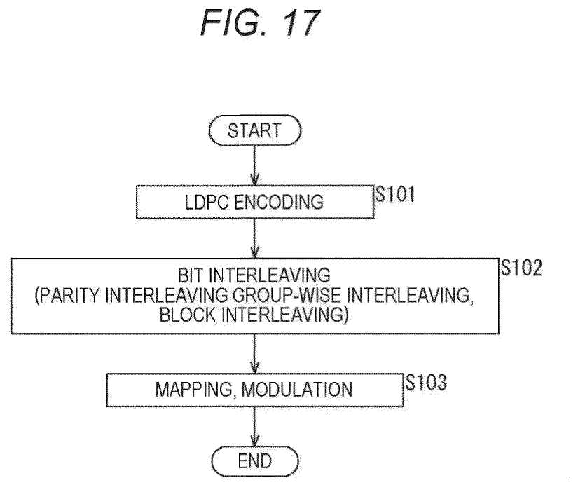

FIG. 17 is a flowchart illustrating processing performed by the LDPC encoder 115, the bit interleaver 116, and the mapper 117 in FIG. 8.

The LDPC encoder 115 waits for the LDPC target data to be supplied from the BCH encoder 114, and in step S101, encodes the LDPC target data into an LDPC code and supplies the LDPC code to the bit interleaver 116, and the process proceeds to step S102.

In step S102, the bit interleaver 116 performs bit interleaving on the LDPC code from the LDPC encoder 115, and supplies a symbol obtained by the bit interleaving to the mapper 117, and the process proceeds to step S103.

That is, in step S102, in the bit interleaver 116 (FIG. 9), the parity interleaver 23 performs parity interleaving on the LDPC code supplied from the LDPC encoder 115, and supplies the LDPC code subjected to the parity interleaving to the group-wise interleaver 24.

The group-wise interleaver 24 performs group-wise interleaving for the LDPC code from the parity interleaver 23 and supplies the LDPC code to the block interleaver 25.

The block interleaver 25 performs block interleaving on the LDPC code subjected to the group-wise interleaving by the group-wise interleaver 24, and supplies an m-bit symbol obtained as a result to the mapper 117.

In step S103, the mapper 117 maps the symbol from the block interleaver 25 to any one of 2^{m} signal points determined by the modulation method of the quadrature modulation performed by the mapper 117, performs the quadrature modulation, and supplies data obtained as a result to the time interleaver 118.

As described above, by performing parity interleaving or group-wise interleaving, it is possible to improve an error rate in a case where a plurality of sign bits of an LDPC code is transmitted as one symbol.

Here, in FIG. 9, for convenience of description, the parity interleaver 23 which is a block for performing parity interleaving and the group-wise interleaver 24 which is a block for performing group-wise interleaving are separately configured, but the parity interleaver 23 and the group-wise interleaver 24 can be integrally configured.

That is, both the parity interleaving and the group-wise interleaving can be performed by writing and reading sign bits to and from the memory, and can be represented by a matrix that converts an address (write address) at which sign bits are written into an address (read address) at which sign bits are read.

Therefore, if a matrix obtained by multiplying the matrix representing the parity interleaving and the matrix representing the group-wise interleaving is obtained, the parity interleaving is performed by converting the sign bits by these matrices, and further, a result of group-wise interleaving of the LDPC code after the parity interleaving can be obtained.

Furthermore, in addition to the parity interleaver 23 and the group-wise interleaver 24, the block interleaver 25 can also be integrally configured.

That is, the block interleaving performed by the block interleaver 25 can also be represented by a matrix that converts the write address of the memory that stores the LDPC code into the read address.

Therefore, if a matrix obtained by multiplying the matrix representing the parity interleaving, the matrix representing the group-wise interleaving, and the matrix representing the block interleaving is obtained, the parity interleaving, the group-wise interleaving, and the block interleaving can be collectively performed by these matrices.

Note that one or an amount of the parity interleaving and the group-wise interleaving may not be performed.

### <Configuration Example of LDPC Encoder 115>

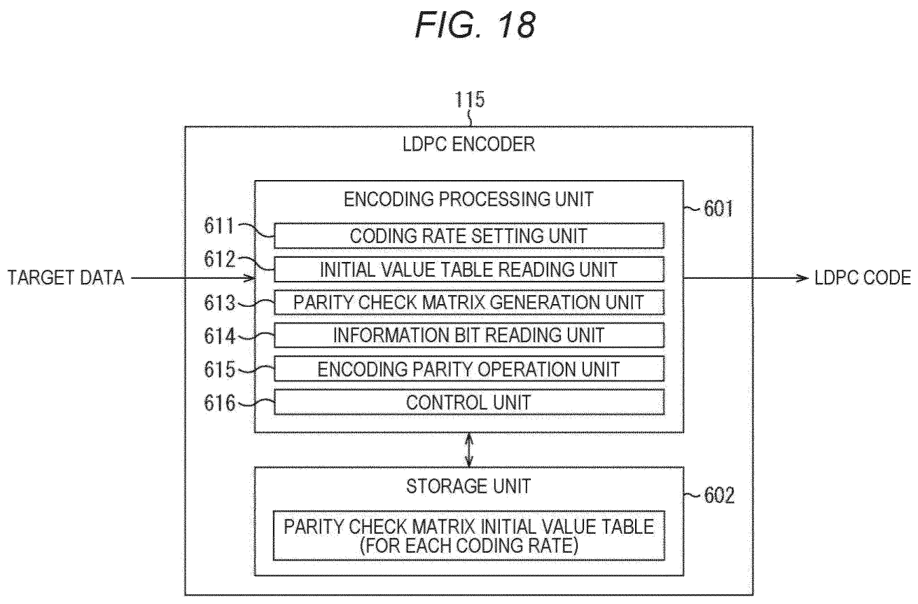

FIG. 18 is a block diagram illustrating a configuration example of the LDPC encoder 115 in FIG. 8.

Note that the LDPC encoder 122 in FIG. 8 is similarly configured.

As described with reference to FIGS. 12 and 13, in the standard such as DVB-T.2, two types of LDPC codes with the code length N of 64800 bits and 16200 bits are defined.

Then, 11 coding rates 1/4, 1/3, 2/5, 1/2, 3/5, 2/3, 3/4, 4/5, 5/6, 8/9, and 9/10 are defined for the LDPC code with the code length N of 64800 bits, and 10 coding rates 1/4, 1/3, 2/5, 1/2, 3/5, 2/3, 3/4, 4/5, 5/6, and 8/9 are defined for the LDPC code with the code length N of 16200 bits (FIGS. 12 and 13).

The LDPC encoder 115 can perform, for example, such coding (error correction coding) with the LDPC codes with the code lengths N of 64800 bits and 16200 bits and the coding rates according to the parity check matrix H prepared for each code length N and each coding rate.

In addition, the LDPC encoder 115 can perform LDPC coding according to the parity check matrix H of an LDPC code of an arbitrary code length N and an arbitrary coding rate r.

The LDPC encoder 115 includes an encoding processing unit 601 and a storage unit 602.

The encoding processing unit 601 includes a coding rate setting unit 611, an initial value table reading unit 612, a parity check matrix generation unit 613, an information bit reading unit 614, an encoding parity operation unit 615, and a control unit 616, performs LDPC encoding on the LDPC target data supplied to the LDPC encoder 115, and supplies a resulting LDPC code to the bit interleaver 116 (FIG. 8).

That is, the coding rate setting unit 611 sets the code length N and the coding rate r of the LDPC code, and other specific information for specifying the LDPC code according to the operation or the like of the operator or the like, for example.

The initial value table reading unit 612 reads a parity check matrix initial value table, which will be described later, representing the parity check matrix of the LDPC code specified by the specifying information set by the coding rate setting unit 611 from the storage unit 602.

The parity check matrix generation unit 613 generates the parity check matrix H on the basis of the parity check matrix initial value table read by the initial value table reading unit 612, and stores the parity check matrix H in the storage unit 602. For example, the parity check matrix generation unit 613 arranges the elements of 1 of the information matrix H_{A} corresponding to the information length K (=code length N−parity length M) according to the code length N and the coding rate r set by the coding rate setting unit 611 in a cycle of every 360 columns (unit size P) in the column direction to generate the parity check matrix H, and stores the parity check matrix H in the storage unit 602.

The information bit reading unit 614 reads (extracts) information bits corresponding to the information length K from the LDPC target data supplied to the LDPC encoder 115.

The encoding parity operation unit 615 reads the parity check matrix H generated by the parity check matrix generation unit 613 from the storage unit 602, and uses the parity check matrix H to calculate parity bits for the information bits read by the information bit reading unit 614 on the basis of a predetermined expression, thereby generating a code word (LDPC code).

The control unit 616 controls each block constituting the encoding processing unit 601.

The storage unit 602 stores, for example, a plurality of check matrix initial value tables and the like corresponding to the plurality of coding rates and the like illustrated in FIGS. 12 and 13 for each code length N such as 64800 bits and 16200 bits. Furthermore, the storage unit 602 temporarily stores data necessary for the processing of the encoding processing unit 601.

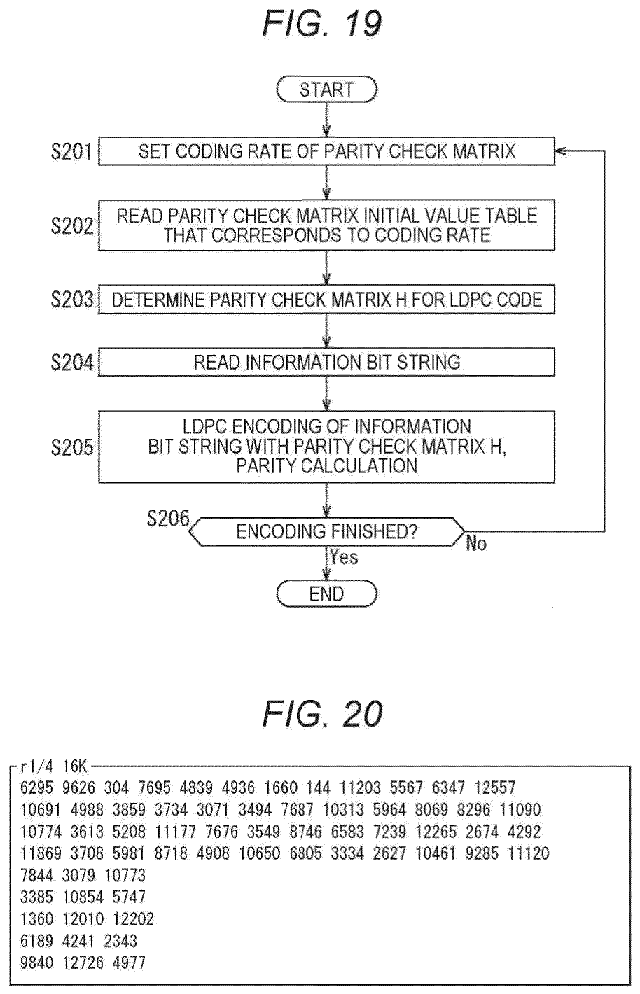

FIG. 19 is a flowchart illustrating exemplary processing of the LDPC encoder 115 in FIG. 18.

In step S201, the coding rate setting unit 611 sets the code length N and the coding rate r for performing LDPC coding, and other specifying information for specifying the LDPC code.

In step S202, the initial value table reading unit 612 reads a predetermined check matrix initial value table specified by the code length N, the coding rate r, and the like as the specifying information set by the coding rate setting unit 611 from the storage unit 602.

In step S203, the parity check matrix generation unit 613 obtains (generates) the parity check matrix H of the LDPC code with the code length N and the coding rate r set by the coding rate setting unit 611 using the parity check matrix initial value table read from the storage unit 602 by the initial value table reading unit 612, and supplies and stores the parity check matrix H in the storage unit 602.

In step S204, the information bit reading unit 614 reads the information bits of the information length K (=N×r) corresponding to the code length N and the coding rate r set by the coding rate setting unit 611 from the LDPC target data supplied to the LDPC encoder 115, reads the parity check matrix H obtained by the parity check matrix generation unit 613 from the storage unit 602, and supplies the parity check matrix H to the encoding parity operation unit 615.

In step S205, the encoding parity operation unit 615 sequentially calculates the parity bits of the code word c satisfying Formula (8) using the information bits from the information bit reading unit 614 and the parity check matrix H.

$${Hc}^{T} = 0 \qquad ( 8 )$$

In Formula (8), c represents a row vector as a code word (LDPC code), and c^{T} represents transposition of the row vector c.

Here, as described above, in a case where a portion of the information bits in the row vector c as the LDPC code (one code word) is represented by the row vector A and a portion of the parity bits is represented by the row vector T, the row vector c can be represented by the equation c=[A|T] by the row vector A as the information bits and the row vector T as the parity bits.

The parity check matrix H and the row vector c=[A|T] as the LDPC code need to satisfy the equation Hc^{T}=0, and in a case where the parity matrix H_{T} of the parity check matrix H=[H_{A}|H_{T}] has the staircase structure illustrated in FIG. 11, the row vector T as the parity bits constituting the row vector c=[A|T] satisfying the equation Hc^{T}=0 can be sequentially obtained by setting the elements of each row to 0 in order from the element of the first row of the column vector Hc^{T} in the equation Hc^{T}=0.

The encoding parity operation unit 615 obtains parity bits T for the information bits A from the information bit reading unit 614, and outputs a code word c=[A|T] represented by the information bits A and the parity bits T as an LDPC encoding result of the information bits A.

Thereafter, in step S206, the control unit 616 determines whether to finish the LDPC coding. In a case where it is determined in step S206 that the LDPC coding is not finished, that is, in a case where there is still LDPC target data to be LDPC-encoded, for example, the process returns to step S201 (alternatively, step S204), and the processes of steps S201 (alternatively, step S204) to S206 are repeated.

Furthermore, in a case where it is determined in step S206 that the LDPC coding is to be finished, that is, for example, in a case where there is no LDPC target data to be LDPC coded, the LDPC encoder 115 ends the processing.

For the LDPC encoder 115, a parity check matrix initial value table (representing a parity check matrix) of LDPC codes with various code lengths N and coding rates r can be prepared in advance. The LDPC encoder 115 can perform LDPC coding for LDPC codes of various code lengths N and coding rates r using the parity check matrix H generated from the parity check matrix initial value table prepared in advance.

### <Example of Parity Check Matrix Initial Value Table>

The parity check matrix initial value table is, for example, a table representing the positions of the elements of 1 of the information matrix H_{A} (FIG. 10) corresponding to the information length K according to the code length N and the coding rate r of the LDPC code (the LDPC code defined by the parity check matrix H) of the parity check matrix H for every 360 columns (unit size P), and is created in advance for each check matrix H of each code length N and each coding rate r.

That is, the parity check matrix initial value table represents at least the positions of the elements of 1 of the information matrix H_{A} in every 360 columns (unit size P).

Furthermore, the parity check matrix H includes a parity check matrix in which all of the parity matrix H_{T} has a staircase structure, and a parity check matrix in which a part of the parity matrix H_{T} has a staircase structure and the remaining part is a diagonal matrix (identity matrix).

Hereinafter, an expression method of the parity check matrix initial value table representing the parity check matrix in which a part of the parity matrix H_{T} has a staircase structure and the remaining part is a diagonal matrix is also referred to as a type A method. Furthermore, an expression method of the parity check matrix initial value table representing the parity check matrix in which all the parity matrices H_{T} have the staircase structure is also referred to as a type B method.

Furthermore, the LDPC code for the parity check matrix represented by the parity check matrix initial value table by the type A method is also referred to as a type A code, and the LDPC code for the parity check matrix represented by the parity check matrix initial value table by the type B method is also referred to as a type B code.

The designations “type A” and “type B” are designations according to the standard of ATSC3.0. For example, in ATSC3.0, both the type A code and the type B code are adopted.

Note that in DVB-T.2 and the like, a type B code is adopted.

FIG. 20 is a diagram illustrating an example of a parity check matrix initial value table by the type B method.

In other words, FIG. 20 illustrates a parity check matrix initial value table (representing the parity check matrix H) of the type B code with the code length N of 16200 bits and the coding rate (notational coding rate of DVB-T.2) r of 1/4 defined in the DVB-T.2 standard.

The parity check matrix generation unit 613 (FIG. 18) uses the parity check matrix initial value table by the type B method to obtain the parity check matrix H as follows.

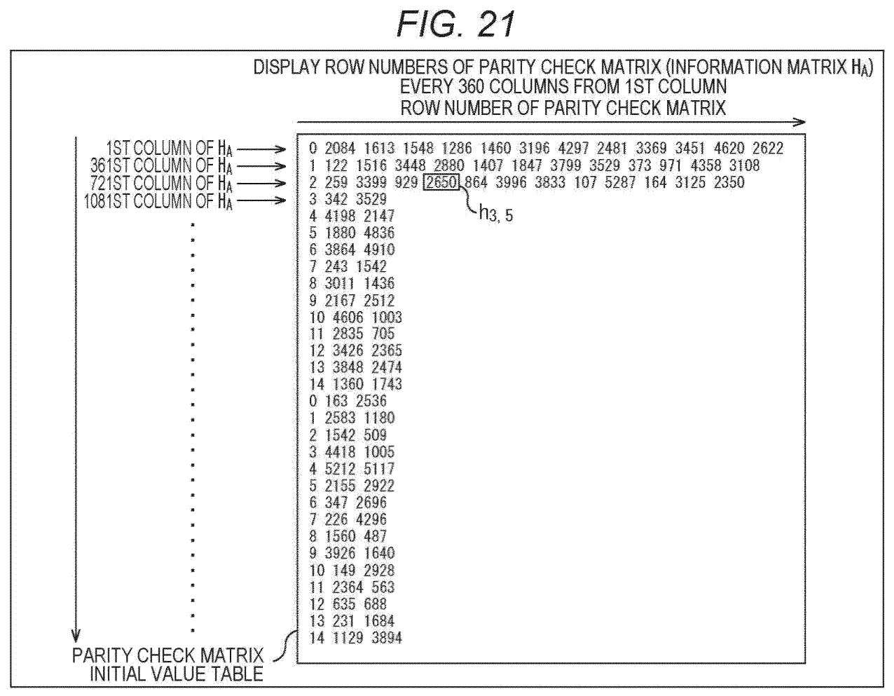

FIG. 21 is a diagram for explaining a method of obtaining the parity check matrix H from the parity check matrix initial value table by the type B method.

In other words, FIG. 21 illustrates a parity check matrix initial value table of a type B code with the code length N of 16200 bits and the coding rate r of 2/3 defined in the DVB-T.2 standard.

The parity check matrix initial value table by the type B method is a table representing the positions of the elements of 1 of the entire information matrix H_{A} corresponding to the information length K according to the code length N and the coding rate r of the LDPC code in every 360 columns (unit size P), and in the i-th row, row numbers of the elements of 1 of the (1+360×(i−1))th column of the parity check matrix H (row numbers in which the row number of the first row of the parity check matrix H is 0) are arranged by the number of column weights of the (1+360×(i−1))th column.

Here, since the parity matrix H_{T} (FIG. 10) corresponding to the parity length M of the parity check matrix H by the type B method has a staircase structure as illustrated in FIG. 15, if the information matrix H_{A}(FIG. 10) corresponding to the information length K can be obtained from the parity check matrix initial value table, the parity check matrix H can be obtained.

The number of rows k+1 of the parity check matrix initial value table by the type B method varies depending on the information length K.

A relationship of Formula (9) holds between the information length K and the number of rows k+1 of the parity check matrix initial value table.

$$K = ( k + 1 ) \times 360 \qquad ( 9 )$$

Here, 360 in Formula (9) is the unit size P described with reference to FIG. 16.

In the parity check matrix initial value table in FIG. 21, 13 numerical values are arranged in the 1st to 3rd rows, and 3 numerical values are arranged in the 4th to (k+1)th rows (In FIG. 21, line 30).

Therefore, the column weight of the parity check matrix H obtained from the parity check matrix initial value table in FIG. 21 is 13 from the 1st to (1+360×(3−1)−1)th columns, and is 3 from the (1+360×(3−1))th to K-th columns.

The 1st row of the parity check matrix initial value table in FIG. 21 is 0, 2084, 1613, 1548, 1286, 1460, 3196, 4297, 2481, 3369, 3451, 4620, and 2622, which indicates that, in the 1st column of the parity check matrix H, the elements of the rows with the row numbers of 0, 2084, 1613, 1548, 1286, 1460, 3196, 4297, 2481, 3369, 3451, 4620, and 2622 are 1 (and other elements are 0.).

Furthermore, the 2nd row of the parity check matrix initial value table in FIG. 21 is 1, 122, 1516, 3448, 2880, 1407, 1847, 3799, 3529, 373, 971, 4358, and 3108, which indicates that, in the 361 (=1+360×(2−1))th column of the parity check matrix H, the elements of the rows with the row numbers of 1, 122, 1516, 3448, 2880, 1407, 1847, 3799, 3529, 373, 971, 4358, and 3108 are 1.

As described above, the parity check matrix initial value table represents the positions of the elements of 1 of the information matrix H_{A} of the parity check matrix H in every 360 columns.

The columns other than the (1+360×(i−1))th column of the parity check matrix H, that is, the (2+360×(i−1))th to (360×i)th columns are obtained by cyclically shifting and arranging the elements of 1 of the (1+360×(i−1))th column determined by the parity check matrix initial value table downward (downward of the columns) according to the parity length M.

That is, for example, the (2+360×(i−1))th column is obtained by cyclically shifting the (1+360×(i−1))th column downward by M/360 (=q), and the next (3+360×(i−1))th column is obtained by cyclically shifting the (1+360×(i−1))th column downward by 2×M/360 (=2×q) (cyclic shift of the (2+360×(i−1))th column downward by M/360 (=q)).

Now, when the numerical value of the j-th column (j-th from the left) in the i-th row (i-th from the top) of the parity check matrix initial value table is represented as h_{i,j}, and the row number of the element of j-th 1 in the w-th column of the parity check matrix H is represented as H_{w-j}, the row number H_{w-j} of the element of 1 in the w-th column that is a column other than the (1+360×(i−1))th column of the parity check matrix H can be obtained by Formula (10).

$${H}_{w - j} = mod \{ {h}_{i , j} + mod ( ( w - 1 ) , P ) \times q , M ) \qquad ( 10 )$$

Here, mod (x,y) means a remainder when x is divided by y.

Furthermore, P is the unit size described above, and in the present embodiment, for example, P is 360 similar to DVB-T.2 and the like and the standard of ATSC3.0. Moreover, q is a value M/360 obtained by dividing the parity length M by the unit size P (=360).

The parity check matrix generation unit 613 (FIG. 18) specifies the row number of the element of 1 in the (1+360×(i−1))th column of the parity check matrix H using the parity check matrix initial value table.

Moreover, the parity check matrix generation unit 613 (FIG. 18) obtains the row number H_{w-j} of the element of 1 in the w-th column which is a column other than the (1+360×(i−1))th column of the parity check matrix H according to Formula (10), and generates the parity check matrix H in which the element of the row number obtained as described above is 1.

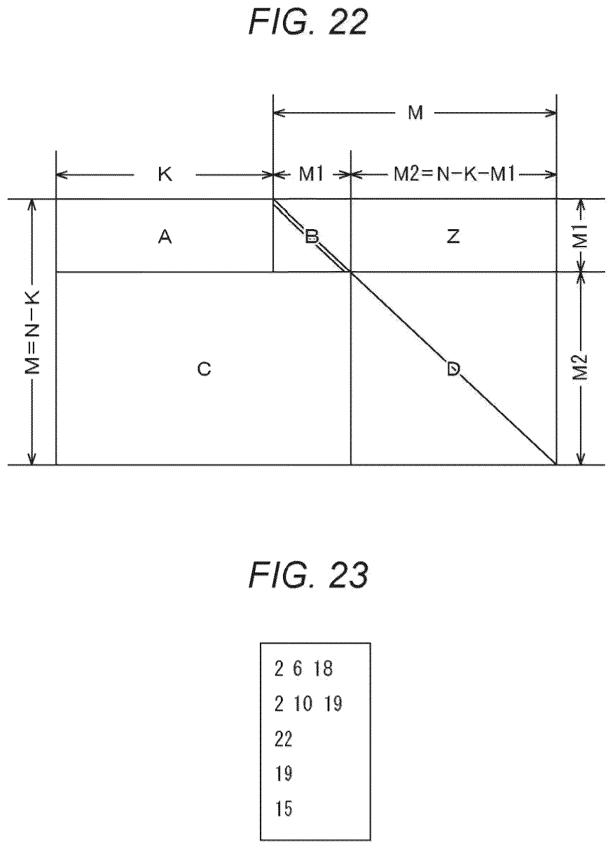

FIG. 22 is a diagram illustrating a structure of the parity check matrix H by the type A method.

The parity check matrix by the type A method includes an A matrix, a B matrix, a C matrix, a D matrix, and a Z matrix.

The A matrix is an upper left matrix of the parity check matrix H in M1 rows and K columns represented by a predetermined value M1 and an information length K=code length N×coding rate r of the LDPC code.

The B matrix is a matrix of M1 rows and M1 columns and having a staircase structure adjacent to the right of the A matrix.

The C matrix is a matrix adjacent below the A matrix and the B matrix in N−K−M1 rows and K+M1 columns.

The D matrix is an identity matrix of N−K−M1 rows and N−K−M1 columns adjacent to the right of the C matrix.

The Z matrix is a zero matrix (0 matrix) of M1 rows and N−K−M1 columns adjacent to the right of the B matrix.

In the parity check matrix H by the type A method including the A matrix to the D matrix and the Z matrix as described above, a part of the A matrix and the C matrix constitute an information matrix, and the B matrix, the remaining portion of the C matrix, the D matrix, and the Z matrix constitute a parity matrix.

Note that, since the B matrix is a matrix having a staircase structure and the D matrix is an identity matrix, a part (portion of the B matrix) of the parity matrix of the parity check matrix H by the type A method has a staircase structure, and the remaining portion (portion of the D matrix) is a diagonal matrix (identity matrix).

Similarly to the information matrix of the parity check matrix H by the type B method, the A matrix and the C matrix have a cyclic structure for each column (for example, 360 columns) of the unit size P, and the parity check matrix initial value table by the type A method represents the positions of the elements of 1 of the A matrix and the C matrix for every 360 columns.

Here, as described above, since the A matrix and a part of the C matrix constitute the information matrix, the parity check matrix initial value table by the type A method representing the positions of the elements of 1 of the A matrix and the C matrix every 360 columns can be said to represent at least the positions of the elements of 1 of the information matrix every 360 columns.

Note that, since the parity check matrix initial value table by the type A method represents the positions of the elements of 1 of the A matrix and the C matrix every 360 columns, it can be said that the positions of the elements of 1 of a part of the parity check matrix (the remaining part of the C matrix) are represented every 360 columns.

FIG. 23 is a diagram illustrating an example of a parity check matrix initial value table by the type A method.

In other words, FIG. 23 illustrates an example of a parity check matrix initial value table representing the parity check matrix H having the code length N of 35 bits and the coding rate r of 2/7.

The parity check matrix initial value table by the type A method is a table representing the positions of the elements of 1 of the A matrix and the C matrix for each unit size P. In the i-th row, row numbers of the elements of 1 of the (1+P×(i−1))th column of the parity check matrix H (row numbers in which the row number of the first row of the parity check matrix H is 0) are arranged by the number of column weights of the (1+P×(i−1))th column.

Note that, here, in order to simplify the description, the unit size P is assumed to be, for example, 5.

The parity check matrix H by the type A method includes M1, M2, Q1, and Q2 as parameters.

M1 (FIG. 22) is a parameter for determining the size of the B matrix, and has a value that is a multiple of the unit size P. By adjusting M1, the performance of the LDPC code changes, and is adjusted to a predetermined value when the parity check matrix H is determined. Here, it is assumed that 15, which is three times the unit size P=5, is employed as M1.

M2 (FIG. 22) takes a value M−M1 obtained by subtracting M1 from the parity length M.

Here, since the information length K is N×r=35×2/7=10 and the parity length M is N−K=35−10=25, M2 is M−M1=25−15=10.

Q1 is obtained according to an equation Q1=M1/P, and represents the number of cyclic shifts (the number of rows) in the A matrix.

That is, the columns other than the (1+P×(i−1))th column of the A matrix of the parity check matrix H by the type A method, that is, the (2+P×(i−1))th to (P×i)th columns are arranged by cyclically shifting the elements of 1 of the (1+P×(i−1))th column determined by the parity check matrix initial value table downward (downward of the columns), and Q1 represents the number of shifts of the cyclic shift in the A matrix.

Q2 is obtained according to an equation Q2=M2/P, and represents the number of cyclic shift shifts (the number of rows) in the C matrix.

That is, the columns other than the (1+P×(i−1))th column of the C matrix of the parity check matrix H by the type A method, that is, the (2+P×(i−1))th to (P×i)th columns are arranged by cyclically shifting the elements of 1 of the (1+P×(i−1))th column determined by the parity check matrix initial value table downward (downward of the columns), and Q2 represents the number of shifts of the cyclic shift in the C matrix.

Here, Q1 is M1/P=15/5=3, and Q2 is M2/P=10/5=2.

In the parity check matrix initial value table in FIG. 23, three numerical values are arranged in the 1st and 2nd rows, and one numerical value is arranged in the 3rd to 5th rows. According to the arrangement of the numerical values, the column weights of the A matrix and the C matrix of the parity check matrix H obtained from the parity check matrix initial value table in FIG. 23 are 3 from the (1=1+5×(1−1))th column to the (10=5×2)th column, and are 1 from the (11=1+5×(3−1))th column to the (25=5×5)th column.

That is, the 1st row of the parity check matrix initial value table in FIG. 23 is 2, 6, and 18, which indicates that, in the 1st column of the parity check matrix H, the elements of the rows with the row numbers 2, 6, and 18 are 1 (and other elements are 0.).

Here, in this case, since the A matrix (FIG. 22) is a matrix of 15 rows and 10 columns (M1 rows and K columns) and the C matrix (FIG. 22) is a matrix of 10 rows and 25 columns (N−K−M1 rows and K+M1 columns), the rows with the row numbers 0 to 14 of the parity check matrix H are rows of the A matrix, and the rows with the row numbers 15 to 24 of the parity check matrix H are rows of the C matrix.

Therefore, among the rows with the row numbers 2, 6, and 18 (Hereinafter, it is described as row #2, #6, and #18.), the rows #2 and #6 are rows of the A matrix, and the row #18 is a row of the C matrix.

The 2nd row of the parity check matrix initial value table in FIG. 23 is 2, 10, and 19, which indicates that, in the 6 (=1+5×(2−1))th column of the parity check matrix H, the elements of the rows #2, #10, and #19 are 1.

Here, in the 6 (=1+5×(2−1))th column of the parity check matrix H, among the rows #2, #10, and #19, the rows #2 and #10 are rows of the A matrix, and the row #19 is a row of the C matrix.

The 3rd row of the parity check matrix initial value table in FIG. 23 is 22, which indicates that, in the 11 (=1+5×(3−1))th column of the parity check matrix H, the element of the row #22 is 1.

Here, in the 11 (=1+5×(3−1))th column of the parity check matrix H, the row #22 is a row of the C matrix.

Similarly, 19 in the 4th row of the parity check matrix initial value table in FIG. 23 indicates that the element of the row #19 is 1 in the 16 (=1+5×(4−1))th column of the parity check matrix H, and 15 in the fifth row of the parity check matrix initial value table in FIG. 23 indicates that the element of the row #15 is 1 in the 21 (=1+5×(5−1))th column of the parity check matrix H.

As described above, the parity check matrix initial value table represents the positions of the elements of 1 of the A matrix and the C matrix of the parity check matrix H for every unit size P=5 columns.

The columns other than the (1+5×(i−1))th column of the A matrix and the C matrix of the parity check matrix H, that is, the (2+5×(i−1))th to (5×i)th columns are arranged by cyclically shifting the elements of 1 of the (1+5×(i−1))th column determined by the parity check matrix initial value table downward (downward of the columns) according to the parameters Q1 and Q2.

That is, for example, the (2+5×(i−1))th column of the A matrix is obtained by cyclically shifting the (1+5×(i−1))th column downward by Q1 (=3), and the next (3+5×(i−1))th column is obtained by cyclically shifting the (1+5×(i−1))th column downward by 2×Q1 (=2×3) ((2+5×(i−1))th column cyclically shifted downward by Q1).

Furthermore, for example, the (2+5×(i−1))th column of the C matrix is obtained by cyclically shifting the (1+5×(i−1))th column downward by Q2 (=2), and the next (3+5×(i−1))th column is obtained by cyclically shifting the (1+5×(i−1))th column downward by 2×Q2 (=2×2) ((2+5×(i−1))th column cyclically shifted downward by Q2).

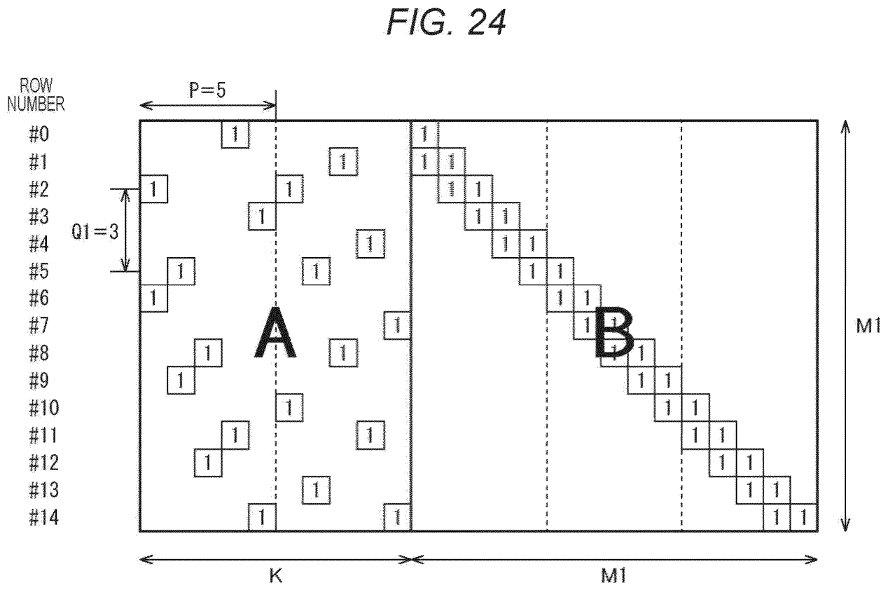

FIG. 24 is a diagram illustrating an A matrix generated from the parity check matrix initial value table in FIG. 23.

In the A matrix in FIG. 24, the elements of the rows #2 and #6 of the 1 (=1+5×(1−1))th column are 1 according to the 1st row of the parity check matrix initial value table in FIG. 23.

Then, the 2 (=2+5×(1−1))th to 5 (=5+5×(1−1))th columns are obtained by cyclically shifting the previous columns downward by Q1=3.

Moreover, in the A matrix in FIG. 24, the elements of the rows #2 and #10 of the 6 (=1+5×(2−1))th column are 1 according to the 2nd row of the parity check matrix initial value table in FIG. 23.

Then, the 7 (=2+5×(2−1))th to 10 (=5+5×(2−1))th columns are obtained by cyclically shifting the previous columns downward by Q1=3.

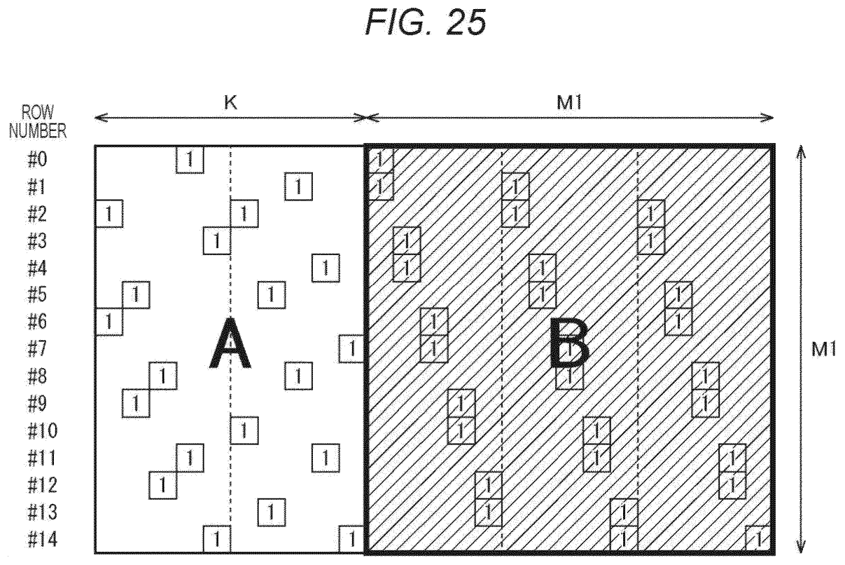

FIG. 25 is a diagram illustrating parity interleaving of the B matrix.

The parity check matrix generation unit 613 (FIG. 18) generates the A matrix, using the parity check matrix initial value table, and arranges the B matrix having the staircase structure on the right of the A matrix. Then, the parity check matrix generation unit 613 regards the B matrix as a parity matrix, and performs parity interleaving such that adjacent elements “1” of the B matrix having the staircase structure are separated in the row direction by the unit size P=5.

FIG. 25 illustrates the A matrix and the B matrix after the parity interleaving of the B matrix in FIG. 24.

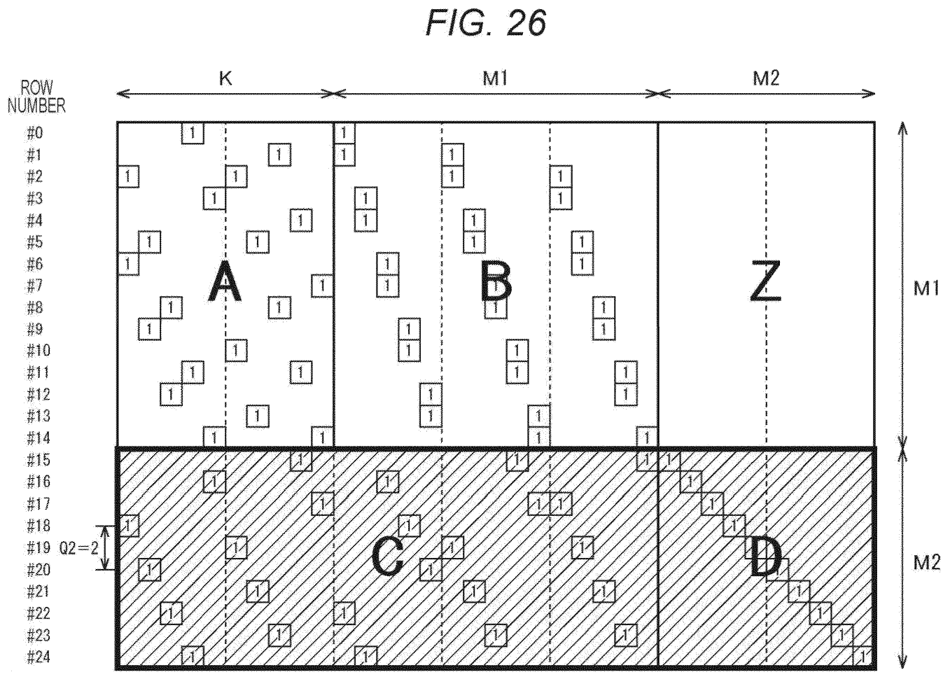

FIG. 26 is a diagram illustrating a C matrix generated from the parity check matrix initial value table in FIG. 23.

In the C matrix in FIG. 26, according to the 1st row of the parity check matrix initial value table in FIG. 23, the element of the row #18 of the 1st (=1+5×(1−1)) column of the parity check matrix H is 1.

Then, the 2 (=2+5×(1−1))th to 5 (=5+5×(1−1))th columns of the C matrix are obtained by cyclically shifting the previous columns downward by Q2=2.

Moreover, in the C matrix in FIG. 26, according to the 2nd to 5th rows of the parity check matrix initial value table in FIG. 23, the elements of the row #19 of the 6 (=1+5×(2−1))th column, the row #22 of the 11 (=1+5×(3−1))th column, the row #19 of the 16 (=1+5×(4−1))th column, and the row #15 of the 21 (=1+5×(5−1))th column of the parity check matrix H are 1.

Then, the 7 (=2+5×(2−1))th to 10 (=5+5×(2−1))th columns, the 12 (=2+5×(3−1))th to 15 (=5+5×(3−1))th columns, the 17 (=2+5×(4−1))th to 20 (=5+5×(4−1))th columns, and the 22 (=2+5×(5−1))th to 25 (=5+5×(5−1))th columns are obtained by cyclically shifting the previous columns downward by Q2=2.

The parity check matrix generation unit 613 (FIG. 18) generates the C matrix using the parity check matrix initial value table and arranges the C matrix below the A matrix and the B matrix (after parity interleaving).

Moreover, the parity check matrix generation unit 613 arranges the Z matrix adjacent to the right of the B matrix and arranges the D matrix adjacent to the right of the C matrix, thereby generating the parity check matrix H illustrated in FIG. 26.

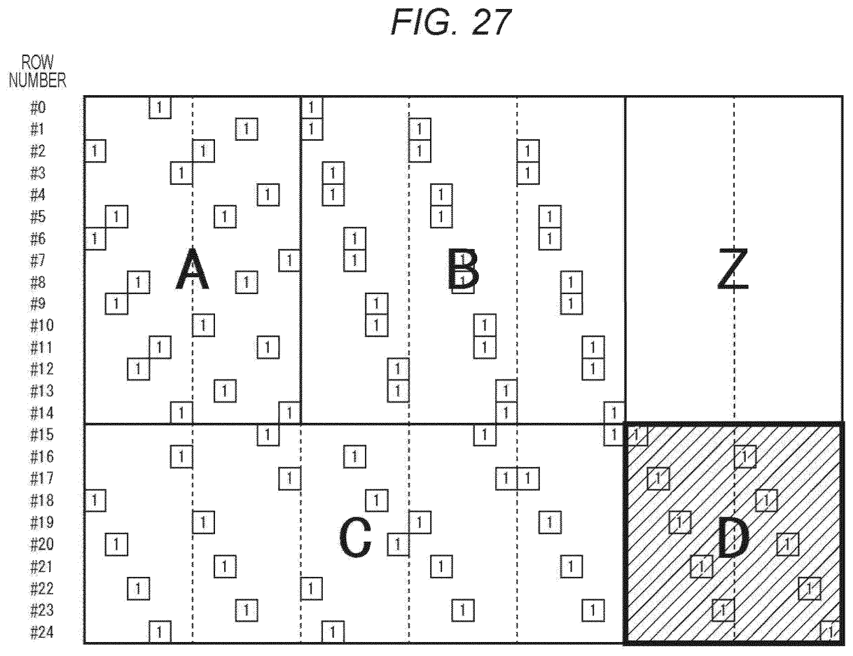

FIG. 27 is a diagram illustrating parity interleaving of the D matrix.

After generating the parity check matrix H in FIG. 26, the parity check matrix generation unit 613 regards the D matrix as a parity matrix, and performs parity interleaving (of only the D matrix) such that the elements of 1 of the odd rows and the next even rows of the D matrix as the identity matrix are separated in the row direction by the unit size P=5.

FIG. 27 illustrates the parity check matrix H after the parity interleaving of the D matrix is performed on the parity check matrix H in FIG. 26.

(The encoding parity operation unit 615 (FIG. 18) of) the LDPC encoder 115 performs LDPC coding (generation of an LDPC code), for example, using the parity check matrix H in FIG. 27.

Here, the LDPC code generated using the parity check matrix H in FIG. 27 is an LDPC code that has been subjected to parity interleaving. Therefore, the parity interleaver 23 (FIG. 9) does not need to perform parity interleaving for the LDPC code generated using the parity check matrix H in FIG. 27. That is, since the LDPC code generated using the parity check matrix H after the parity interleaving of the D matrix is performed is the LDPC code subjected to the parity interleaving, the parity interleaving in the parity interleaver 23 is skipped for such an LDPC code.

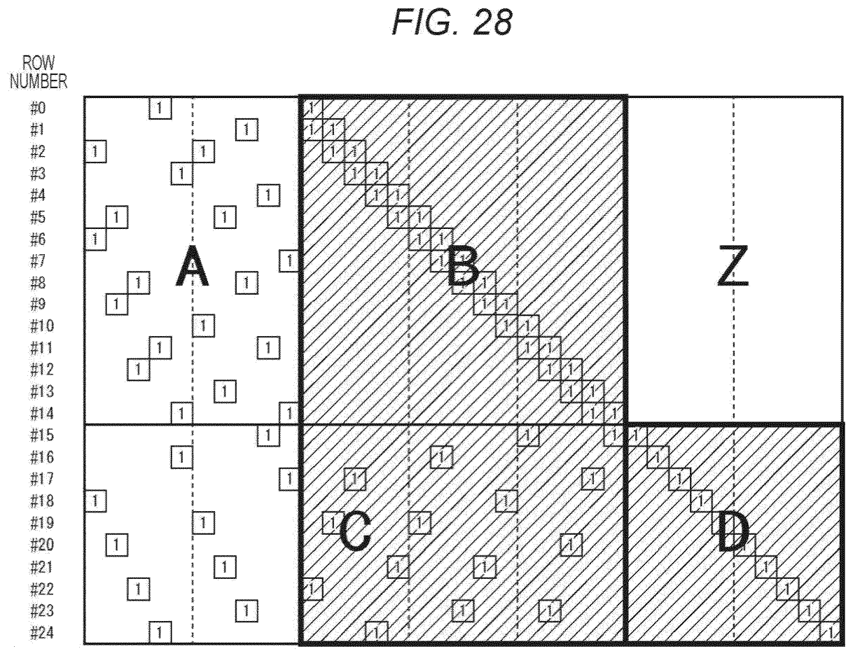

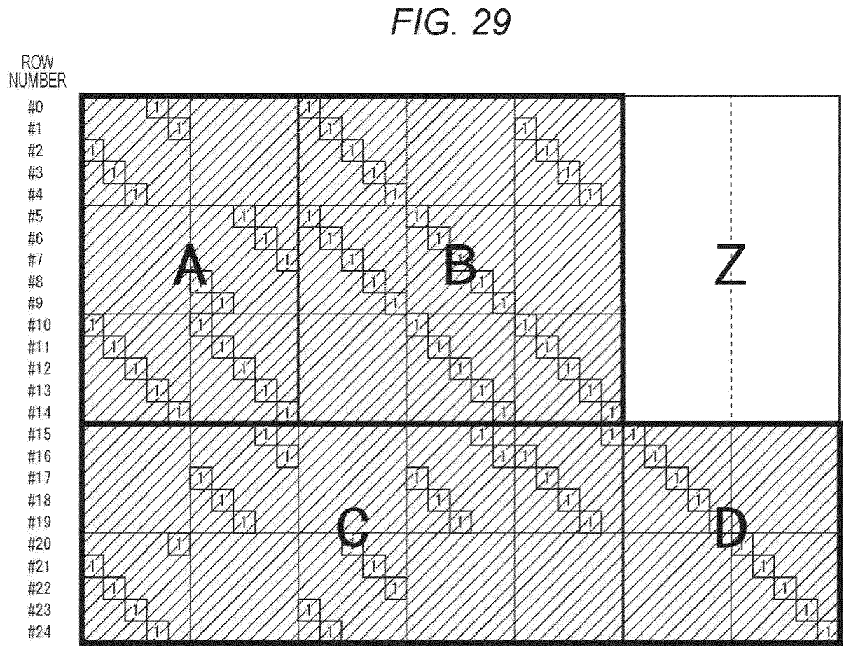

FIG. 28 is a diagram illustrating a parity check matrix H in which column permutation as parity deinterleaving for restoring the parity interleaving is performed for the B matrix, a part of the C matrix (portion of C matrix arranged below B matrix), and the D matrix of the parity check matrix H in FIG. 27.

The LDPC encoder 115 can perform LDPC coding (generation of an LDPC code) using the parity check matrix H in FIG. 28.

In a case where the LDPC coding is performed using the parity check matrix H in FIG. 28, an LDPC code on which parity interleaving is not performed is obtained according to the LDPC coding. Therefore, in a case where the LDPC coding is performed using the parity check matrix H in FIG. 28, parity interleaving is performed in the parity interleaver 23 (FIG. 9).

FIG. 29 is a diagram illustrating a transformed parity check matrix H obtained by performing row permutation for the parity check matrix H in FIG. 27.

As described later, the transformed parity check matrix is a matrix represented by a combination of a P×P identity matrix, a quasi identity matrix in which one or more of is in the identity matrix are 0, a shift matrix obtained by cyclically shifting the identity matrix or the quasi identity matrix, a sum matrix that is a sum of two or more of the identity matrix, the quasi identity matrix, or the shift matrix, and a P×P zero matrix.

By using the transformed parity check matrix for decoding the LDPC code, it is possible to adopt an architecture in which P check node operations and variable node operations are simultaneously performed in decoding the LDPC code as described later.

### <New LDPC Code>

In data transmission using an LDPC code, there is a method of using an LDPC code with good performance as one of methods of securing good communication quality.

Hereinafter, a new high-performance LDPC code (hereinafter, also referred to as a new LDPC code) will be described.

As the new LDPC code, for example, a type A code or a type B code corresponding to the parity check matrix H having a cyclic structure with the unit size P of 360 similar to DVB-T.2, ATSC3.0, or the like can be adopted.

The LDPC encoder 115 (FIG. 8, FIG. 18) can perform LDPC coding to obtain the new LDPC code, using (the parity check matrix H obtained from) the parity check matrix initial value table of the new LDPC code with the code length N of 69120 bits, for example, which is longer than 64 k bits, and the coding rate r of any of 2/16, 3/16, 4/16, 5/16, 6/16, 7/16, 8/16, 9/16, 10/16, 11/16, 12/16, 13/16, or 14/16, for example.

In this case, a parity check matrix initial value table of the new LDPC code is stored in the storage unit 602 of the LDPC encoder 115 (FIG. 8).

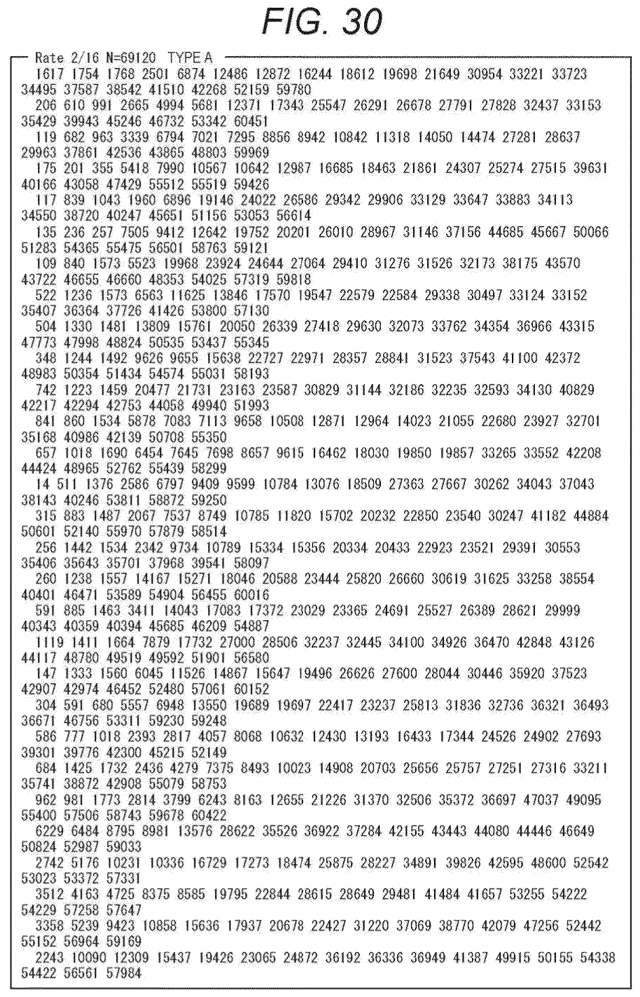

FIG. 30 is a diagram illustrating an example of a parity check matrix initial value table (of the type A method) representing the parity check matrix H of the type A code (hereinafter, also referred to as a type A code with r=2/16) as a new LDPC code with the code length N of 69120 bits and the coding rate r of 2/16.

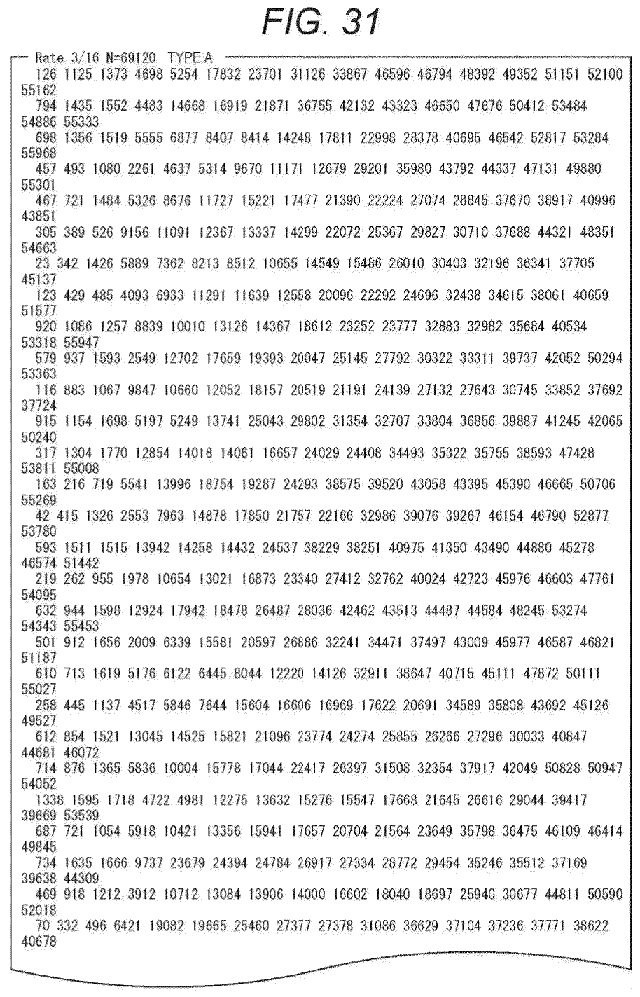

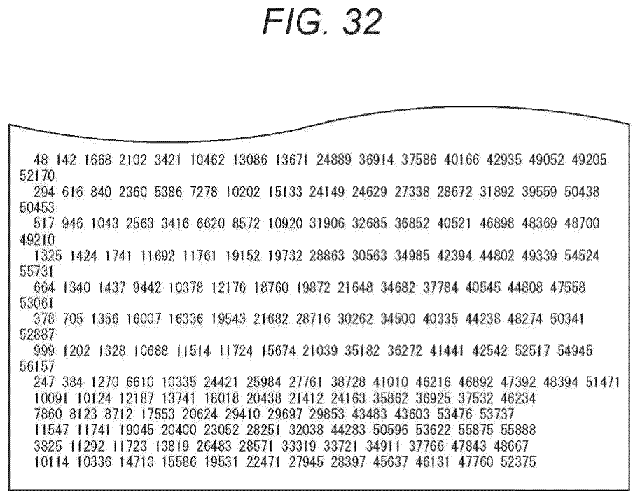

FIGS. 31 and 32 are diagrams illustrating examples of a parity check matrix initial value table representing the parity check matrix H of the type A code (hereinafter, also referred to as a type A code with r=3/16) as a new LDPC code with the code length N of 69120 bits and the coding rate r of 3/16.

Note that FIG. 32 is a diagram following FIG. 31.

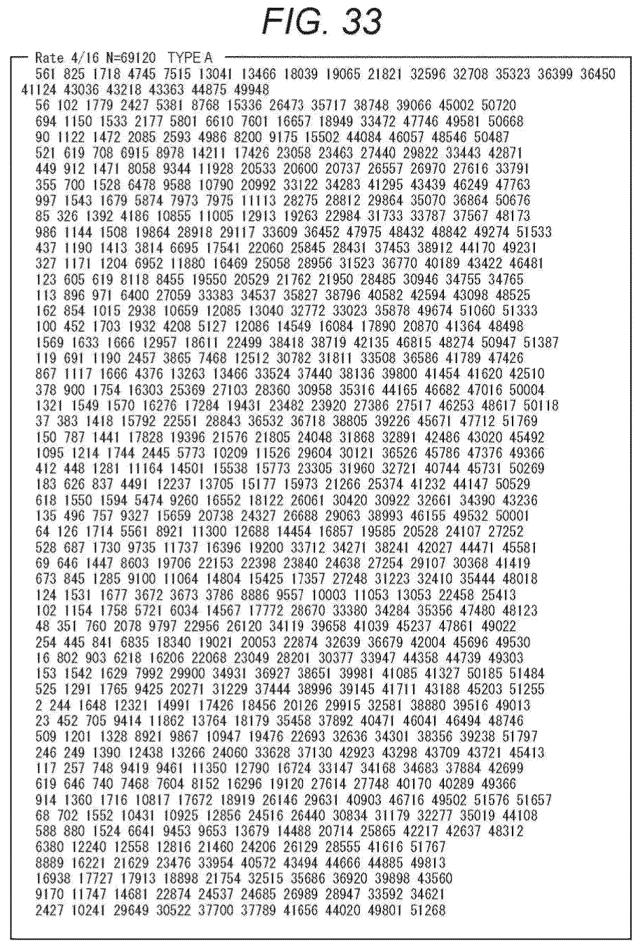

FIG. 33 is a diagram illustrating an example of a parity check matrix initial value table representing the parity check matrix H of the type A code (hereinafter, also referred to as a type A code with r=4/16) as a new LDPC code with the code length N of 69120 bits and the coding rate r of 4/16.

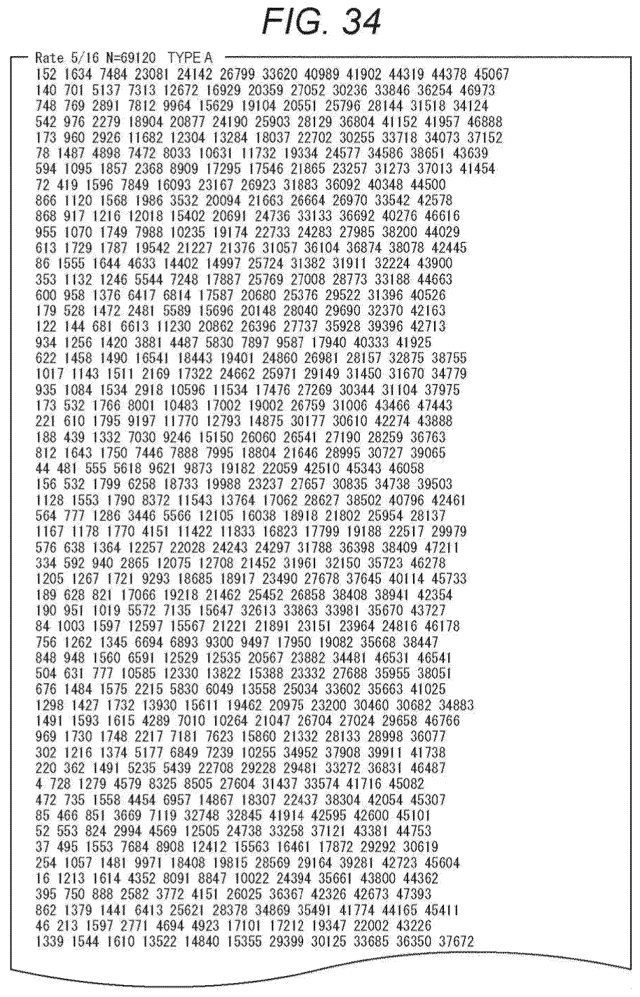

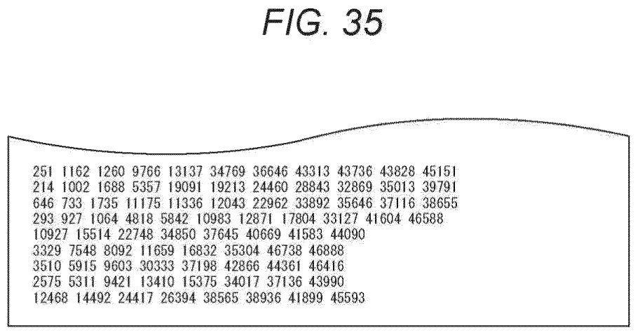

FIGS. 34 and 35 are diagrams illustrating examples of a parity check matrix initial value table representing the parity check matrix H of the type A code (hereinafter, also referred to as a type A code with r=5/16) as a new LDPC code with the code length N of 69120 bits and the coding rate r of 5/16.

Note that FIG. 35 is a diagram following FIG. 34.

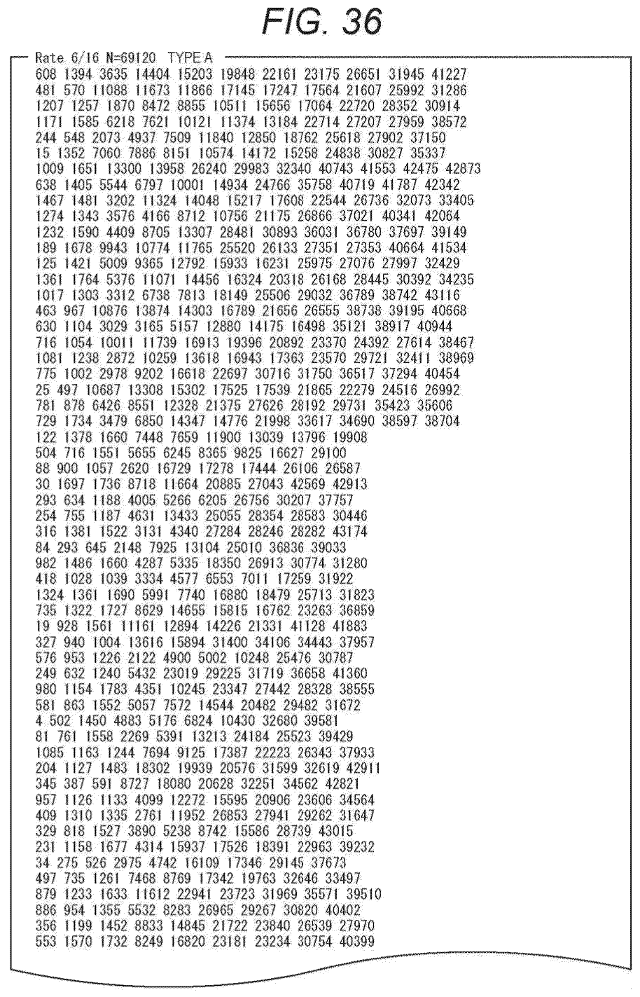

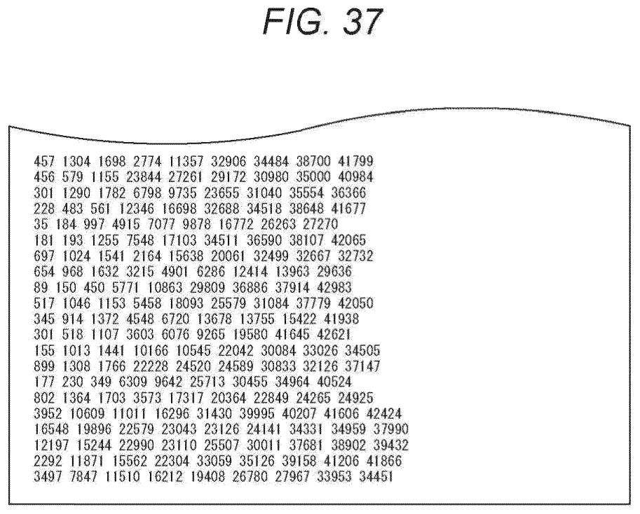

FIGS. 36 and 37 are diagrams illustrating examples of a parity check matrix initial value table representing the parity check matrix H of the type A code (hereinafter, also referred to as a type A code with r=6/16) as a new LDPC code with the code length N of 69120 bits and the coding rate r of 6/16.

Note that FIG. 37 is a diagram following FIG. 36.

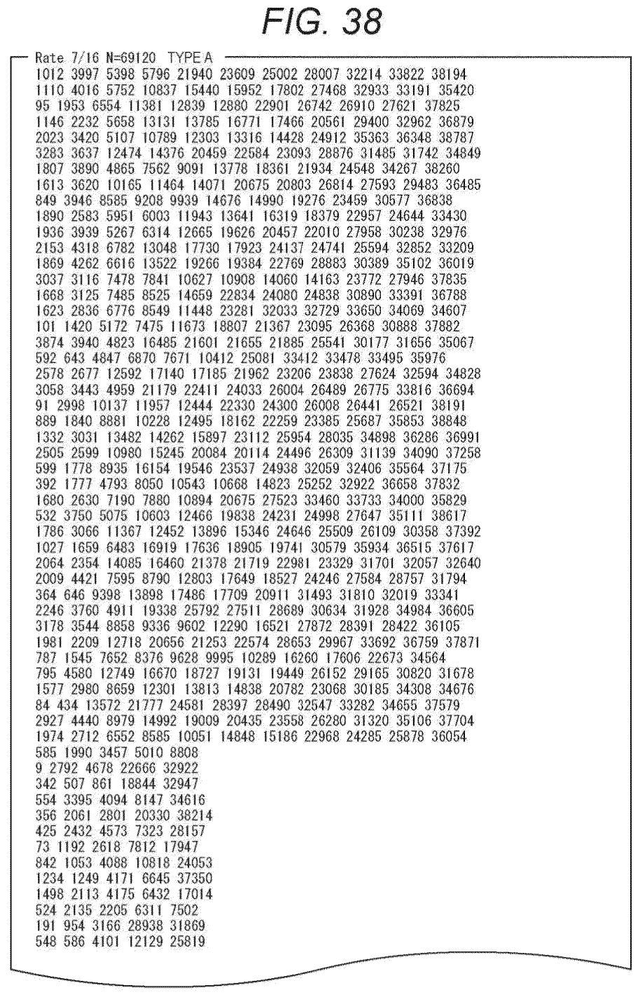

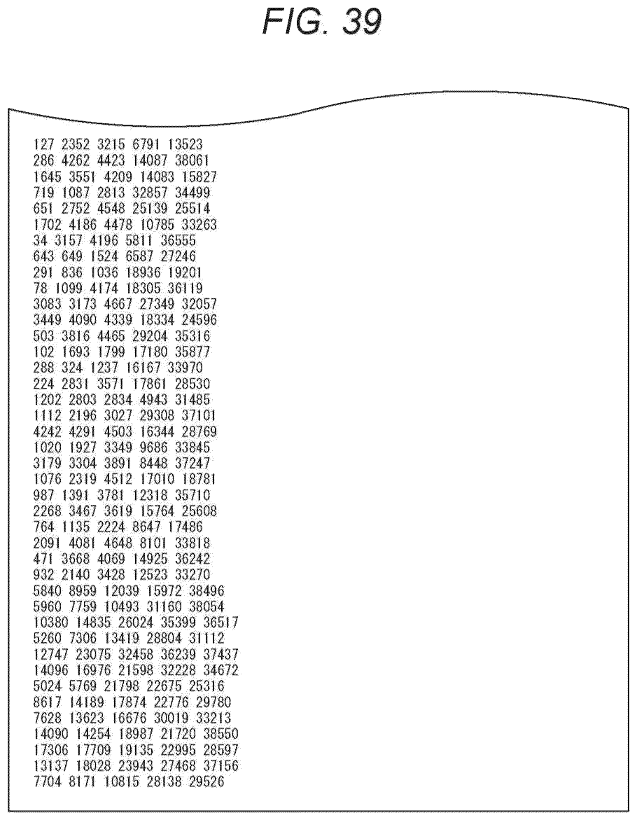

FIGS. 38 and 39 are diagrams illustrating examples of a parity check matrix initial value table representing the parity check matrix H of the type A code (hereinafter, also referred to as a type A code with r=7/16) as a new LDPC code with the code length N of 69120 bits and the coding rate r of 7/16.

Note that FIG. 39 is a diagram following FIG. 38.

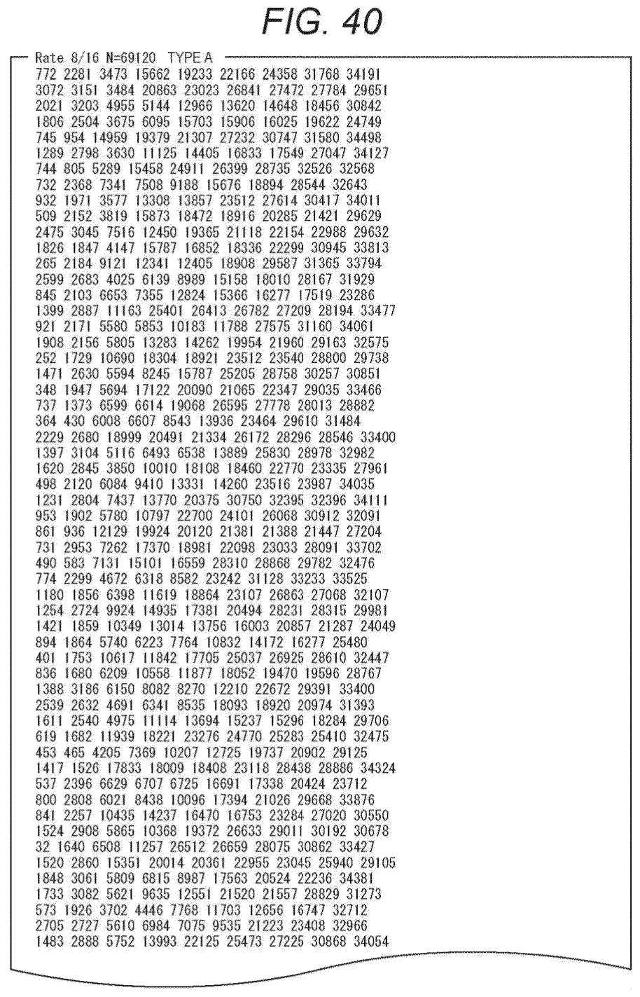

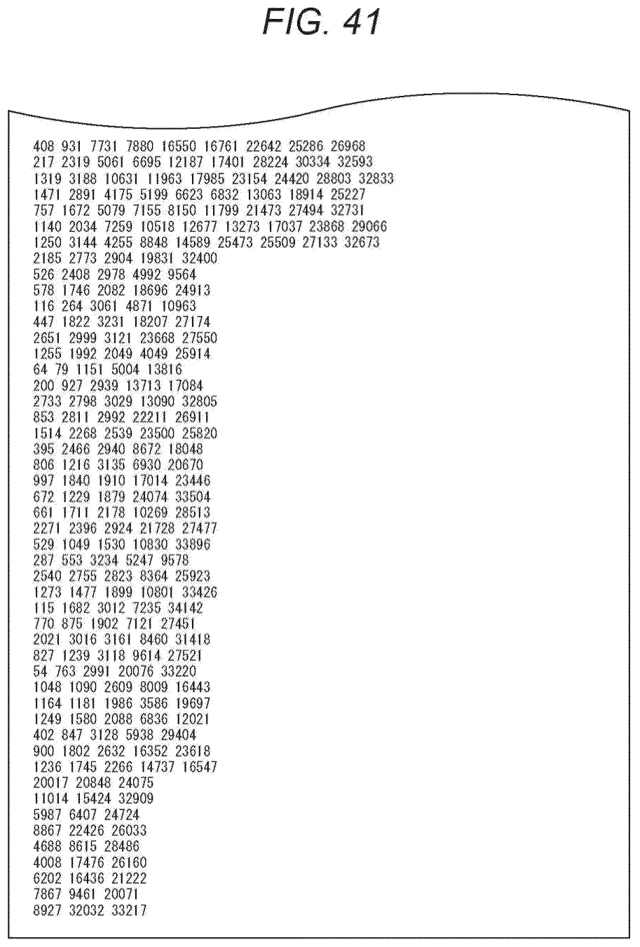

FIGS. 40 and 41 are diagrams illustrating examples of a parity check matrix initial value table representing the parity check matrix H of the type A code (hereinafter, also referred to as a type A code with r=8/16) as a new LDPC code with the code length N of 69120 bits and the coding rate r of 8/16.

Note that FIG. 41 is a diagram following FIG. 40.

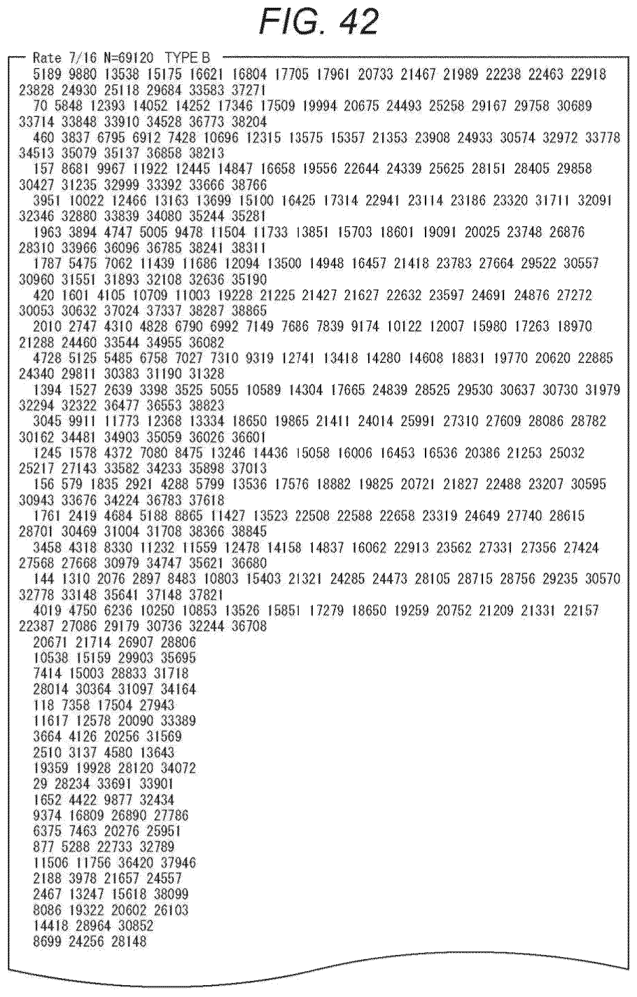

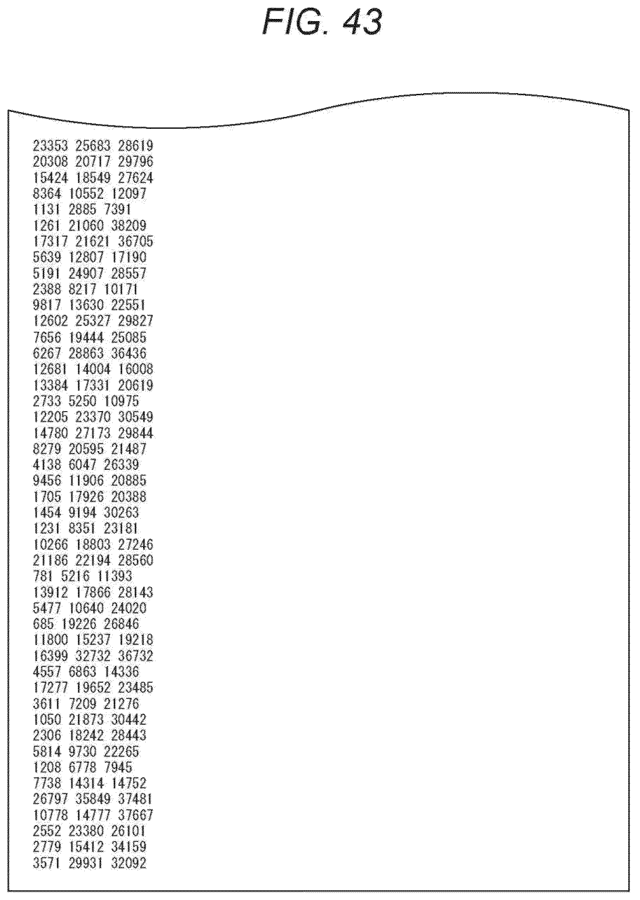

FIGS. 42 and 43 are diagrams illustrating examples of a parity check matrix initial value table (of the type B method) representing the parity check matrix H of the type B code (hereinafter, also referred to as a type B code with r=7/16) as a new LDPC code with the code length N of 69120 bits and the coding rate r of 7/16.

Note that FIG. 43 is a diagram following FIG. 42.

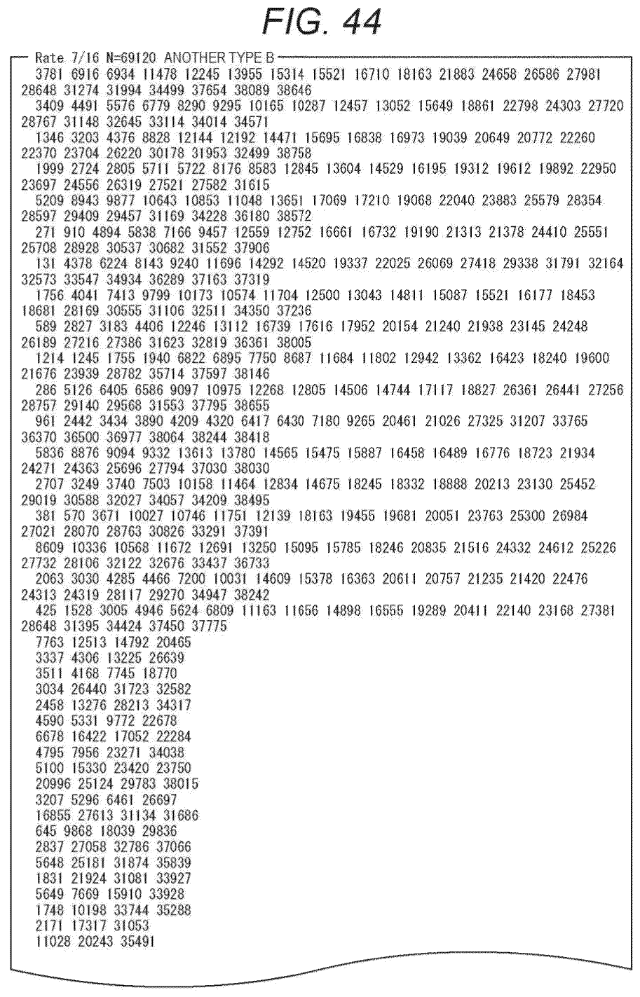

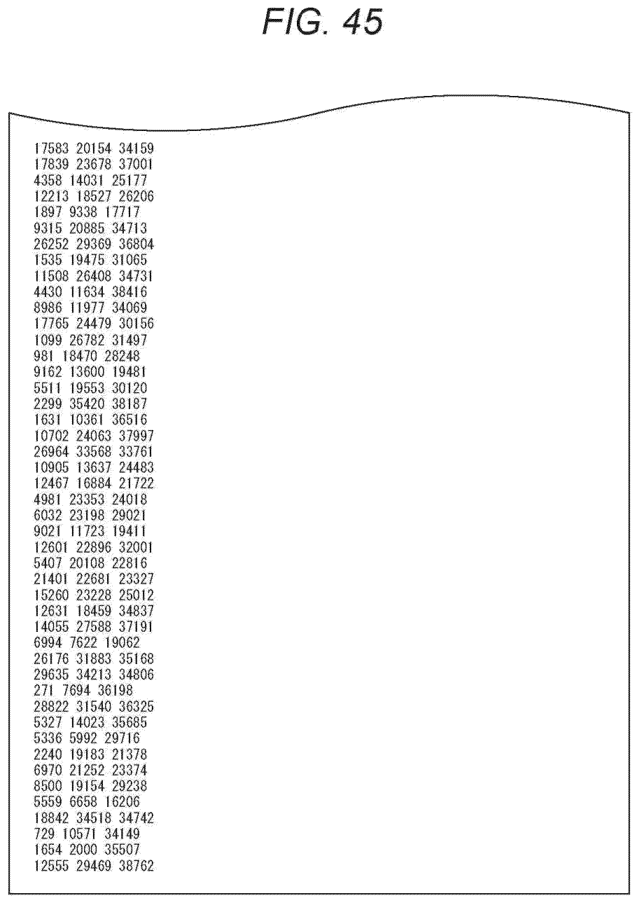

FIGS. 44 and 45 are diagrams illustrating another example of a parity check matrix initial value table representing the parity check matrix H of the type B code with r=7/16.

Note that FIG. 45 is a diagram following FIG. 44. The type B code with r=7/16 obtained from (the parity check matrix H represented by) the parity check matrix initial value table in FIGS. 44 and 45 is hereinafter also referred to as another type B code with r=7/16.

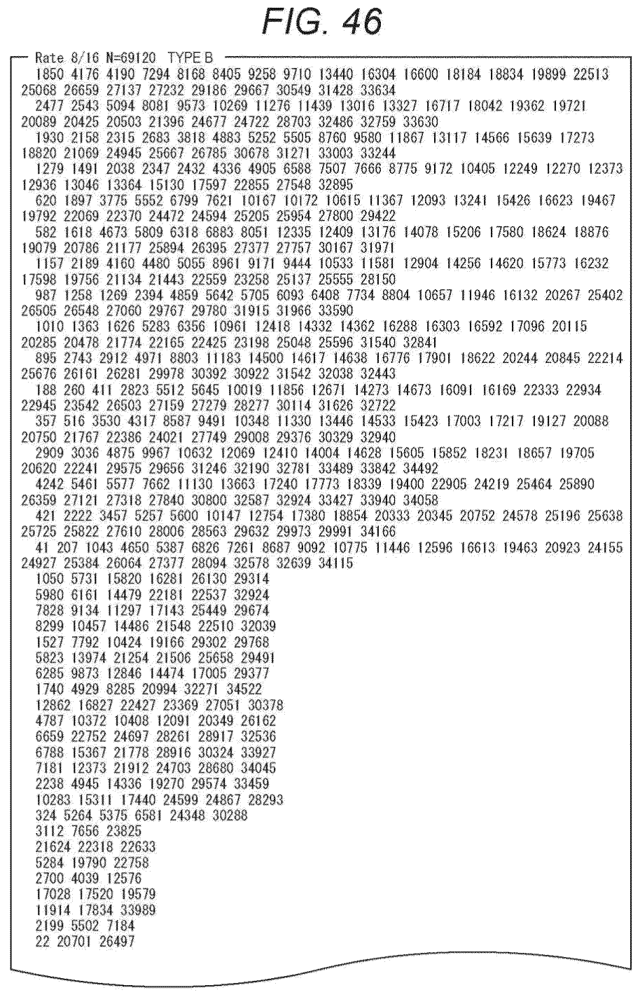

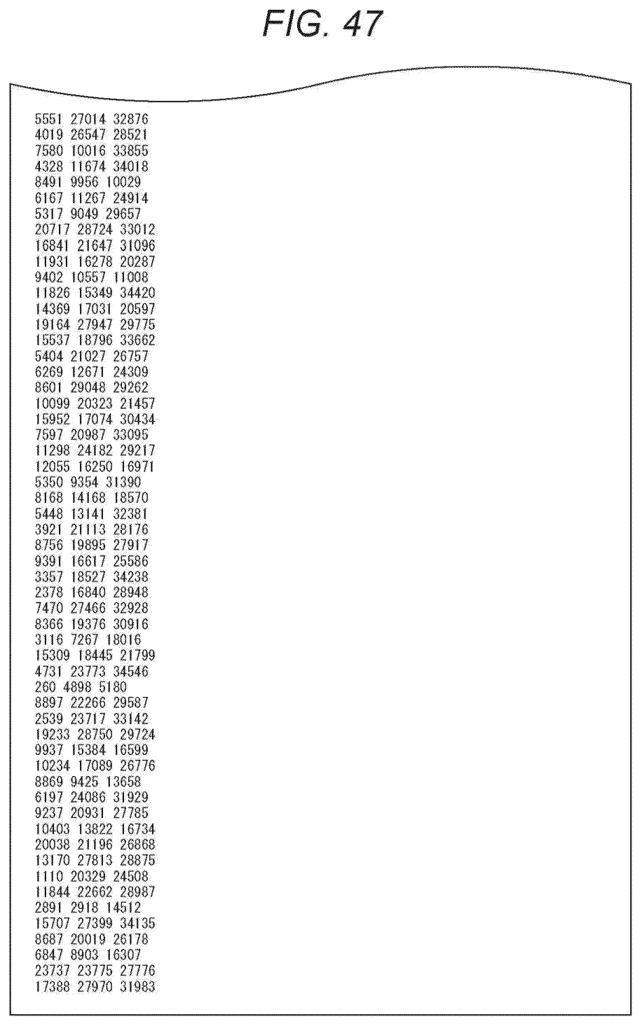

FIGS. 46 and 47 are diagrams illustrating examples of a parity check matrix initial value table representing the parity check matrix H of the type B code (hereinafter, also referred to as a type B code with r=8/16) as a new LDPC code with the code length N of 69120 bits and the coding rate r of 8/16.

Note that FIG. 47 is a diagram following FIG. 46.

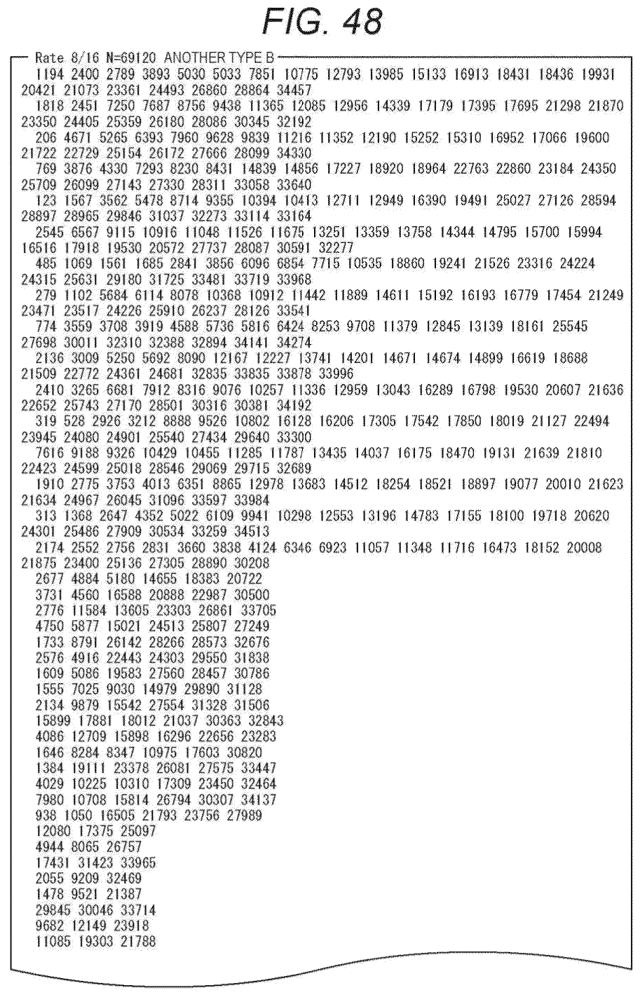

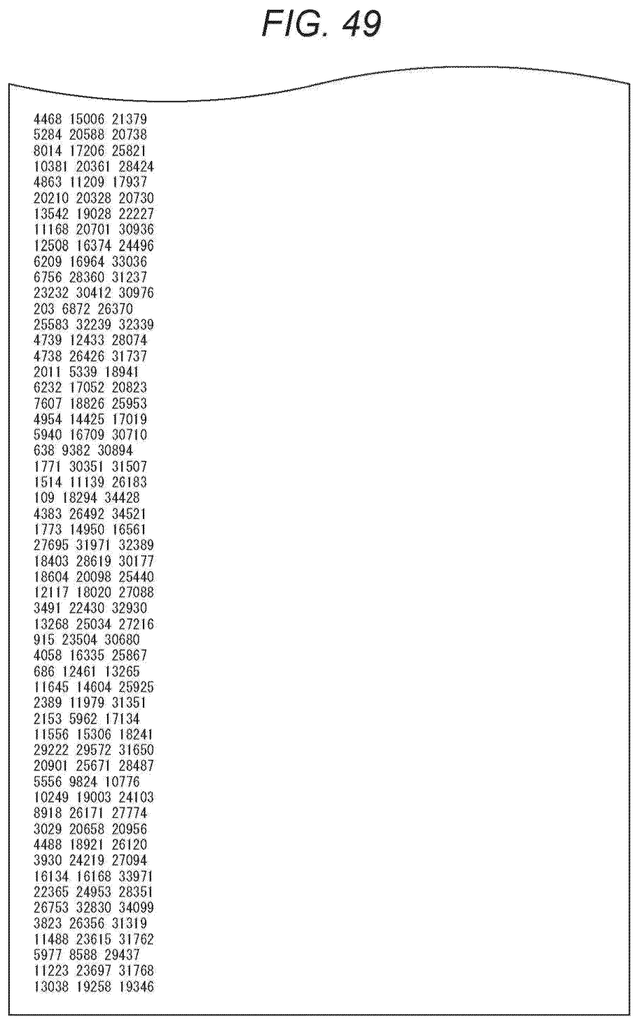

FIGS. 48 and 49 are diagrams illustrating another example of a parity check matrix initial value table representing the parity check matrix H of the type B code with r=8/16.

Note that FIG. 49 is a diagram following FIG. 48. The type B code with r=8/16 obtained from the parity check matrix initial value table in FIGS. 48 and 49 is hereinafter also referred to as another type B code with r=8/16.

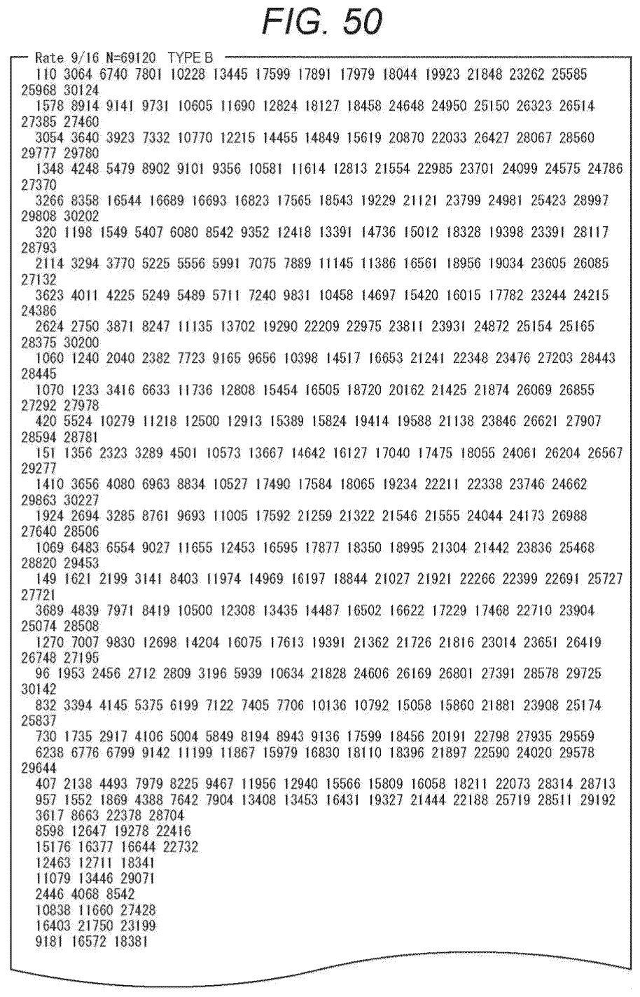

FIGS. 50, 51, and 52 are diagrams illustrating examples of a parity check matrix initial value table representing the parity check matrix H of the type B code (hereinafter, also referred to as a type B code with r=9/16) as a new LDPC code with the code length N of 69120 bits and the coding rate r of 9/16.

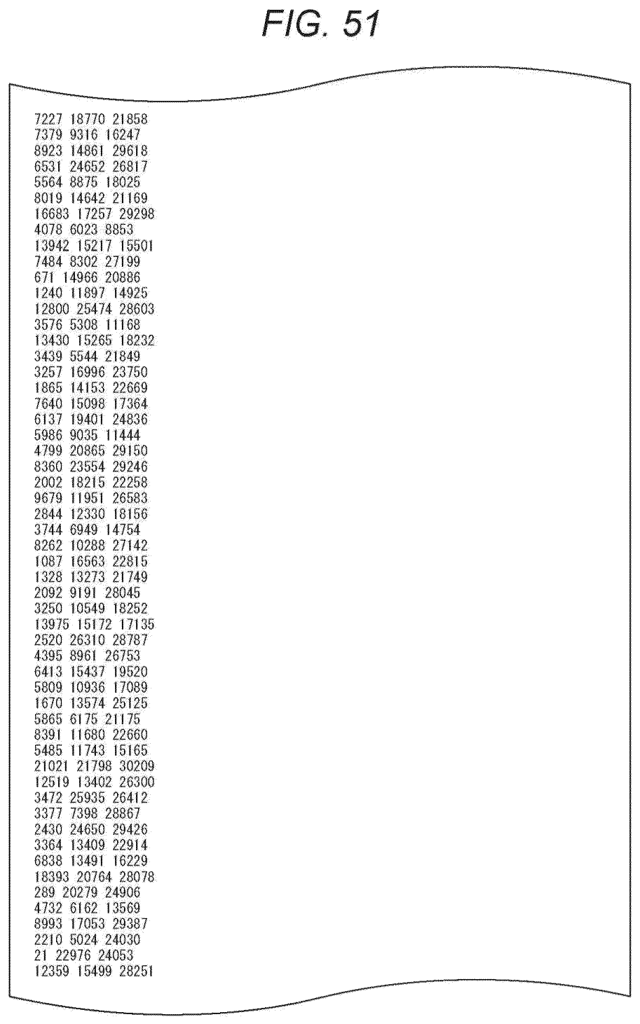

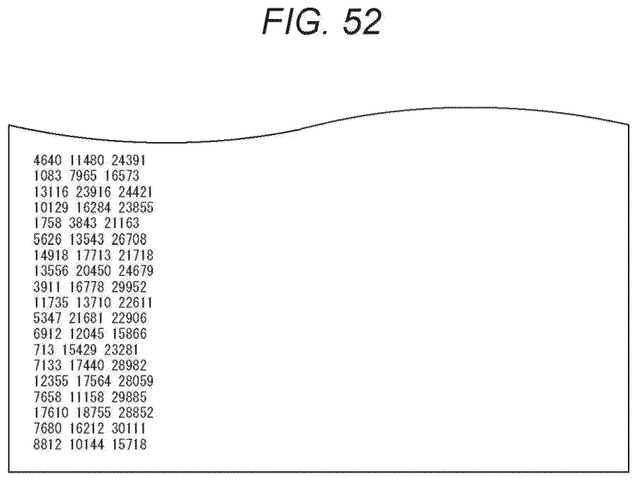

Note that FIG. 51 is a diagram following FIG. 50, and FIG. 52 is a diagram following FIG. 51.

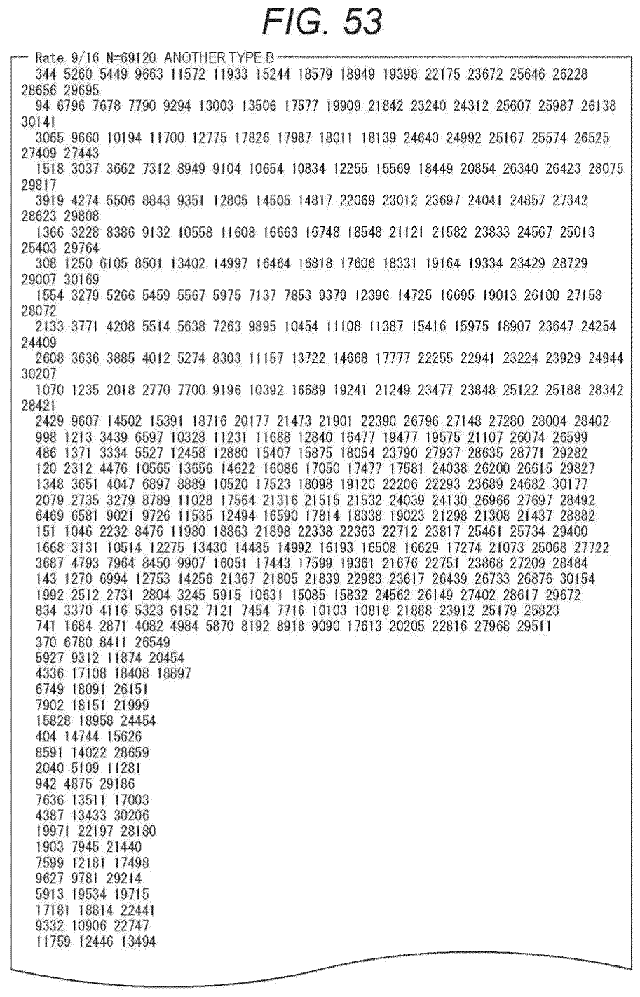

FIGS. 53, 54, and 55 are diagrams illustrating another example of a parity check matrix initial value table representing the parity check matrix H of the type B code with r=9/16.

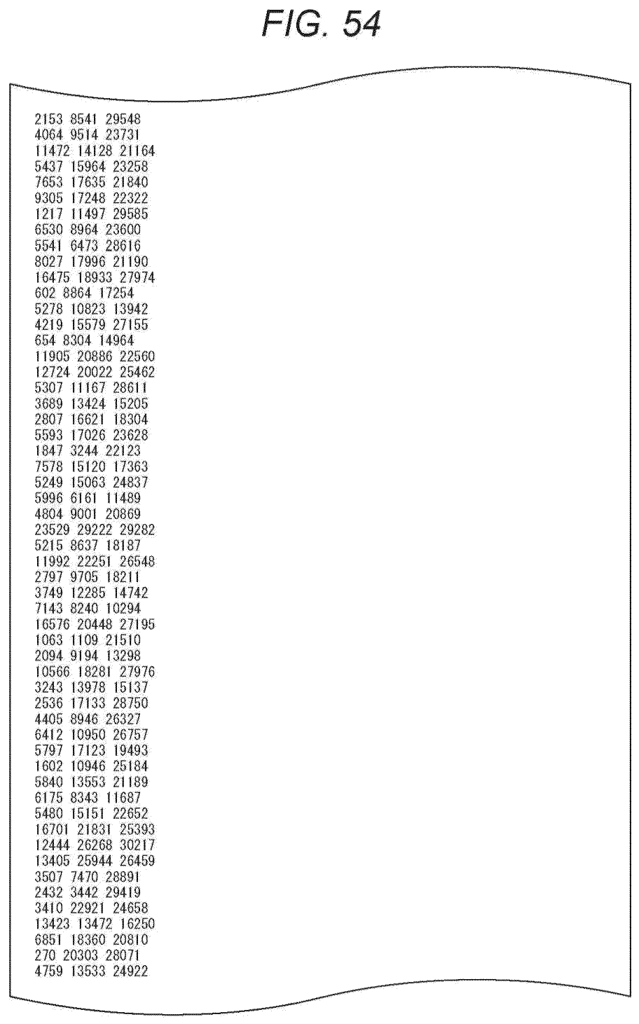

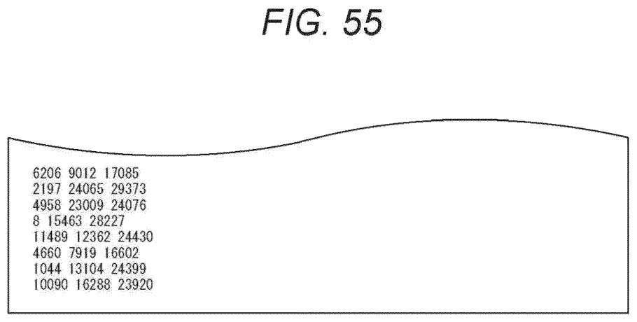

Note that FIG. 54 is a diagram following FIG. 53, and FIG. 55 is a diagram following FIG. 54. The type B code with r=9/16 obtained from the parity check matrix initial value table in FIGS. 53 to 55 is hereinafter also referred to as another type B code with r=9/16.

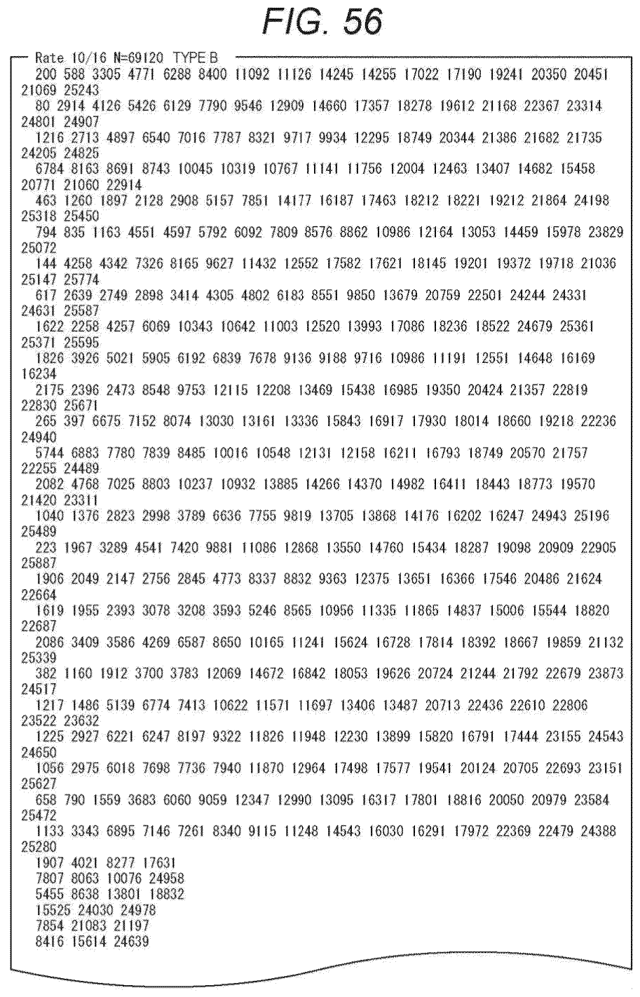

FIGS. 56, 57, and 58 are diagrams illustrating examples of a parity check matrix initial value table representing the parity check matrix H of the type B code (hereinafter, also referred to as a type B code with r=10/16) as a new LDPC code with the code length N of 69120 bits and the coding rate r of 10/16.

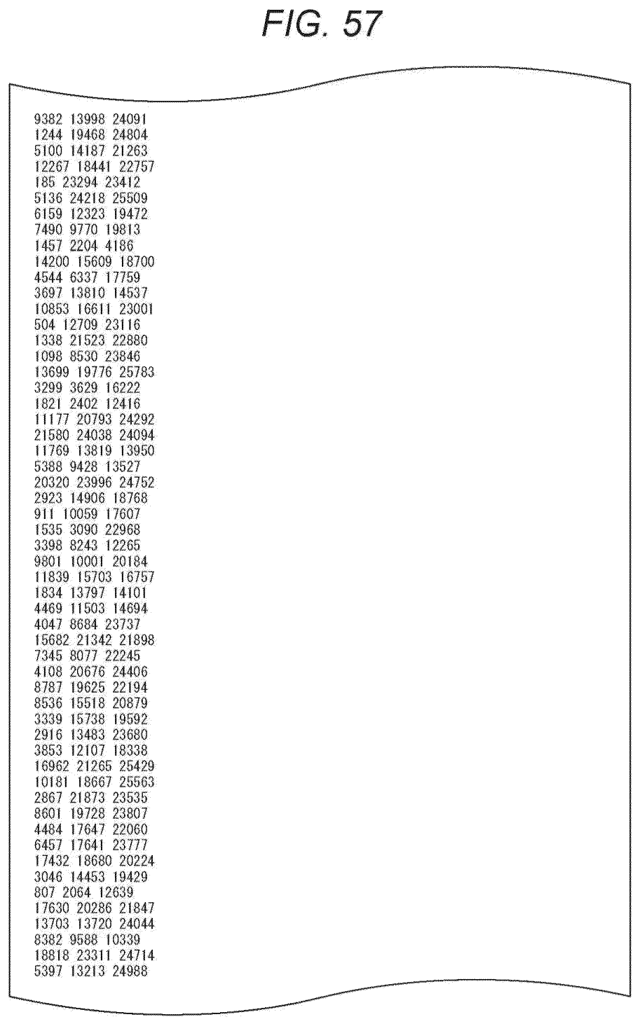

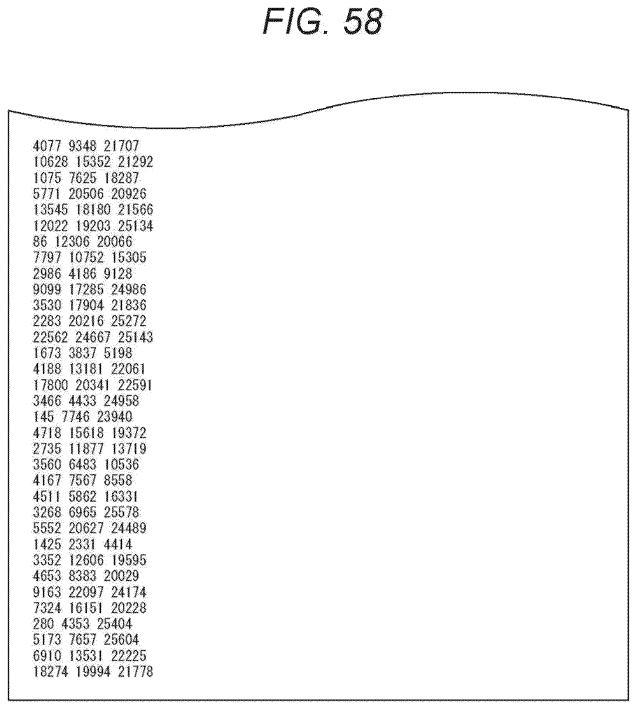

Note that FIG. 57 is a diagram following FIG. 56, and FIG. 58 is a diagram following FIG. 57.

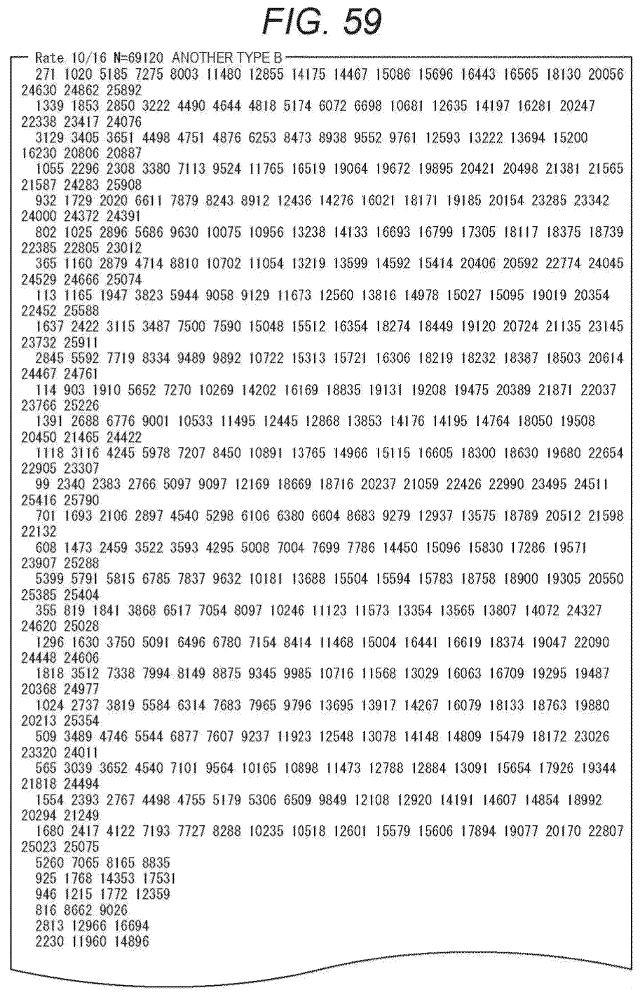

FIGS. 59, 60, and 61 are diagrams illustrating another example of a parity check matrix initial value table representing the parity check matrix H of the type B code with r=10/16.

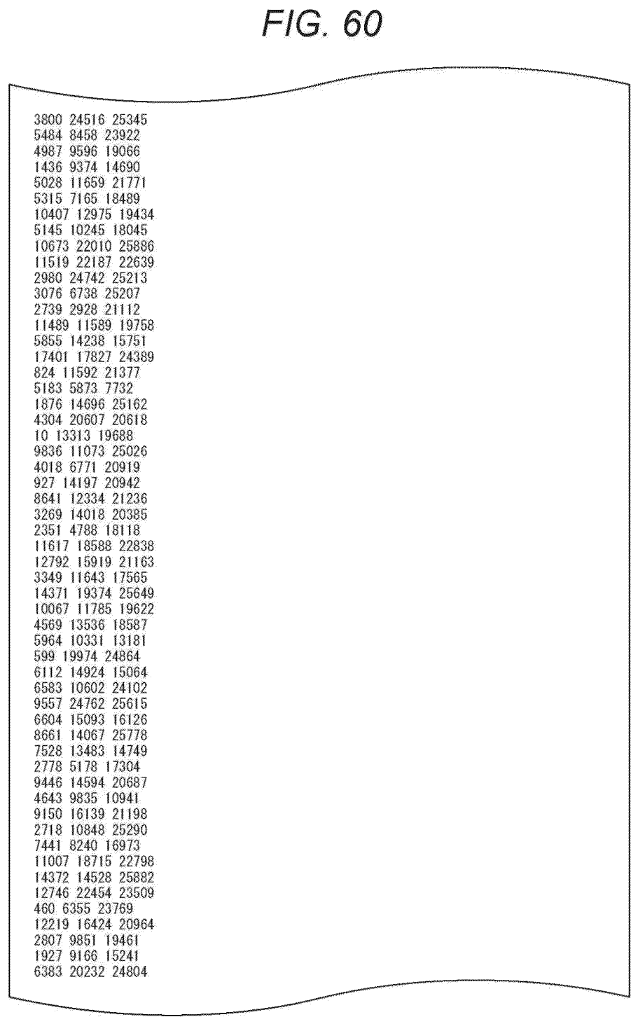

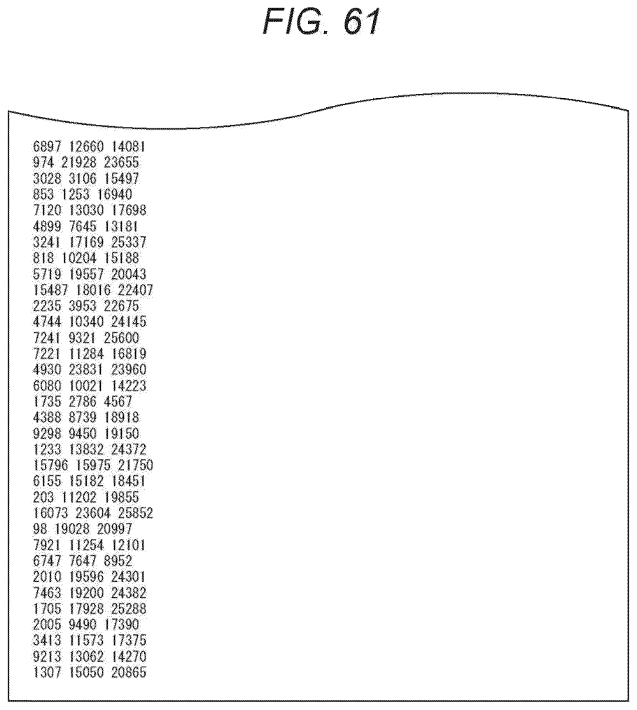

Note that FIG. 60 is a diagram following FIG. 59, and FIG. 61 is a diagram following FIG. 60. The type B code with r=10/16 obtained from the parity check matrix initial value table in FIGS. 59 to 61 is hereinafter also referred to as another type B code with r=10/16.

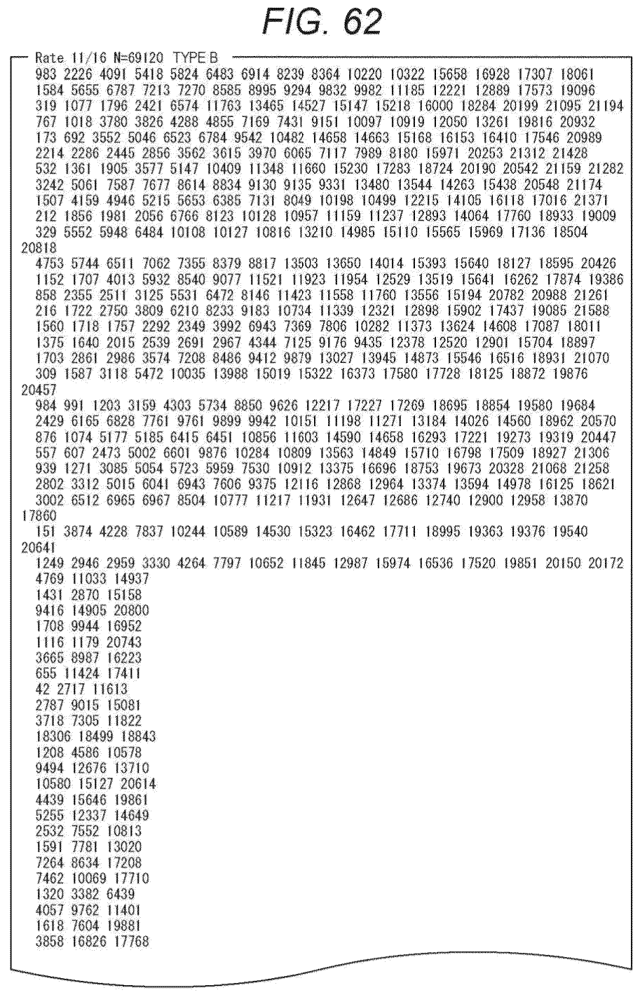

FIGS. 62, 63, and 64 are diagrams illustrating examples of a parity check matrix initial value table representing the parity check matrix H of the type B code (hereinafter, also referred to as a type B code with r=11/16) as a new LDPC code with the code length N of 69120 bits and the coding rate r of 11/16.

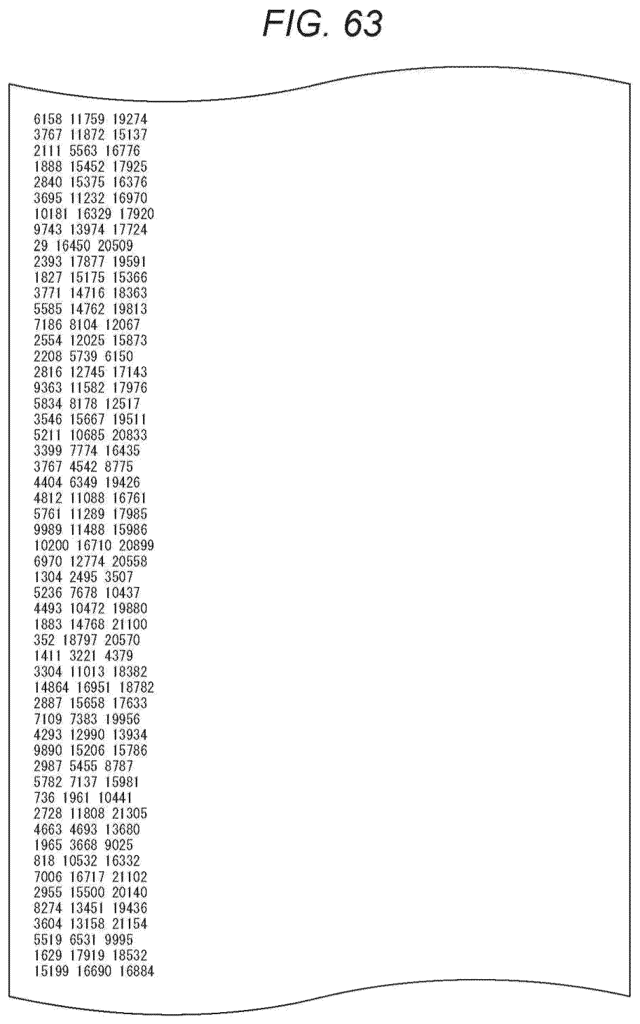

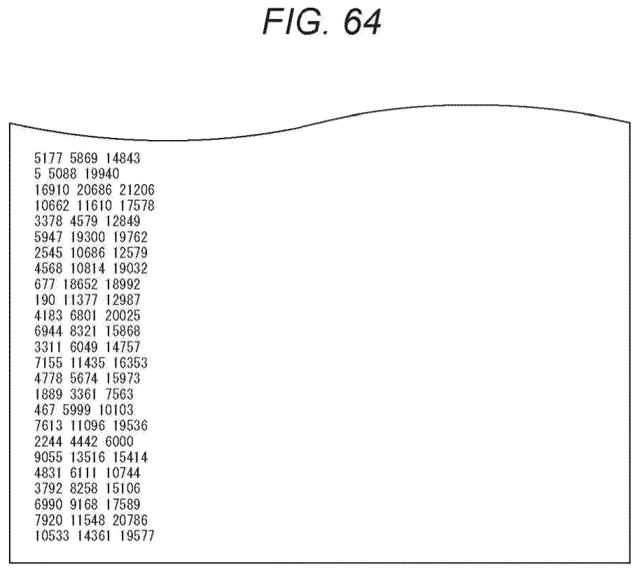

Note that FIG. 63 is a diagram following FIG. 62, and FIG. 64 is a diagram following FIG. 63.

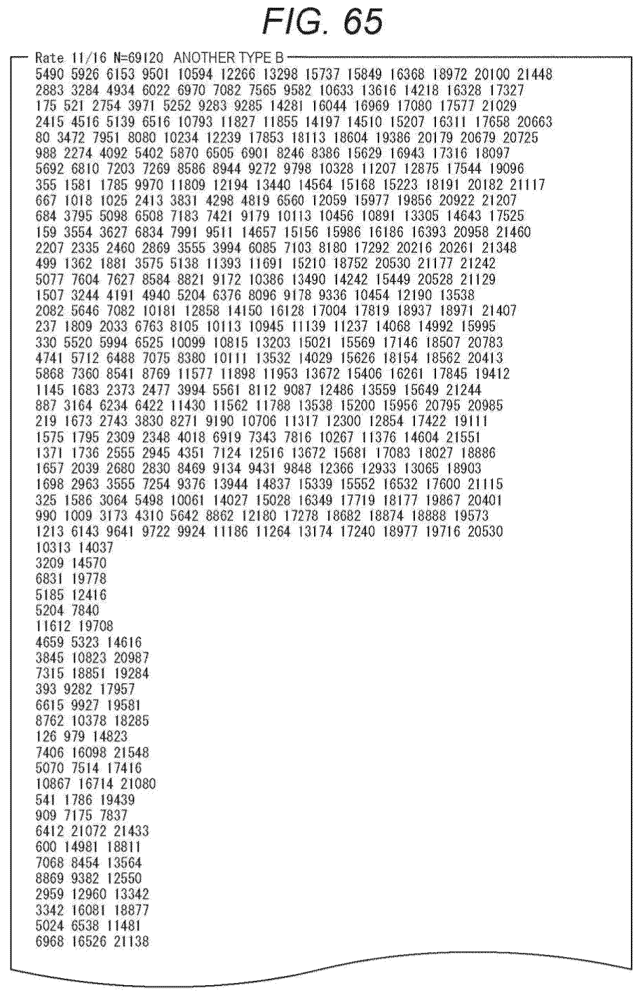

FIGS. 65, 66, and 67 are diagrams illustrating another example of a parity check matrix initial value table representing the parity check matrix H of the type B code with r=11/16.

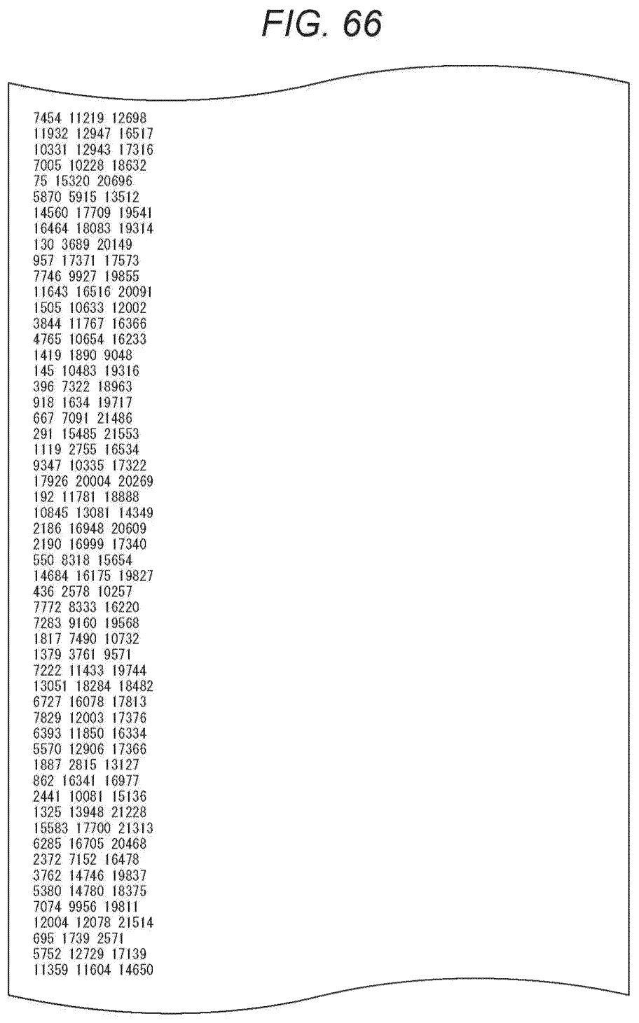

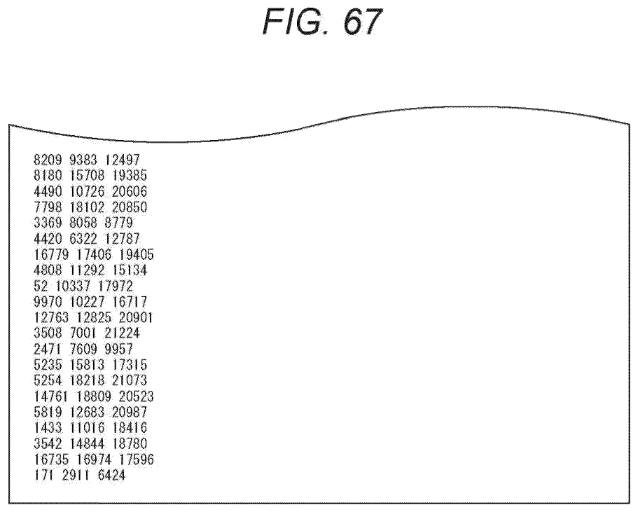

Note that FIG. 66 is a diagram following FIG. 65, and FIG. 67 is a diagram following FIG. 66. The type B code with r=11/16 obtained from the parity check matrix initial value table in FIGS. 65 to 67 is hereinafter also referred to as another type B code with r=11/16.

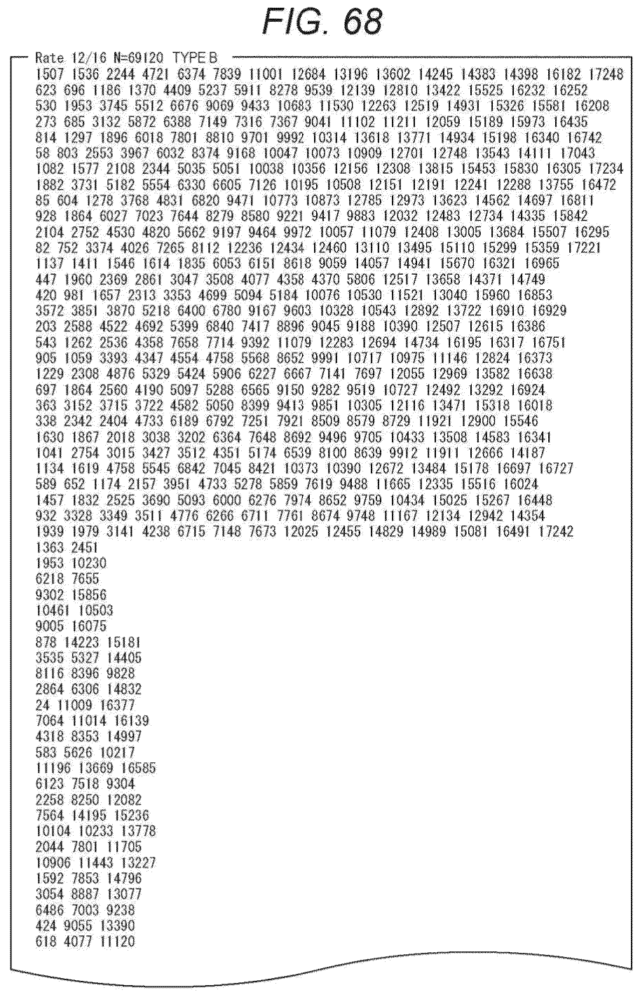

FIGS. 68, 69, and 70 are diagrams illustrating examples of a parity check matrix initial value table representing the parity check matrix H of the type B code (hereinafter, also referred to as a type B code with r=12/16) as a new LDPC code with the code length N of 69120 bits and the coding rate r of 12/16.

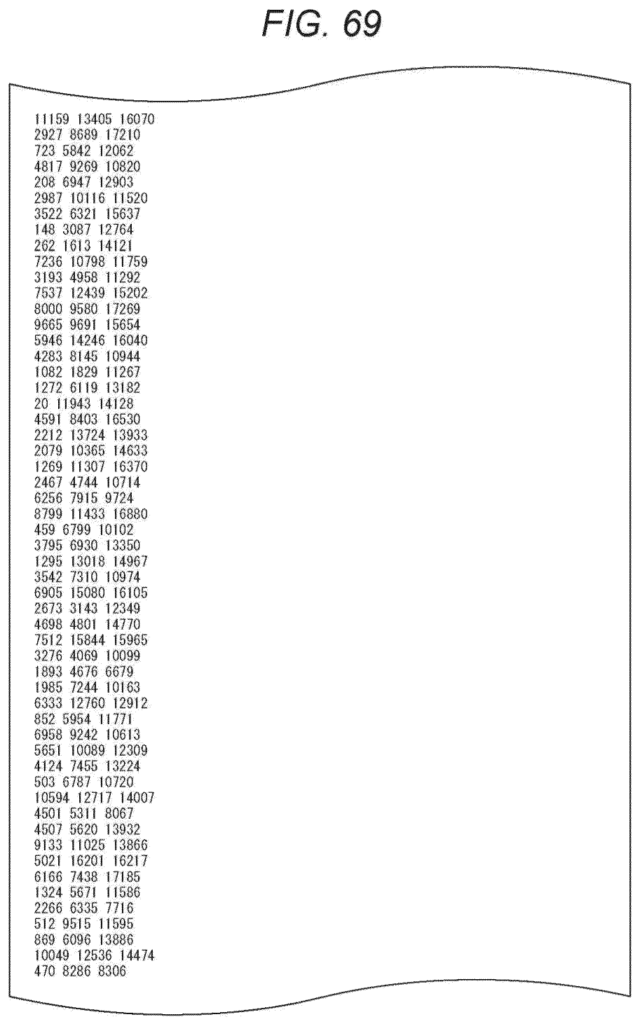

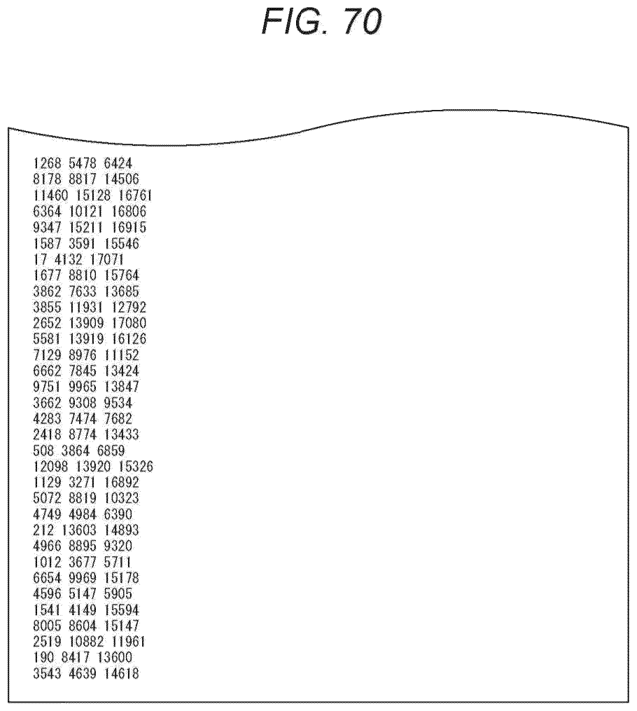

Note that FIG. 69 is a diagram following FIG. 68, and FIG. 70 is a diagram following FIG. 69.

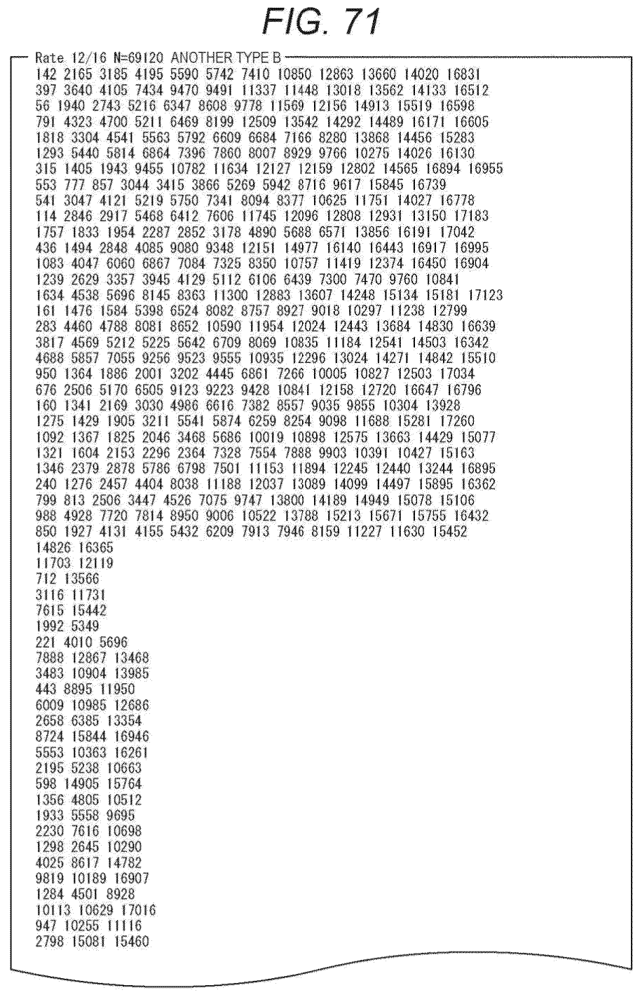

FIGS. 71, 72, and 73 are diagrams illustrating another example of a parity check matrix initial value table representing the parity check matrix H of the type B code with r=12/16.

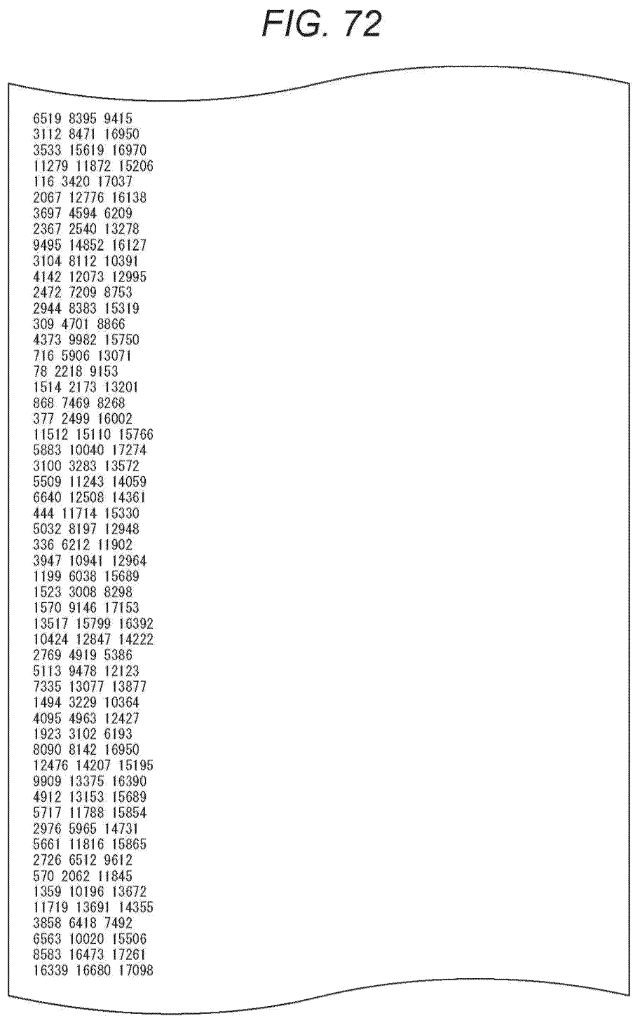

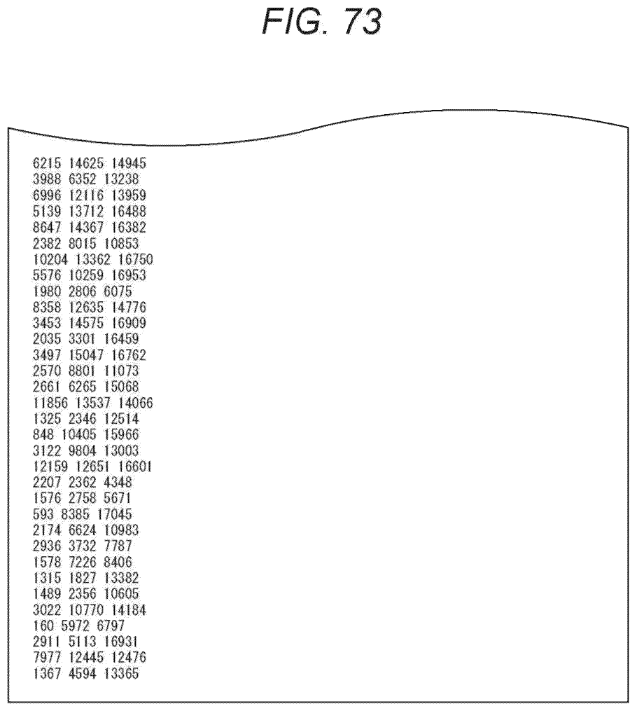

Note that FIG. 72 is a diagram following FIG. 71, and FIG. 73 is a diagram following FIG. 72. The type B code with r=12/16 obtained from the parity check matrix initial value table in FIGS. 71 to 73 is hereinafter also referred to as another type B code with r=12/16.

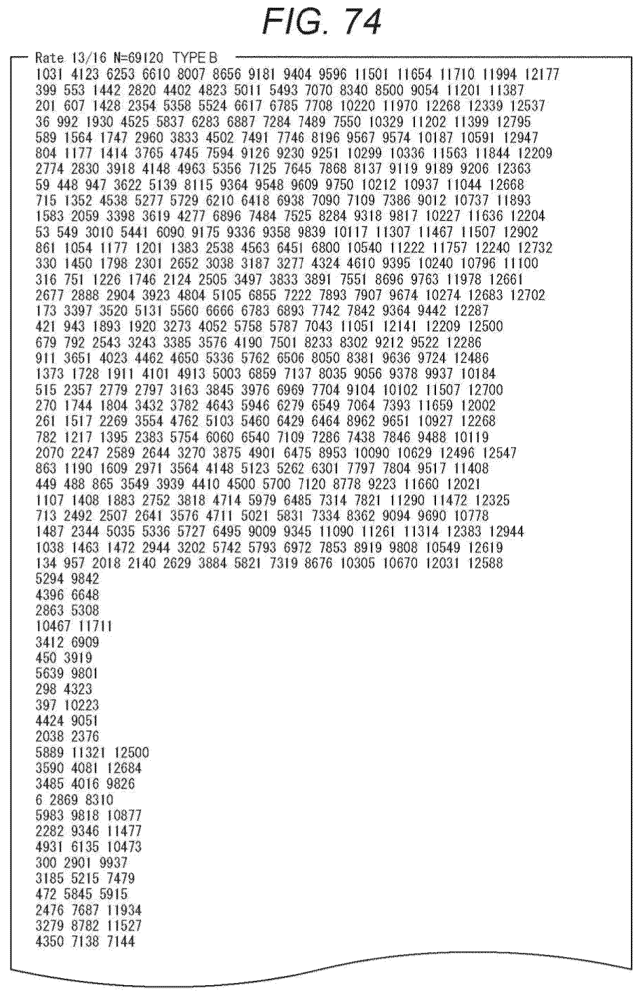

FIGS. 74, 75, and 76 are diagrams illustrating examples of a parity check matrix initial value table representing the parity check matrix H of the type B code (hereinafter, also referred to as a type B code with r=13/16) as a new LDPC code with the code length N of 69120 bits and the coding rate r of 13/16.

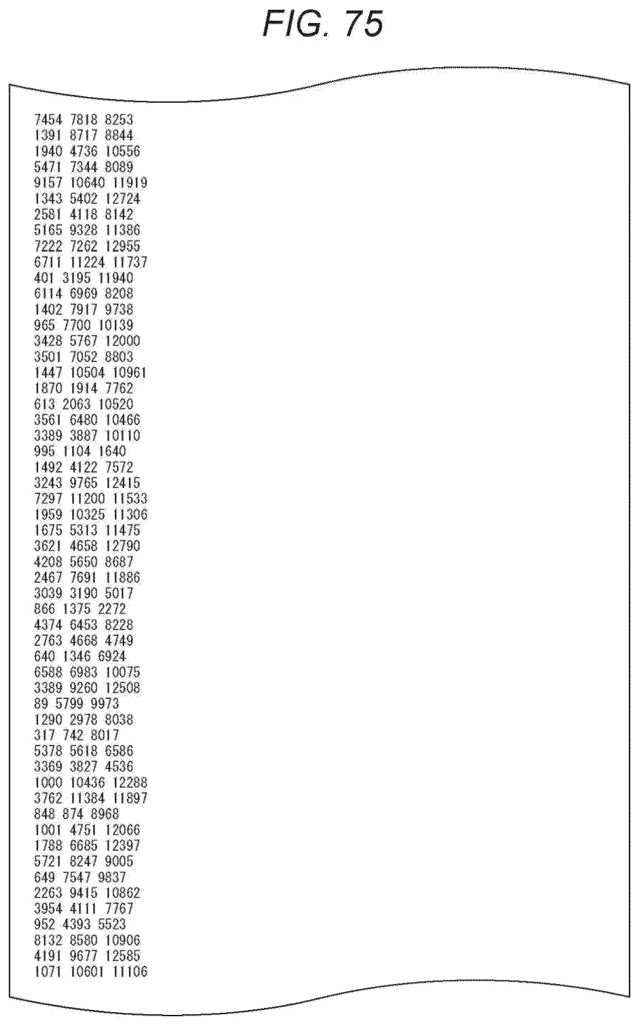

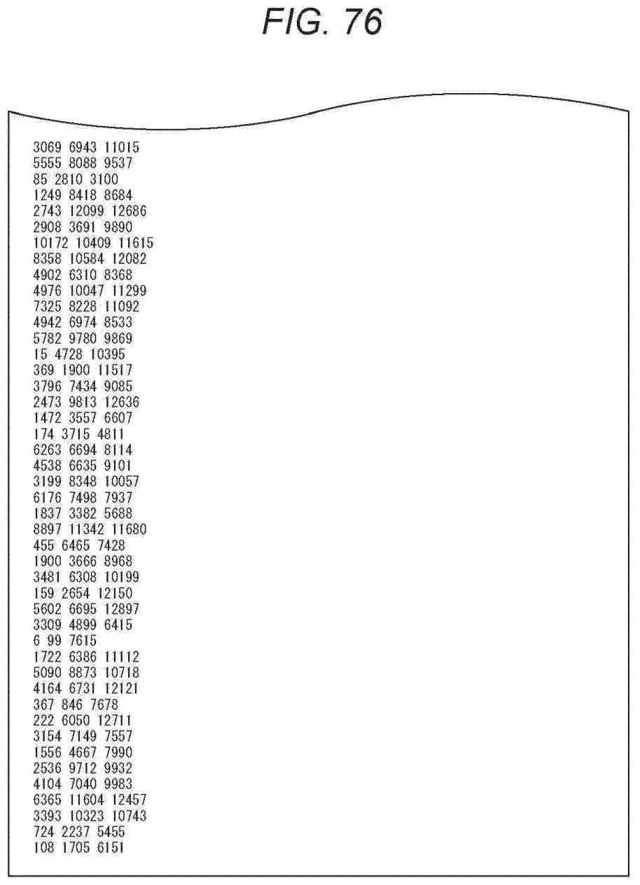

Note that FIG. 75 is a diagram following FIG. 74, and FIG. 76 is a diagram following FIG. 75.

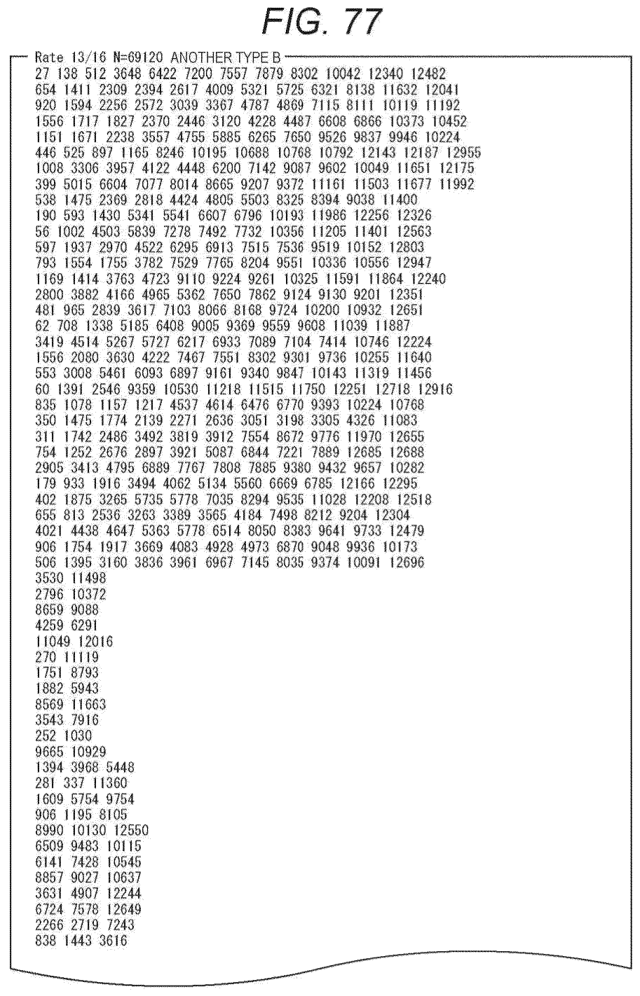

FIGS. 77, 78, and 79 are diagrams illustrating another example of a parity check matrix initial value table representing the parity check matrix H of the type B code with r=13/16.

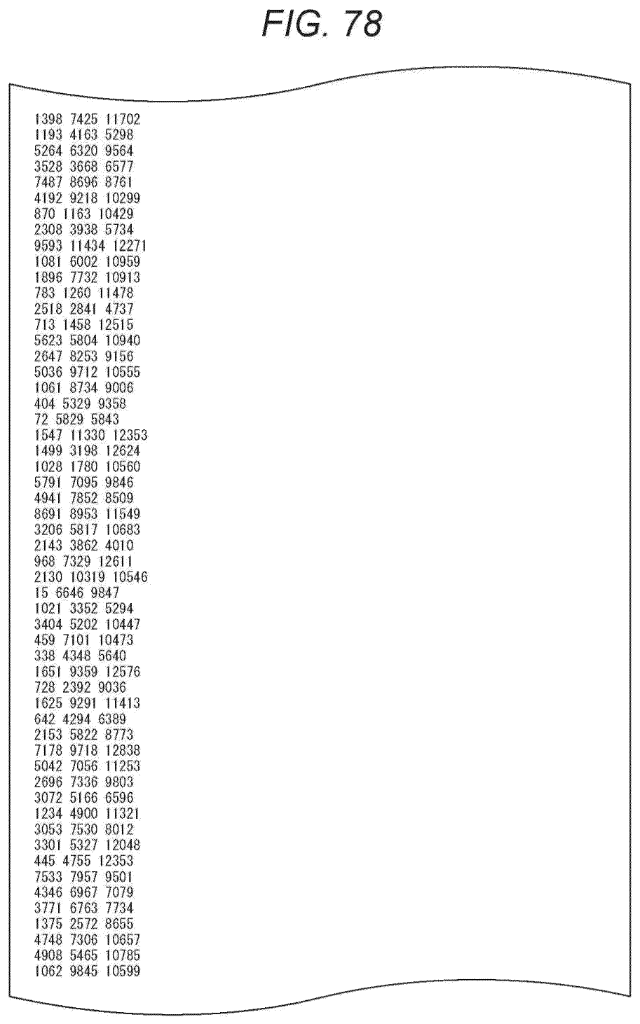

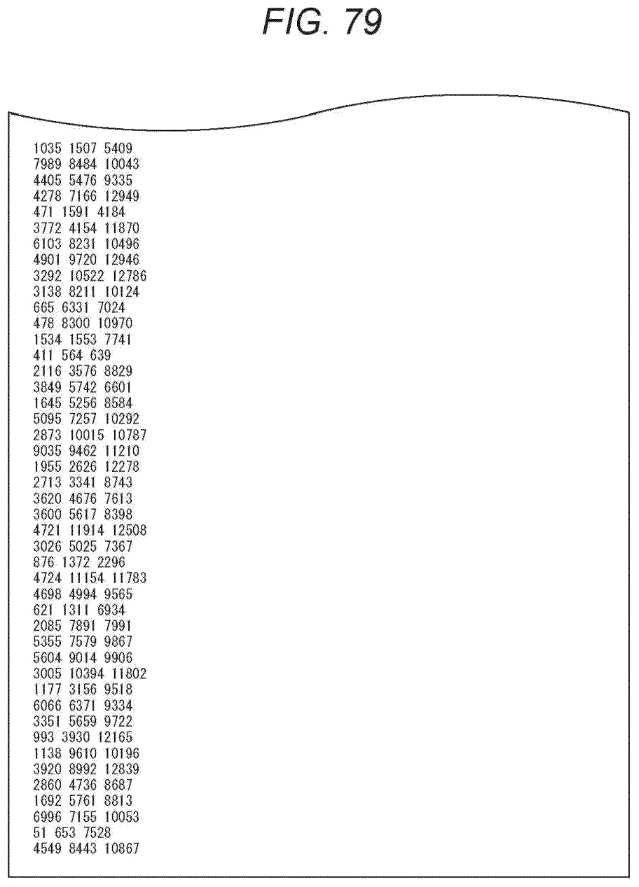

Note that FIG. 78 is a diagram following FIG. 77, and FIG. 79 is a diagram following FIG. 78. The type B code with r=13/16 obtained from the parity check matrix initial value table in FIGS. 77 to 79 is hereinafter also referred to as another type B code with r=13/16.

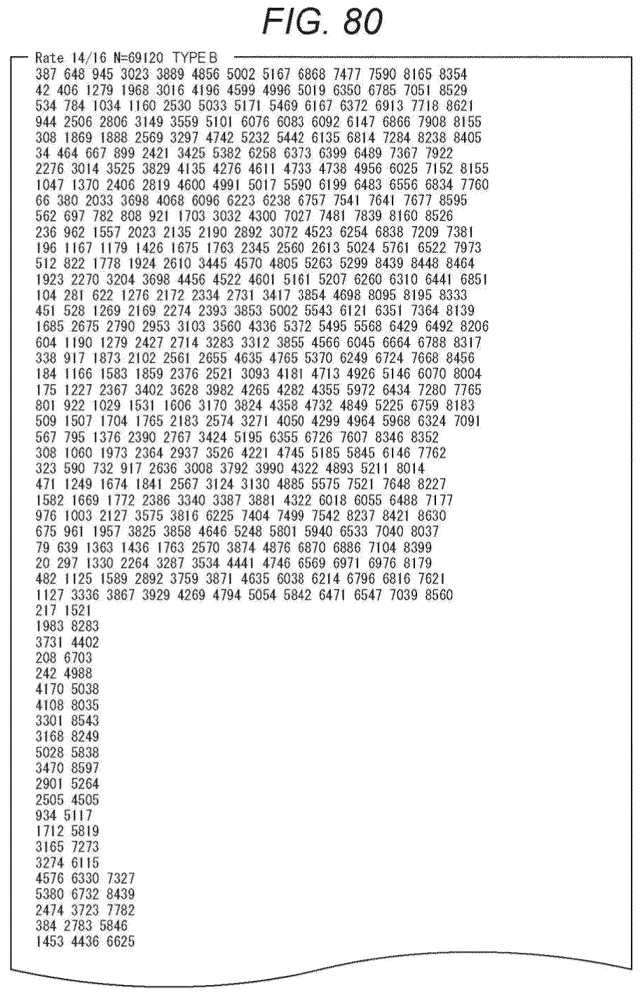

FIGS. 80, 81, and 82 are diagrams illustrating examples of a parity check matrix initial value table representing the parity check matrix H of the type B code (hereinafter, also referred to as a type B code with r=14/16) as a new LDPC code with the code length N of 69120 bits and the coding rate r of 14/16.

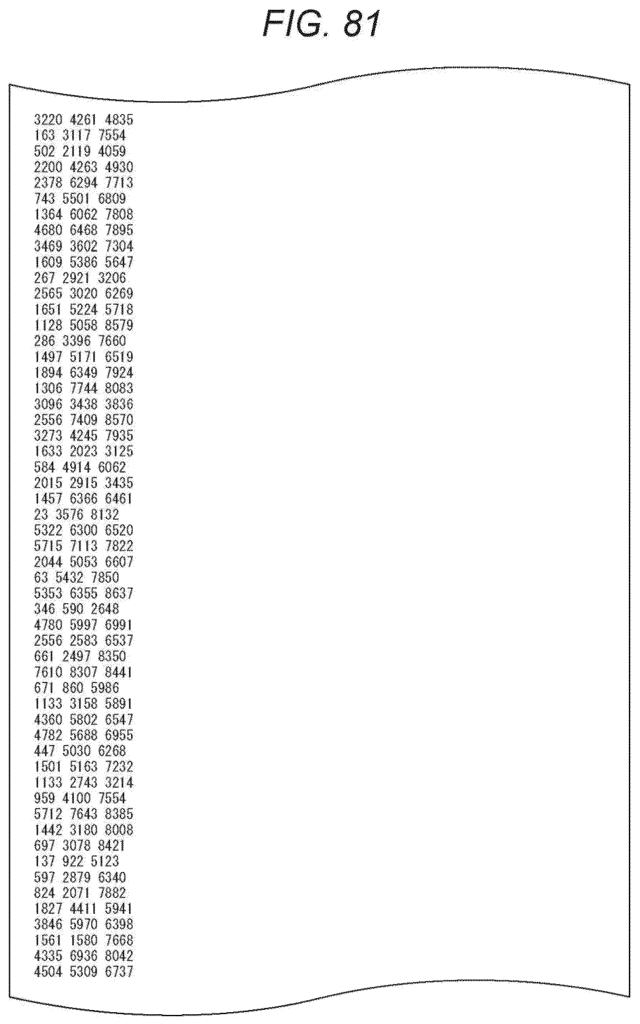

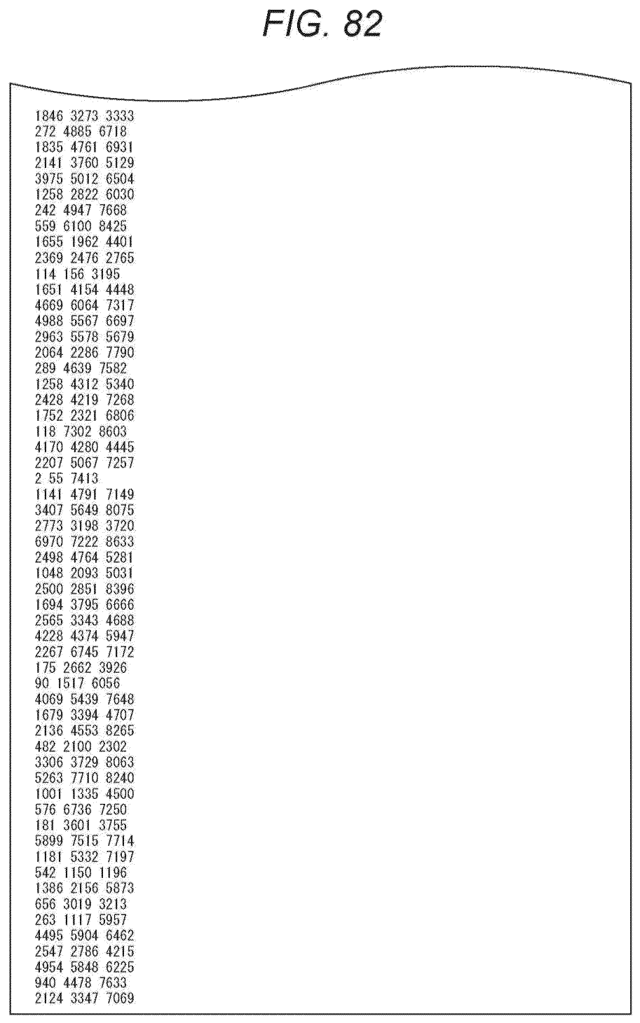

Note that FIG. 81 is a diagram following FIG. 80, and FIG. 82 is a diagram following FIG. 81.

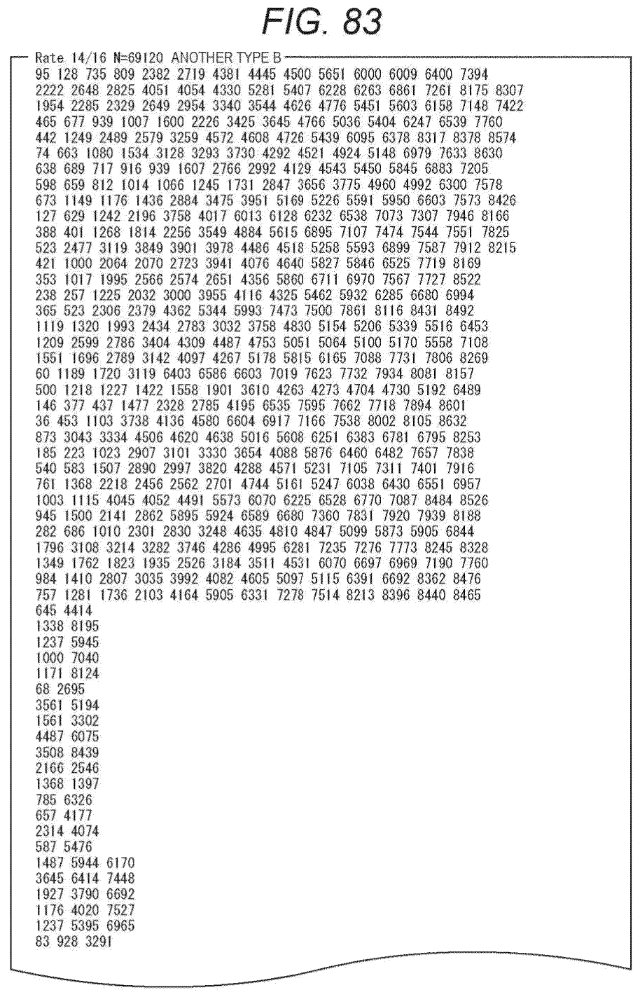

FIGS. 83, 84, and 85 are diagrams illustrating another example of a parity check matrix initial value table representing the parity check matrix H of the type B code with r=14/16.

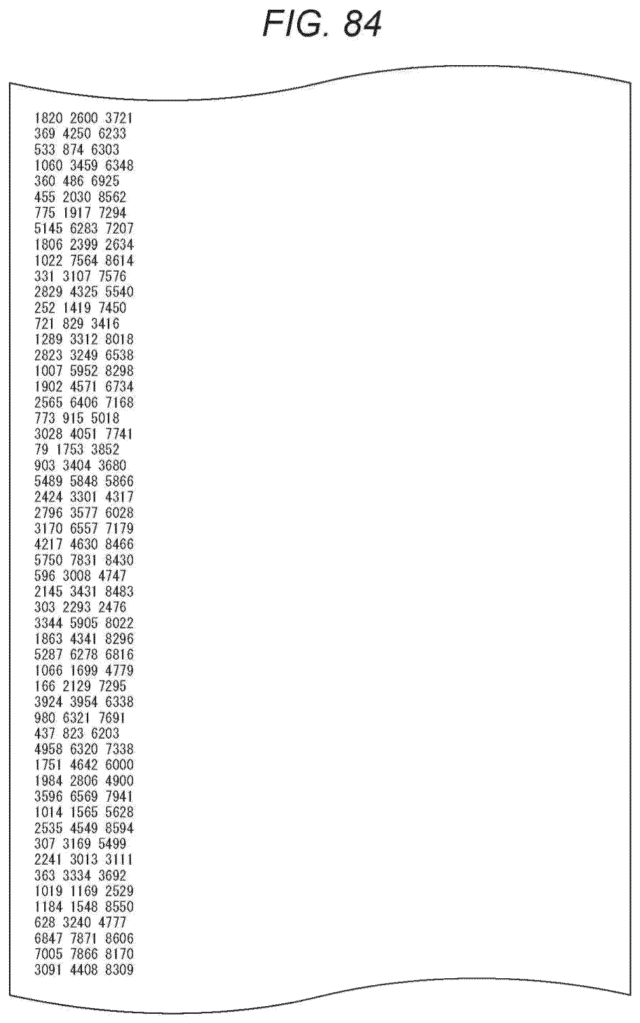

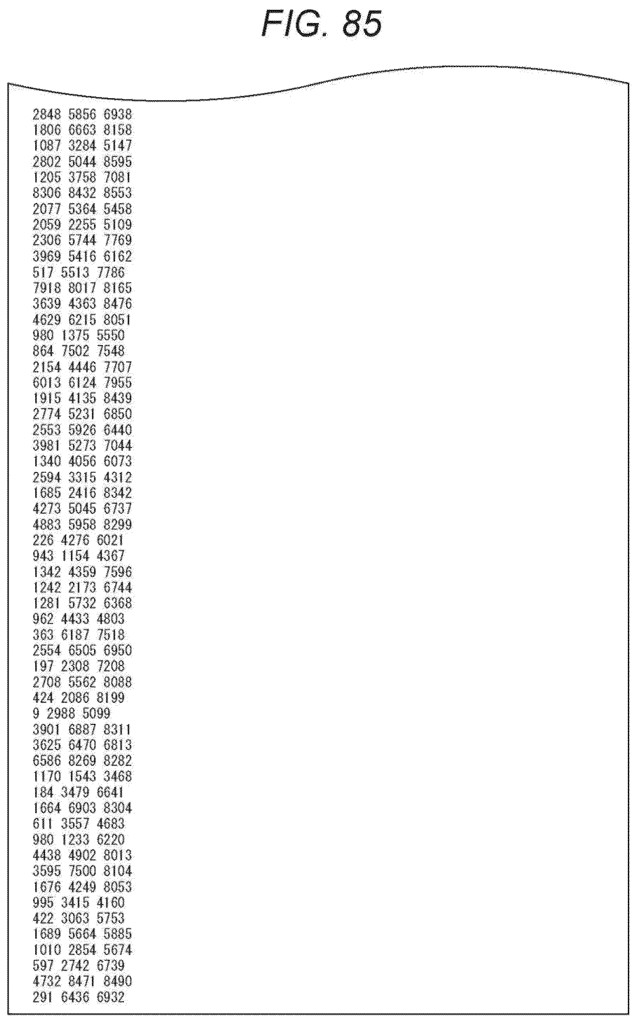

Note that FIG. 84 is a diagram following FIG. 83, and FIG. 85 is a diagram following FIG. 84. The type B code with r=14/16 obtained from the parity check matrix initial value table in FIGS. 83 to 85 is hereinafter also referred to as another type B code with r=14/16.

The new LDPC code is a high-performance LDPC code.

Here, the high-performance LDPC code is an LDPC code obtained from an appropriate check matrix H.

The appropriate check matrix H is, for example, a parity check matrix that satisfies a predetermined condition for making a bit error rate (BER) (and a frame error rate (FER)) smaller when an LDPC code obtained from the parity check matrix H is transmitted at a low Eₛ/N₀ or E_{b}/Nₒ (signal power to noise power ratio per bit).

The appropriate check matrix H can be obtained, for example, by performing simulation for measuring BER when an LDPC code obtained from various parity check matrices satisfying a predetermined condition is transmitted at a low Eₛ/Nₒ.

Examples of the predetermined condition to be satisfied by the appropriate check matrix H include that an analysis result obtained by a code performance analysis method called density evolution is good, that there is no loop of elements of 1 called cycle 4, and the like.

Here, in the information matrix H_{A}, it is known that the decoding performance of the LDPC code deteriorates when the elements of 1 are dense as in cycle 4, and thus, it is desirable that cycle 4 does not exist in the parity check matrix H.

In the parity check matrix H, the minimum value of the length (loop length) of the loop constituted by the elements of 1 is called girth. The absence of cycle 4 means that the girth is greater than 4.

Note that the predetermined condition to be satisfied by the appropriate check matrix H can be appropriately determined from the viewpoint of improving the decoding performance of the LDPC code, facilitating (simplifying) the decoding processing of the LDPC code, and the like.

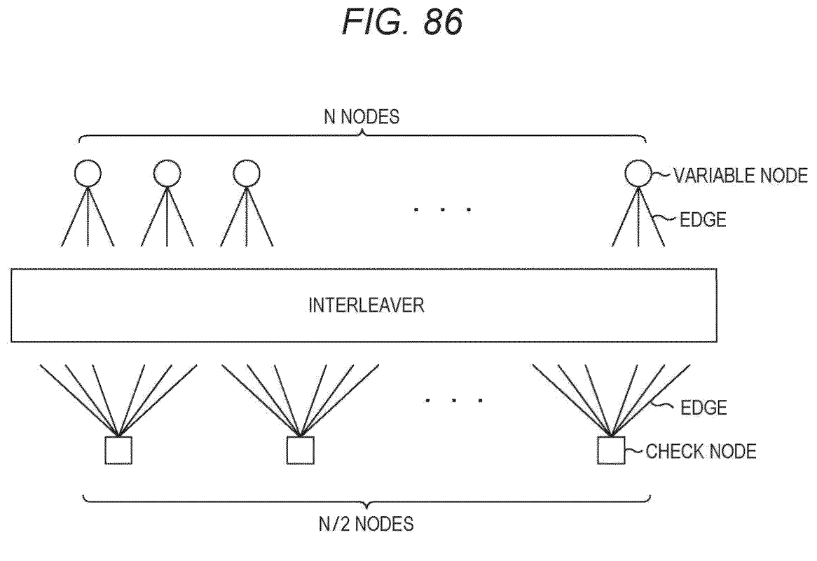

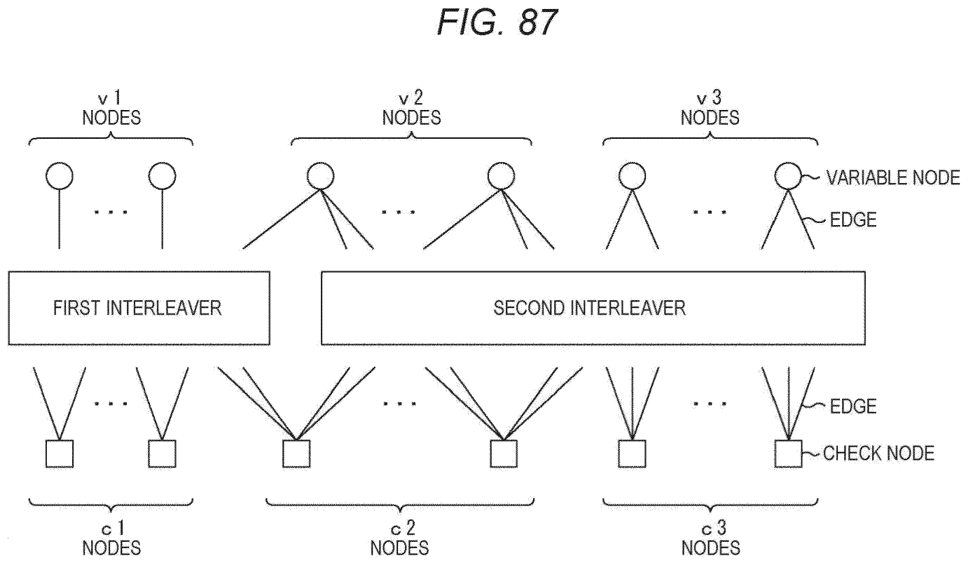

FIGS. 86 and 87 are diagrams for explaining density evolution by which an analysis result as a predetermined condition to be satisfied by an appropriate check matrix H can be obtained.

The density evolution is a code analysis method for calculating an expected value of an error probability of an entire LDPC code (ensemble) having a code length N of ∞ characterized by a degree sequence as described later.

For example, when the variance value of the noise is gradually increased from 0 on the AWGN channel, the expected value of the error probability of a certain ensemble is initially 0, but is not 0 when the variance value of the noise is a certain threshold or more.

According to the density evolution, it is possible to determine whether the performance of the ensemble (appropriateness of the parity check matrix) is good or bad by comparing the threshold (hereinafter, also referred to as a performance threshold) of the variance value of the noise at which the expected value of the error probability is not 0.

Note that, when an ensemble to which a specific LDPC code belongs is determined and density evolution is performed on the ensemble, rough performance of the LDPC code can be predicted.

Therefore, if a high-performance ensemble is found, the high-performance LDPC code can be found from the LDPC codes belonging to the ensemble.

Here, the degree sequence described above represents a ratio of variable nodes and check nodes having weights of respective values to the code length N of the LDPC code.

For example, a regular (3, 6)LDPC code with a code rate of 1/2 belongs to an ensemble characterized by a degree sequence in which weights (column weights) of all variable nodes are 3 and weights (row weights) of all check nodes are 6.

FIG. 86 illustrates a Tanner graph of such an ensemble.

In the Tanner bluff of FIG. 86, there are N variable nodes indicated by circles (∘) in the drawing, the number being equal to the code length N, and there are N/2 check nodes indicated by squares (□) in the drawing, the number being equal to a multiplication value obtained by multiplying the code length N by the coding rate 1/2.

Three edges equal to the column weight are connected to each variable node, and thus, there are 3N edges in total connected to the N variable nodes.

Furthermore, six edges equal to the row weight are connected to each check node, and thus, there are a total of 3N edges connected to N/2 check nodes.

Moreover, in the Tanner graph of FIG. 86, there is one interleaver.

The interleaver randomly rearranges the 3N edges connected to the N variable nodes, and connects each rearranged edge to any one of the 3N edges connected to the N/2 check nodes.

The rearrangement pattern for rearranging 3N edges connected to N variable nodes in the interleaver is (3N)!(=(3N)×(3N−1)× . . . ×1) Therefore, the ensemble characterized by the degree sequence that the weights of all the variable nodes are 3 and the weights of all the check nodes are 6 is (3N)! a set of LDPC codes.

In the simulation for obtaining a high-performance LDPC code (appropriate parity check matrix), a multi-edge type ensemble is used in density evolution.

In the multi-edge type, the interleaver through which the edge connected to the variable node and the edge connected to the check node pass is divided into a plurality of (multiple edges), whereby the ensemble is characterized more strictly.

FIG. 87 illustrates an example of a Tanner graph of a multi-edge type ensemble.

In the Tanner graph of FIG. 87, there are two interleavers: a first interleaver and a second interleaver.

Furthermore, in the Tanner graph of FIG. 87, there are v1 variable nodes each having one edge connected to the first interleaver and 0 edges connected to the second interleaver, v2 variable nodes each having one edge connected to the first interleaver and two edges connected to the second interleaver, and v3 variable nodes each having 0 edges connected to the first interleaver and two edges connected to the second interleaver.

Moreover, in the Tanner graph of FIG. 87, there are c1 check nodes each having two edges connected to the first interleaver and 0 edges connected to the second interleaver, c2 check nodes each having two edges connected to the first interleaver and two edges connected to the second interleaver, and c3 check nodes each having 0 edges connected to the first interleaver and 3 edges connected to the second interleaver.

Here, the density evolution and the implementation thereof are described in, for example, “On the Design of Low-Density Parity-Check Codes within 0.0045 dB of the Shannon Limit”, S. Y. Chung, G. D. Forney, T. J. Richardson, R. Urbanke, IEEE Communications Leggers, VOL. 5, NO. 2, February 2001.

In the simulation for obtaining (the parity check matrix of) the new LDPC code, an ensemble in which the performance threshold, which is E_{b}/N₀ (the signal power-to-noise power ratio per bit) at which the BER starts to drop (becomes smaller), becomes a predetermined value or less is found by the multi-edge type density evolution, and the LDPC code that decreases the BER in the case of using one or more orthogonal modulations such as QPSK is selected from the LDPC codes belonging to the ensemble as the LDPC code with high performance.

(The parity check matrix initial value table representing the parity check matrix of) the new LDPC code was obtained by the above simulation.

Therefore, according to the new LDPC code, good communication quality can be secured in data transmission.

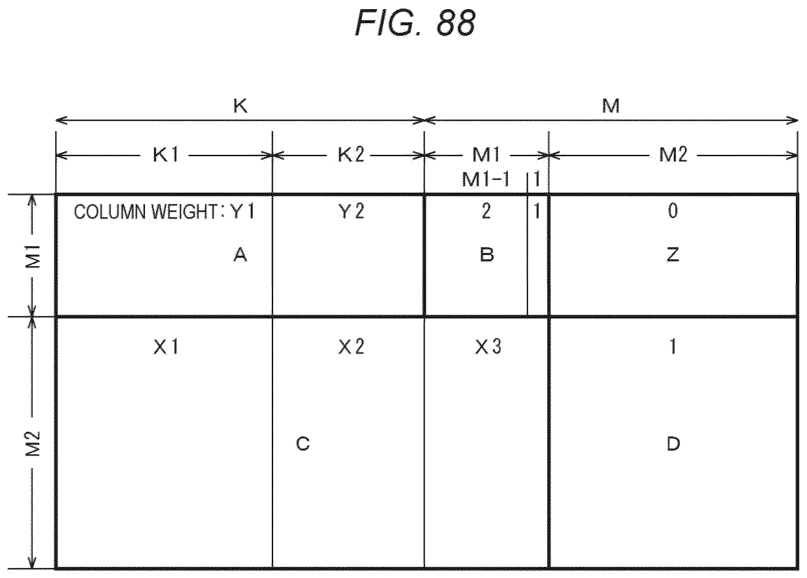

FIG. 88 is a diagram for explaining column weights of a parity check matrix H of a type A code as a new LDPC code.

For the parity check matrix H of the type A code, as illustrated in FIG. 88, the column weight of K1 columns from the 1st column of the A matrix is represented as Y1, the column weight of K2 columns after the A matrix is represented as Y2, the column weight of K1 columns from the 1st column of the C matrix is represented as X1, the column weight of K2 columns after the C matrix is represented as X2, and the column weight of M1 columns after the C matrix is represented as X3.

Note that K1+K2 is equal to the information length K, and M1+M2 is equal to the parity length M. Therefore, K1+K2+M1+M2 is equal to the code length N=69120 bits.

Furthermore, for the parity check matrix H of the type A code, the column weight of M1−1 columns from the 1st column of the B matrix is 2, and the column weight of the M1 column (last column) of the B matrix is 1. Moreover, a column weight of the D matrix is 1, and a column weight of the Z matrix is 0.

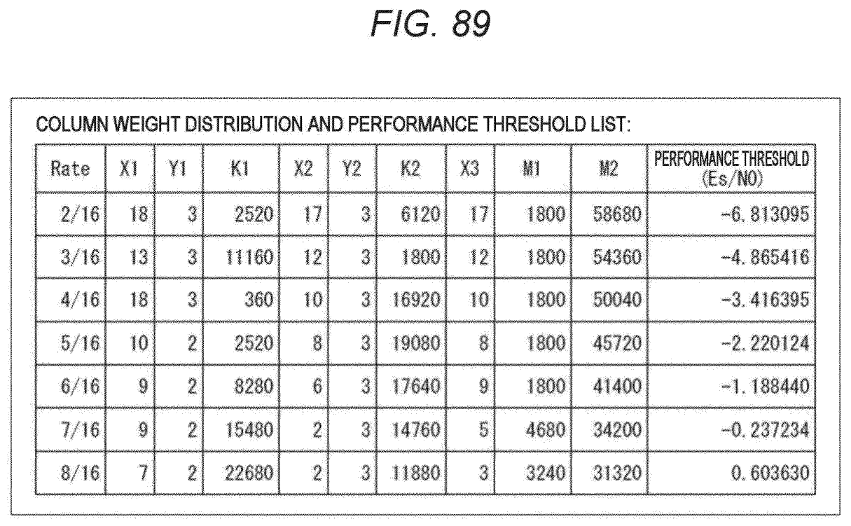

FIG. 89 is a diagram illustrating parameters of parity check matrices H of the type A codes (represented by the parity check matrix initial value tables) in FIGS. 30 to 41.

X1, Y1, K1, X2, Y2, K2, X3, M1, and M2 as parameters of the parity check matrix H of the type A code with r=2/16, 3/16, 4/16, 5/16, 6/16, 7/16, and 8/16, and the performance threshold are as illustrated in FIG. 89.

The parameters X1, Y1, K1 (or K2), X2, Y2, X3, M1 (or M2) are set so that the performance (for example, an error rate or the like) of the LDPC code is further improved.

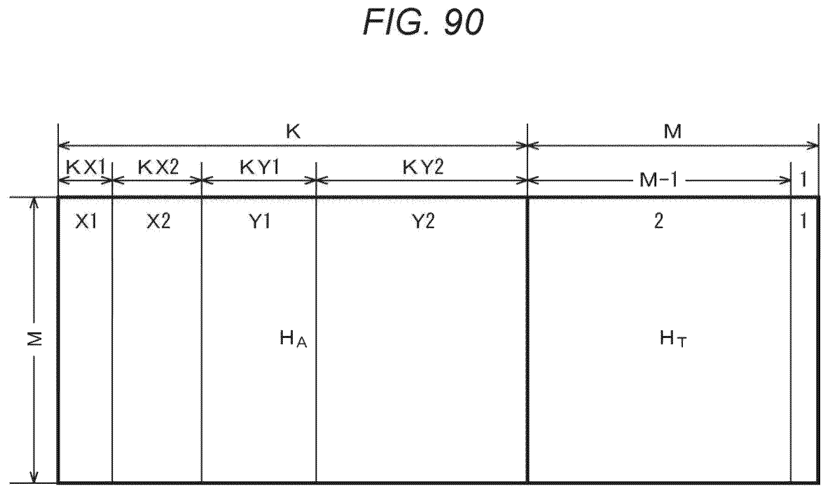

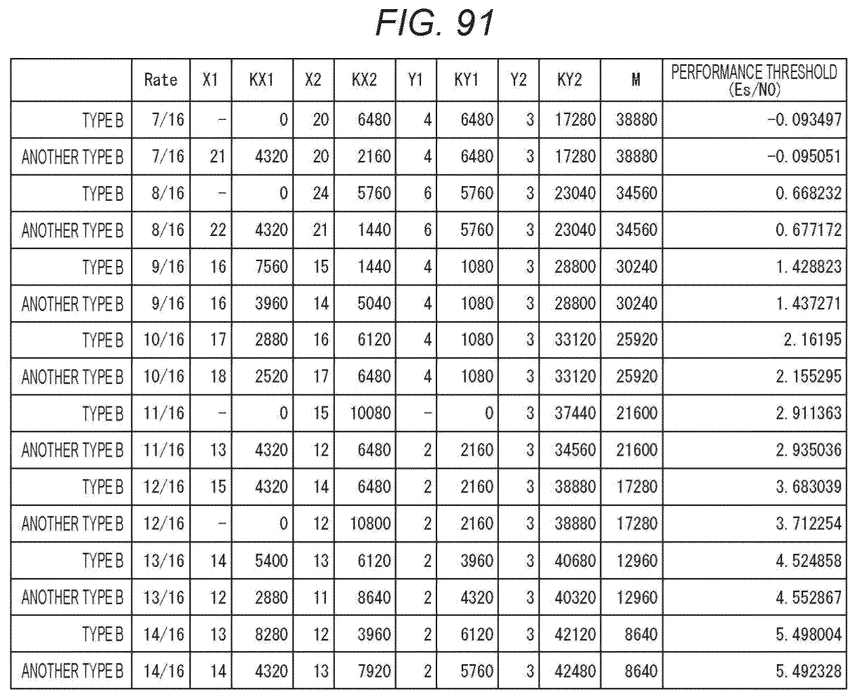

FIG. 90 is a diagram for explaining column weights of a parity check matrix H of a type B code as a new LDPC code.

For the parity check matrix H of the type B code, as illustrated in FIG. 90, the column weight of the first to KX1 columns is represented as X1, the column weight of the subsequent KX2 columns is represented as X2, the column weight of the subsequent KY1 columns is represented as Y1, and the column weight of the subsequent KY2 columns is represented as Y2.

Note that KX1+KX2+KY1+KY2 is equal to the information length K, and KX1+KX2+KY1+KY2+M is equal to the code length N=69120 bits.

Furthermore, for the parity check matrix H of the type B code, the column weight of M−1 columns excluding the last one column among the last M columns is 2, and the column weight of the last one column is 1.

FIG. 91 is a diagram illustrating parameters of parity check matrices H of the type B codes (represented by the parity check matrix initial value tables) in FIGS. 42 to 85.

X1, KX1, X2, KX2, Y1, KY1, Y2, KY2, and M as parameters of the parity check matrix H of the type B code and the other type B codes with r=7/16, 8/16, 9/16, 10/16, 11/16, 12/16, 13/16, and 14/16, and the performance thresholds are as illustrated in FIG. 91.

The parameters X1, KX1, X2, KX2, Y1, KY1, Y2, and KY2 are set to further improve the performance of the LDPC code.

According to the new LDPC code, good BER/FER is realized, and a capacity (communication path capacity) close to the Shannon limit is realized.

### <Constellation>

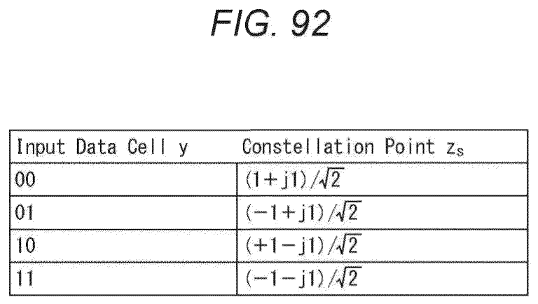

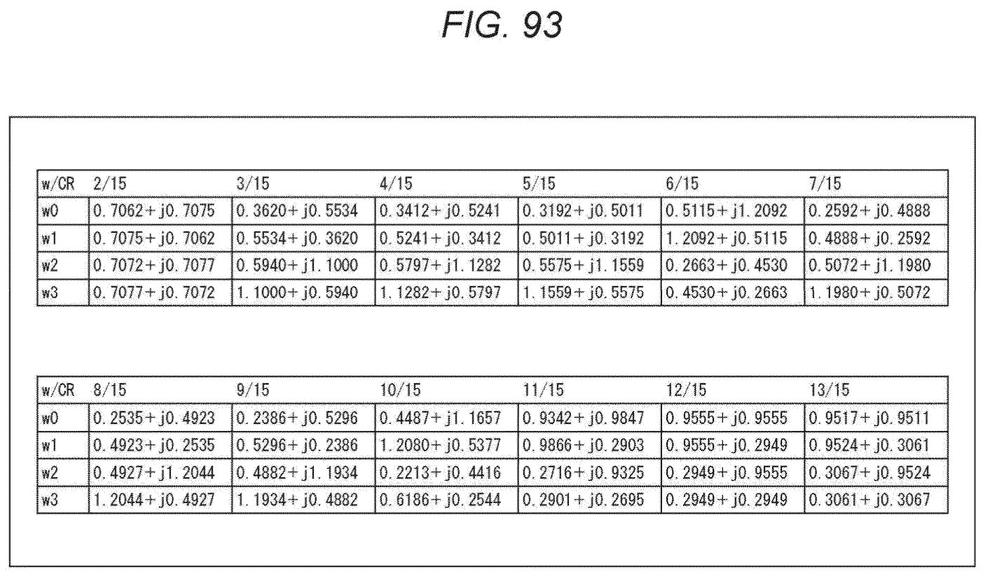

FIGS. 92 to 116 are diagrams illustrating examples of constellations that can be adopted in the transmission system in FIG. 7.

In the transmission system in FIG. 7, for example, for MODCOD that is a combination of a modulation method (MODulation) and an LDPC code (CODe), a constellation used in the MODCOD can be set.

One or more constellations can be set for one MODCOD.

The constellation includes a uniform constellation (UC) in which arrangement of signal points is uniform and a non-uniform constellation (NUC) in which arrangement of signal points is not uniform.

Furthermore, the NUC includes, for example, a constellation called 1-dimensional (M²-QAM) non-uniform constellation (1D-NUC), a constellation called 2-dimensional (QQAM) non-uniform constellation (2D-NUC), and the like.

In general, the BER is improved in the 1D-NUC than the UC, and further, the BER is improved in the 2D-NUC than the 1D-NUC.

The constellation in which the modulation method is QPSK is UC. For example, UC or 2D-NUC can be adopted as a constellation such as 16QAM, 64QAM, or 256QAM as the modulation method, and for example, UC or 1D-NUC can be adopted as a constellation such as 1024QAM or 4096QAM as the modulation method.

In the transmission system in FIG. 7, for example, constellations defined in ATSC3.0, DVB-C.2, and the like, and various other constellations that improve the error rate can be used.

That is, in a case where the modulation method is QPSK, for example, the same UC can be used for each coding rate r of the LDPC code.

Furthermore, in a case where the modulation method is 16QAM, 64QAM, or 256QAM, for example, the same UC can be used for each coding rate r of the LDPC code. Moreover, in a case where the modulation method is 16QAM, 64QAM, or 256QAM, for example, different 2D-NUCs can be used for each coding rate r of the LDPC code.

Furthermore, in a case where the modulation method is 1024QAM or 4096QAM, for example, the same UC can be used for each coding rate r of the LDPC code. Moreover, in a case where the modulation method is 1024QAM or 4096QAM, for example, different 1D-NUCs can be used for each coding rate r of the LDPC code.

Here, UC of QPSK is also referred to as QPSK-UC, and UC of 2^{m}QAM is also referred to as 2^{m}QAM-UC. Furthermore, 1D-NUC and 2D-NUC of 2^{m}QAM are also referred to as 2^{m}QAM-1D-NUC and 2^{m}QAM-2D-NUC, respectively.

Some constellations defined in ATSC3.0 will be described below.

FIG. 92 is a diagram illustrating coordinates of signal points of QPSK-UC used for all coding rates of LDPC codes defined in ATSC3.0 in a case where the modulation method is QPSK.

In FIG. 92, “Input Data cell y” represents a 2-bit symbol mapped to QPSK-UC, and “Constellation point zₛ” represents the coordinates of the signal point zₛ. Note that an index s of the signal point zₛ(This is similar to an index q of a signal point z(as described later.) represents a discrete time of a symbol (a time interval between a certain symbol and a next symbol).

In FIG. 92, the coordinates of the signal point zₛ are represented in the form of a complex number, and j represents an imaginary unit (√(−1).

FIG. 93 is a diagram illustrating coordinates of signal points of 16QAM-2D-NUC used for the coding rates r(CR)=2/15, 3/15, 4/15, 5/15, 6/15, 7/15, 8/15, 9/15, 10/15, 11/15, 12, 15, and 13/15 of the LDPC codes defined in ATSC3.0 in a case where the modulation method is 16QAM.

In FIG. 93, similarly to FIG. 92, the coordinates of the signal point zₛ are represented in the form of a complex number, and j represents an imaginary unit.

In FIG. 93, w #k represents a coordinate of a signal point in the first quadrant of the constellation.

In the 2D-NUC, the signal point in the second quadrant of the constellation is arranged at a position obtained by symmetrically moving the signal point in the first quadrant with respect to the Q axis, and the signal point in the third quadrant of the constellation is arranged at a position obtained by symmetrically moving the signal point in the first quadrant with respect to the origin. Then, the signal points in the fourth quadrant of the constellation are arranged at positions obtained by symmetrically moving the signal points in the first quadrant with respect to an I axis.

Here, in a case where the modulation method is 2^{m}QAM, m bits are defined as one symbol, and the one symbol is mapped to a signal point corresponding to the symbol.

The m-bit symbol can be expressed by, for example, an integer value of 0 to 2^{m}−1. Now, when b=2^{m}/4, the symbols y(0), y(1), . . . , and y(2^{m}−1) expressed by integer values of 0 to 2^{m}−1 can be classified into four groups of symbols y(0) to y(b−1), y(b) to y(2b−1), y(2b) to y(3b−1), and y(3b) to y(4b−1).

In FIG. 93, the suffix k of w #k takes an integer value in a range of 0 to b−1, and w #k represents coordinates of a signal point corresponding to a symbol y(k) in a range of symbols y(0) to y(b−1).

Then, the coordinate of the signal point corresponding to the symbol y(k+b) in the range of symbols y(b) to y(2b−1) is represented by −conj(w #k), and the coordinate of the signal point corresponding to the symbol y(k+2b) in the range of symbols y(2b) to y(3b−1) is represented by conj(w #k). Furthermore, the coordinates of the signal point corresponding to the symbol y(k+3b) in the range of symbols y(3b) to y(4b−1) are represented by −w #k.

Here, conj(w #k) represents a complex conjugate of w #k.

For example, in a case where the modulation method is 16QAM, symbols y(0), y(1), . . . , and y(15) of m=4 bits are classified into four groups of symbols y(0) to y(3), y(4) to y(7), y(8) to y(11), and y(12) to y(15), where b=24/4=4.

Then, for example, since the symbol y(12), of the symbols y(0) to y(15), is a symbol y (k+3b)=y(0+3 4) in the range of symbols y(3b) to y(4b−1) and k=0, the coordinate of the signal point corresponding to the symbol y(12) is −w #k=−w0.

Now, assuming that the coding rate r(CR) of the LDPC code is, for example, 9/15, w0 in a case where the modulation method is 16QAM and the coding rate r is 9/15 is 0.2386+j0.5296 according to FIG. 93, so that the coordinate−w0 of the signal point corresponding to the symbol y(12) is −(0.2386+j0.5296).

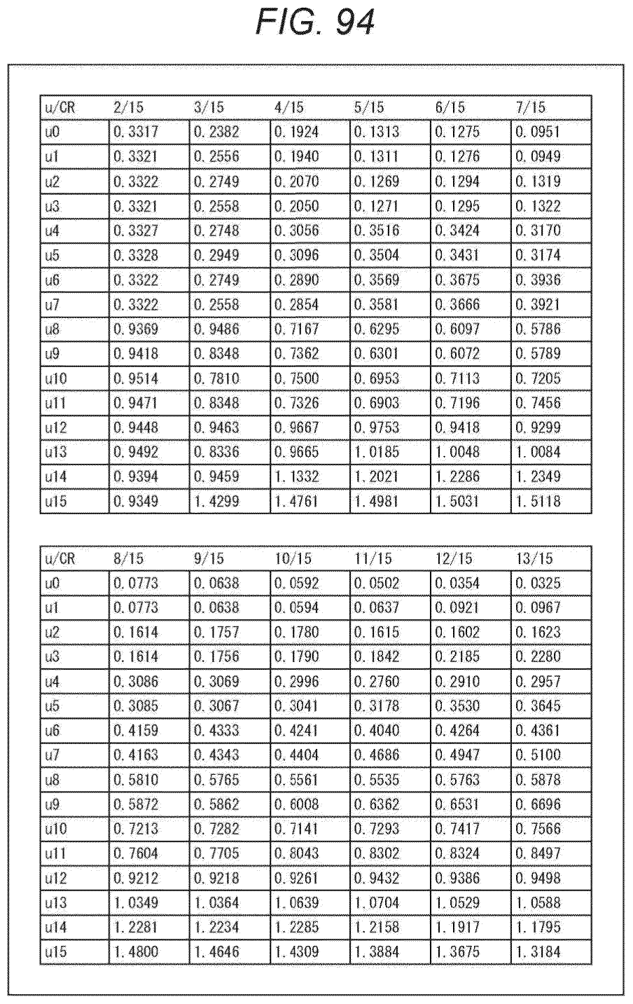

FIG. 94 is a diagram illustrating examples of coordinates of signal points of 1024QAM-1D-NUC used for the coding rates r(CR)=2/15, 3/15, 4/15, 5/15, 6/15, 7/15, 8/15, 9/15, 10/15, 11/15, 12, 15, and 13/15 of the LDPC codes defined in ATSC3.0 in a case where the modulation method is 1024QAM.

In FIG. 94, u #k represents a real part Re(zₛ) and an imaginary part Im(zₛ) of a complex number as coordinates of a signal point zₑ of 1D-NUC, and is a component of a vector u=(u0, u1, . . . , u #V−1) called a position vector. The number V of the component u #k of the position vector u is given by an equation V=√(2^{m})/2.

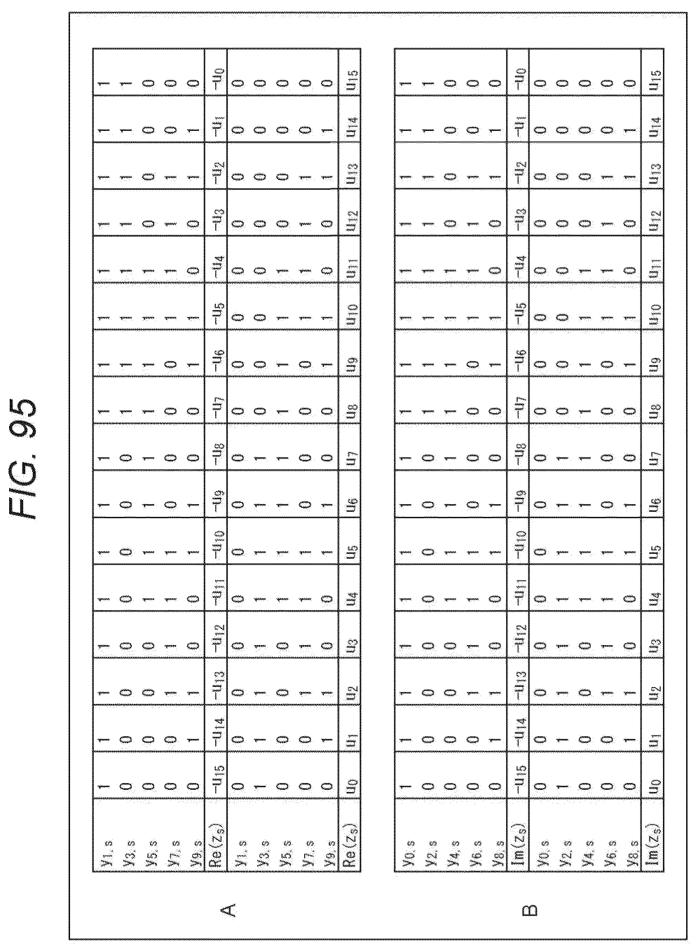

FIG. 95 is a diagram illustrating a relationship between the symbol y of 1024QAM and (the component u #k of) the position vector u.

Now, the 10 bit symbol y of 1024QAM is represented as y_{0,s}, y_{1,s}, y_{2,s}, y_{3,s}, y_{4,s}, y_{5,s}, y_{6,s}, y_{7,s}, y_{8,s}, y_{9,s} from the first bit (most significant bit).

A of FIG. 95 illustrates a correspondence between the even-numbered 5 bits y_{1,s}, y_{3,s}, y_{5,s}, y_{7,s}, y_{9,s} of the symbol y and u #k representing the real part Re(zₛ) (of the coordinates) of the signal point zₛ corresponding to the symbol y.

B of FIG. 95 illustrates a correspondence between the odd-numbered 5 bits y_{0,s}, y_{2,s}, y_{4,s}, y_{6,s}, y_{8,s} of the symbol y and u #k representing the imaginary part Im(zₛ) of the signal point zₛ corresponding to the symbol y.

In a case where the 10 bit symbol y of 1024QAM=(y_{0,s}, y_{1,s}, y_{2,s}, y_{3,s}, y_{4,s}, y_{5,s}, y_{6,s}, y_{7,s}, y_{8,s}, y_{9,s}) is, for example, (0, 0, 1, 0, 0, 1, 1, 1, 0, 0), the odd-numbered 5 bits (y_{0,s}, y_{2,s}, y_{4,s}, y_{6,s}, y_{8,s}) are (0, 1, 0, 1, 0), and the even-numbered 5 bits (y_{1,s}, y_{3,s}, y_{5,s}, y_{7,s}, y_{9,s}) are (0, 0, 1, 1, 0).

In A of FIG. 95, the even-numbered 5 bits (0, 0, 1, 1, 0) are associated with u11, and thus the real part Re(zₛ) of the signal point zₛ corresponding to the symbol y=(0, 0, 1, 0, 0, 1, 1, 1, 0, 0) is u11.

In B of FIG. 95, the odd-numbered 5 bits (0, 1, 0, 1, 0) are associated with u3, and thus the imaginary part Im(zₛ) of the signal point zₛ corresponding to the symbol y=(0, 0, 1, 0, 0, 1, 1, 1, 0, 0) is u3.

Meanwhile, when the coding rate r of the LDPC code is, for example, 6/15, u3 is 0.1295 and u11 is 0.7196 for the 1D-NUC used in a case where the modulation method is 1024QAM and the coding rate r(CR) of the LDPC code=6/15 according to FIG. 94.

Therefore, the real part Re(zₛ) of the signal point zₛ corresponding to the symbol y=(0, 0, 1, 0, 0, 1, 1, 1, 0, 0) is u11=0.7196, and the imaginary part Im(zₛ) is u3=0.1295. As a result, the coordinates of the signal point zₛ corresponding to the symbol y=(0, 0, 1, 0, 0, 1, 1, 1, 0, 0) are expressed by 0.7196+j0.1295.

Note that the signal points of the 1D-NUC are arranged in a lattice pattern on a straight line parallel to the I axis or a straight line parallel to the Q axis in the constellation. However, an interval between the signal points is not constant. Furthermore, the average power of the signal points on the constellation can be normalized in transmission of (data mapped to) the signal points. When the root mean square value of the absolute values of all (the coordinates of) the signal points on the constellation is represented by Pₐᵥₑ, the normalization can be performed by multiplying each signal point zₛ on the constellation by a reciprocal 1/(√Pₐᵥₑ) of a square root √Pₐᵥₑ of the root mean square value Pₐᵥₑ.

In the transmission system in FIG. 7, the constellation defined in ATSC3.0 as described above can be used.

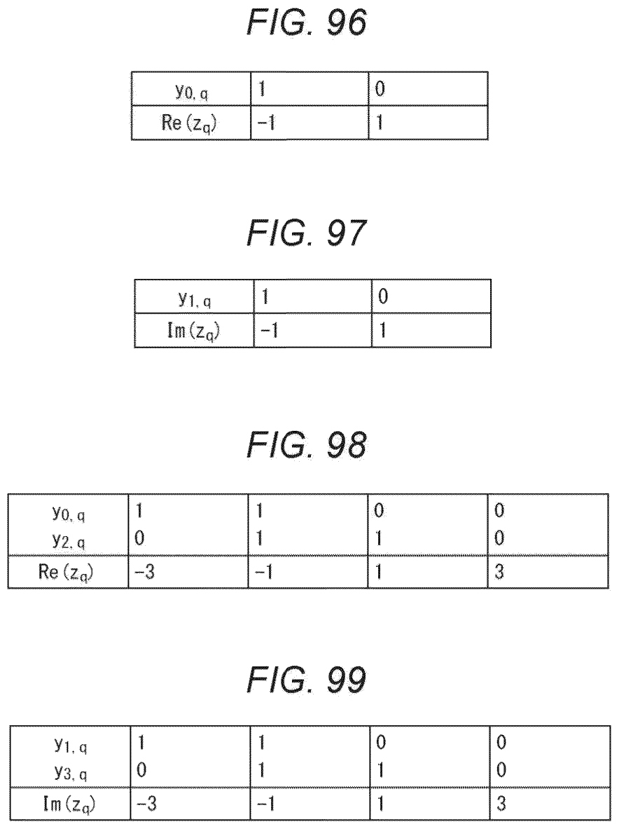

FIGS. 96 to 107 are diagrams illustrating coordinates of signal points of UC defined in DVB-C.2.

That is, FIG. 96 is a diagram illustrating a real part Re (z_{q}) of a coordinate z_{q} of a signal point of QPSK-UC (UC of QPSK) defined in DVB-C.2. FIG. 97 is a diagram illustrating an imaginary part Im(z_{q} of the coordinate z_{q} of the signal point of QPSK-UC defined in DVB-C.2.

FIG. 98 is a diagram illustrating a real part Re(z_{q}) of a coordinate z_{q} of a signal point of 16QAM-UC (UC of 16QAM) defined in DVB-C.2. FIG. 99 is a diagram illustrating an imaginary part Im(z_{q}) of the coordinate z_{q} of the signal point of 16QAM-UC defined in DVB-C.2.

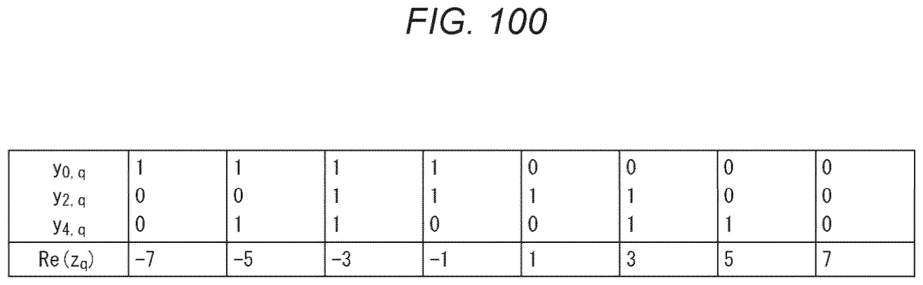

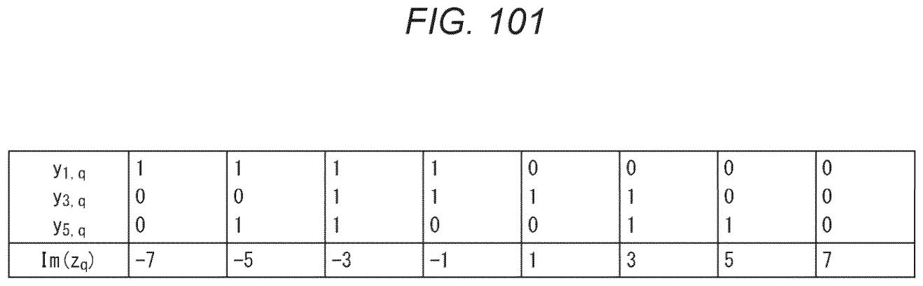

FIG. 100 is a diagram illustrating a real part Re(z_{q}) of a coordinate z_{q} of a signal point of 64QAM-UC (UC of 64QAM) defined in DVB-C.2. FIG. 101 is a diagram illustrating an imaginary part Im(z_{q}) of the coordinate z_{q} of the signal point of 64QAM-UC defined in DVB-C.2.

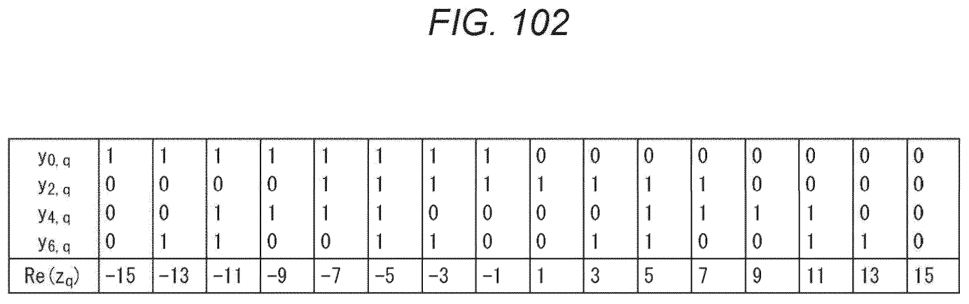

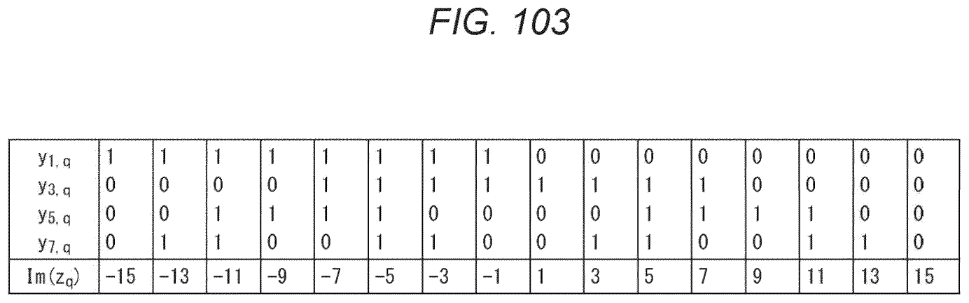

FIG. 102 is a diagram illustrating a real part Re(z_{q}) of a coordinate z_{q} of a signal point of 256QAM-UC (UC of 256QAM) defined in DVB-C.2. FIG. 103 is a diagram illustrating an imaginary part Im(z_{q}) of the coordinate z_{q} of the signal point of 256QAM-UC defined in DVB-C.2.

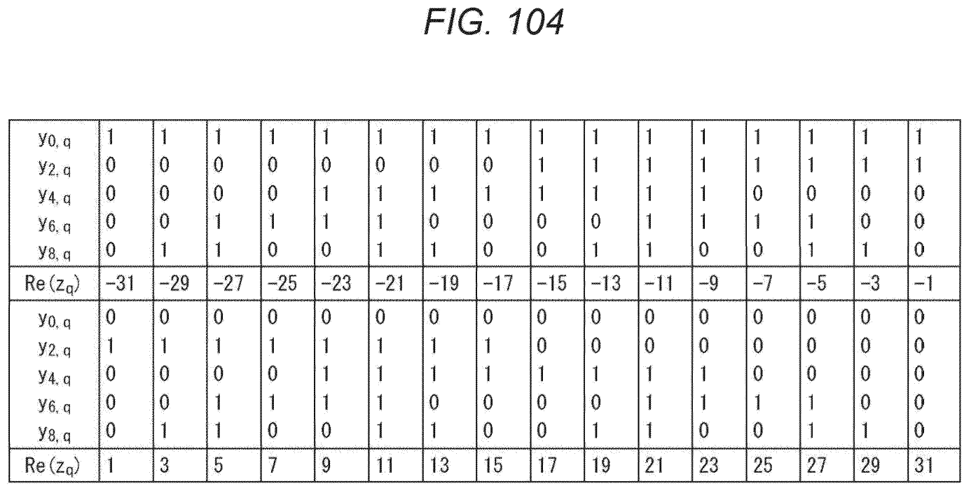

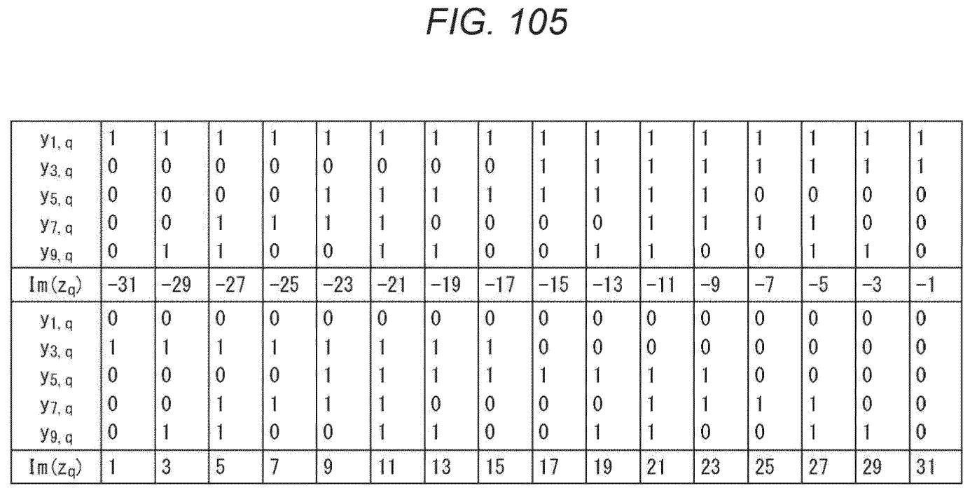

FIG. 104 is a diagram illustrating a real part Re(z_{q}) of a coordinate z_{q} of a signal point of 1024QAM-UC (UC of 1024QAM) defined in DVB-C.2. FIG. 105 is a diagram illustrating an imaginary part Im(z_{q}) of the coordinate z_{q} of the signal point of 1024QAM-UC defined in DVB-C.2.

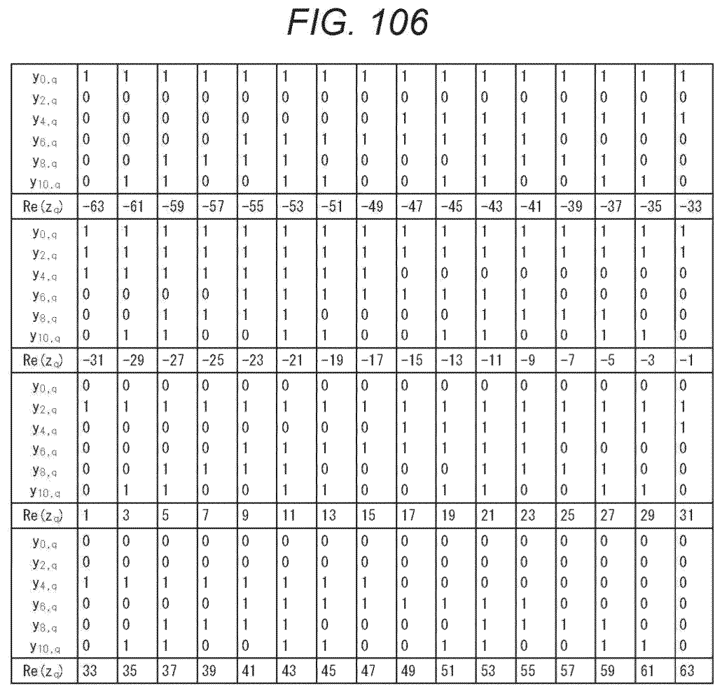

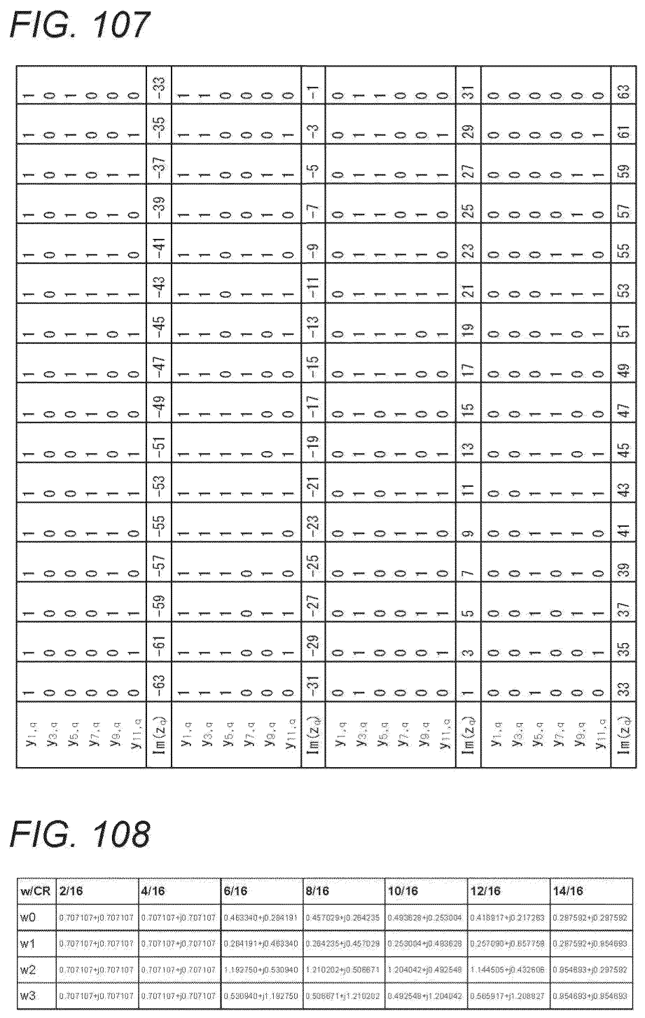

FIG. 106 is a diagram illustrating a real part Re(z_{q}) of a coordinate z_{q} of a signal point of 4096QAM-UC (UC of 4096QAM) defined in DVB-C.2. FIG. 107 is a diagram illustrating an imaginary part Im(z_{q}) of the coordinate z_{q} of the signal point of 4096QAM-UC defined in DVB-C.2.

Note that in FIGS. 96 to 107, y_{i,q} represents the (i+1)th bit from the head of the m-bit (for example, 2 bits in QPSK) symbol of 2^{m}QAM. Furthermore, in transmission of (data mapped to) the signal points of the UC, the average power of the signal points on the constellation can be normalized. When the root mean square value of the absolute values of all (the coordinates of) the signal points on the constellation is represented by Pₐᵥₑ, the normalization can be performed by multiplying each signal point z_{q} on the constellation by a reciprocal 1/(√Pₐᵥₑ) of a square root √Pₐᵥₑ of the root mean square value Pₐᵥₑ.

In the transmission system in FIG. 7, the UC defined in DVB-C.2 as described above can be used.

In other words, the UCs illustrated in FIGS. 96 to 107 can be used for the new LDPC codes (corresponding to the parity check matrix initial value table) with the code length N of 69120 bits and the coding rates r of 2/16, 3/16, 4/16, 5/16, 6/16, 7/16, 8/16, 9/16, 10/16, 11/16, 12/16, 13/16, and 14/16 in FIGS. 30 to 85.

FIGS. 108 to 116 are diagrams illustrating examples of coordinates of signal points of other NUCs that can be used for the new LDPC codes with the code length N of 69120 bits and the coding rates r of 2/16, 3/16, 4/16, 5/16, 6/16, 7/16, 8/16, 9/16, 10/16, 11/16, 12/16, 13/16, and 14/16 in FIGS. 30 to 85.

In other words, FIG. 108 is a diagram illustrating examples of coordinates of signal points of 16QAM-2D-NUC that can be used for the new LDPC codes with the coding rate r(CR) of 2/16, 4/16, 6/16, 8/16, 10/16, 12/16, and 14/16 among the new LDPC codes with the code length N of 69120 bits in FIGS. 30 to 85.

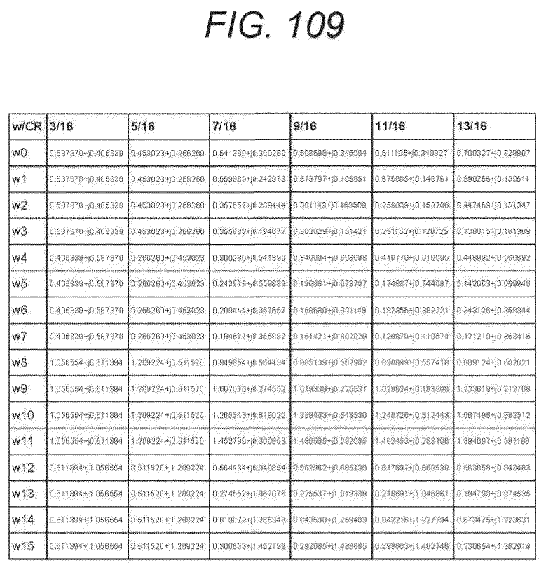

FIG. 109 is a diagram illustrating examples of coordinates of signal points of 64QAM-2D-NUC that can be used for the new LDPC codes with the coding rates r of 3/16, 5/16, 7/16, 9/16, 11/16, and 13/16 among the new LDPC codes with the code length N of 69120 bits in FIGS. 30 to 85.

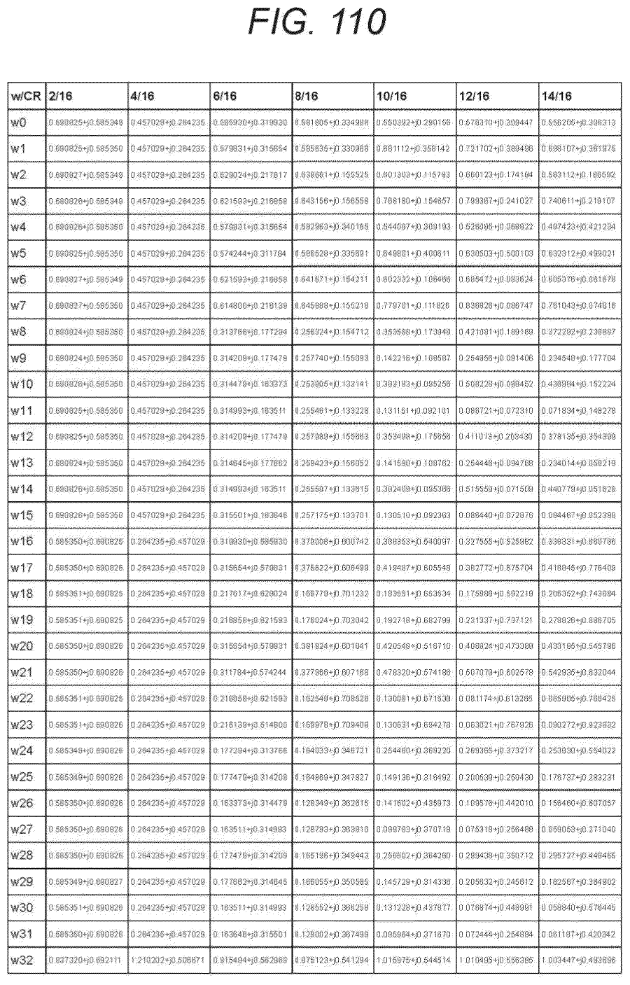

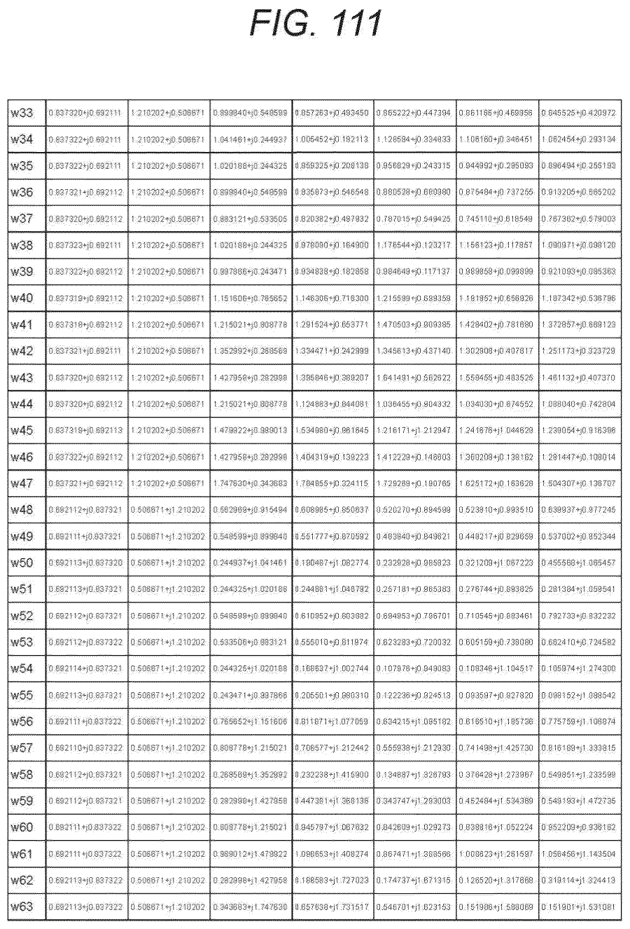

FIGS. 110 and 111 are diagrams illustrating examples of coordinates of signal points of 256QAM-2D-NUC that can be used for the new LDPC codes with the coding rate r of 2/16, 4/16, 6/16, 8/16, 10/16, 12/16, and 14/16 among the new LDPC codes with the code length N of 69120 bits in FIGS. 30 to 85.

Note that FIG. 111 is a diagram following FIG. 110.

In FIGS. 108 to 111, similarly to FIG. 93, the coordinate of the signal point zₛ is represented in the form of a complex number, and j represents an imaginary unit.

In FIGS. 108 to 111, w #k represents the coordinates of the signal point in the first quadrant of the constellation, similarly to FIG. 93.

Here, as described with reference to FIG. 93, when the m-bit symbol is expressed by an integer value of 0 to 2^{m}−1, and b=2^{m}/4, the symbols y(0), y(1), . . . , and y(2^{m}−1) expressed by integer values of 0 to 2^{m}−1 can be classified into four groups of symbols y(0) to y(b−1), y(b) to y(2b−1), y(2b) to y(3b−1), and y(3b) to y(4b−1).

In FIGS. 108 to 111, the suffix k of w #k takes an integer value in the range of 0 to b−1, and w #k represents a coordinate of a signal point corresponding to the symbol y(k) in the range of symbols y(0) to y(b−1), similarly to FIG. 93.

Moreover, in FIGS. 108 to 111, similarly to FIG. 93, the coordinate of the signal point corresponding to the symbol y(k+3b) in the range of symbols y(3b) to y(4b−1) is represented by −w #k.

However, in FIG. 93, the coordinate of the signal point corresponding to the symbol y(k+b) in the range of symbols y(b) to y(2b−1) is represented by −conj(w #k), and the coordinate of the signal point corresponding to the symbol y(k+2b) in the range of symbols y(2b) to y(3b−1) is represented by conj(w #k), but the sign of conj is reversed in FIGS. 108 to 111.

That is, in FIGS. 108 to 111, the coordinate of the signal point corresponding to the symbol y(k+b) in the range of symbols y(b) to y(2b−1) is represented by conj(w #k), and the coordinate of the signal point corresponding to the symbol y(k+2b) in the range of symbols y(2b) to y(3b−1) is represented by −conj(w #k).

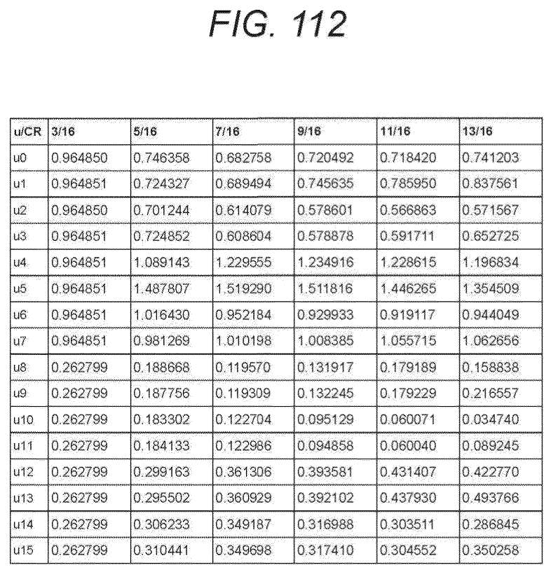

FIG. 112 is a diagram illustrating examples of coordinates of signal points of 1024QAM-1D-NUC that can be used for the new LDPC codes with the coding rates r of 3/16, 5/16, 7/16, 9/16, 11/16, and 13/16 among the new LDPC codes with the code length N of 69120 bits in FIGS. 30 to 85.

In other words, FIG. 112 is a diagram illustrating a relationship between the real part Re(zₛ) and the imaginary part Im(zₛ) of the complex number as the coordinates of the signal point zₛ of 1024QAM-1D-NUC, and (the component u #k of) the position vector u.

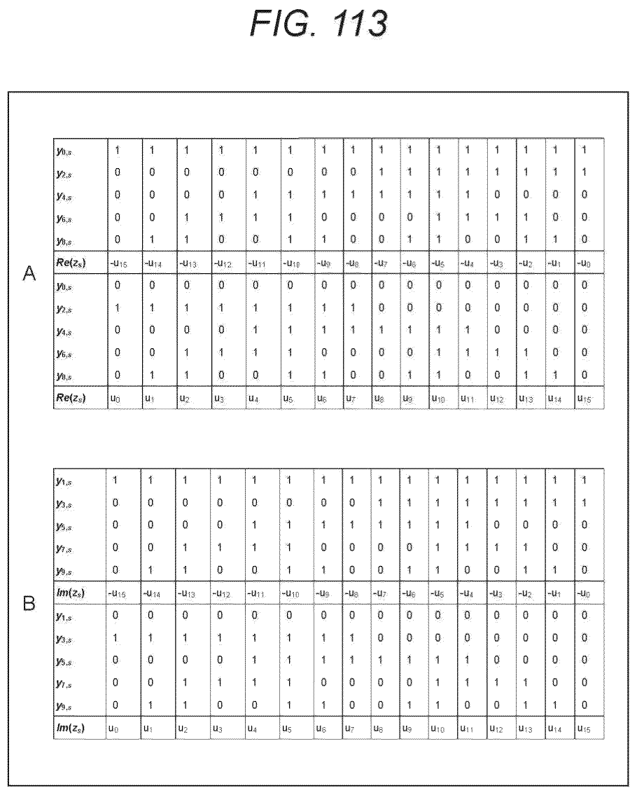

FIG. 113 is a diagram illustrating a relationship between the symbol y of 1024QAM and (the component u #k of) the position vector u in FIG. 112.

That is, now, the 10 bit symbol y of 1024QAM is expressed as y_{0,s}, y_{1,s}, y_{2,s}, y_{3,s}, y_{4,s}, y_{5,s}, y_{6,s}, y_{7,s}, y_{8,s}, y_{9,s} from the first bit (most significant bit).

A in FIG. 113 illustrates a correspondence between the odd-numbered 5 bits y_{0,s}, y_{2,s}, y_{4,s}, y_{6,s}, y_{8,s} of the 10 bit symbol y, and the position vector u #k representing the real part Re(zₛ) of (the coordinates of) the signal point zₛ corresponding to the symbol y.

B in FIG. 113 illustrates a correspondence between the even-numbered 5 bits y_{1,s}, y_{3,s}, y_{5,s}, y_{7,s}, y_{9,s} of the 10 bit symbol y, and the position vector u #k representing the imaginary part Im(zₛ) of the signal point zₛ corresponding to the symbol y.

Since the method of obtaining the coordinates of the signal point zₛ when the 10 bit symbol y of 1024QAM is mapped to the signal point zₛ of 1024QAM-1D-NUC defined in FIGS. 112 and 113 is similar to the case described with reference to FIGS. 94 and 95, the description will be omitted.

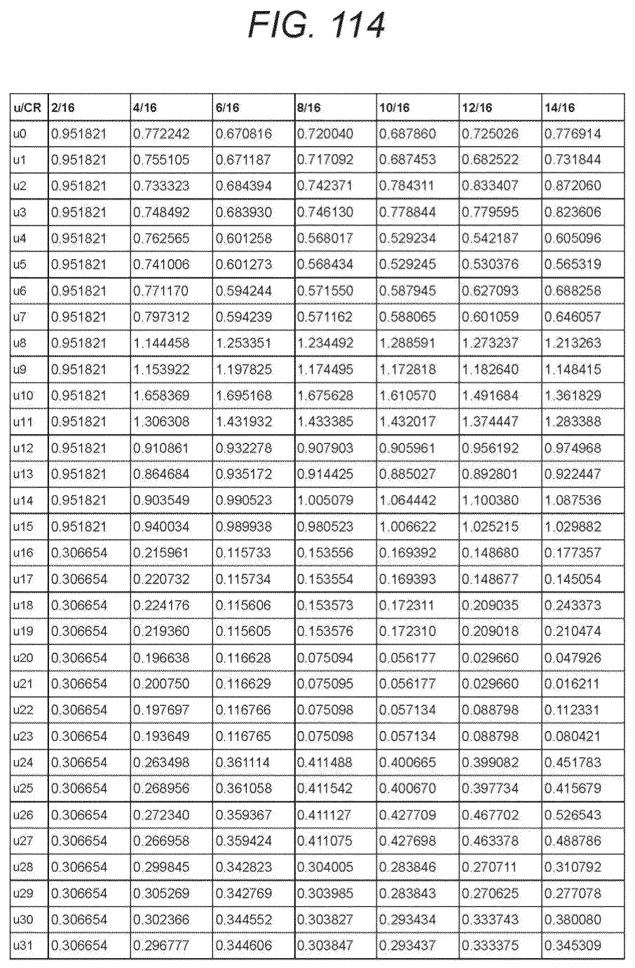

FIG. 114 is a diagram illustrating examples of coordinates of signal points of 4096QAM-1D-NUC that can be used for the new LDPC codes with the coding rates r of 2/16, 4/16, 6/16, 8/16, 10/16, 12/16, and 14/16 among the new LDPC codes with the code length N of 69120 bits in FIGS. 30 to 85.

In other words, FIG. 114 is a diagram illustrating a relationship between the real part Re(zₛ) and the imaginary part Im(zₛ) of the complex number as the coordinates of the signal point zₛ of 4096QAM-1D-NUC, and the position vector u(u #k).

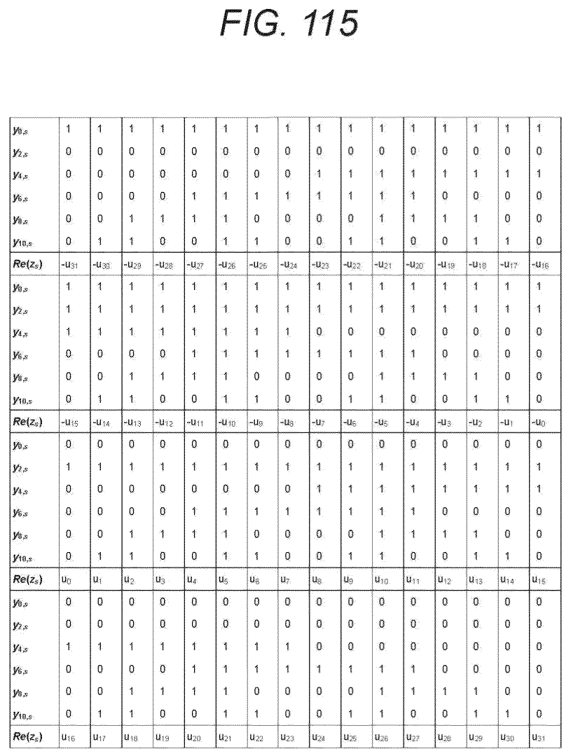

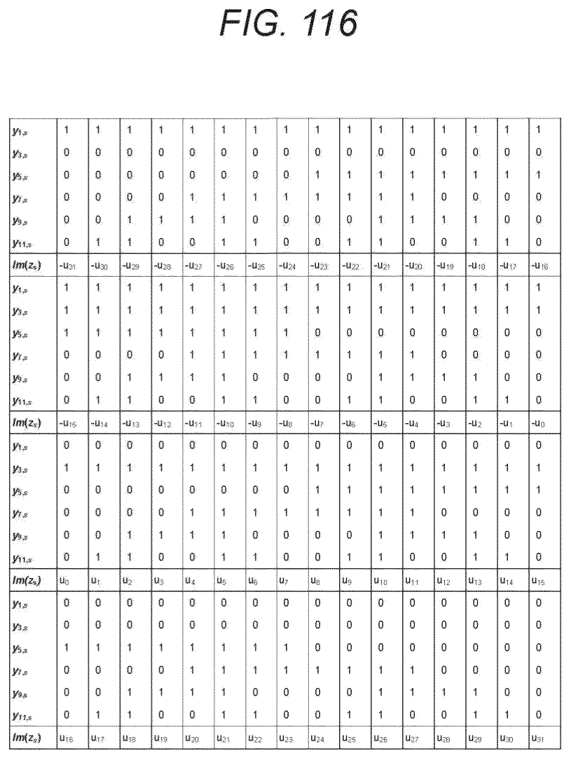

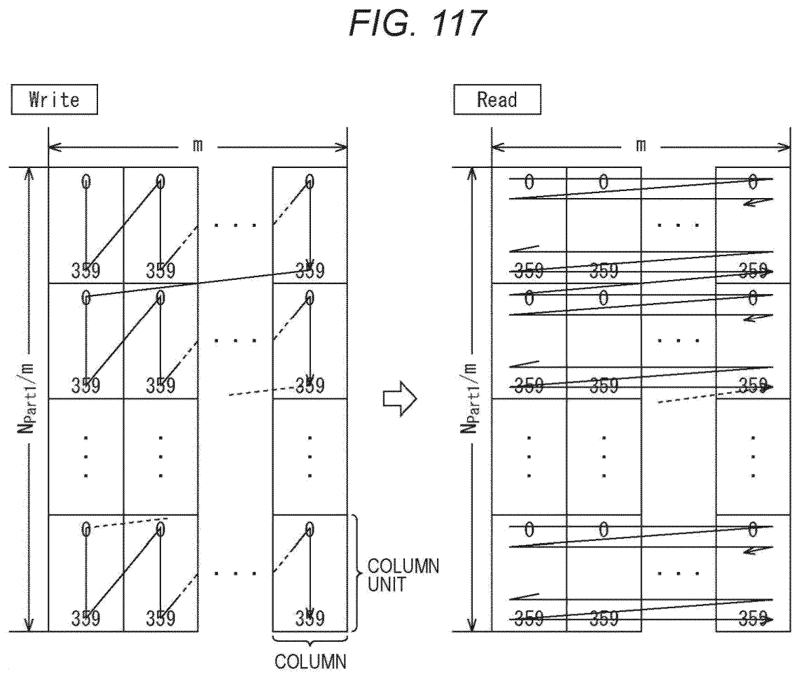

FIGS. 115 and 116 are diagrams illustrating a relationship between the symbol y of 4096QAM and (the component u #k of) the position vector u in FIG. 114.

That is, now, the 4096QAM 12 bit symbol y is expressed as y_{0,s}, y_{1,s}, y_{2,s}, y_{3,s}, y_{4,s}, y_{5,s}, y_{6,s}, y_{7,s}, y_{8,s}, y_{9,s}, y_{10,s}, y_{11,s} from the first bit (most significant bit).

FIG. 115 illustrates a correspondence between the odd-numbered 6 bits y_{0,s}, y_{2,s}, y_{4,s}, y_{6,s}, y_{8,s}, y_{10,s} of the 12 bit symbol y, and the position vector u #k representing the real part Re (zₛ) of the signal point zₛ corresponding to the symbol y.

FIG. 116 illustrates a correspondence between the even-numbered 6 bits y_{1,s}, y_{3,s}, y_{5,s}, y_{7,s}, y_{9,s}, y_{11,s} of the 12 bit symbol y, and the position vector u #k representing the imaginary part Im(zₛ) of the signal point zₛ corresponding to the symbol y.

Since the method of obtaining the coordinates of the signal point zₛ when the 4096QAM 12 bit symbol y is mapped to the signal point zₑ of 4096QAM-1D-NUC defined in FIGS. 114 to 116 is similar to the case described with reference to FIGS. 94 and 95, the description will be omitted.

Note that the average power of the signal points on the constellation can be normalized in transmission of (data mapped to) the signal points of the NUCs in FIGS. 108 to 116. When the root mean square value of the absolute values of all (the coordinates of) the signal points on the constellation is represented by Pₐᵥₑ, the normalization can be performed by multiplying each signal point zₛ on the constellation by a reciprocal 1/(√Pₐᵥₑ) of a square root √Pₐᵥₑ of the root mean square value Pₐᵥₑ. Furthermore, in FIG. 95 described above, the odd-numbered bits of the symbol y are associated with the position vector u #k representing the imaginary part Im(zₛ) of the signal point zₛ and the even-numbered bits of the symbol y are associated with the position vector u #k representing the real part Re(zₛ) of the signal point zₛ. In FIG. 113, and FIGS. 115 and 116, conversely, the odd-numbered bits of the symbol y are associated with the position vector u #k representing the real part Re(zₛ) of the signal point zₛ and the even-numbered bits of the symbol y are associated with the position vector u #k representing the imaginary part Im(zₛ) of the signal point z₃.

### <Block Interleaver 25>

FIG. 117 is a diagram illustrating block interleaving performed by the block interleaver 25 in FIG. 9.

Block interleaving is performed by dividing an LDPC code of one code word into a portion called part 1 and a portion called part 2 from the head of the LDPC code.

When the length (the bit length) of part 1 is represented as Npart1 and the length of part 2 is represented as Npart2, Npart1+Npart2 is equal to the code length N.

Conceptually, in the block interleaving, columns as storage areas for storing Npart1/m bits are arranged in a column (vertical) direction as one direction by a length m equal to the bit length m of a symbol in a row direction orthogonal to the column direction, and each column is divided from the top into small units of 360 bits having a unit size P. The small unit of the column is also referred to as a column unit.

In the block interleaving, as illustrated in FIG. 117, writing of part 1 of the LDPC code of one code word downward (in the column direction) from the top of the first column unit of the column is performed in the columns from left to right direction.

Then, when the writing to the first column unit of the rightmost column is completed, the writing returns to the leftmost column, and writing downward from the top of the second column unit of the column is performed in the columns from the left to right direction as illustrated in FIG. 117. Hereinafter, writing of part 1 of the LDPC code of one code word is similarly performed.

When the writing of part 1 of the LDPC code of one code word is completed, part 1 of the LDPC code is read in units of m bits in the row direction from the first row of all the m columns as illustrated in FIG. 117.

The m-bit unit of part 1 is supplied as an m-bit symbol from the block interleaver 25 to the mapper 117 (FIG. 8).

The reading of part 1 in units of m bits is sequentially performed toward the lower rows of the m columns, and when the reading of part 1 is completed, part 2 is divided in units of m bits from the head and is supplied from the block interleaver 25 to the mapper 117 as an m-bit symbol.

Therefore, part 1 is symbolized while being interleaved, and part 2 is symbolized by being sequentially divided into m bits without being interleaved.

Npart1/m, which is the length of the column, is a multiple of 360, which is the unit size P, and the LDPC code of one code word is divided into part 1 and part 2 such that Npart1/m is a multiple of 360.

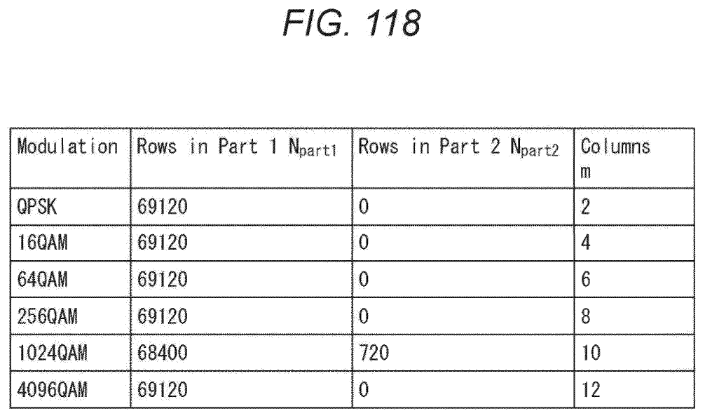

FIG. 118 is a diagram illustrating examples of part 1 and part 2 of the LDPC code with the code length N of 69120 bits in a case where the modulation method is QPSK, 16QAM, 64QAM, 256QAM, 1024QAM, and 4096QAM.

In FIG. 118, in a case where the modulation method is 1024QAM, part 1 is 68400 bits and part 2 is 720 bits, and in a case where the modulation method is QPSK, 16QAM, 64QAM, 256QAM, or 4096QAM, part 1 is 69120 bits and part 2 is 0 bits in any case.

### <Group-Wise Interleaving>

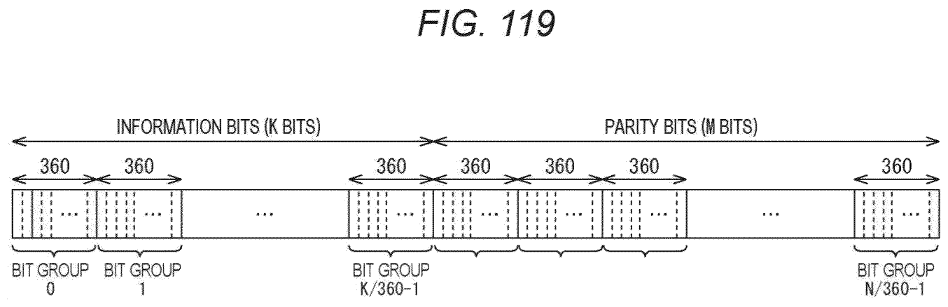

FIG. 119 is a diagram for describing group-wise interleaving performed by the group-wise interleaver 24 in FIG. 9.

In the group-wise interleaving, as illustrated in FIG. 119, the LDPC code of one code word is interleaved in units of bit groups according to a predetermined pattern (Hereinafter, it is also referred to as a GW pattern.) with one section of 360 bits, which is obtained by dividing the LDPC code of one code word into 360 bit units equal to the unit size P from the head, as bit groups.

Hereinafter, the (i+1)th bit group from the head when the LDPC code of one code word is divided into bit groups is also referred to as a bit group i.

In a case where the unit size P is 360, for example, an LDPC code with the code length N of 1800 bits is divided into 5 (=1800/360) bit groups of bit groups 0, 1, 2, 3, and 4. Moreover, for example, an LDPC code with the code length N of 69120 bits is divided into 192 (=69120/360) bit groups of bit groups 0, 1, . . . , and 191.

Furthermore, hereinafter, the GW pattern is represented by a sequence of numbers representing bit groups. For example, regarding the LDPC code with the code length N of 1800 bits, for example, the GW patterns 4, 2, 0, 3, and 1 represent interleaving (rearranging) the sequence of the bit groups 0, 1, 2, 3, and 4 into the sequence of the bit groups 4, 2, 0, 3, and 1.

For example, it is assumed that the (i+1)th sign bit from the head of the LDPC code with the code length N of 1800 bits is represented by xᵢ.

In this case, according to the group-wise interleaving of the GW patterns 4, 2, 0, 3, and 1, the 1800 bit LDPC code {x₀, x₁, . . . , x₁₇₉₉} is interleaved in a sequence of {x₁₄₄₀, x₁₄₄₁, . . . , x₁₇₉₉}, {x₇₂₀, x₇₂₁, . . . , x₁₀₇₉}, {x₀, x₁, . . . , x₃₅}, {x₁₀₈₀, x₁₀₈₁, . . . , x₁₄₃₉}, and {x₃₆₀, x₃₆₁, . . . , x₇₁₉}.

The GW pattern can be set for each code length N of the LDPC code, for each coding rate r, for each modulation method, for each constellation, and for each combination of two or more of the code length N, the coding rate r, the modulation method, and the constellation.

### <Example of GW Pattern for LDPC Code>

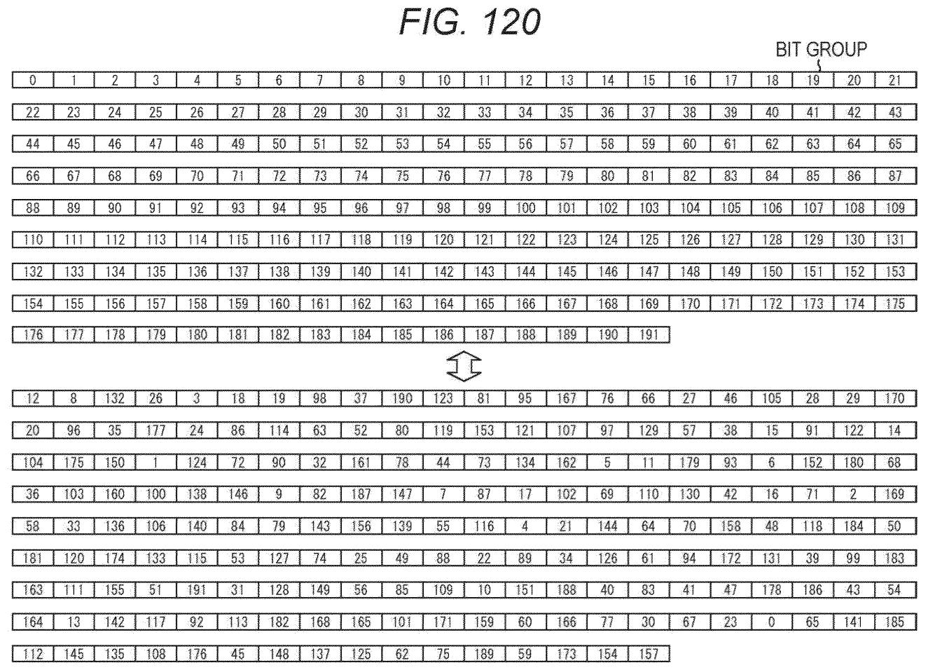

FIG. 120 is a diagram illustrating a first example of the GW pattern for an LDPC code with a code length N of 69120 bits.

According to the GW pattern in FIG. 120, a sequence of bit groups 0 to 191 of the 69120 bit LDPC code is interleaved into a sequence of the following bit group.
12, 8, 132, 26, 3, 18, 19, 98, 37, 190, 123, 81, 95, 167, 76, 66, 27, 46, 105, 28, 29, 170, 20, 96, 35, 177, 24, 86, 114, 63, 52, 80, 119, 153, 121, 107, 97, 129, 57, 38, 15, 91, 122, 14, 104, 175, 150, 1, 124, 72, 90, 32, 161, 78, 44, 73, 134, 162, 5, 11, 179, 93, 6, 152, 180, 68, 36, 103, 160, 100, 138, 146, 9, 82, 187, 147, 7, 87, 17, 102, 69, 110, 130, 42, 16, 71, 2, 169, 58, 33, 136, 106, 140, 84, 79, 143, 156, 139, 55, 116, 4, 21, 144, 64, 70, 158, 48, 118, 184, 50, 181, 120, 174, 133, 115, 53, 127, 74, 25, 49, 88, 22, 89, 34, 126, 61, 94, 172, 131, 39, 99, 183, 163, 111, 155, 51, 191, 31, 128, 149, 56, 85, 109, 10, 151, 188, 40, 83, 41, 47, 178, 186, 43, 54, 164, 13, 142, 117, 92, 113, 182, 168, 165, 101, 171, 159, 60, 166, 77, 30, 67, 23, 0, 65, 141, 185, 112, 145, 135, 108, 176, 45, 148, 137, 125, 62, 75, 189, 59, 173, 154, 157

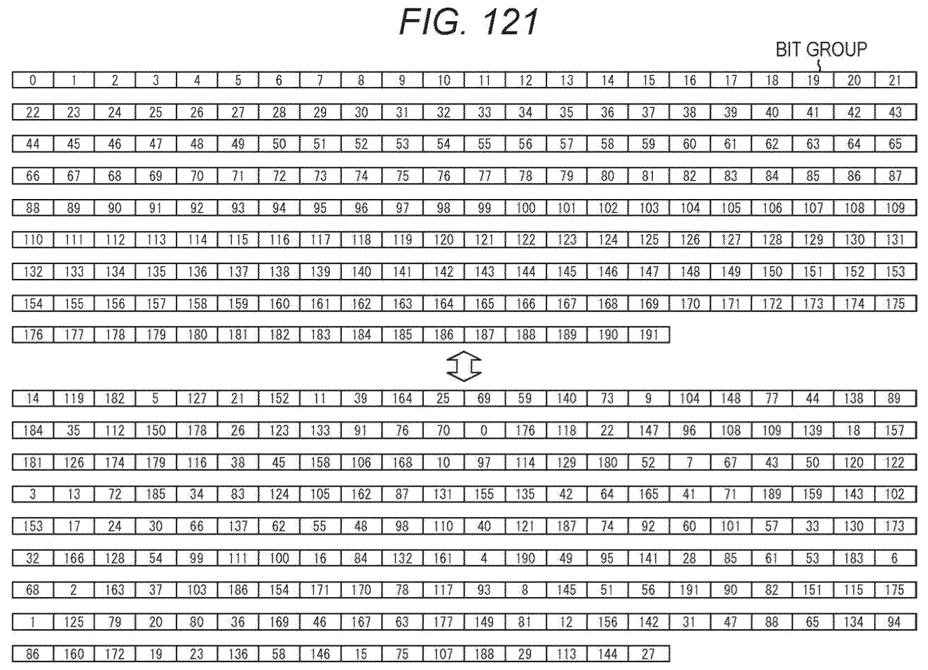

FIG. 121 is a diagram illustrating a second example of the GW pattern for the LDPC code with the code length N of 69120 bits.

According to the GW pattern in FIG. 121, a sequence of bit groups 0 to 191 of the 69120 bit LDPC code is interleaved into a sequence of the following bit group.
14, 119, 182, 5, 127, 21, 152, 11, 39, 164, 25, 69, 59, 140, 73, 9, 104, 148, 77, 44, 138, 89, 184, 35, 112, 150, 178, 26, 123, 133, 91, 76, 70, 0, 176, 118, 22, 147, 96, 108, 109, 139, 18, 157, 181, 126, 174, 179, 116, 38, 45, 158, 106, 168, 10, 97, 114, 129, 180, 52, 7, 67, 43, 50, 120, 122, 3, 13, 72, 185, 34, 83, 124, 105, 162, 87, 131, 155, 135, 42, 64, 165, 41, 71, 189, 159, 143, 102, 153, 17, 24, 30, 66, 137, 62, 55, 48, 98, 110, 40, 121, 187, 74, 92, 60, 101, 57, 33, 130, 173, 32, 166, 128, 54, 99, 111, 100, 16, 84, 132, 161, 4, 190, 49, 95, 141, 28, 85, 61, 53, 183, 6, 68, 2, 163, 37, 103, 186, 154, 171, 170, 78, 117, 93, 8, 145, 51, 56, 191, 90, 82, 151, 115, 175, 1, 125, 79, 20, 80, 36, 169, 46, 167, 63, 177, 149, 81, 12, 156, 142, 31, 47, 88, 65, 134, 94, 86, 160, 172, 19, 23, 136, 58, 146, 15, 75, 107, 188, 29, 113, 144, 27

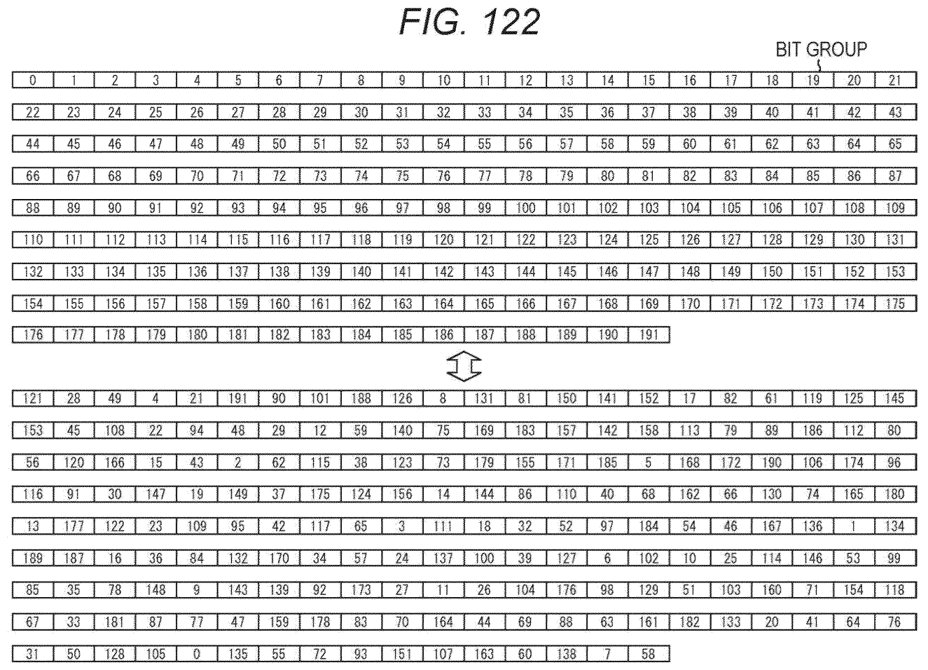

FIG. 122 is a diagram illustrating a third example of the GW pattern for an LDPC code with a code length N of 69120 bits.

According to the GW pattern in FIG. 122, a sequence of bit groups 0 to 191 of the 69120 bit LDPC code is interleaved into a sequence of the following bit group.
121, 28, 49, 4, 21, 191, 90, 101, 188, 126, 8, 131, 81, 150, 141, 152, 17, 82, 61, 119, 125, 145, 153, 45, 108, 22, 94, 48, 29, 12, 59, 140, 75, 169, 183, 157, 142, 158, 113, 79, 89, 186, 112, 80, 56, 120, 166, 15, 43, 2, 62, 115, 38, 123, 73, 179, 155, 171, 185, 5, 168, 172, 190, 106, 174, 96, 116, 91, 30, 147, 19, 149, 37, 175, 124, 156, 14, 144, 86, 110, 40, 68, 162, 66, 130, 74, 165, 180, 13, 177, 122, 23, 109, 95, 42, 117, 65, 3, 111, 18, 32, 52, 97, 184, 54, 46, 167, 136, 1, 134, 189, 187, 16, 36, 84, 132, 170, 34, 57, 24, 137, 100, 39, 127, 6, 102, 10, 25, 114, 146, 53, 99, 85, 35, 78, 148, 9, 143, 139, 92, 173, 27, 11, 26, 104, 176, 98, 129, 51, 103, 160, 71, 154, 118, 67, 33, 181, 87, 77, 47, 159, 178, 83, 70, 164, 44, 69, 88, 63, 161, 182, 133, 20, 41, 64, 76, 31, 50, 128, 105, 0, 135, 55, 72, 93, 151, 107, 163, 60, 138, 7, 58

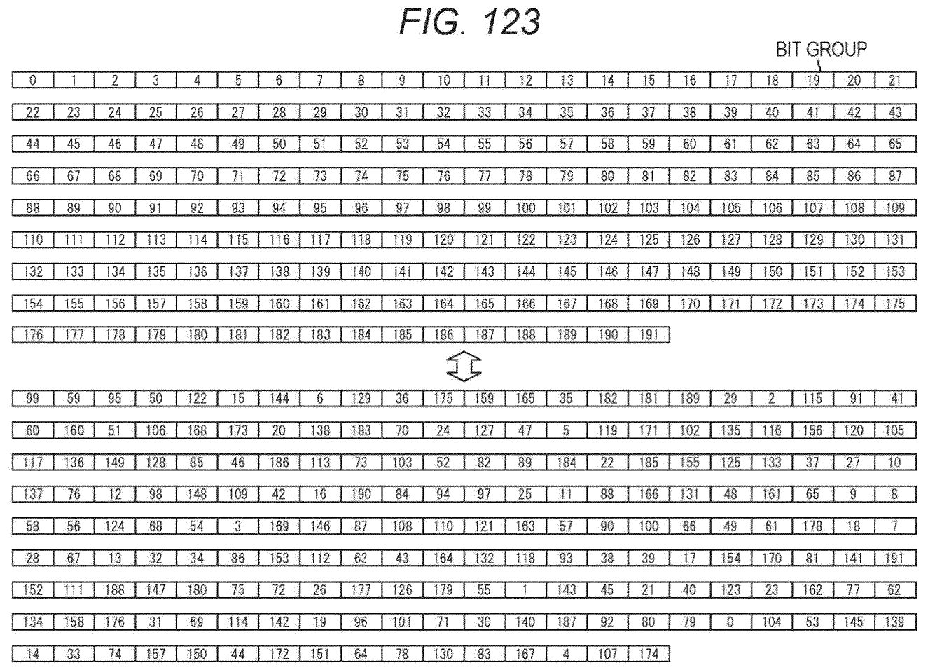

FIG. 123 is a diagram illustrating a fourth example of the GW pattern for an LDPC code with a code length N of 69120 bits.

According to the GW pattern in FIG. 123, a sequence of bit groups 0 to 191 of the 69120 bit LDPC code is interleaved into a sequence of the following bit group.
99, 59, 95, 50, 122, 15, 144, 6, 129, 36, 175, 159, 165, 35, 182, 181, 189, 29, 2, 115, 91, 41, 60, 160, 51, 106, 168, 173, 20, 138, 183, 70, 24, 127, 47, 5, 119, 171, 102, 135, 116, 156, 120, 105, 117, 136, 149, 128, 85, 46, 186, 113, 73, 103, 52, 82, 89, 184, 22, 185, 155, 125, 133, 37, 27, 10, 137, 76, 12, 98, 148, 109, 42, 16, 190, 84, 94, 97, 25, 11, 88, 166, 131, 48, 161, 65, 9, 8, 58, 56, 124, 68, 54, 3, 169, 146, 87, 108, 110, 121, 163, 57, 90, 100, 66, 49, 61, 178, 18, 7, 28, 67, 13, 32, 34, 86, 153, 112, 63, 43, 164, 132, 118, 93, 38, 39, 17, 154, 170, 81, 141, 191, 152, 111, 188, 147, 180, 75, 72, 26, 177, 126, 179, 55, 1, 143, 45, 21, 40, 123, 23, 162, 77, 62, 134, 158, 176, 31, 69, 114, 142, 19, 96, 101, 71, 30, 140, 187, 92, 80, 79, 0, 104, 53, 145, 139, 14, 33, 74, 157, 150, 44, 172, 151, 64, 78, 130, 83, 167, 4, 107, 174

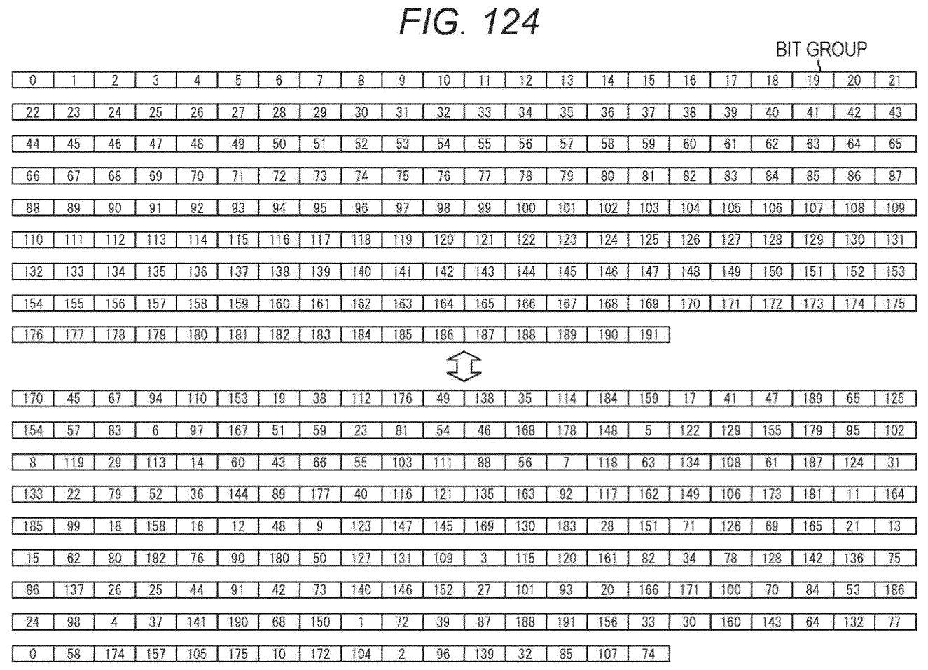

FIG. 124 is a diagram illustrating a fifth example of the GW pattern for an LDPC code with a code length N of 69120 bits.

According to the GW pattern in FIG. 124, a sequence of bit groups 0 to 191 of the 69120 bit LDPC code is interleaved into a sequence of the following bit group.
170, 45, 67, 94, 110, 153, 19, 38, 112, 176, 49, 138, 35, 114, 184, 159, 17, 41, 47, 189, 65, 125, 154, 57, 83, 6, 97, 167, 51, 59, 23, 81, 54, 46, 168, 178, 148, 5, 122, 129, 155, 179, 95, 102, 8, 119, 29, 113, 14, 60, 43, 66, 55, 103, 111, 88, 56, 7, 118, 63, 134, 108, 61, 187, 124, 31, 133, 22, 79, 52, 36, 144, 89, 177, 40, 116, 121, 135, 163, 92, 117, 162, 149, 106, 173, 181, 11, 164, 185, 99, 18, 158, 16, 12, 48, 9, 123, 147, 145, 169, 130, 183, 28, 151, 71, 126, 69, 165, 21, 13, 15, 62, 80, 182, 76, 90, 180, 50, 127, 131, 109, 3, 115, 120, 161, 82, 34, 78, 128, 142, 136, 75, 86, 137, 26, 25, 44, 91, 42, 73, 140, 146, 152, 27, 101, 93, 20, 166, 171, 100, 70, 84, 53, 186, 24, 98, 4, 37, 141, 190, 68, 150, 1, 72, 39, 87, 188, 191, 156, 33, 30, 160, 143, 64, 132, 77, 0, 58, 174, 157, 105, 175, 10, 172, 104, 2, 96, 139, 32, 85, 107, 74

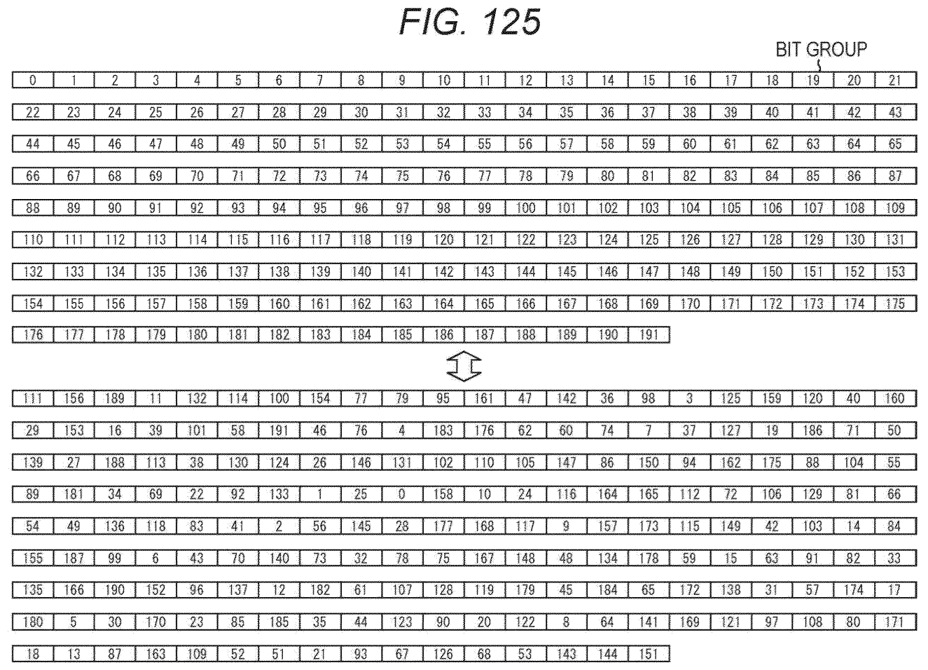

FIG. 125 is a diagram illustrating a sixth example of the GW pattern for an LDPC code with a code length N of 69120 bits.

According to the GW pattern in FIG. 125, a sequence of bit groups 0 to 191 of the 69120 bit LDPC code is interleaved into a sequence of the following bit group.
111, 156, 189, 11, 132, 114, 100, 154, 77, 79, 95, 161, 47, 142, 36, 98, 3, 125, 159, 120, 40, 160, 29, 153, 16, 39, 101, 58, 191, 46, 76, 4, 183, 176, 62, 60, 74, 7, 37, 127, 19, 186, 71, 50, 139, 27, 188, 113, 38, 130, 124, 26, 146, 131, 102, 110, 105, 147, 86, 150, 94, 162, 175, 88, 104, 55, 89, 181, 34, 69, 22, 92, 133, 1, 25, 0, 158, 10, 24, 116, 164, 165, 112, 72, 106, 129, 81, 66, 54, 49, 136, 118, 83, 41, 2, 56, 145, 28, 177, 168, 117, 9, 157, 173, 115, 149, 42, 103, 14, 84, 155, 187, 99, 6, 43, 70, 140, 73, 32, 78, 75, 167, 148, 48, 134, 178, 59, 15, 63, 91, 82, 33, 135, 166, 190, 152, 96, 137, 12, 182, 61, 107, 128, 119, 179, 45, 184, 65, 172, 138, 31, 57, 174, 17, 180, 5, 30, 170, 23, 85, 185, 35, 44, 123, 90, 20, 122, 8, 64, 141, 169, 121, 97, 108, 80, 171, 18, 13, 87, 163, 109, 52, 51, 21, 93, 67, 126, 68, 53, 143, 144, 151

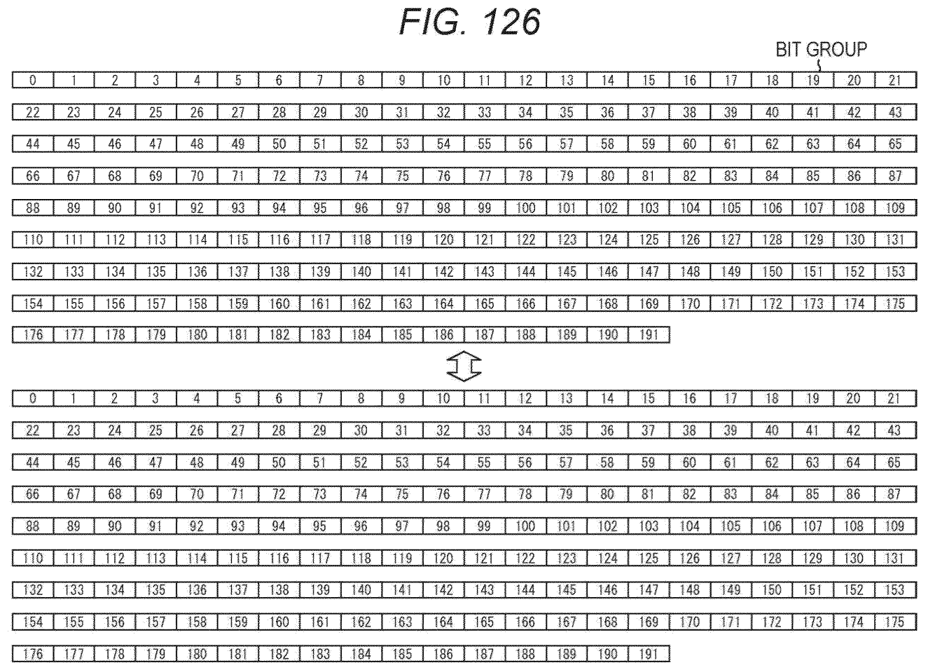

FIG. 126 is a diagram illustrating a seventh example of the GW pattern for an LDPC code with a code length N of 69120 bits.

According to the GW pattern in FIG. 126, a sequence of bit groups 0 to 191 of the 69120 bit LDPC code is interleaved into a sequence of the following bit group.
0, 1, 2, 3, 4, 5, 6, 7, 8, 9, 10, 11, 12, 13, 14, 15, 16, 17, 18, 19, 20, 21, 22, 23, 24, 25, 26, 27, 28, 29, 30, 31, 32, 33, 34, 35, 36, 37, 38, 39, 40, 41, 42, 43, 44, 45, 46, 47, 48, 49, 50, 51, 52, 53, 54, 55, 56, 57, 58, 59, 60, 61, 62, 63, 64, 65, 66, 67, 68, 69, 70, 71, 72, 73, 74, 75, 76, 77, 78, 79, 80, 81, 82, 83, 84, 85, 86, 87, 88, 89, 90, 91, 92, 93, 94, 95, 96, 97, 98, 99, 100, 101, 102, 103, 104, 105, 106, 107, 108, 109, 110, 111, 112, 113, 114, 115, 116, 117, 118, 119, 120, 121, 122, 123, 124, 125, 126, 127, 128, 129, 130, 131, 132, 133, 134, 135, 136, 137, 138, 139, 140, 141, 142, 143, 144, 145, 146, 147, 148, 149, 150, 151, 152, 153, 154, 155, 156, 157, 158, 159, 160, 161, 162, 163, 164, 165, 166, 167, 168, 169, 170, 171, 172, 173, 174, 175, 176, 177, 178, 179, 180, 181, 182, 183, 184, 185, 186, 187, 188, 189, 190, 191

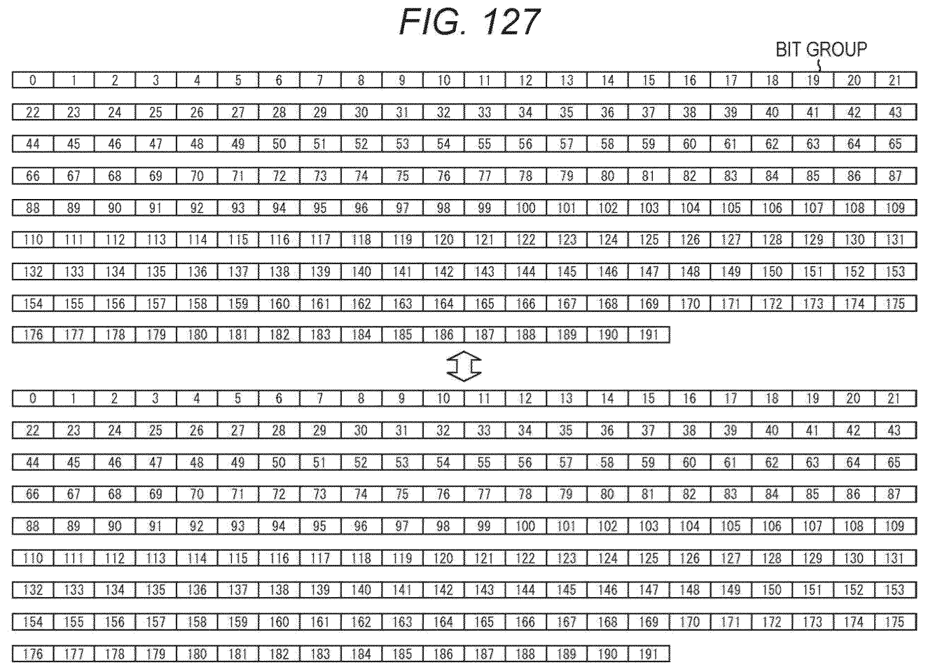

FIG. 127 is a diagram illustrating an eighth example of the GW pattern for an LDPC code with a code length N of 69120 bits.

According to the GW pattern in FIG. 127, a sequence of bit groups 0 to 191 of the 69120 bit LDPC code is interleaved into a sequence of the following bit group.
0, 1, 2, 3, 4, 5, 6, 7, 8, 9, 10, 11, 12, 13, 14, 15, 16, 17, 18, 19, 20, 21, 22, 23, 24, 25, 26, 27, 28, 29, 30, 31, 32, 33, 34, 35, 36, 37, 38, 39, 40, 41, 42, 43, 44, 45, 46, 47, 48, 49, 50, 51, 52, 53, 54, 55, 56, 57, 58, 59, 60, 61, 62, 63, 64, 65, 66, 67, 68, 69, 70, 71, 72, 73, 74, 75, 76, 77, 78, 79, 80, 81, 82, 83, 84, 85, 86, 87, 88, 89, 90, 91, 92, 93, 94, 95, 96, 97, 98, 99, 100, 101, 102, 103, 104, 105, 106, 107, 108, 109, 110, 111, 112, 113, 114, 115, 116, 117, 118, 119, 120, 121, 122, 123, 124, 125, 126, 127, 128, 129, 130, 131, 132, 133, 134, 135, 136, 137, 138, 139, 140, 141, 142, 143, 144, 145, 146, 147, 148, 149, 150, 151, 152, 153, 154, 155, 156, 157, 158, 159, 160, 161, 162, 163, 164, 165, 166, 167, 168, 169, 170, 171, 172, 173, 174, 175, 176, 177, 178, 179, 180, 181, 182, 183, 184, 185, 186, 187, 188, 189, 190, 191

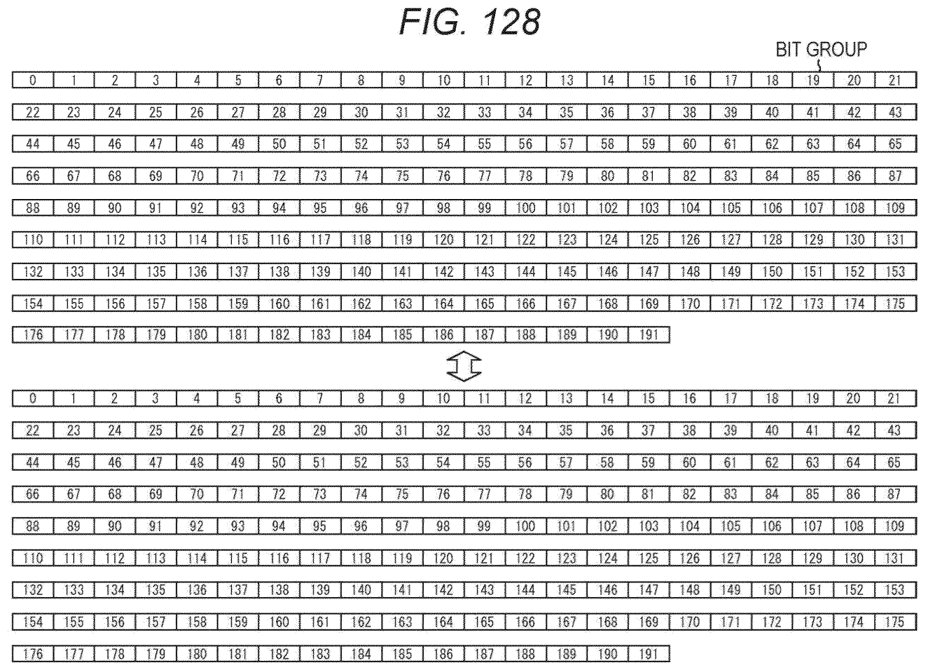

FIG. 128 is a diagram illustrating a ninth example of the GW pattern for an LDPC code with a code length N of 69120 bits.

According to the GW pattern in FIG. 128, a sequence of bit groups 0 to 191 of the 69120 bit LDPC code is interleaved into a sequence of the following bit group.
0, 1, 2, 3, 4, 5, 6, 7, 8, 9, 10, 11, 12, 13, 14, 15, 16, 17, 18, 19, 20, 21, 22, 23, 24, 25, 26, 27, 28, 29, 30, 31, 32, 33, 34, 35, 36, 37, 38, 39, 40, 41, 42, 43, 44, 45, 46, 47, 48, 49, 50, 51, 52, 53, 54, 55, 56, 57, 58, 59, 60, 61, 62, 63, 64, 65, 66, 67, 68, 69, 70, 71, 72, 73, 74, 75, 76, 77, 78, 79, 80, 81, 82, 83, 84, 85, 86, 87, 88, 89, 90, 91, 92, 93, 94, 95, 96, 97, 98, 99, 100, 101, 102, 103, 104, 105, 106, 107, 108, 109, 110, 111, 112, 113, 114, 115, 116, 117, 118, 119, 120, 121, 122, 123, 124, 125, 126, 127, 128, 129, 130, 131, 132, 133, 134, 135, 136, 137, 138, 139, 140, 141, 142, 143, 144, 145, 146, 147, 148, 149, 150, 151, 152, 153, 154, 155, 156, 157, 158, 159, 160, 161, 162, 163, 164, 165, 166, 167, 168, 169, 170, 171, 172, 173, 174, 175, 176, 177, 178, 179, 180, 181, 182, 183, 184, 185, 186, 187, 188, 189, 190, 191

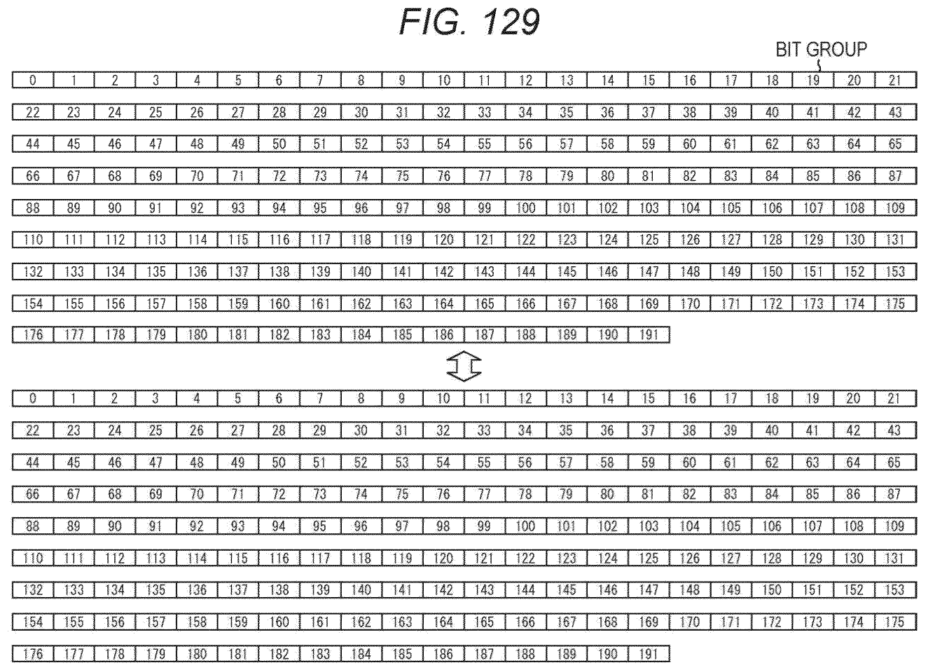

FIG. 129 is a diagram illustrating a tenth example of the GW pattern for an LDPC code with a code length N of 69120 bits.

According to the GW pattern in FIG. 129, a sequence of bit groups 0 to 191 of the 69120 bit LDPC code is interleaved into a sequence of the following bit group.
0, 1, 2, 3, 4, 5, 6, 7, 8, 9, 10, 11, 12, 13, 14, 15, 16, 17, 18, 19, 20, 21, 22, 23, 24, 25, 26, 27, 28, 29, 30, 31, 32, 33, 34, 35, 36, 37, 38, 39, 40, 41, 42, 43, 44, 45, 46, 47, 48, 49, 50, 51, 52, 53, 54, 55, 56, 57, 58, 59, 60, 61, 62, 63, 64, 65, 66, 67, 68, 69, 70, 71, 72, 73, 74, 75, 76, 77, 78, 79, 80, 81, 82, 83, 84, 85, 86, 87, 88, 89, 90, 91, 92, 93, 94, 95, 96, 97, 98, 99, 100, 101, 102, 103, 104, 105, 106, 107, 108, 109, 110, 111, 112, 113, 114, 115, 116, 117, 118, 119, 120, 121, 122, 123, 124, 125, 126, 127, 128, 129, 130, 131, 132, 133, 134, 135, 136, 137, 138, 139, 140, 141, 142, 143, 144, 145, 146, 147, 148, 149, 150, 151, 152, 153, 154, 155, 156, 157, 158, 159, 160, 161, 162, 163, 164, 165, 166, 167, 168, 169, 170, 171, 172, 173, 174, 175, 176, 177, 178, 179, 180, 181, 182, 183, 184, 185, 186, 187, 188, 189, 190, 191

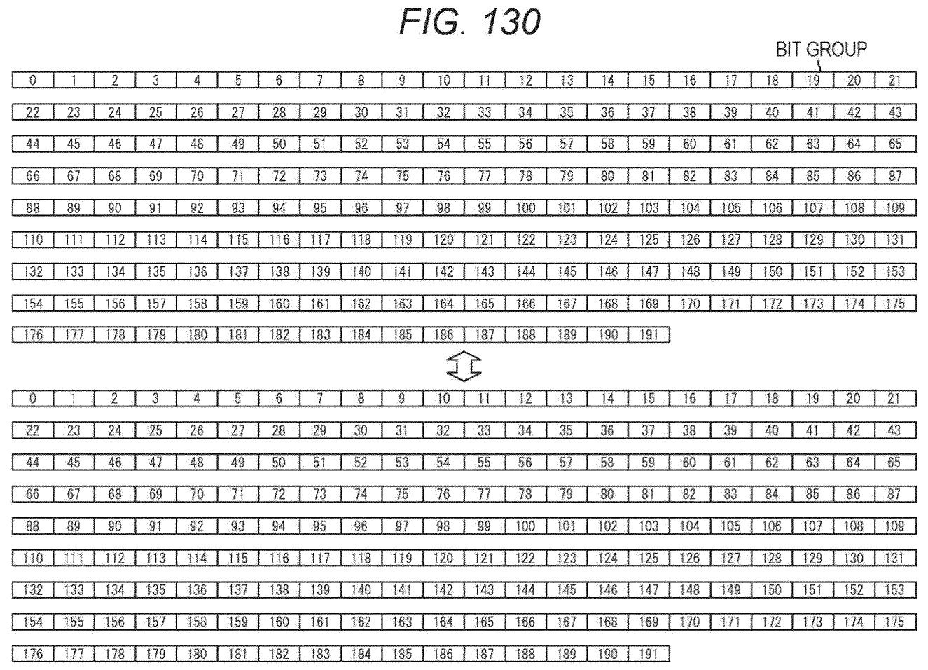

FIG. 130 is a diagram illustrating an eleventh example of the GW pattern for an LDPC code with a code length N of 69120 bits.

According to the GW pattern in FIG. 130, a sequence of bit groups 0 to 191 of the 69120 bit LDPC code is interleaved into a sequence of the following bit group.
0, 1, 2, 3, 4, 5, 6, 7, 8, 9, 10, 11, 12, 13, 14, 15, 16, 17, 18, 19, 20, 21, 22, 23, 24, 25, 26, 27, 28, 29, 30, 31, 32, 33, 34, 35, 36, 37, 38, 39, 40, 41, 42, 43, 44, 45, 46, 47, 48, 49, 50, 51, 52, 53, 54, 55, 56, 57, 58, 59, 60, 61, 62, 63, 64, 65, 66, 67, 68, 69, 70, 71, 72, 73, 74, 75, 76, 77, 78, 79, 80, 81, 82, 83, 84, 85, 86, 87, 88, 89, 90, 91, 92, 93, 94, 95, 96, 97, 98, 99, 100, 101, 102, 103, 104, 105, 106, 107, 108, 109, 110, 111, 112, 113, 114, 115, 116, 117, 118, 119, 120, 121, 122, 123, 124, 125, 126, 127, 128, 129, 130, 131, 132, 133, 134, 135, 136, 137, 138, 139, 140, 141, 142, 143, 144, 145, 146, 147, 148, 149, 150, 151, 152, 153, 154, 155, 156, 157, 158, 159, 160, 161, 162, 163, 164, 165, 166, 167, 168, 169, 170, 171, 172, 173, 174, 175, 176, 177, 178, 179, 180, 181, 182, 183, 184, 185, 186, 187, 188, 189, 190, 191

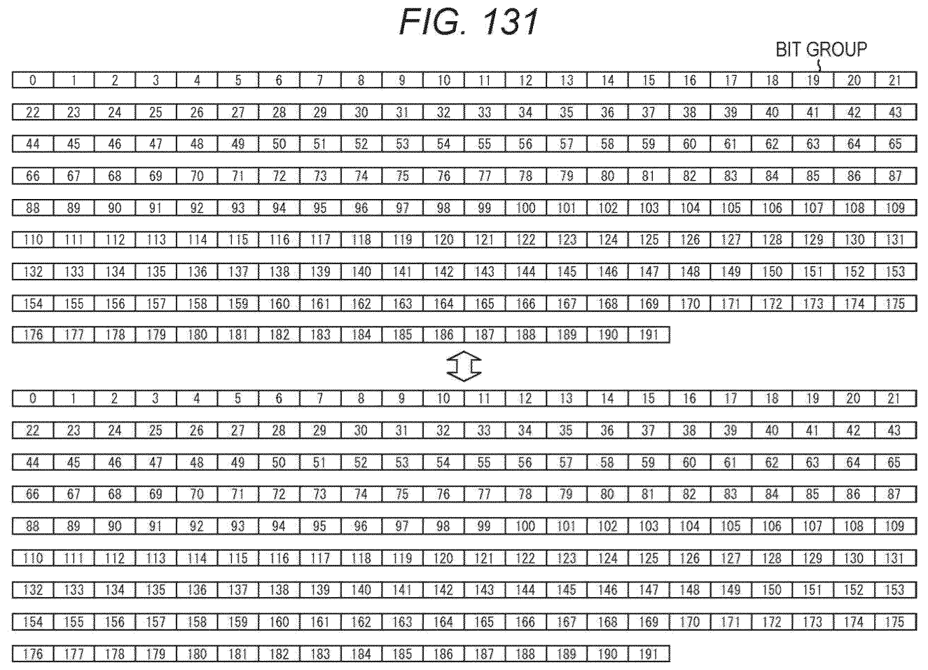

FIG. 131 is a diagram illustrating a twelfth example of the GW pattern for an LDPC code with a code length N of 69120 bits.

According to the GW pattern in FIG. 131, a sequence of bit groups 0 to 191 of the 69120 bit LDPC code is interleaved into a sequence of the following bit group.
0, 1, 2, 3, 4, 5, 6, 7, 8, 9, 10, 11, 12, 13, 14, 15, 16, 17, 18, 19, 20, 21, 22, 23, 24, 25, 26, 27, 28, 29, 30, 31, 32, 33, 34, 35, 36, 37, 38, 39, 40, 41, 42, 43, 44, 45, 46, 47, 48, 49, 50, 51, 52, 53, 54, 55, 56, 57, 58, 59, 60, 61, 62, 63, 64, 65, 66, 67, 68, 69, 70, 71, 72, 73, 74, 75, 76, 77, 78, 79, 80, 81, 82, 83, 84, 85, 86, 87, 88, 89, 90, 91, 92, 93, 94, 95, 96, 97, 98, 99, 100, 101, 102, 103, 104, 105, 106, 107, 108, 109, 110, 111, 112, 113, 114, 115, 116, 117, 118, 119, 120, 121, 122, 123, 124, 125, 126, 127, 128, 129, 130, 131, 132, 133, 134, 135, 136, 137, 138, 139, 140, 141, 142, 143, 144, 145, 146, 147, 148, 149, 150, 151, 152, 153, 154, 155, 156, 157, 158, 159, 160, 161, 162, 163, 164, 165, 166, 167, 168, 169, 170, 171, 172, 173, 174, 175, 176, 177, 178, 179, 180, 181, 182, 183, 184, 185, 186, 187, 188, 189, 190, 191

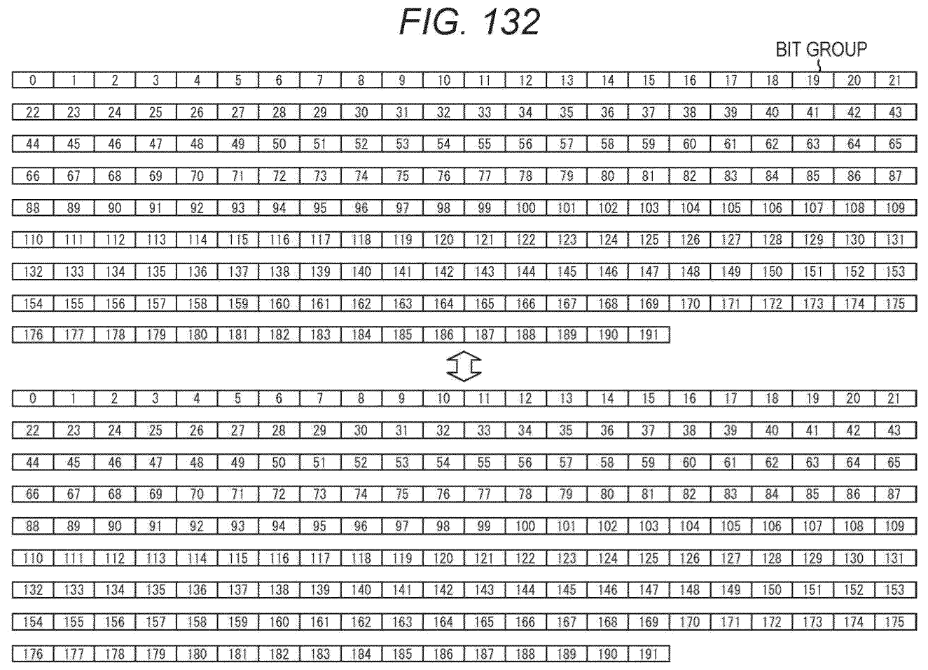

FIG. 132 is a diagram illustrating a thirteenth example of the GW pattern for an LDPC code with a code length N of 69120 bits.

According to the GW pattern in FIG. 132, a sequence of bit groups 0 to 191 of the 69120 bit LDPC code is interleaved into a sequence of the following bit group.
0, 1, 2, 3, 4, 5, 6, 7, 8, 9, 10, 11, 12, 13, 14, 15, 16, 17, 18, 19, 20, 21, 22, 23, 24, 25, 26, 27, 28, 29, 30, 31, 32, 33, 34, 35, 36, 37, 38, 39, 40, 41, 42, 43, 44, 45, 46, 47, 48, 49, 50, 51, 52, 53, 54, 55, 56, 57, 58, 59, 60, 61, 62, 63, 64, 65, 66, 67, 68, 69, 70, 71, 72, 73, 74, 75, 76, 77, 78, 79, 80, 81, 82, 83, 84, 85, 86, 87, 88, 89, 90, 91, 92, 93, 94, 95, 96, 97, 98, 99, 100, 101, 102, 103, 104, 105, 106, 107, 108, 109, 110, 111, 112, 113, 114, 115, 116, 117, 118, 119, 120, 121, 122, 123, 124, 125, 126, 127, 128, 129, 130, 131, 132, 133, 134, 135, 136, 137, 138, 139, 140, 141, 142, 143, 144, 145, 146, 147, 148, 149, 150, 151, 152, 153, 154, 155, 156, 157, 158, 159, 160, 161, 162, 163, 164, 165, 166, 167, 168, 169, 170, 171, 172, 173, 174, 175, 176, 177, 178, 179, 180, 181, 182, 183, 184, 185, 186, 187, 188, 189, 190, 191

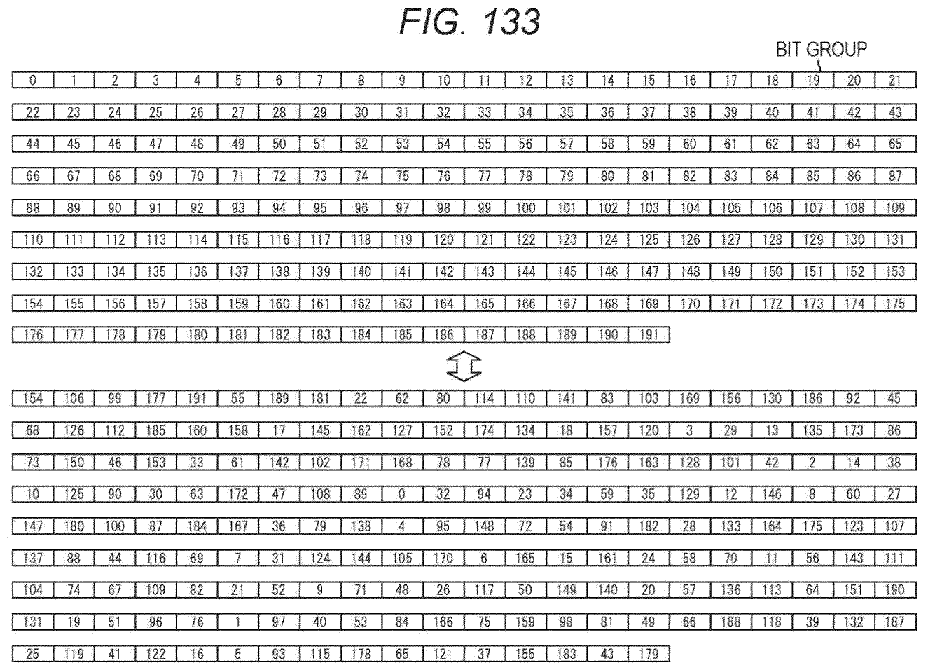

FIG. 133 is a diagram illustrating a fourteenth example of the GW pattern for an LDPC code with a code length N of 69120 bits.

According to the GW pattern in FIG. 133, a sequence of bit groups 0 to 191 of the 69120 bit LDPC code is interleaved into a sequence of the following bit group.
154, 106, 99, 177, 191, 55, 189, 181, 22, 62, 80, 114, 110, 141, 83, 103, 169, 156, 130, 186, 92, 45, 68, 126, 112, 185, 160, 158, 17, 145, 162, 127, 152, 174, 134, 18, 157, 120, 3, 29, 13, 135, 173, 86, 73, 150, 46, 153, 33, 61, 142, 102, 171, 168, 78, 77, 139, 85, 176, 163, 128, 101, 42, 2, 14, 38, 10, 125, 90, 30, 63, 172, 47, 108, 89, 0, 32, 94, 23, 34, 59, 35, 129, 12, 146, 8, 60, 27, 147, 180, 100, 87, 184, 167, 36, 79, 138, 4, 95, 148, 72, 54, 91, 182, 28, 133, 164, 175, 123, 107, 137, 88, 44, 116, 69, 7, 31, 124, 144, 105, 170, 6, 165, 15, 161, 24, 58, 70, 11, 56, 143, 111, 104, 74, 67, 109, 82, 21, 52, 9, 71, 48, 26, 117, 50, 149, 140, 20, 57, 136, 113, 64, 151, 190, 131, 19, 51, 96, 76, 1, 97, 40, 53, 84, 166, 75, 159, 98, 81, 49, 66, 188, 118, 39, 132, 187, 25, 119, 41, 122, 16, 5, 93, 115, 178, 65, 121, 37, 155, 183, 43, 179

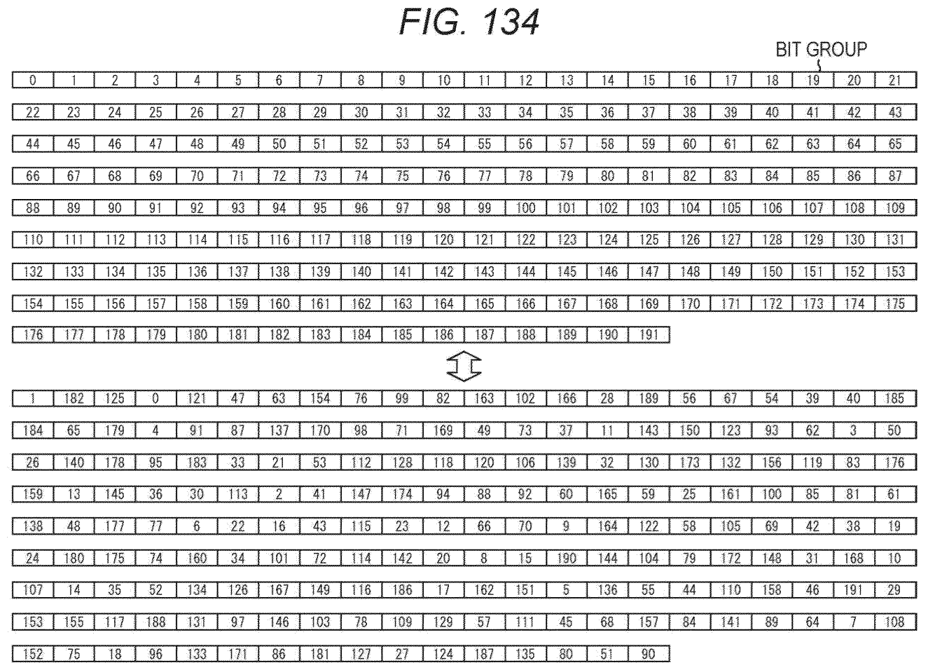

FIG. 134 is a diagram illustrating a fifteenth example of the GW pattern for an LDPC code with a code length N of 69120 bits.

According to the GW pattern in FIG. 134, a sequence of bit groups 0 to 191 of the 69120 bit LDPC code is interleaved into a sequence of the following bit group.
1, 182, 125, 0, 121, 47, 63, 154, 76, 99, 82, 163, 102, 166, 28, 189, 56, 67, 54, 39, 40, 185, 184, 65, 179, 4, 91, 87, 137, 170, 98, 71, 169, 49, 73, 37, 11, 143, 150, 123, 93, 62, 3, 50, 26, 140, 178, 95, 183, 33, 21, 53, 112, 128, 118, 120, 106, 139, 32, 130, 173, 132, 156, 119, 83, 176, 159, 13, 145, 36, 30, 113, 2, 41, 147, 174, 94, 88, 92, 60, 165, 59, 25, 161, 100, 85, 81, 61, 138, 48, 177, 77, 6, 22, 16, 43, 115, 23, 12, 66, 70, 9, 164, 122, 58, 105, 69, 42, 38, 19, 24, 180, 175, 74, 160, 34, 101, 72, 114, 142, 20, 8, 15, 190, 144, 104, 79, 172, 148, 31, 168, 10, 107, 14, 35, 52, 134, 126, 167, 149, 116, 186, 17, 162, 151, 5, 136, 55, 44, 110, 158, 46, 191, 29, 153, 155, 117, 188, 131, 97, 146, 103, 78, 109, 129, 57, 111, 45, 68, 157, 84, 141, 89, 64, 7, 108, 152, 75, 18, 96, 133, 171, 86, 181, 127, 27, 124, 187, 135, 80, 51, 90

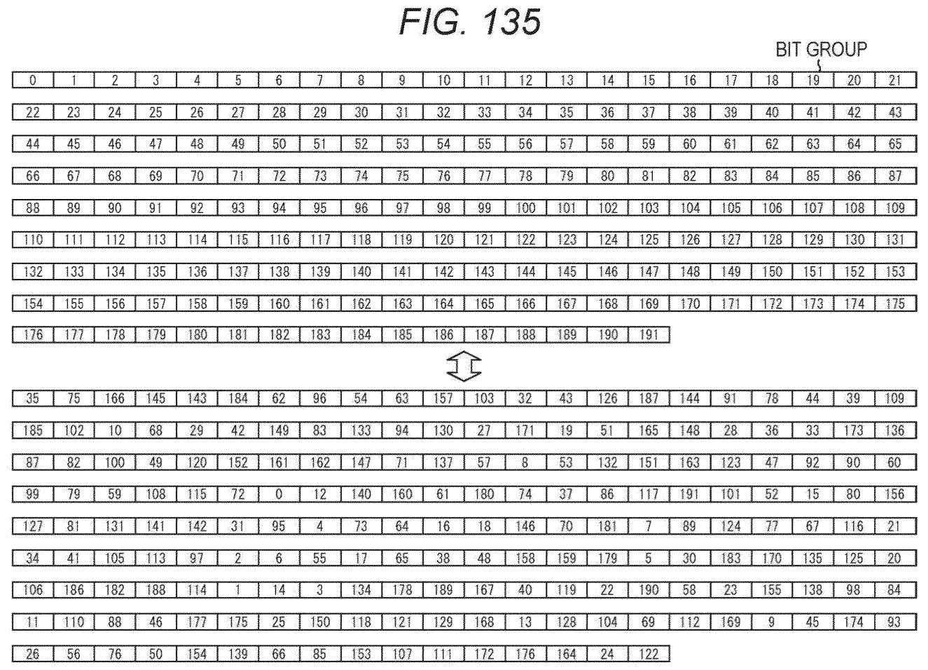

FIG. 135 is a diagram illustrating a sixteenth example of the GW pattern for an LDPC code with a code length N of 69120 bits.

According to the GW pattern in FIG. 135, a sequence of bit groups 0 to 191 of the 69120 bit LDPC code is interleaved into a sequence of the following bit group.
35, 75, 166, 145, 143, 184, 62, 96, 54, 63, 157, 103, 32, 43, 126, 187, 144, 91, 78, 44, 39, 109, 185, 102, 10, 68, 29, 42, 149, 83, 133, 94, 130, 27, 171, 19, 51, 165, 148, 28, 36, 33, 173, 136, 87, 82, 100, 49, 120, 152, 161, 162, 147, 71, 137, 57, 8, 53, 132, 151, 163, 123, 47, 92, 90, 60, 99, 79, 59, 108, 115, 72, 0, 12, 140, 160, 61, 180, 74, 37, 86, 117, 191, 101, 52, 15, 80, 156, 127, 81, 131, 141, 142, 31, 95, 4, 73, 64, 16, 18, 146, 70, 181, 7, 89, 124, 77, 67, 116, 21, 34, 41, 105, 113, 97, 2, 6, 55, 17, 65, 38, 48, 158, 159, 179, 5, 30, 183, 170, 135, 125, 20, 106, 186, 182, 188, 114, 1, 14, 3, 134, 178, 189, 167, 40, 119, 22, 190, 58, 23, 155, 138, 98, 84, 11, 110, 88, 46, 177, 175, 25, 150, 118, 121, 129, 168, 13, 128, 104, 69, 112, 169, 9, 45, 174, 93, 26, 56, 76, 50, 154, 139, 66, 85, 153, 107, 111, 172, 176, 164, 24, 122

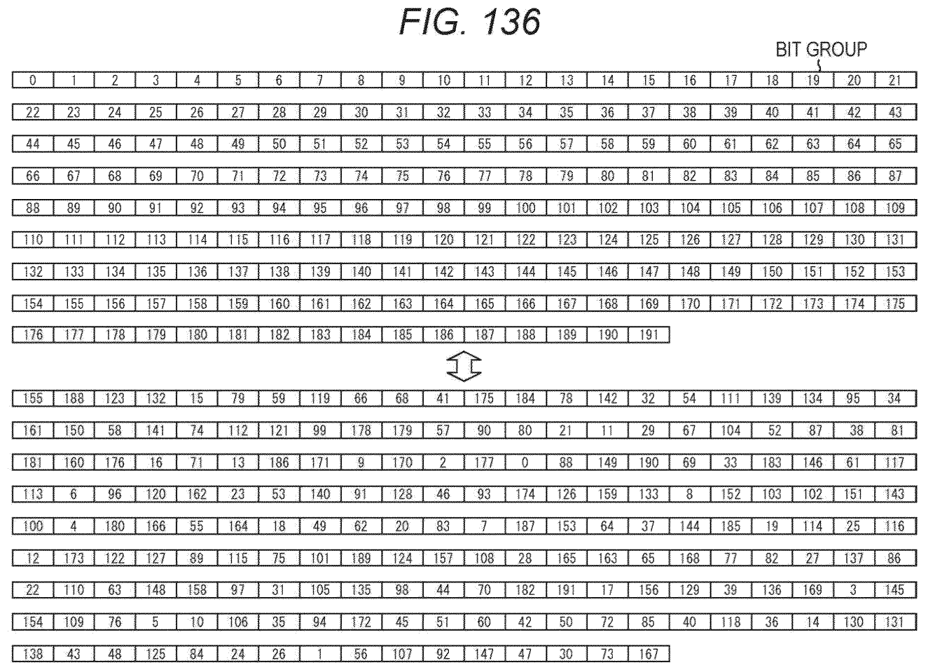

FIG. 136 is a diagram illustrating a seventeenth example of the GW pattern for an LDPC code with a code length N of 69120 bits.

According to the GW pattern in FIG. 136, a sequence of bit groups 0 to 191 of the 69120 bit LDPC code is interleaved into a sequence of the following bit group.
155, 188, 123, 132, 15, 79, 59, 119, 66, 68, 41, 175, 184, 78, 142, 32, 54, 111, 139, 134, 95, 34, 161, 150, 58, 141, 74, 112, 121, 99, 178, 179, 57, 90, 80, 21, 11, 29, 67, 104, 52, 87, 38, 81, 181, 160, 176, 16, 71, 13, 186, 171, 9, 170, 2, 177, 0, 88, 149, 190, 69, 33, 183, 146, 61, 117, 113, 6, 96, 120, 162, 23, 53, 140, 91, 128, 46, 93, 174, 126, 159, 133, 8, 152, 103, 102, 151, 143, 100, 4, 180, 166, 55, 164, 18, 49, 62, 20, 83, 7, 187, 153, 64, 37, 144, 185, 19, 114, 25, 116, 12, 173, 122, 127, 89, 115, 75, 101, 189, 124, 157, 108, 28, 165, 163, 65, 168, 77, 82, 27, 137, 86, 22, 110, 63, 148, 158, 97, 31, 105, 135, 98, 44, 70, 182, 191, 17, 156, 129, 39, 136, 169, 3, 145, 154, 109, 76, 5, 10, 106, 35, 94, 172, 45, 51, 60, 42, 50, 72, 85, 40, 118, 36, 14, 130, 131, 138, 43, 48, 125, 84, 24, 26, 1, 56, 107, 92, 147, 47, 30, 73, 167

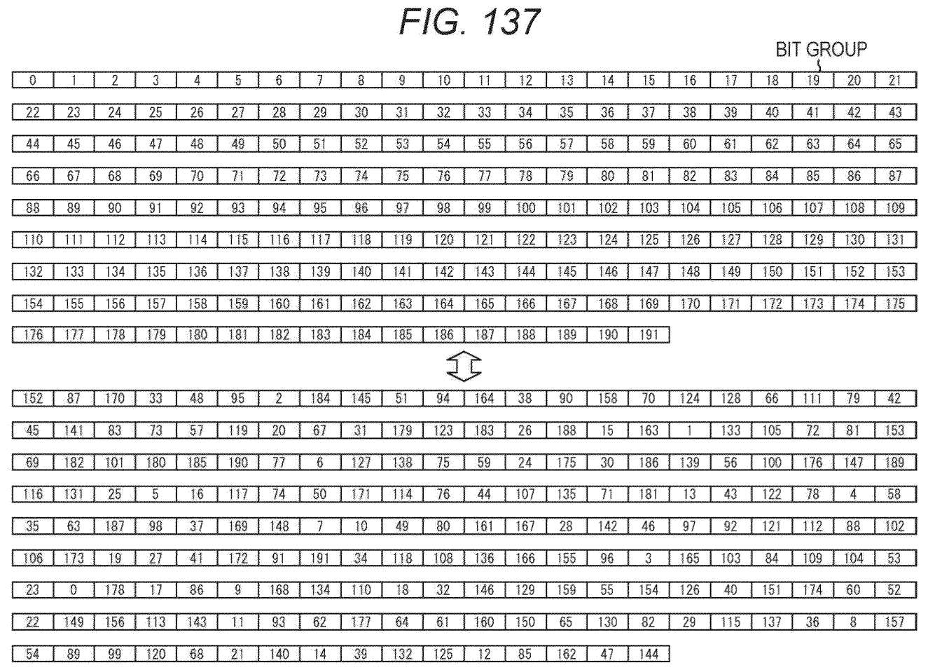

FIG. 137 is a diagram illustrating an eighteenth example of the GW pattern for an LDPC code with a code length N of 69120 bits.

According to the GW pattern in FIG. 137, a sequence of bit groups 0 to 191 of the 69120 bit LDPC code is interleaved into a sequence of the following bit group.
152, 87, 170, 33, 48, 95, 2, 184, 145, 51, 94, 164, 38, 90, 158, 70, 124, 128, 66, 111, 79, 42, 45, 141, 83, 73, 57, 119, 20, 67, 31, 179, 123, 183, 26, 188, 15, 163, 1, 133, 105, 72, 81, 153, 69, 182, 101, 180, 185, 190, 77, 6, 127, 138, 75, 59, 24, 175, 30, 186, 139, 56, 100, 176, 147, 189, 116, 131, 25, 5, 16, 117, 74, 50, 171, 114, 76, 44, 107, 135, 71, 181, 13, 43, 122, 78, 4, 58, 35, 63, 187, 98, 37, 169, 148, 7, 10, 49, 80, 161, 167, 28, 142, 46, 97, 92, 121, 112, 88, 102, 106, 173, 19, 27, 41, 172, 91, 191, 34, 118, 108, 136, 166, 155, 96, 3, 165, 103, 84, 109, 104, 53, 23, 0, 178, 17, 86, 9, 168, 134, 110, 18, 32, 146, 129, 159, 55, 154, 126, 40, 151, 174, 60, 52, 22, 149, 156, 113, 143, 11, 93, 62, 177, 64, 61, 160, 150, 65, 130, 82, 29, 115, 137, 36, 8, 157, 54, 89, 99, 120, 68, 21, 140, 14, 39, 132, 125, 12, 85, 162, 47, 144

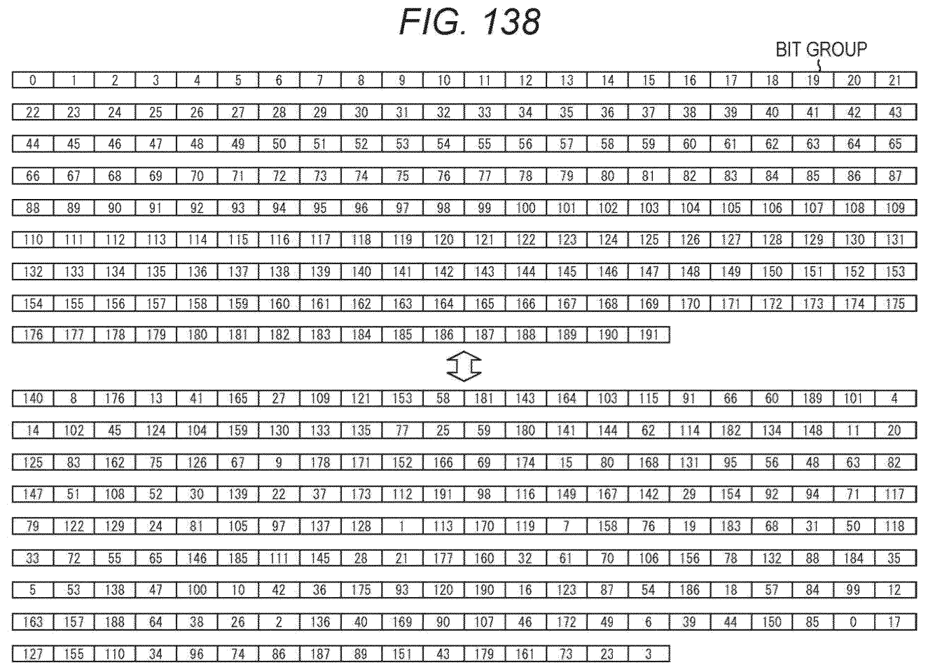

FIG. 138 is a diagram illustrating a nineteenth example of the GW pattern for an LDPC code with a code length N of 69120 bits.

According to the GW pattern in FIG. 138, a sequence of bit groups 0 to 191 of the 69120 bit LDPC code is interleaved into a sequence of the following bit group.
140, 8, 176, 13, 41, 165, 27, 109, 121, 153, 58, 181, 143, 164, 103, 115, 91, 66, 60, 189, 101, 4, 14, 102, 45, 124, 104, 159, 130, 133, 135, 77, 25, 59, 180, 141, 144, 62, 114, 182, 134, 148, 11, 20, 125, 83, 162, 75, 126, 67, 9, 178, 171, 152, 166, 69, 174, 15, 80, 168, 131, 95, 56, 48, 63, 82, 147, 51, 108, 52, 30, 139, 22, 37, 173, 112, 191, 98, 116, 149, 167, 142, 29, 154, 92, 94, 71, 117, 79, 122, 129, 24, 81, 105, 97, 137, 128, 1, 113, 170, 119, 7, 158, 76, 19, 183, 68, 31, 50, 118, 33, 72, 55, 65, 146, 185, 111, 145, 28, 21, 177, 160, 32, 61, 70, 106, 156, 78, 132, 88, 184, 35, 5, 53, 138, 47, 100, 10, 42, 36, 175, 93, 120, 190, 16, 123, 87, 54, 186, 18, 57, 84, 99, 12, 163, 157, 188, 64, 38, 26, 2, 136, 40, 169, 90, 107, 46, 172, 49, 6, 39, 44, 150, 85, 0, 17, 127, 155, 110, 34, 96, 74, 86, 187, 89, 151, 43, 179, 161, 73, 23, 3

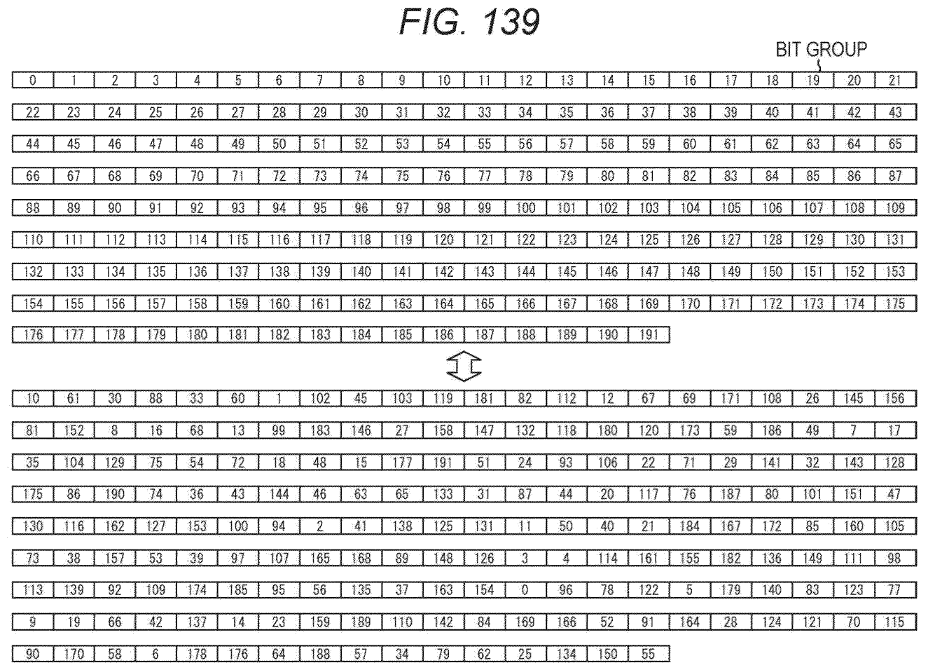

FIG. 139 is a diagram illustrating a twentieth example of the GW pattern for an LDPC code with a code length N of 69120 bits.

According to the GW pattern in FIG. 139, a sequence of bit groups 0 to 191 of the 69120 bit LDPC code is interleaved into a sequence of the following bit group.
10, 61, 30, 88, 33, 60, 1, 102, 45, 103, 119, 181, 82, 112, 12, 67, 69, 171, 108, 26, 145, 156, 81, 152, 8, 16, 68, 13, 99, 183, 146, 27, 158, 147, 132, 118, 180, 120, 173, 59, 186, 49, 7, 17, 35, 104, 129, 75, 54, 72, 18, 48, 15, 177, 191, 51, 24, 93, 106, 22, 71, 29, 141, 32, 143, 128, 175, 86, 190, 74, 36, 43, 144, 46, 63, 65, 133, 31, 87, 44, 20, 117, 76, 187, 80, 101, 151, 47, 130, 116, 162, 127, 153, 100, 94, 2, 41, 138, 125, 131, 11, 50, 40, 21, 184, 167, 172, 85, 160, 105, 73, 38, 157, 53, 39, 97, 107, 165, 168, 89, 148, 126, 3, 4, 114, 161, 155, 182, 136, 149, 111, 98, 113, 139, 92, 109, 174, 185, 95, 56, 135, 37, 163, 154, 0, 96, 78, 122, 5, 179, 140, 83, 123, 77, 9, 19, 66, 42, 137, 14, 23, 159, 189, 110, 142, 84, 169, 166, 52, 91, 164, 28, 124, 121, 70, 115, 90, 170, 58, 6, 178, 176, 64, 188, 57, 34, 79, 62, 25, 134, 150, 55

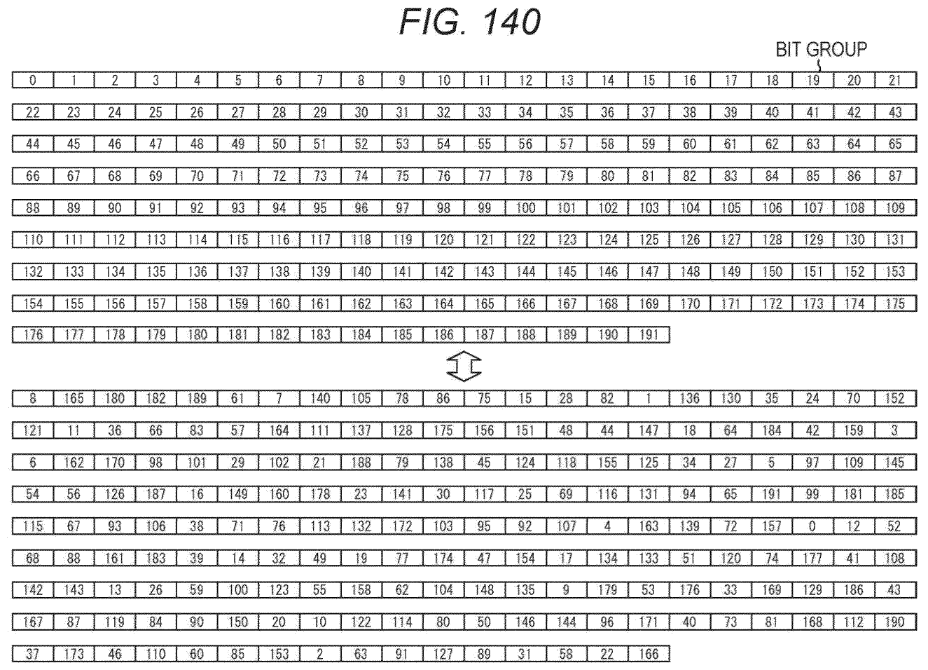

FIG. 140 is a diagram illustrating a twenty first example of the GW pattern for an LDPC code with a code length N of 69120 bits.

According to the GW pattern in FIG. 140, a sequence of bit groups 0 to 191 of the 69120 bit LDPC code is interleaved into a sequence of the following bit group.
8, 165, 180, 182, 189, 61, 7, 140, 105, 78, 86, 75, 15, 28, 82, 1, 136, 130, 35, 24, 70, 152, 121, 11, 36, 66, 83, 57, 164, 111, 137, 128, 175, 156, 151, 48, 44, 147, 18, 64, 184, 42, 159, 3, 6, 162, 170, 98, 101, 29, 102, 21, 188, 79, 138, 45, 124, 118, 155, 125, 34, 27, 5, 97, 109, 145, 54, 56, 126, 187, 16, 149, 160, 178, 23, 141, 30, 117, 25, 69, 116, 131, 94, 65, 191, 99, 181, 185, 115, 67, 93, 106, 38, 71, 76, 113, 132, 172, 103, 95, 92, 107, 4, 163, 139, 72, 157, 0, 12, 52, 68, 88, 161, 183, 39, 14, 32, 49, 19, 77, 174, 47, 154, 17, 134, 133, 51, 120, 74, 177, 41, 108, 142, 143, 13, 26, 59, 100, 123, 55, 158, 62, 104, 148, 135, 9, 179, 53, 176, 33, 169, 129, 186, 43, 167, 87, 119, 84, 90, 150, 20, 10, 122, 114, 80, 50, 146, 144, 96, 171, 40, 73, 81, 168, 112, 190, 37, 173, 46, 110, 60, 85, 153, 2, 63, 91, 127, 89, 31, 58, 22, 166

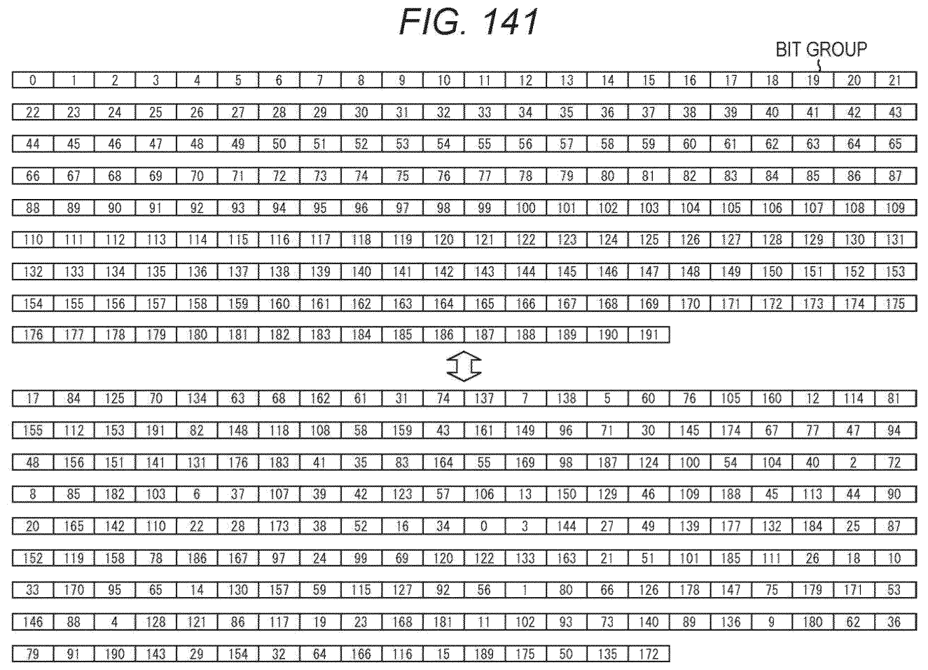

FIG. 141 is a diagram illustrating a twenty second example of the GW pattern for an LDPC code with a code length N of 69120 bits.

According to the GW pattern in FIG. 141, a sequence of bit groups 0 to 191 of the 69120 bit LDPC code is interleaved into a sequence of the following bit group.
17, 84, 125, 70, 134, 63, 68, 162, 61, 31, 74, 137, 7, 138, 5, 60, 76, 105, 160, 12, 114, 81, 155, 112, 153, 191, 82, 148, 118, 108, 58, 159, 43, 161, 149, 96, 71, 30, 145, 174, 67, 77, 47, 94, 48, 156, 151, 141, 131, 176, 183, 41, 35, 83, 164, 55, 169, 98, 187, 124, 100, 54, 104, 40, 2, 72, 8, 85, 182, 103, 6, 37, 107, 39, 42, 123, 57, 106, 13, 150, 129, 46, 109, 188, 45, 113, 44, 90, 20, 165, 142, 110, 22, 28, 173, 38, 52, 16, 34, 0, 3, 144, 27, 49, 139, 177, 132, 184, 25, 87, 152, 119, 158, 78, 186, 167, 97, 24, 99, 69, 120, 122, 133, 163, 21, 51, 101, 185, 111, 26, 18, 10, 33, 170, 95, 65, 14, 130, 157, 59, 115, 127, 92, 56, 1, 80, 66, 126, 178, 147, 75, 179, 171, 53, 146, 88, 4, 128, 121, 86, 117, 19, 23, 168, 181, 11, 102, 93, 73, 140, 89, 136, 9, 180, 62, 36, 79, 91, 190, 143, 29, 154, 32, 64, 166, 116, 15, 189, 175, 50, 135, 172

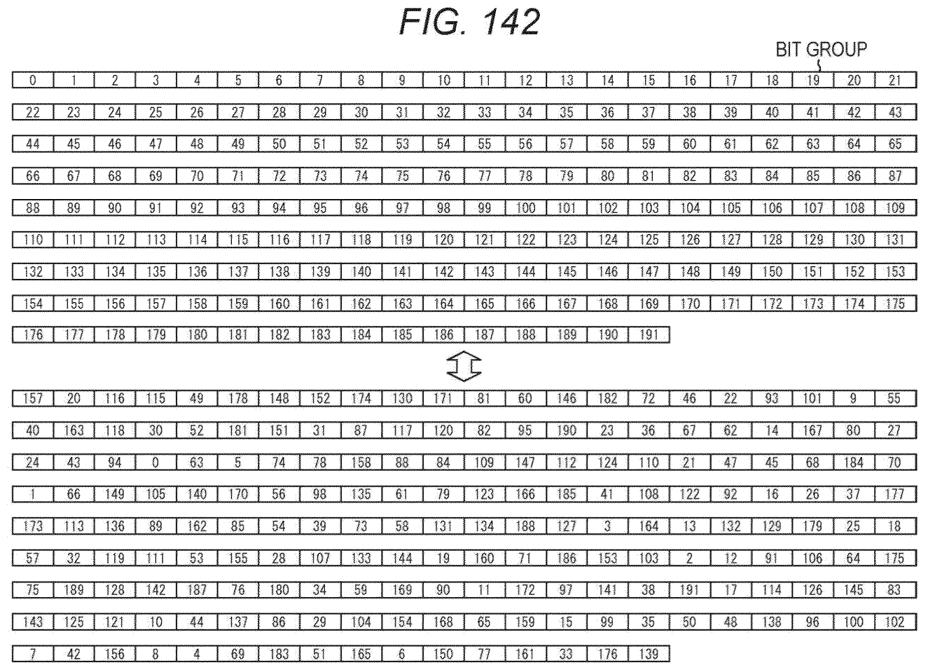

FIG. 142 is a diagram illustrating a twenty third example of the GW pattern for an LDPC code with a code length N of 69120 bits.

According to the GW pattern in FIG. 142, a sequence of bit groups 0 to 191 of the 69120 bit LDPC code is interleaved into a sequence of the following bit group.
157, 20, 116, 115, 49, 178, 148, 152, 174, 130, 171, 81, 60, 146, 182, 72, 46, 22, 93, 101, 9, 55, 40, 163, 118, 30, 52, 181, 151, 31, 87, 117, 120, 82, 95, 190, 23, 36, 67, 62, 14, 167, 80, 27, 24, 43, 94, 0, 63, 5, 74, 78, 158, 88, 84, 109, 147, 112, 124, 110, 21, 47, 45, 68, 184, 70, 1, 66, 149, 105, 140, 170, 56, 98, 135, 61, 79, 123, 166, 185, 41, 108, 122, 92, 16, 26, 37, 177, 173, 113, 136, 89, 162, 85, 54, 39, 73, 58, 131, 134, 188, 127, 3, 164, 13, 132, 129, 179, 25, 18, 57, 32, 119, 111, 53, 155, 28, 107, 133, 144, 19, 160, 71, 186, 153, 103, 2, 12, 91, 106, 64, 175, 75, 189, 128, 142, 187, 76, 180, 34, 59, 169, 90, 11, 172, 97, 141, 38, 191, 17, 114, 126, 145, 83, 143, 125, 121, 10, 44, 137, 86, 29, 104, 154, 168, 65, 159, 15, 99, 35, 50, 48, 138, 96, 100, 102, 7, 42, 156, 8, 4, 69, 183, 51, 165, 6, 150, 77, 161, 33, 176, 139

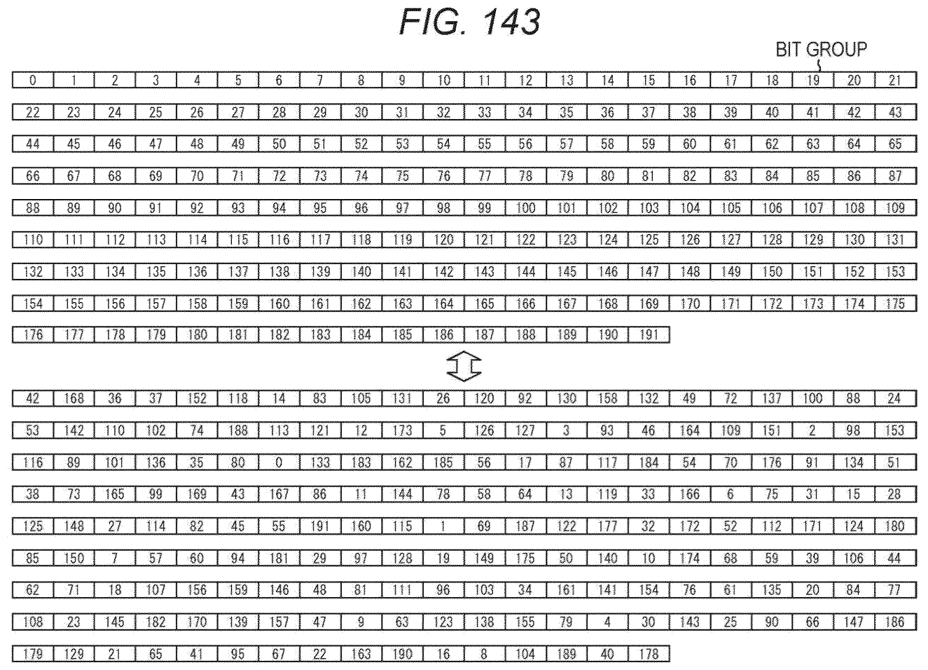

FIG. 143 is a diagram illustrating a twenty fourth example of the GW pattern for an LDPC code with a code length N of 69120 bits.

According to the GW pattern in FIG. 143, a sequence of bit groups 0 to 191 of the 69120 bit LDPC code is interleaved into a sequence of the following bit group.
42, 168, 36, 37, 152, 118, 14, 83, 105, 131, 26, 120, 92, 130, 158, 132, 49, 72, 137, 100, 88, 24, 53, 142, 110, 102, 74, 188, 113, 121, 12, 173, 5, 126, 127, 3, 93, 46, 164, 109, 151, 2, 98, 153, 116, 89, 101, 136, 35, 80, 0, 133, 183, 162, 185, 56, 17, 87, 117, 184, 54, 70, 176, 91, 134, 51, 38, 73, 165, 99, 169, 43, 167, 86, 11, 144, 78, 58, 64, 13, 119, 33, 166, 6, 75, 31, 15, 28, 125, 148, 27, 114, 82, 45, 55, 191, 160, 115, 1, 69, 187, 122, 177, 32, 172, 52, 112, 171, 124, 180, 85, 150, 7, 57, 60, 94, 181, 29, 97, 128, 19, 149, 175, 50, 140, 10, 174, 68, 59, 39, 106, 44, 62, 71, 18, 107, 156, 159, 146, 48, 81, 111, 96, 103, 34, 161, 141, 154, 76, 61, 135, 20, 84, 77, 108, 23, 145, 182, 170, 139, 157, 47, 9, 63, 123, 138, 155, 79, 4, 30, 143, 25, 90, 66, 147, 186, 179, 129, 21, 65, 41, 95, 67, 22, 163, 190, 16, 8, 104, 189, 40, 178

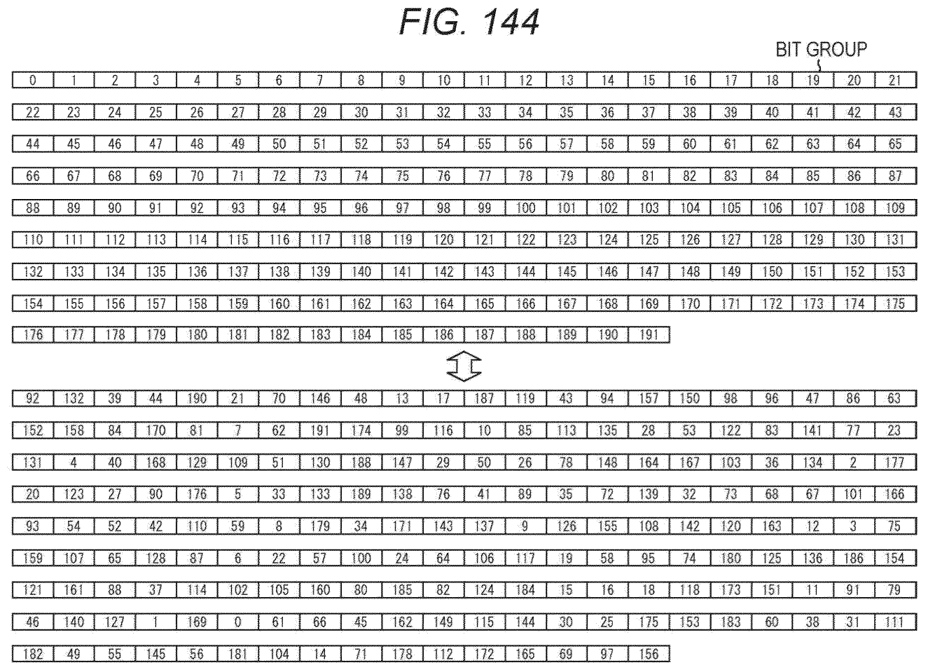

FIG. 144 is a diagram illustrating a twenty fifth example of the GW pattern for an LDPC code with a code length N of 69120 bits.

According to the GW pattern in FIG. 144, a sequence of bit groups 0 to 191 of the 69120 bit LDPC code is interleaved into a sequence of the following bit group.
92, 132, 39, 44, 190, 21, 70, 146, 48, 13, 17, 187, 119, 43, 94, 157, 150, 98, 96, 47, 86, 63, 152, 158, 84, 170, 81, 7, 62, 191, 174, 99, 116, 10, 85, 113, 135, 28, 53, 122, 83, 141, 77, 23, 131, 4, 40, 168, 129, 109, 51, 130, 188, 147, 29, 50, 26, 78, 148, 164, 167, 103, 36, 134, 2, 177, 20, 123, 27, 90, 176, 5, 33, 133, 189, 138, 76, 41, 89, 35, 72, 139, 32, 73, 68, 67, 101, 166, 93, 54, 52, 42, 110, 59, 8, 179, 34, 171, 143, 137, 9, 126, 155, 108, 142, 120, 163, 12, 3, 75, 159, 107, 65, 128, 87, 6, 22, 57, 100, 24, 64, 106, 117, 19, 58, 95, 74, 180, 125, 136, 186, 154, 121, 161, 88, 37, 114, 102, 105, 160, 80, 185, 82, 124, 184, 15, 16, 18, 118, 173, 151, 11, 91, 79, 46, 140, 127, 1, 169, 0, 61, 66, 45, 162, 149, 115, 144, 30, 25, 175, 153, 183, 60, 38, 31, 111, 182, 49, 55, 145, 56, 181, 104, 14, 71, 178, 112, 172, 165, 69, 97, 156

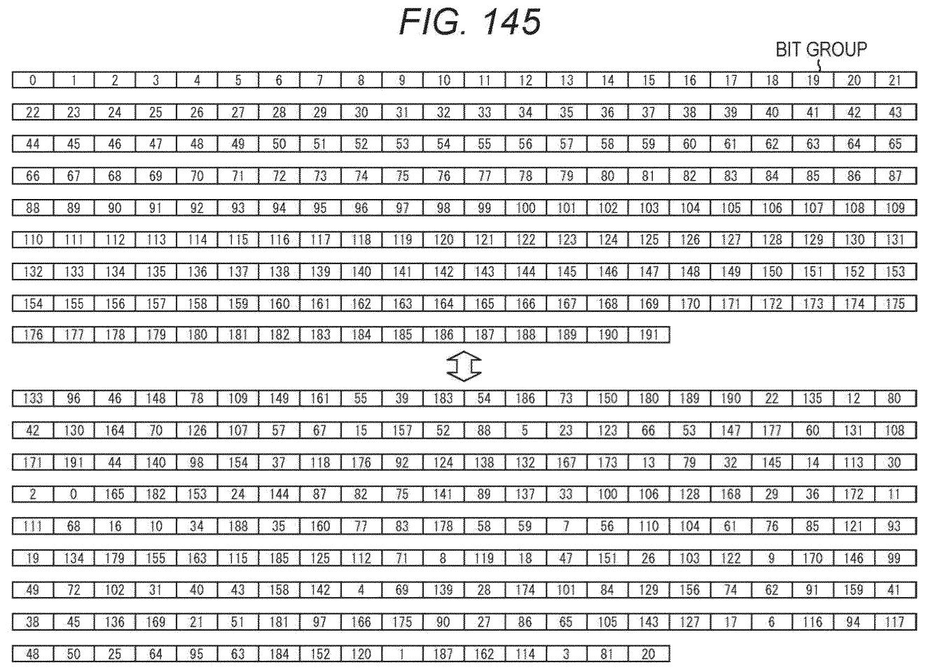

FIG. 145 is a diagram illustrating a twenty sixth example of the GW pattern for an LDPC code with a code length N of 69120 bits.

According to the GW pattern in FIG. 145, a sequence of bit groups 0 to 191 of the 69120 bit LDPC code is interleaved into a sequence of the following bit group.
133, 96, 46, 148, 78, 109, 149, 161, 55, 39, 183, 54, 186, 73, 150, 180, 189, 190, 22, 135, 12, 80, 42, 130, 164, 70, 126, 107, 57, 67, 15, 157, 52, 88, 5, 23, 123, 66, 53, 147, 177, 60, 131, 108, 171, 191, 44, 140, 98, 154, 37, 118, 176, 92, 124, 138, 132, 167, 173, 13, 79, 32, 145, 14, 113, 30, 2, 0, 165, 182, 153, 24, 144, 87, 82, 75, 141, 89, 137, 33, 100, 106, 128, 168, 29, 36, 172, 11, 111, 68, 16, 10, 34, 188, 35, 160, 77, 83, 178, 58, 59, 7, 56, 110, 104, 61, 76, 85, 121, 93, 19, 134, 179, 155, 163, 115, 185, 125, 112, 71, 8, 119, 18, 47, 151, 26, 103, 122, 9, 170, 146, 99, 49, 72, 102, 31, 40, 43, 158, 142, 4, 69, 139, 28, 174, 101, 84, 129, 156, 74, 62, 91, 159, 41, 38, 45, 136, 169, 21, 51, 181, 97, 166, 175, 90, 27, 86, 65, 105, 143, 127, 17, 6, 116, 94, 117, 48, 50, 25, 64, 95, 63, 184, 152, 120, 1, 187, 162, 114, 3, 81, 20

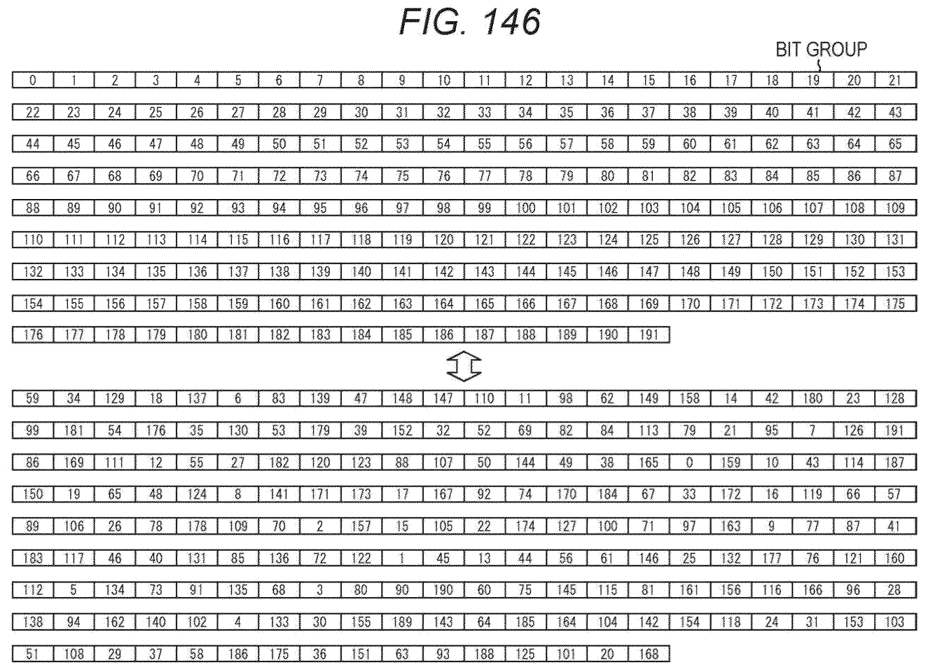

FIG. 146 is a diagram illustrating a twenty seventh example of the GW pattern for an LDPC code with a code length N of 69120 bits.

According to the GW pattern in FIG. 146, a sequence of bit groups 0 to 191 of the 69120 bit LDPC code is interleaved into a sequence of the following bit group.
59, 34, 129, 18, 137, 6, 83, 139, 47, 148, 147, 110, 11, 98, 62, 149, 158, 14, 42, 180, 23, 128, 99, 181, 54, 176, 35, 130, 53, 179, 39, 152, 32, 52, 69, 82, 84, 113, 79, 21, 95, 7, 126, 191, 86, 169, 111, 12, 55, 27, 182, 120, 123, 88, 107, 50, 144, 49, 38, 165, 0, 159, 10, 43, 114, 187, 150, 19, 65, 48, 124, 8, 141, 171, 173, 17, 167, 92, 74, 170, 184, 67, 33, 172, 16, 119, 66, 57, 89, 106, 26, 78, 178, 109, 70, 2, 157, 15, 105, 22, 174, 127, 100, 71, 97, 163, 9, 77, 87, 41, 183, 117, 46, 40, 131, 85, 136, 72, 122, 1, 45, 13, 44, 56, 61, 146, 25, 132, 177, 76, 121, 160, 112, 5, 134, 73, 91, 135, 68, 3, 80, 90, 190, 60, 75, 145, 115, 81, 161, 156, 116, 166, 96, 28, 138, 94, 162, 140, 102, 4, 133, 30, 155, 189, 143, 64, 185, 164, 104, 142, 154, 118, 24, 31, 153, 103, 51, 108, 29, 37, 58, 186, 175, 36, 151, 63, 93, 188, 125, 101, 20, 168

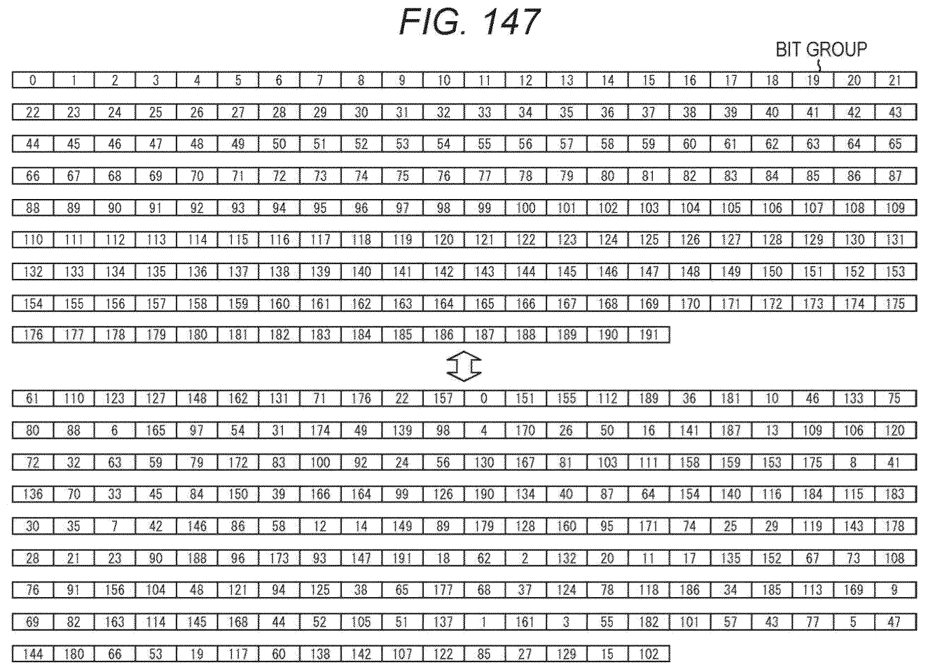

FIG. 147 is a diagram illustrating a twenty eighth example of the GW pattern for an LDPC code with a code length N of 69120 bits.

According to the GW pattern in FIG. 147, a sequence of bit groups 0 to 191 of the 69120 bit LDPC code is interleaved into a sequence of the following bit group.
61, 110, 123, 127, 148, 162, 131, 71, 176, 22, 157, 0, 151, 155, 112, 189, 36, 181, 10, 46, 133, 75, 80, 88, 6, 165, 97, 54, 31, 174, 49, 139, 98, 4, 170, 26, 50, 16, 141, 187, 13, 109, 106, 120, 72, 32, 63, 59, 79, 172, 83, 100, 92, 24, 56, 130, 167, 81, 103, 111, 158, 159, 153, 175, 8, 41, 136, 70, 33, 45, 84, 150, 39, 166, 164, 99, 126, 190, 134, 40, 87, 64, 154, 140, 116, 184, 115, 183, 30, 35, 7, 42, 146, 86, 58, 12, 14, 149, 89, 179, 128, 160, 95, 171, 74, 25, 29, 119, 143, 178, 28, 21, 23, 90, 188, 96, 173, 93, 147, 191, 18, 62, 2, 132, 20, 11, 17, 135, 152, 67, 73, 108, 76, 91, 156, 104, 48, 121, 94, 125, 38, 65, 177, 68, 37, 124, 78, 118, 186, 34, 185, 113, 169, 9, 69, 82, 163, 114, 145, 168, 44, 52, 105, 51, 137, 1, 161, 3, 55, 182, 101, 57, 43, 77, 5, 47, 144, 180, 66, 53, 19, 117, 60, 138, 142, 107, 122, 85, 27, 129, 15, 102

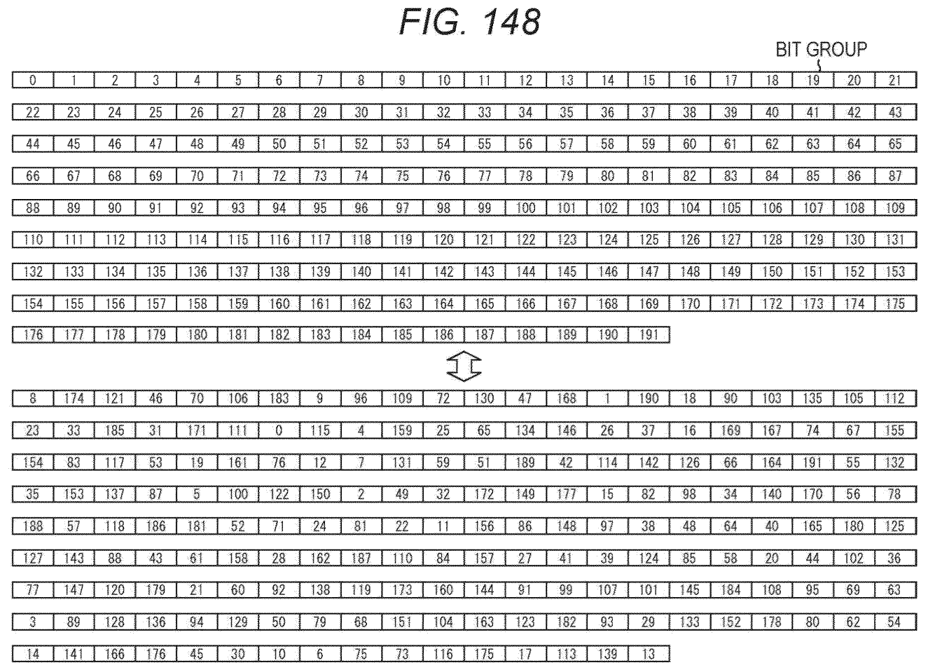

FIG. 148 is a diagram illustrating a twenty ninth example of the GW pattern for an LDPC code with a code length N of 69120 bits.

According to the GW pattern in FIG. 148, a sequence of bit groups 0 to 191 of the 69120 bit LDPC code is interleaved into a sequence of the following bit group.
8, 174, 121, 46, 70, 106, 183, 9, 96, 109, 72, 130, 47, 168, 1, 190, 18, 90, 103, 135, 105, 112, 23, 33, 185, 31, 171, 111, 0, 115, 4, 159, 25, 65, 134, 146, 26, 37, 16, 169, 167, 74, 67, 155, 154, 83, 117, 53, 19, 161, 76, 12, 7, 131, 59, 51, 189, 42, 114, 142, 126, 66, 164, 191, 55, 132, 35, 153, 137, 87, 5, 100, 122, 150, 2, 49, 32, 172, 149, 177, 15, 82, 98, 34, 140, 170, 56, 78, 188, 57, 118, 186, 181, 52, 71, 24, 81, 22, 11, 156, 86, 148, 97, 38, 48, 64, 40, 165, 180, 125, 127, 143, 88, 43, 61, 158, 28, 162, 187, 110, 84, 157, 27, 41, 39, 124, 85, 58, 20, 44, 102, 36, 77, 147, 120, 179, 21, 60, 92, 138, 119, 173, 160, 144, 91, 99, 107, 101, 145, 184, 108, 95, 69, 63, 3, 89, 128, 136, 94, 129, 50, 79, 68, 151, 104, 163, 123, 182, 93, 29, 133, 152, 178, 80, 62, 54, 14, 141, 166, 176, 45, 30, 10, 6, 75, 73, 116, 175, 17, 113, 139, 13

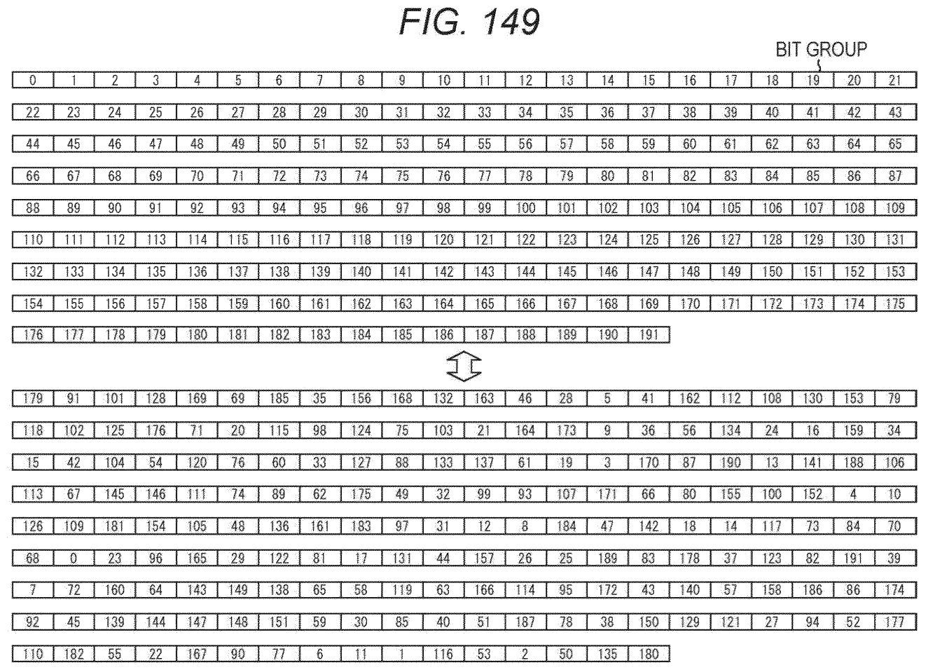

FIG. 149 is a diagram illustrating a thirtieth example of the GW pattern for an LDPC code with a code length N of 69120 bits.

According to the GW pattern in FIG. 149, a sequence of bit groups 0 to 191 of the 69120 bit LDPC code is interleaved into a sequence of the following bit group.
179, 91, 101, 128, 169, 69, 185, 35, 156, 168, 132, 163, 46, 28, 5, 41, 162, 112, 108, 130, 153, 79, 118, 102, 125, 176, 71, 20, 115, 98, 124, 75, 103, 21, 164, 173, 9, 36, 56, 134, 24, 16, 159, 34, 15, 42, 104, 54, 120, 76, 60, 33, 127, 88, 133, 137, 61, 19, 3, 170, 87, 190, 13, 141, 188, 106, 113, 67, 145, 146, 111, 74, 89, 62, 175, 49, 32, 99, 93, 107, 171, 66, 80, 155, 100, 152, 4, 10, 126, 109, 181, 154, 105, 48, 136, 161, 183, 97, 31, 12, 8, 184, 47, 142, 18, 14, 117, 73, 84, 70, 68, 0, 23, 96, 165, 29, 122, 81, 17, 131, 44, 157, 26, 25, 189, 83, 178, 37, 123, 82, 191, 39, 7, 72, 160, 64, 143, 149, 138, 65, 58, 119, 63, 166, 114, 95, 172, 43, 140, 57, 158, 186, 86, 174, 92, 45, 139, 144, 147, 148, 151, 59, 30, 85, 40, 51, 187, 78, 38, 150, 129, 121, 27, 94, 52, 177, 110, 182, 55, 22, 167, 90, 77, 6, 11, 1, 116, 53, 2, 50, 135, 180

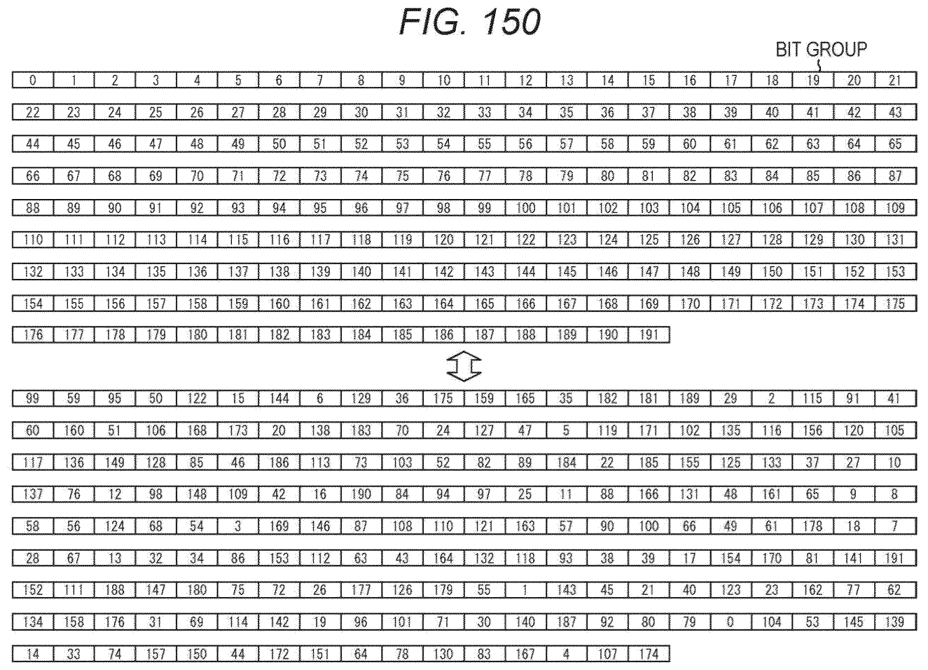

FIG. 150 is a diagram illustrating a thirty first example of the GW pattern for an LDPC code with a code length N of 69120 bits.

According to the GW pattern in FIG. 150, a sequence of bit groups 0 to 191 of the 69120 bit LDPC code is interleaved into a sequence of the following bit group.
99, 59, 95, 50, 122, 15, 144, 6, 129, 36, 175, 159, 165, 35, 182, 181, 189, 29, 2, 115, 91, 41, 60, 160, 51, 106, 168, 173, 20, 138, 183, 70, 24, 127, 47, 5, 119, 171, 102, 135, 116, 156, 120, 105, 117, 136, 149, 128, 85, 46, 186, 113, 73, 103, 52, 82, 89, 184, 22, 185, 155, 125, 133, 37, 27, 10, 137, 76, 12, 98, 148, 109, 42, 16, 190, 84, 94, 97, 25, 11, 88, 166, 131, 48, 161, 65, 9, 8, 58, 56, 124, 68, 54, 3, 169, 146, 87, 108, 110, 121, 163, 57, 90, 100, 66, 49, 61, 178, 18, 7, 28, 67, 13, 32, 34, 86, 153, 112, 63, 43, 164, 132, 118, 93, 38, 39, 17, 154, 170, 81, 141, 191, 152, 111, 188, 147, 180, 75, 72, 26, 177, 126, 179, 55, 1, 143, 45, 21, 40, 123, 23, 162, 77, 62, 134, 158, 176, 31, 69, 114, 142, 19, 96, 101, 71, 30, 140, 187, 92, 80, 79, 0, 104, 53, 145, 139, 14, 33, 74, 157, 150, 44, 172, 151, 64, 78, 130, 83, 167, 4, 107, 174

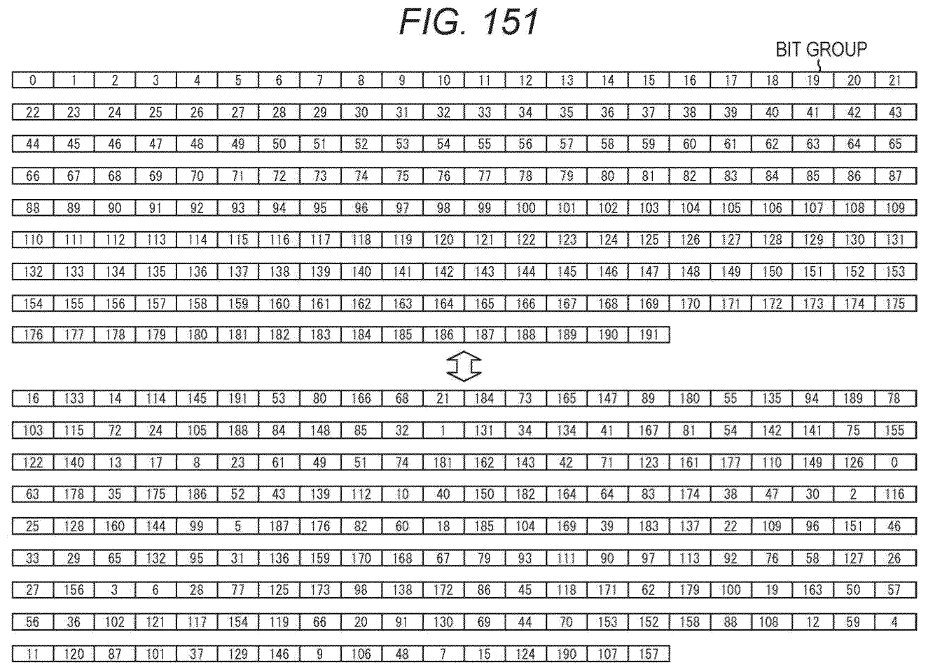

FIG. 151 is a diagram illustrating a thirty second example of the GW pattern for an LDPC code with a code length N of 69120 bits.

According to the GW pattern in FIG. 151, a sequence of bit groups 0 to 191 of the 69120 bit LDPC code is interleaved into a sequence of the following bit group.
16, 133, 14, 114, 145, 191, 53, 80, 166, 68, 21, 184, 73, 165, 147, 89, 180, 55, 135, 94, 189, 78, 103, 115, 72, 24, 105, 188, 84, 148, 85, 32, 1, 131, 34, 134, 41, 167, 81, 54, 142, 141, 75, 155, 122, 140, 13, 17, 8, 23, 61, 49, 51, 74, 181, 162, 143, 42, 71, 123, 161, 177, 110, 149, 126, 0, 63, 178, 35, 175, 186, 52, 43, 139, 112, 10, 40, 150, 182, 164, 64, 83, 174, 38, 47, 30, 2, 116, 25, 128, 160, 144, 99, 5, 187, 176, 82, 60, 18, 185, 104, 169, 39, 183, 137, 22, 109, 96, 151, 46, 33, 29, 65, 132, 95, 31, 136, 159, 170, 168, 67, 79, 93, 111, 90, 97, 113, 92, 76, 58, 127, 26, 27, 156, 3, 6, 28, 77, 125, 173, 98, 138, 172, 86, 45, 118, 171, 62, 179, 100, 19, 163, 50, 57, 56, 36, 102, 121, 117, 154, 119, 66, 20, 91, 130, 69, 44, 70, 153, 152, 158, 88, 108, 12, 59, 4, 11, 120, 87, 101, 37, 129, 146, 9, 106, 48, 7, 15, 124, 190, 107, 157

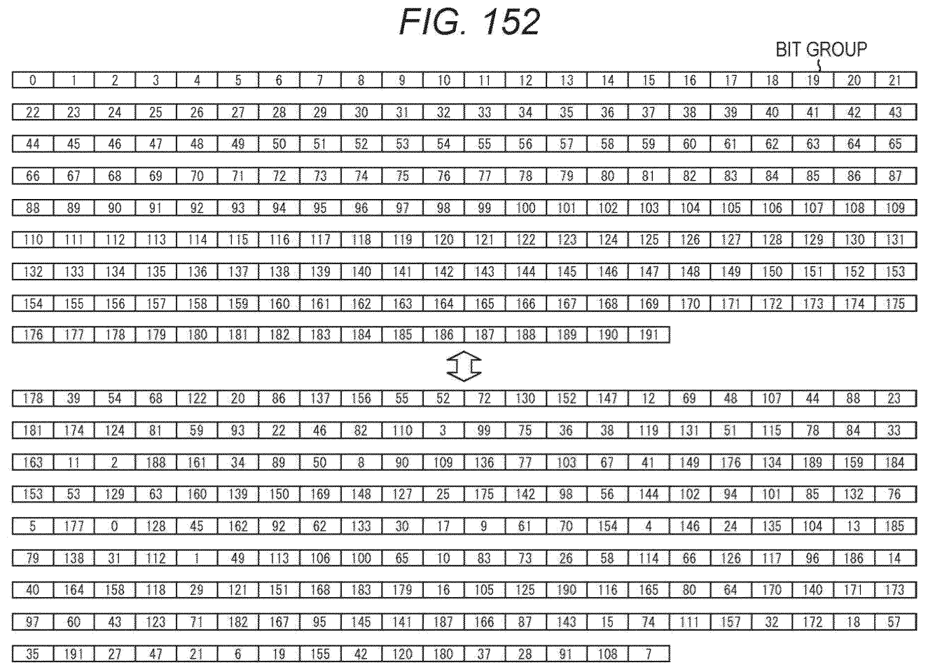

FIG. 152 is a diagram illustrating a thirty third example of the GW pattern for an LDPC code with a code length N of 69120 bits.

According to the GW pattern in FIG. 152, a sequence of bit groups 0 to 191 of the 69120 bit LDPC code is interleaved into a sequence of the following bit group.
178, 39, 54, 68, 122, 20, 86, 137, 156, 55, 52, 72, 130, 152, 147, 12, 69, 48, 107, 44, 88, 23, 181, 174, 124, 81, 59, 93, 22, 46, 82, 110, 3, 99, 75, 36, 38, 119, 131, 51, 115, 78, 84, 33, 163, 11, 2, 188, 161, 34, 89, 50, 8, 90, 109, 136, 77, 103, 67, 41, 149, 176, 134, 189, 159, 184, 153, 53, 129, 63, 160, 139, 150, 169, 148, 127, 25, 175, 142, 98, 56, 144, 102, 94, 101, 85, 132, 76, 5, 177, 0, 128, 45, 162, 92, 62, 133, 30, 17, 9, 61, 70, 154, 4, 146, 24, 135, 104, 13, 185, 79, 138, 31, 112, 1, 49, 113, 106, 100, 65, 10, 83, 73, 26, 58, 114, 66, 126, 117, 96, 186, 14, 40, 164, 158, 118, 29, 121, 151, 168, 183, 179, 16, 105, 125, 190, 116, 165, 80, 64, 170, 140, 171, 173, 97, 60, 43, 123, 71, 182, 167, 95, 145, 141, 187, 166, 87, 143, 15, 74, 111, 157, 32, 172, 18, 57, 35, 191, 27, 47, 21, 6, 19, 155, 42, 120, 180, 37, 28, 91, 108, 7

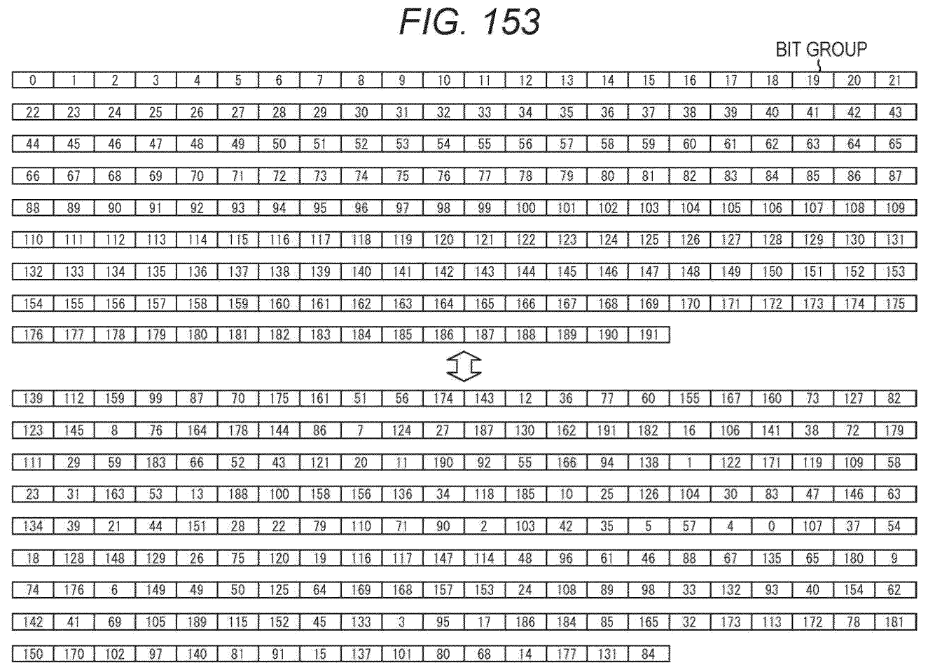

FIG. 153 is a diagram illustrating a thirty fourth example of the GW pattern for an LDPC code with a code length N of 69120 bits.

According to the GW pattern in FIG. 153, a sequence of bit groups 0 to 191 of the 69120 bit LDPC code is interleaved into a sequence of the following bit group.
139, 112, 159, 99, 87, 70, 175, 161, 51, 56, 174, 143, 12, 36, 77, 60, 155, 167, 160, 73, 127, 82, 123, 145, 8, 76, 164, 178, 144, 86, 7, 124, 27, 187, 130, 162, 191, 182, 16, 106, 141, 38, 72, 179, 111, 29, 59, 183, 66, 52, 43, 121, 20, 11, 190, 92, 55, 166, 94, 138, 1, 122, 171, 119, 109, 58, 23, 31, 163, 53, 13, 188, 100, 158, 156, 136, 34, 118, 185, 10, 25, 126, 104, 30, 83, 47, 146, 63, 134, 39, 21, 44, 151, 28, 22, 79, 110, 71, 90, 2, 103, 42, 35, 5, 57, 4, 0, 107, 37, 54, 18, 128, 148, 129, 26, 75, 120, 19, 116, 117, 147, 114, 48, 96, 61, 46, 88, 67, 135, 65, 180, 9, 74, 176, 6, 149, 49, 50, 125, 64, 169, 168, 157, 153, 24, 108, 89, 98, 33, 132, 93, 40, 154, 62, 142, 41, 69, 105, 189, 115, 152, 45, 133, 3, 95, 17, 186, 184, 85, 165, 32, 173, 113, 172, 78, 181, 150, 170, 102, 97, 140, 81, 91, 15, 137, 101, 80, 68, 14, 177, 131, 84

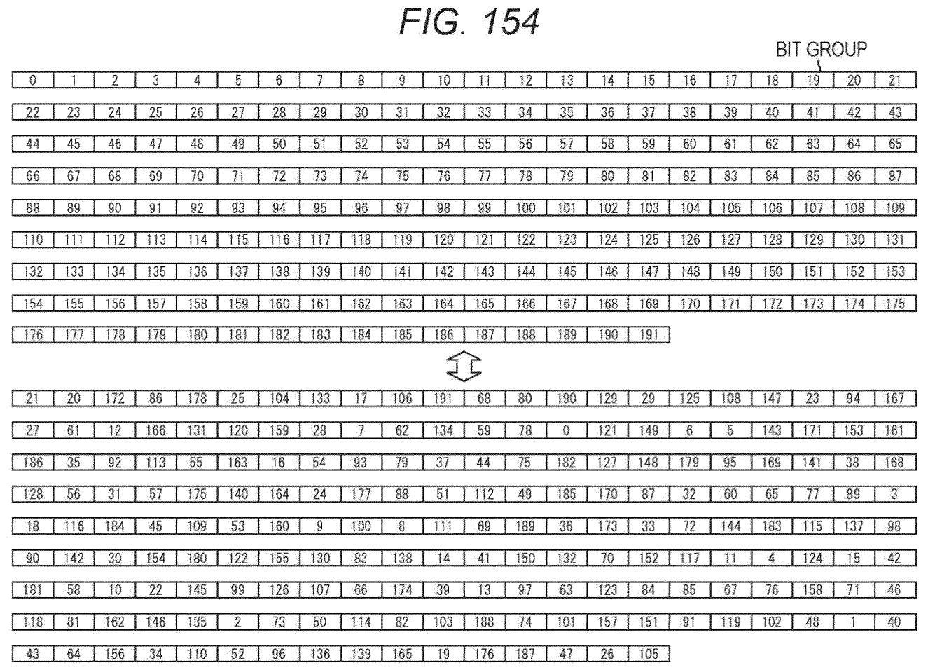

FIG. 154 is a diagram illustrating a thirty fifth example of the GW pattern for an LDPC code with a code length N of 69120 bits.

According to the GW pattern in FIG. 154, a sequence of bit groups 0 to 191 of the 69120 bit LDPC code is interleaved into a sequence of the following bit group.
21, 20, 172, 86, 178, 25, 104, 133, 17, 106, 191, 68, 80, 190, 129, 29, 125, 108, 147, 23, 94, 167, 27, 61, 12, 166, 131, 120, 159, 28, 7, 62, 134, 59, 78, 0, 121, 149, 6, 5, 143, 171, 153, 161, 186, 35, 92, 113, 55, 163, 16, 54, 93, 79, 37, 44, 75, 182, 127, 148, 179, 95, 169, 141, 38, 168, 128, 56, 31, 57, 175, 140, 164, 24, 177, 88, 51, 112, 49, 185, 170, 87, 32, 60, 65, 77, 89, 3, 18, 116, 184, 45, 109, 53, 160, 9, 100, 8, 111, 69, 189, 36, 173, 33, 72, 144, 183, 115, 137, 98, 90, 142, 30, 154, 180, 122, 155, 130, 83, 138, 14, 41, 150, 132, 70, 152, 117, 11, 4, 124, 15, 42, 181, 58, 10, 22, 145, 99, 126, 107, 66, 174, 39, 13, 97, 63, 123, 84, 85, 67, 76, 158, 71, 46, 118, 81, 162, 146, 135, 2, 73, 50, 114, 82, 103, 188, 74, 101, 157, 151, 91, 119, 102, 48, 1, 40, 43, 64, 156, 34, 110, 52, 96, 136, 139, 165, 19, 176, 187, 47, 26, 105

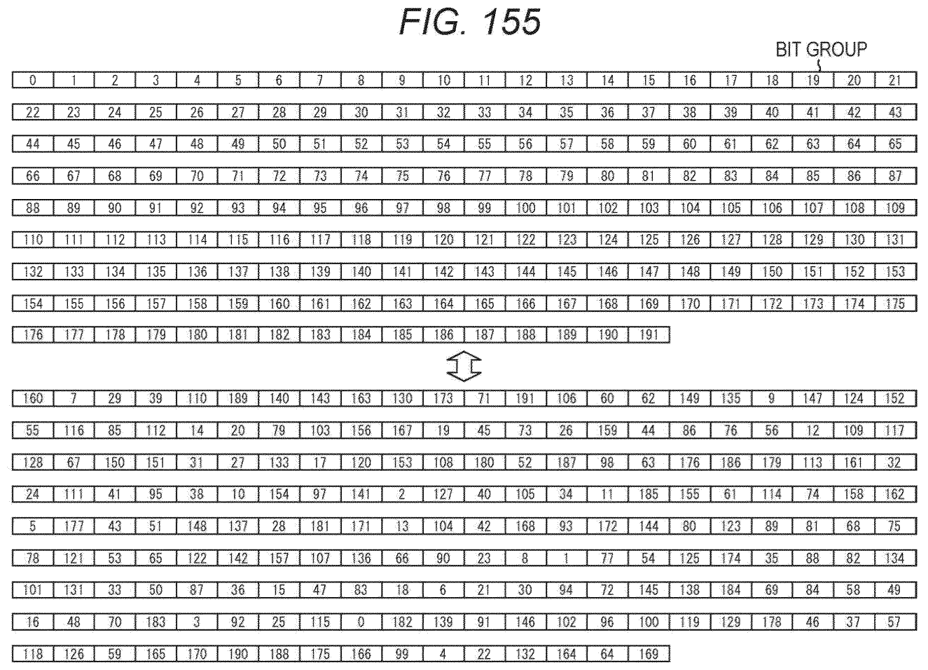

FIG. 155 is a diagram illustrating a thirty sixth example of the GW pattern for an LDPC code with a code length N of 69120 bits.

According to the GW pattern in FIG. 155, a sequence of bit groups 0 to 191 of the 69120 bit LDPC code is interleaved into a sequence of the following bit group.
160, 7, 29, 39, 110, 189, 140, 143, 163, 130, 173, 71, 191, 106, 60, 62, 149, 135, 9, 147, 124, 152, 55, 116, 85, 112, 14, 20, 79, 103, 156, 167, 19, 45, 73, 26, 159, 44, 86, 76, 56, 12, 109, 117, 128, 67, 150, 151, 31, 27, 133, 17, 120, 153, 108, 180, 52, 187, 98, 63, 176, 186, 179, 113, 161, 32, 24, 111, 41, 95, 38, 10, 154, 97, 141, 2, 127, 40, 105, 34, 11, 185, 155, 61, 114, 74, 158, 162, 5, 177, 43, 51, 148, 137, 28, 181, 171, 13, 104, 42, 168, 93, 172, 144, 80, 123, 89, 81, 68, 75, 78, 121, 53, 65, 122, 142, 157, 107, 136, 66, 90, 23, 8, 1, 77, 54, 125, 174, 35, 88, 82, 134, 101, 131, 33, 50, 87, 36, 15, 47, 83, 18, 6, 21, 30, 94, 72, 145, 138, 184, 69, 84, 58, 49, 16, 48, 70, 183, 3, 92, 25, 115, 0, 182, 139, 91, 146, 102, 96, 100, 119, 129, 178, 46, 37, 57, 118, 126, 59, 165, 170, 190, 188, 175, 166, 99, 4, 22, 132, 164, 64, 169

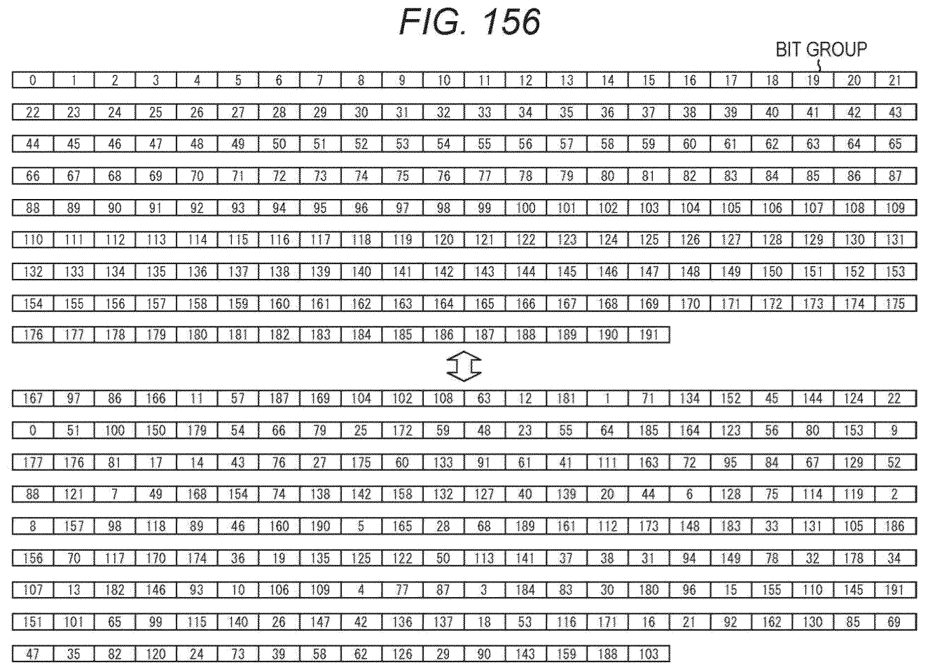

FIG. 156 is a diagram illustrating a thirty seventh example of the GW pattern for an LDPC code with a code length N of 69120 bits.

According to the GW pattern in FIG. 156, a sequence of bit groups 0 to 191 of the 69120 bit LDPC code is interleaved into a sequence of the following bit group.
167, 97, 86, 166, 11, 57, 187, 169, 104, 102, 108, 63, 12, 181, 1, 71, 134, 152, 45, 144, 124, 22, 0, 51, 100, 150, 179, 54, 66, 79, 25, 172, 59, 48, 23, 55, 64, 185, 164, 123, 56, 80, 153, 9, 177, 176, 81, 17, 14, 43, 76, 27, 175, 60, 133, 91, 61, 41, 111, 163, 72, 95, 84, 67, 129, 52, 88, 121, 7, 49, 168, 154, 74, 138, 142, 158, 132, 127, 40, 139, 20, 44, 6, 128, 75, 114, 119, 2, 8, 157, 98, 118, 89, 46, 160, 190, 5, 165, 28, 68, 189, 161, 112, 173, 148, 183, 33, 131, 105, 186, 156, 70, 117, 170, 174, 36, 19, 135, 125, 122, 50, 113, 141, 37, 38, 31, 94, 149, 78, 32, 178, 34, 107, 13, 182, 146, 93, 10, 106, 109, 4, 77, 87, 3, 184, 83, 30, 180, 96, 15, 155, 110, 145, 191, 151, 101, 65, 99, 115, 140, 26, 147, 42, 136, 137, 18, 53, 116, 171, 16, 21, 92, 162, 130, 85, 69, 47, 35, 82, 120, 24, 73, 39, 58, 62, 126, 29, 90, 143, 159, 188, 103

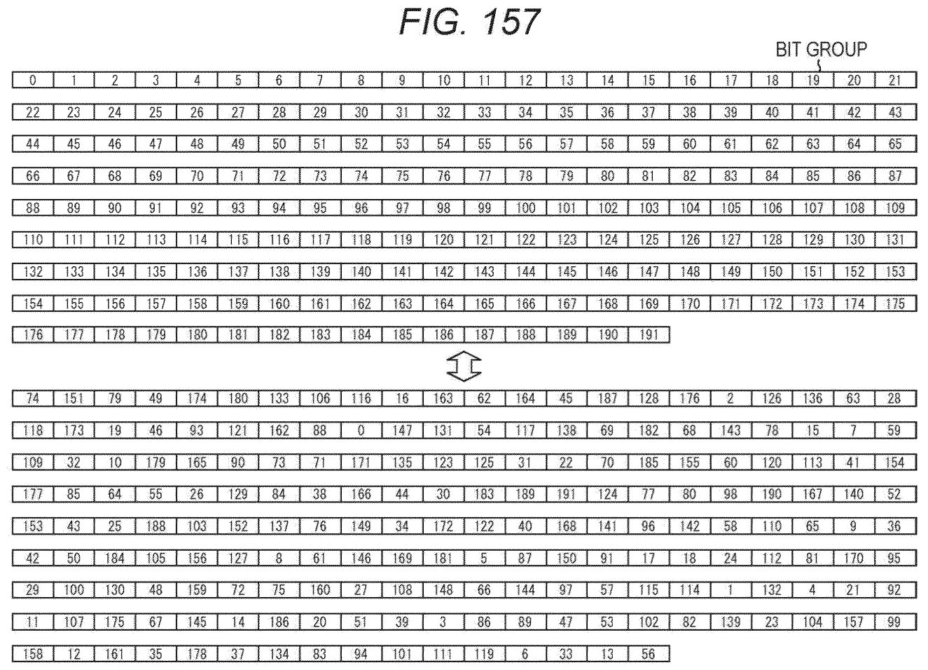

FIG. 157 is a diagram illustrating a thirty eighth example of the GW pattern for an LDPC code with a code length N of 69120 bits.

According to the GW pattern in FIG. 157, a sequence of bit groups 0 to 191 of the 69120 bit LDPC code is interleaved into a sequence of the following bit group.
74, 151, 79, 49, 174, 180, 133, 106, 116, 16, 163, 62, 164, 45, 187, 128, 176, 2, 126, 136, 63, 28, 118, 173, 19, 46, 93, 121, 162, 88, 0, 147, 131, 54, 117, 138, 69, 182, 68, 143, 78, 15, 7, 59, 109, 32, 10, 179, 165, 90, 73, 71, 171, 135, 123, 125, 31, 22, 70, 185, 155, 60, 120, 113, 41, 154, 177, 85, 64, 55, 26, 129, 84, 38, 166, 44, 30, 183, 189, 191, 124, 77, 80, 98, 190, 167, 140, 52, 153, 43, 25, 188, 103, 152, 137, 76, 149, 34, 172, 122, 40, 168, 141, 96, 142, 58, 110, 65, 9, 36, 42, 50, 184, 105, 156, 127, 8, 61, 146, 169, 181, 5, 87, 150, 91, 17, 18, 24, 112, 81, 170, 95, 29, 100, 130, 48, 159, 72, 75, 160, 27, 108, 148, 66, 144, 97, 57, 115, 114, 1, 132, 4, 21, 92, 11, 107, 175, 67, 145, 14, 186, 20, 51, 39, 3, 86, 89, 47, 53, 102, 82, 139, 23, 104, 157, 99, 158, 12, 161, 35, 178, 37, 134, 83, 94, 101, 111, 119, 6, 33, 13, 56

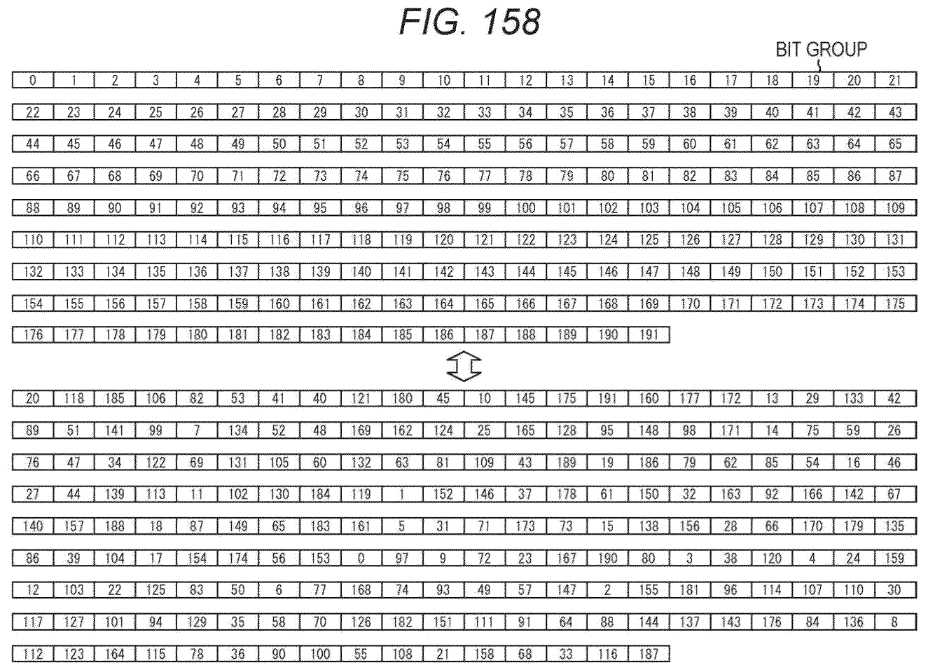

FIG. 158 is a diagram illustrating a thirty ninth example of the GW pattern for an LDPC code with a code length N of 69120 bits.

According to the GW pattern in FIG. 158, a sequence of bit groups 0 to 191 of the 69120 bit LDPC code is interleaved into a sequence of the following bit group.
20, 118, 185, 106, 82, 53, 41, 40, 121, 180, 45, 10, 145, 175, 191, 160, 177, 172, 13, 29, 133, 42, 89, 51, 141, 99, 7, 134, 52, 48, 169, 162, 124, 25, 165, 128, 95, 148, 98, 171, 14, 75, 59, 26, 76, 47, 34, 122, 69, 131, 105, 60, 132, 63, 81, 109, 43, 189, 19, 186, 79, 62, 85, 54, 16, 46, 27, 44, 139, 113, 11, 102, 130, 184, 119, 1, 152, 146, 37, 178, 61, 150, 32, 163, 92, 166, 142, 67, 140, 157, 188, 18, 87, 149, 65, 183, 161, 5, 31, 71, 173, 73, 15, 138, 156, 28, 66, 170, 179, 135, 86, 39, 104, 17, 154, 174, 56, 153, 0, 97, 9, 72, 23, 167, 190, 80, 3, 38, 120, 4, 24, 159, 12, 103, 22, 125, 83, 50, 6, 77, 168, 74, 93, 49, 57, 147, 2, 155, 181, 96, 114, 107, 110, 30, 117, 127, 101, 94, 129, 35, 58, 70, 126, 182, 151, 111, 91, 64, 88, 144, 137, 143, 176, 84, 136, 8, 112, 123, 164, 115, 78, 36, 90, 100, 55, 108, 21, 158, 68, 33, 116, 187

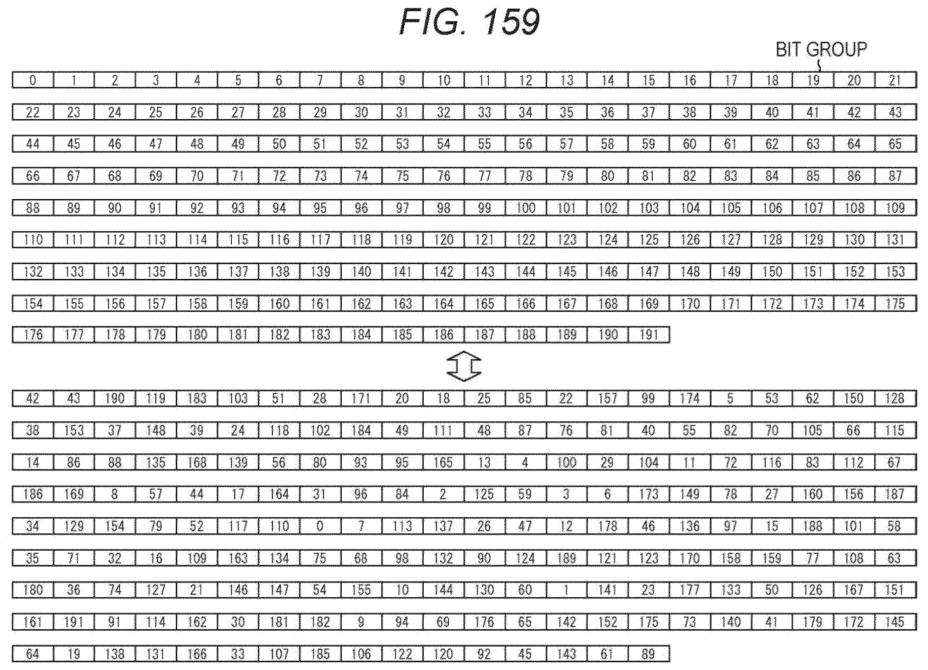

FIG. 159 is a diagram illustrating a fortieth example of the GW pattern for an LDPC code with a code length N of 69120 bits.

According to the GW pattern in FIG. 159, a sequence of bit groups 0 to 191 of the 69120 bit LDPC code is interleaved into a sequence of the following bit group.
42, 43, 190, 119, 183, 103, 51, 28, 171, 20, 18, 25, 85, 22, 157, 99, 174, 5, 53, 62, 150, 128, 38, 153, 37, 148, 39, 24, 118, 102, 184, 49, 111, 48, 87, 76, 81, 40, 55, 82, 70, 105, 66, 115, 14, 86, 88, 135, 168, 139, 56, 80, 93, 95, 165, 13, 4, 100, 29, 104, 11, 72, 116, 83, 112, 67, 186, 169, 8, 57, 44, 17, 164, 31, 96, 84, 2, 125, 59, 3, 6, 173, 149, 78, 27, 160, 156, 187, 34, 129, 154, 79, 52, 117, 110, 0, 7, 113, 137, 26, 47, 12, 178, 46, 136, 97, 15, 188, 101, 58, 35, 71, 32, 16, 109, 163, 134, 75, 68, 98, 132, 90, 124, 189, 121, 123, 170, 158, 159, 77, 108, 63, 180, 36, 74, 127, 21, 146, 147, 54, 155, 10, 144, 130, 60, 1, 141, 23, 177, 133, 50, 126, 167, 151, 161, 191, 91, 114, 162, 30, 181, 182, 9, 94, 69, 176, 65, 142, 152, 175, 73, 140, 41, 179, 172, 145, 64, 19, 138, 131, 166, 33, 107, 185, 106, 122, 120, 92, 45, 143, 61, 89

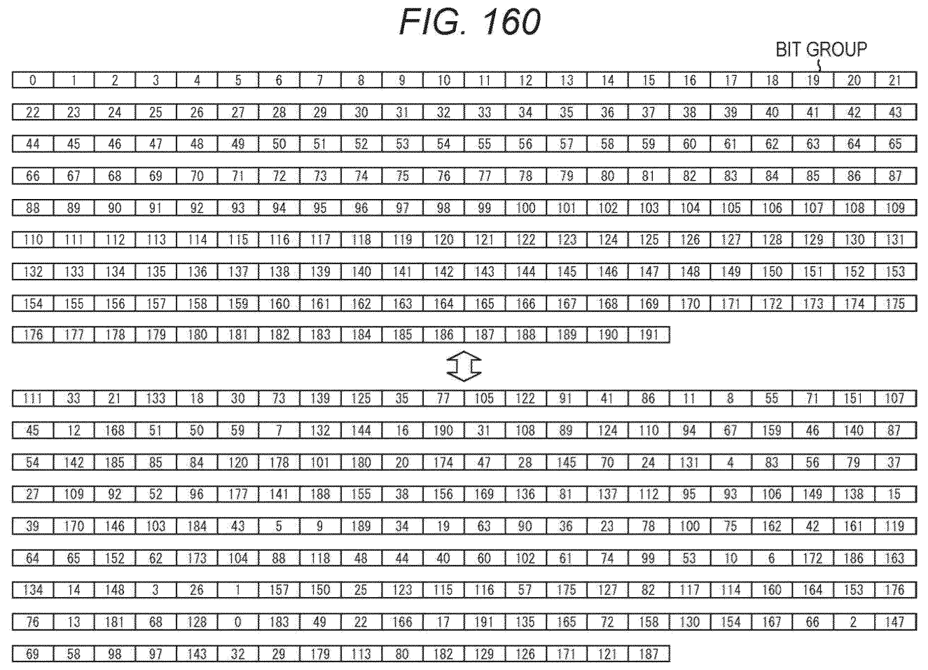

FIG. 160 is a diagram illustrating a forty first example of the GW pattern for an LDPC code with a code length N of 69120 bits.

According to the GW pattern in FIG. 160, a sequence of bit groups 0 to 191 of the 69120 bit LDPC code is interleaved into a sequence of the following bit group.
111, 33, 21, 133, 18, 30, 73, 139, 125, 35, 77, 105, 122, 91, 41, 86, 11, 8, 55, 71, 151, 107, 45, 12, 168, 51, 50, 59, 7, 132, 144, 16, 190, 31, 108, 89, 124, 110, 94, 67, 159, 46, 140, 87, 54, 142, 185, 85, 84, 120, 178, 101, 180, 20, 174, 47, 28, 145, 70, 24, 131, 4, 83, 56, 79, 37, 27, 109, 92, 52, 96, 177, 141, 188, 155, 38, 156, 169, 136, 81, 137, 112, 95, 93, 106, 149, 138, 15, 39, 170, 146, 103, 184, 43, 5, 9, 189, 34, 19, 63, 90, 36, 23, 78, 100, 75, 162, 42, 161, 119, 64, 65, 152, 62, 173, 104, 88, 118, 48, 44, 40, 60, 102, 61, 74, 99, 53, 10, 6, 172, 186, 163, 134, 14, 148, 3, 26, 1, 157, 150, 25, 123, 115, 116, 57, 175, 127, 82, 117, 114, 160, 164, 153, 176, 76, 13, 181, 68, 128, 0, 183, 49, 22, 166, 17, 191, 135, 165, 72, 158, 130, 154, 167, 66, 2, 147, 69, 58, 98, 97, 143, 32, 29, 179, 113, 80, 182, 129, 126, 171, 121, 187

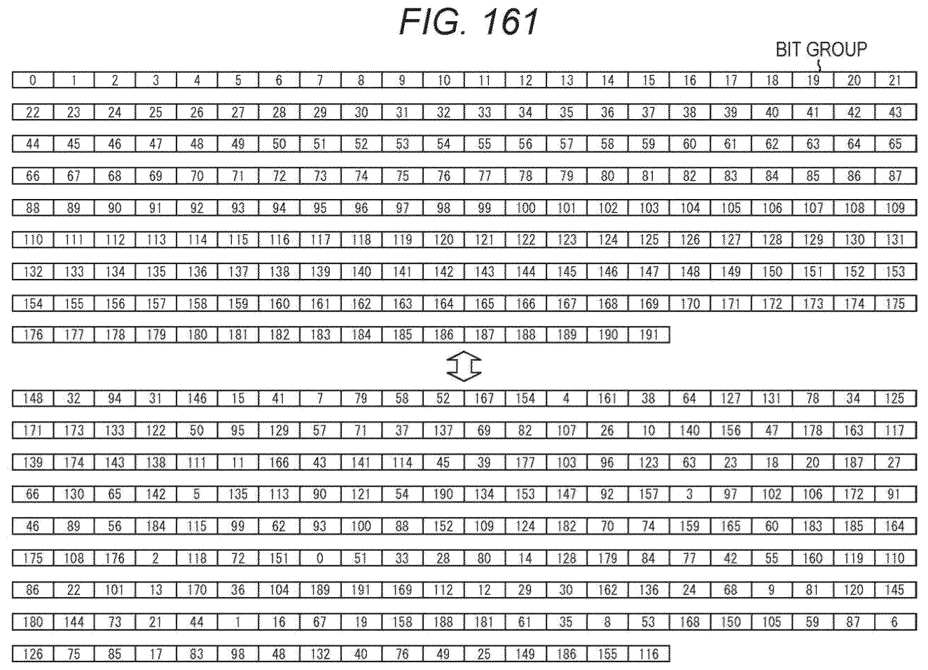

FIG. 161 is a diagram illustrating a forty second example of the GW pattern for an LDPC code with a code length N of 69120 bits.

According to the GW pattern in FIG. 161, a sequence of bit groups 0 to 191 of the 69120 bit LDPC code is interleaved into a sequence of the following bit group.
148, 32, 94, 31, 146, 15, 41, 7, 79, 58, 52, 167, 154, 4, 161, 38, 64, 127, 131, 78, 34, 125, 171, 173, 133, 122, 50, 95, 129, 57, 71, 37, 137, 69, 82, 107, 26, 10, 140, 156, 47, 178, 163, 117, 139, 174, 143, 138, 111, 11, 166, 43, 141, 114, 45, 39, 177, 103, 96, 123, 63, 23, 18, 20, 187, 27, 66, 130, 65, 142, 5, 135, 113, 90, 121, 54, 190, 134, 153, 147, 92, 157, 3, 97, 102, 106, 172, 91, 46, 89, 56, 184, 115, 99, 62, 93, 100, 88, 152, 109, 124, 182, 70, 74, 159, 165, 60, 183, 185, 164, 175, 108, 176, 2, 118, 72, 151, 0, 51, 33, 28, 80, 14, 128, 179, 84, 77, 42, 55, 160, 119, 110, 86, 22, 101, 13, 170, 36, 104, 189, 191, 169, 112, 12, 29, 30, 162, 136, 24, 68, 9, 81, 120, 145, 180, 144, 73, 21, 44, 1, 16, 67, 19, 158, 188, 181, 61, 35, 8, 53, 168, 150, 105, 59, 87, 6, 126, 75, 85, 17, 83, 98, 48, 132, 40, 76, 49, 25, 149, 186, 155, 116

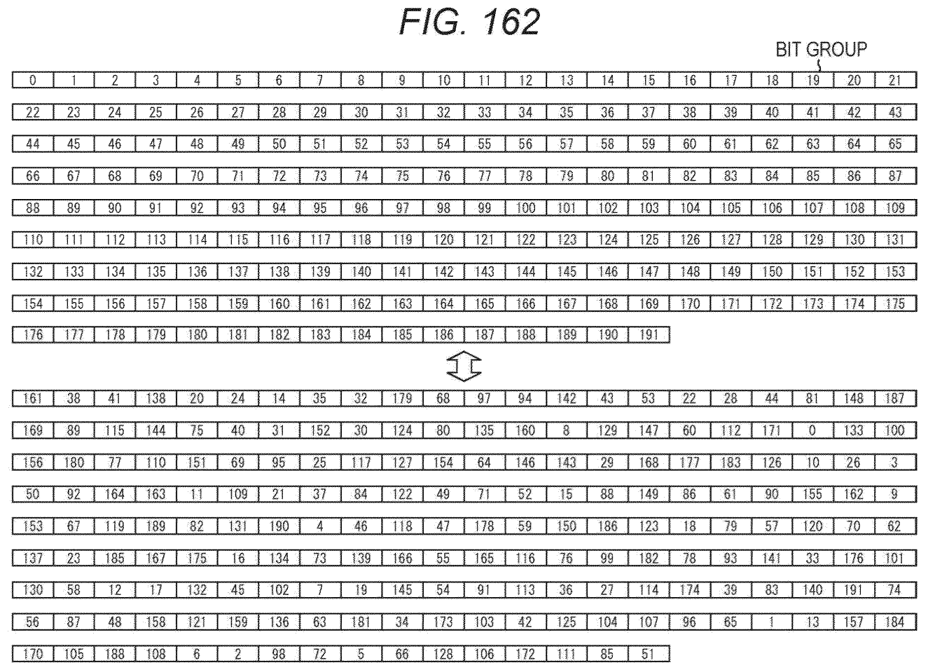

FIG. 162 is a diagram illustrating a forty third example of the GW pattern for an LDPC code with a code length N of 69120 bits.

According to the GW pattern in FIG. 162, a sequence of bit groups 0 to 191 of the 69120 bit LDPC code is interleaved into a sequence of the following bit group.
161, 38, 41, 138, 20, 24, 14, 35, 32, 179, 68, 97, 94, 142, 43, 53, 22, 28, 44, 81, 148, 187, 169, 89, 115, 144, 75, 40, 31, 152, 30, 124, 80, 135, 160, 8, 129, 147, 60, 112, 171, 0, 133, 100, 156, 180, 77, 110, 151, 69, 95, 25, 117, 127, 154, 64, 146, 143, 29, 168, 177, 183, 126, 10, 26, 3, 50, 92, 164, 163, 11, 109, 21, 37, 84, 122, 49, 71, 52, 15, 88, 149, 86, 61, 90, 155, 162, 9, 153, 67, 119, 189, 82, 131, 190, 4, 46, 118, 47, 178, 59, 150, 186, 123, 18, 79, 57, 120, 70, 62, 137, 23, 185, 167, 175, 16, 134, 73, 139, 166, 55, 165, 116, 76, 99, 182, 78, 93, 141, 33, 176, 101, 130, 58, 12, 17, 132, 45, 102, 7, 19, 145, 54, 91, 113, 36, 27, 114, 174, 39, 83, 140, 191, 74, 56, 87, 48, 158, 121, 159, 136, 63, 181, 34, 173, 103, 42, 125, 104, 107, 96, 65, 1, 13, 157, 184, 170, 105, 188, 108, 6, 2, 98, 72, 5, 66, 128, 106, 172, 111, 85, 51

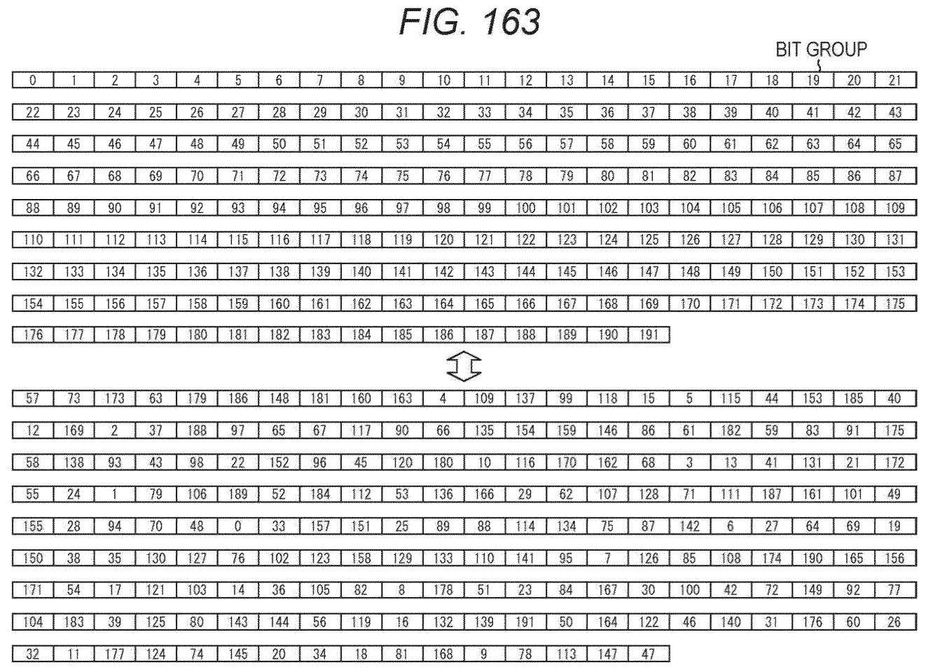

FIG. 163 is a diagram illustrating a forty fourth example of the GW pattern for an LDPC code with a code length N of 69120 bits.

According to the GW pattern in FIG. 163, a sequence of bit groups 0 to 191 of the 69120 bit LDPC code is interleaved into a sequence of the following bit group.
57, 73, 173, 63, 179, 186, 148, 181, 160, 163, 4, 109, 137, 99, 118, 15, 5, 115, 44, 153, 185, 40, 12, 169, 2, 37, 188, 97, 65, 67, 117, 90, 66, 135, 154, 159, 146, 86, 61, 182, 59, 83, 91, 175, 58, 138, 93, 43, 98, 22, 152, 96, 45, 120, 180, 10, 116, 170, 162, 68, 3, 13, 41, 131, 21, 172, 55, 24, 1, 79, 106, 189, 52, 184, 112, 53, 136, 166, 29, 62, 107, 128, 71, 111, 187, 161, 101, 49, 155, 28, 94, 70, 48, 0, 33, 157, 151, 25, 89, 88, 114, 134, 75, 87, 142, 6, 27, 64, 69, 19, 150, 38, 35, 130, 127, 76, 102, 123, 158, 129, 133, 110, 141, 95, 7, 126, 85, 108, 174, 190, 165, 156, 171, 54, 17, 121, 103, 14, 36, 105, 82, 8, 178, 51, 23, 84, 167, 30, 100, 42, 72, 149, 92, 77, 104, 183, 39, 125, 80, 143, 144, 56, 119, 16, 132, 139, 191, 50, 164, 122, 46, 140, 31, 176, 60, 26, 32, 11, 177, 124, 74, 145, 20, 34, 18, 81, 168, 9, 78, 113, 147, 47

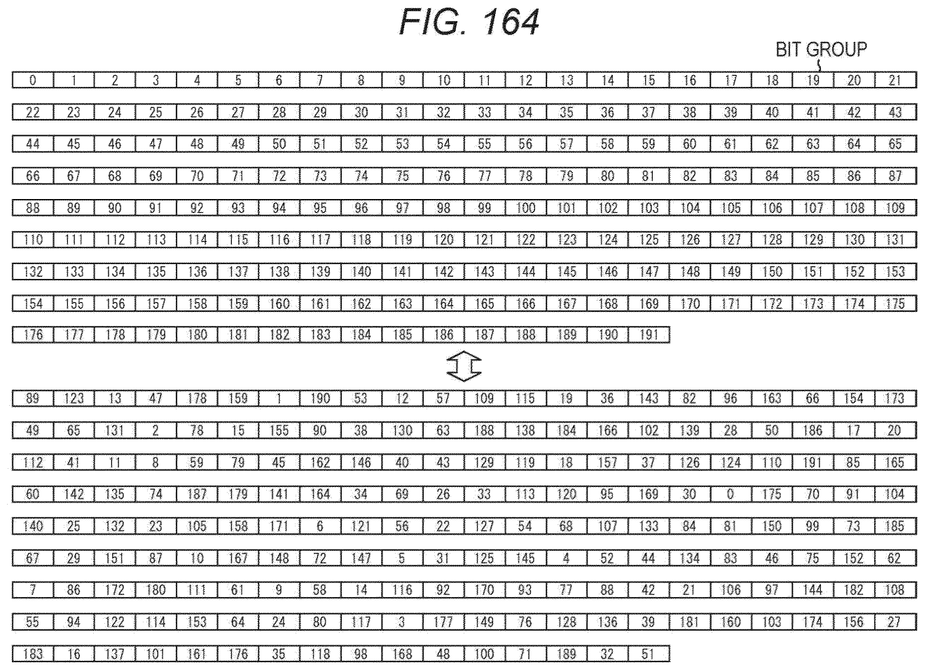

FIG. 164 is a diagram illustrating a forty fifth example of the GW pattern for an LDPC code with a code length N of 69120 bits.

According to the GW pattern in FIG. 164, a sequence of bit groups 0 to 191 of the 69120 bit LDPC code is interleaved into a sequence of the following bit group.
89, 123, 13, 47, 178, 159, 1, 190, 53, 12, 57, 109, 115, 19, 36, 143, 82, 96, 163, 66, 154, 173, 49, 65, 131, 2, 78, 15, 155, 90, 38, 130, 63, 188, 138, 184, 166, 102, 139, 28, 50, 186, 17, 20, 112, 41, 11, 8, 59, 79, 45, 162, 146, 40, 43, 129, 119, 18, 157, 37, 126, 124, 110, 191, 85, 165, 60, 142, 135, 74, 187, 179, 141, 164, 34, 69, 26, 33, 113, 120, 95, 169, 30, 0, 175, 70, 91, 104, 140, 25, 132, 23, 105, 158, 171, 6, 121, 56, 22, 127, 54, 68, 107, 133, 84, 81, 150, 99, 73, 185, 67, 29, 151, 87, 10, 167, 148, 72, 147, 5, 31, 125, 145, 4, 52, 44, 134, 83, 46, 75, 152, 62, 7, 86, 172, 180, 111, 61, 9, 58, 14, 116, 92, 170, 93, 77, 88, 42, 21, 106, 97, 144, 182, 108, 55, 94, 122, 114, 153, 64, 24, 80, 117, 3, 177, 149, 76, 128, 136, 39, 181, 160, 103, 174, 156, 27, 183, 16, 137, 101, 161, 176, 35, 118, 98, 168, 48, 100, 71, 189, 32, 51

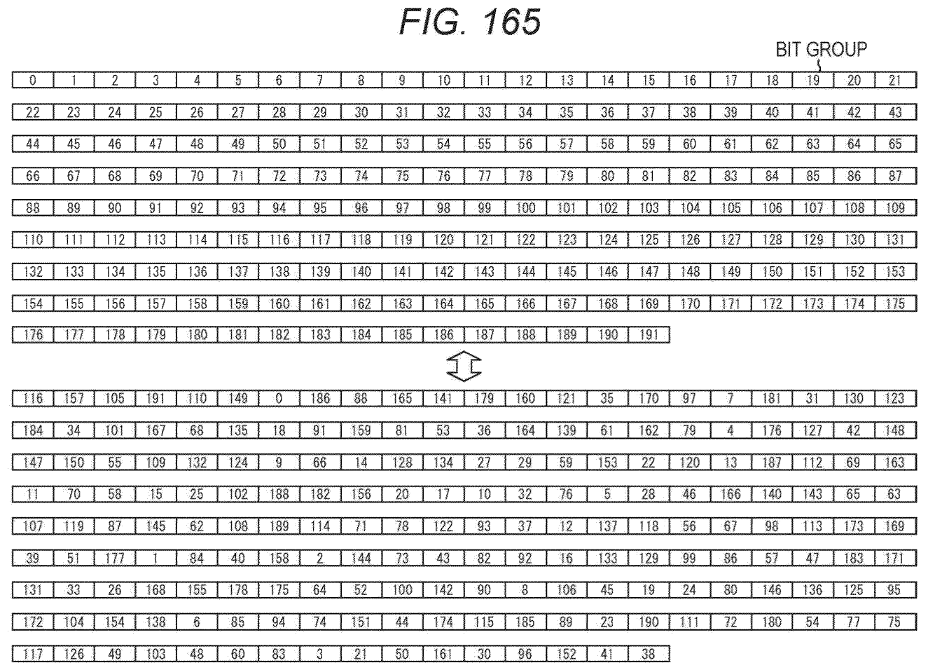

FIG. 165 is a diagram illustrating a forty sixth example of the GW pattern for an LDPC code with a code length N of 69120 bits.

According to the GW pattern in FIG. 165, a sequence of bit groups 0 to 191 of the 69120 bit LDPC code is interleaved into a sequence of the following bit group.
116, 157, 105, 191, 110, 149, 0, 186, 88, 165, 141, 179, 160, 121, 35, 170, 97, 7, 181, 31, 130, 123, 184, 34, 101, 167, 68, 135, 18, 91, 159, 81, 53, 36, 164, 139, 61, 162, 79, 4, 176, 127, 42, 148, 147, 150, 55, 109, 132, 124, 9, 66, 14, 128, 134, 27, 29, 59, 153, 22, 120, 13, 187, 112, 69, 163, 11, 70, 58, 15, 25, 102, 188, 182, 156, 20, 17, 10, 32, 76, 5, 28, 46, 166, 140, 143, 65, 63, 107, 119, 87, 145, 62, 108, 189, 114, 71, 78, 122, 93, 37, 12, 137, 118, 56, 67, 98, 113, 173, 169, 39, 51, 177, 1, 84, 40, 158, 2, 144, 73, 43, 82, 92, 16, 133, 129, 99, 86, 57, 47, 183, 171, 131, 33, 26, 168, 155, 178, 175, 64, 52, 100, 142, 90, 8, 106, 45, 19, 24, 80, 146, 136, 125, 95, 172, 104, 154, 138, 6, 85, 94, 74, 151, 44, 174, 115, 185, 89, 23, 190, 111, 72, 180, 54, 77, 75, 117, 126, 49, 103, 48, 60, 83, 3, 21, 50, 161, 30, 96, 152, 41, 38

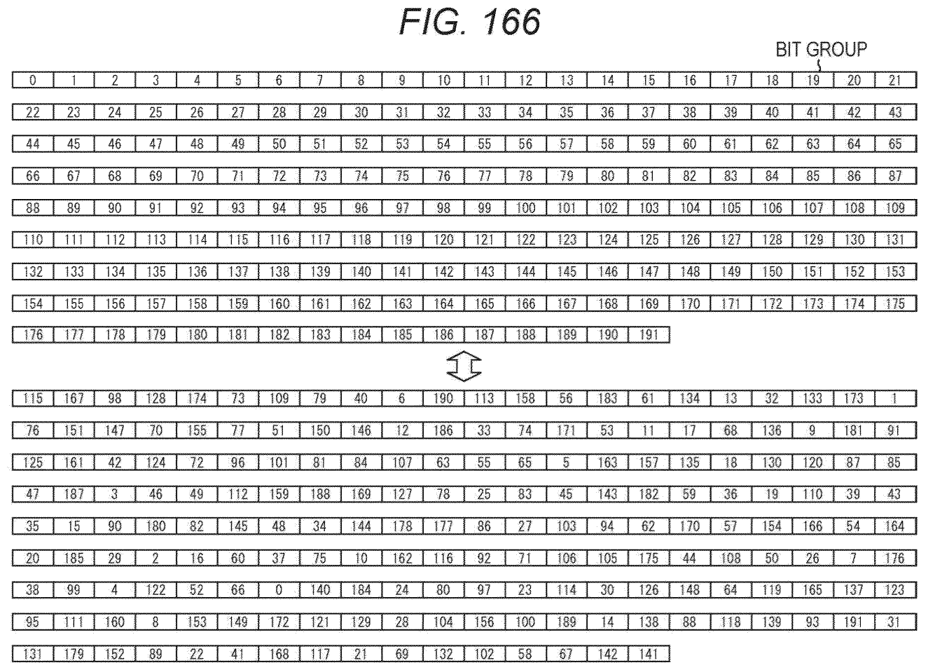

FIG. 166 is a diagram illustrating a forty seventh example of the GW pattern for an LDPC code with a code length N of 69120 bits.

According to the GW pattern in FIG. 166, a sequence of bit groups 0 to 191 of the 69120 bit LDPC code is interleaved into a sequence of the following bit group.
115, 167, 98, 128, 174, 73, 109, 79, 40, 6, 190, 113, 158, 56, 183, 61, 134, 13, 32, 133, 173, 1, 76, 151, 147, 70, 155, 77, 51, 150, 146, 12, 186, 33, 74, 171, 53, 11, 17, 68, 136, 9, 181, 91, 125, 161, 42, 124, 72, 96, 101, 81, 84, 107, 63, 55, 65, 5, 163, 157, 135, 18, 130, 120, 87, 85, 47, 187, 3, 46, 49, 112, 159, 188, 169, 127, 78, 25, 83, 45, 143, 182, 59, 36, 19, 110, 39, 43, 35, 15, 90, 180, 82, 145, 48, 34, 144, 178, 177, 86, 27, 103, 94, 62, 170, 57, 154, 166, 54, 164, 20, 185, 29, 2, 16, 60, 37, 75, 10, 162, 116, 92, 71, 106, 105, 175, 44, 108, 50, 26, 7, 176, 38, 99, 4, 122, 52, 66, 0, 140, 184, 24, 80, 97, 23, 114, 30, 126, 148, 64, 119, 165, 137, 123, 95, 111, 160, 8, 153, 149, 172, 121, 129, 28, 104, 156, 100, 189, 14, 138, 88, 118, 139, 93, 191, 31, 131, 179, 152, 89, 22, 41, 168, 117, 21, 69, 132, 102, 58, 67, 142, 141

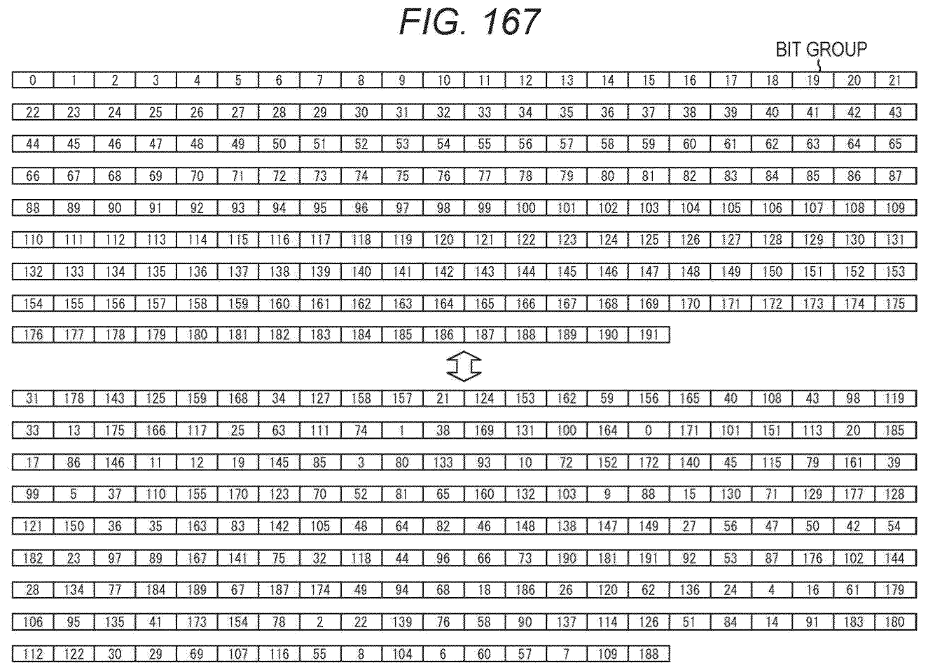

FIG. 167 is a diagram illustrating a forty eighth example of the GW pattern for an LDPC code with a code length N of 69120 bits.

According to the GW pattern in FIG. 167, a sequence of bit groups 0 to 191 of the 69120 bit LDPC code is interleaved into a sequence of the following bit group.
31, 178, 143, 125, 159, 168, 34, 127, 158, 157, 21, 124, 153, 162, 59, 156, 165, 40, 108, 43, 98, 119, 33, 13, 175, 166, 117, 25, 63, 111, 74, 1, 38, 169, 131, 100, 164, 0, 171, 101, 151, 113, 20, 185, 17, 86, 146, 11, 12, 19, 145, 85, 3, 80, 133, 93, 10, 72, 152, 172, 140, 45, 115, 79, 161, 39, 99, 5, 37, 110, 155, 170, 123, 70, 52, 81, 65, 160, 132, 103, 9, 88, 15, 130, 71, 129, 177, 128, 121, 150, 36, 35, 163, 83, 142, 105, 48, 64, 82, 46, 148, 138, 147, 149, 27, 56, 47, 50, 42, 54, 182, 23, 97, 89, 167, 141, 75, 32, 118, 44, 96, 66, 73, 190, 181, 191, 92, 53, 87, 176, 102, 144, 28, 134, 77, 184, 189, 67, 187, 174, 49, 94, 68, 18, 186, 26, 120, 62, 136, 24, 4, 16, 61, 179, 106, 95, 135, 41, 173, 154, 78, 2, 22, 139, 76, 58, 90, 137, 114, 126, 51, 84, 14, 91, 183, 180, 112, 122, 30, 29, 69, 107, 116, 55, 8, 104, 6, 60, 57, 7, 109, 188

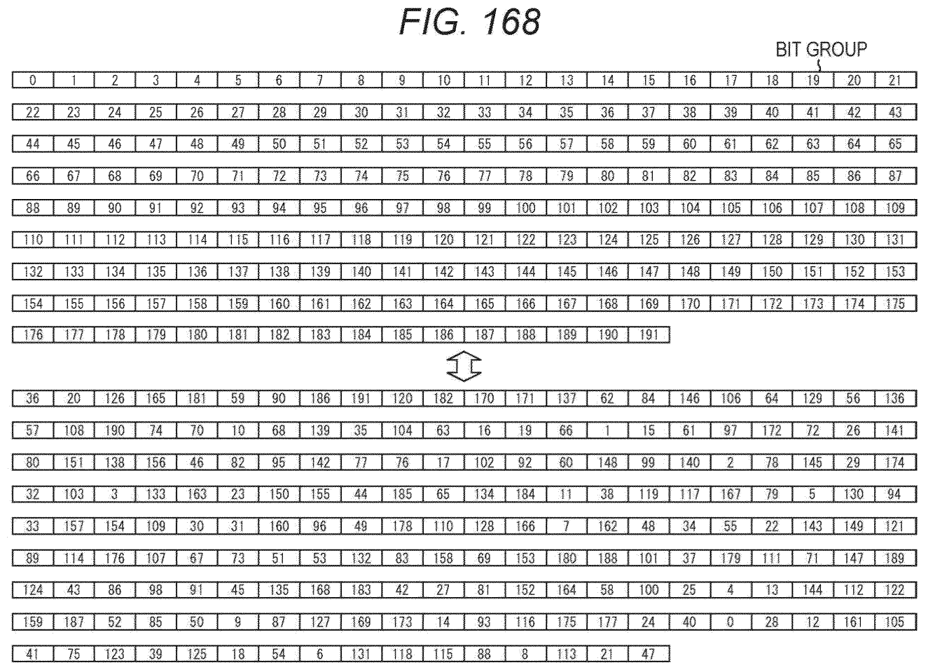

FIG. 168 is a diagram illustrating a forty ninth example of the GW pattern for an LDPC code with a code length N of 69120 bits.

According to the GW pattern in FIG. 168, a sequence of bit groups 0 to 191 of the 69120 bit LDPC code is interleaved into a sequence of the following bit group.
36, 20, 126, 165, 181, 59, 90, 186, 191, 120, 182, 170, 171, 137, 62, 84, 146, 106, 64, 129, 56, 136, 57, 108, 190, 74, 70, 10, 68, 139, 35, 104, 63, 16, 19, 66, 1, 15, 61, 97, 172, 72, 26, 141, 80, 151, 138, 156, 46, 82, 95, 142, 77, 76, 17, 102, 92, 60, 148, 99, 140, 2, 78, 145, 29, 174, 32, 103, 3, 133, 163, 23, 150, 155, 44, 185, 65, 134, 184, 11, 38, 119, 117, 167, 79, 5, 130, 94, 33, 157, 154, 109, 30, 31, 160, 96, 49, 178, 110, 128, 166, 7, 162, 48, 34, 55, 22, 143, 149, 121, 89, 114, 176, 107, 67, 73, 51, 53, 132, 83, 158, 69, 153, 180, 188, 101, 37, 179, 111, 71, 147, 189, 124, 43, 86, 98, 91, 45, 135, 168, 183, 42, 27, 81, 152, 164, 58, 100, 25, 4, 13, 144, 112, 122, 159, 187, 52, 85, 50, 9, 87, 127, 169, 173, 14, 93, 116, 175, 177, 24, 40, 0, 28, 12, 161, 105, 41, 75, 123, 39, 125, 18, 54, 6, 131, 118, 115, 88, 8, 113, 21, 47

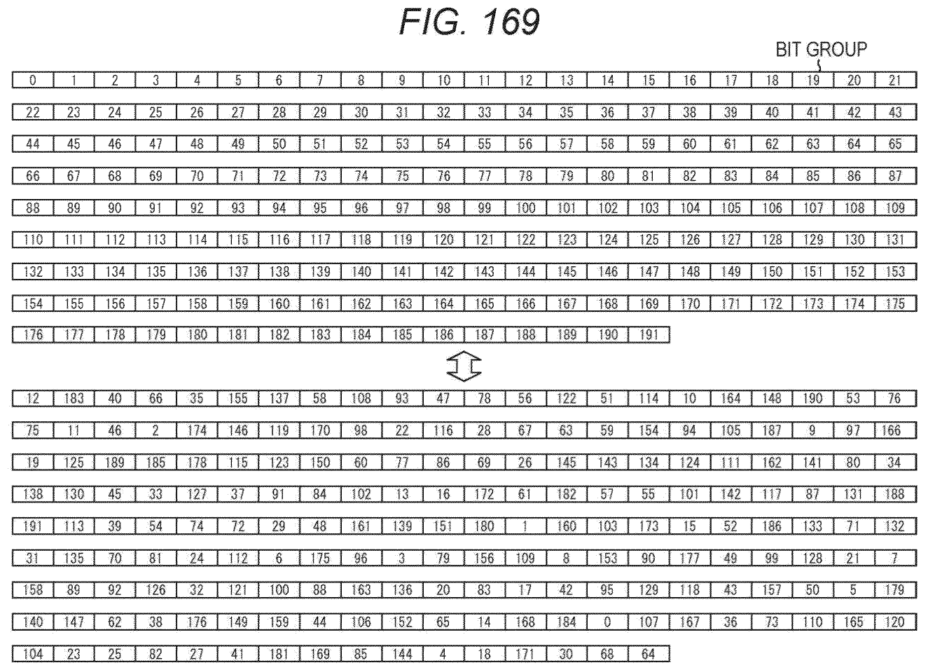

FIG. 169 is a diagram illustrating a fiftieth example of the GW pattern for an LDPC code with a code length N of 69120 bits.

According to the GW pattern in FIG. 169, a sequence of bit groups 0 to 191 of the 69120 bit LDPC code is interleaved into a sequence of the following bit group.
12, 183, 40, 66, 35, 155, 137, 58, 108, 93, 47, 78, 56, 122, 51, 114, 10, 164, 148, 190, 53, 76, 75, 11, 46, 2, 174, 146, 119, 170, 98, 22, 116, 28, 67, 63, 59, 154, 94, 105, 187, 9, 97, 166, 19, 125, 189, 185, 178, 115, 123, 150, 60, 77, 86, 69, 26, 145, 143, 134, 124, 111, 162, 141, 80, 34, 138, 130, 45, 33, 127, 37, 91, 84, 102, 13, 16, 172, 61, 182, 57, 55, 101, 142, 117, 87, 131, 188, 191, 113, 39, 54, 74, 72, 29, 48, 161, 139, 151, 180, 1, 160, 103, 173, 15, 52, 186, 133, 71, 132, 31, 135, 70, 81, 24, 112, 6, 175, 96, 3, 79, 156, 109, 8, 153, 90, 177, 49, 99, 128, 21, 7, 158, 89, 92, 126, 32, 121, 100, 88, 163, 136, 20, 83, 17, 42, 95, 129, 118, 43, 157, 50, 5, 179, 140, 147, 62, 38, 176, 149, 159, 44, 106, 152, 65, 14, 168, 184, 0, 107, 167, 36, 73, 110, 165, 120, 104, 23, 25, 82, 27, 41, 181, 169, 85, 144, 4, 18, 171, 30, 68, 64

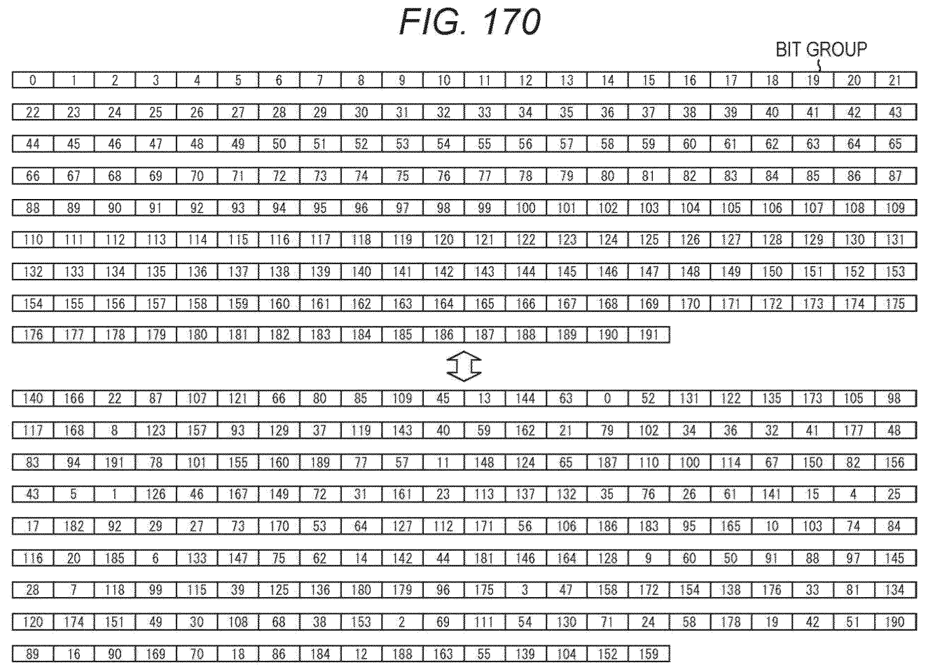

FIG. 170 is a diagram illustrating a fifty first example of the GW pattern for an LDPC code with a code length N of 69120 bits.

According to the GW pattern in FIG. 170, a sequence of bit groups 0 to 191 of the 69120 bit LDPC code is interleaved into a sequence of the following bit group.
140, 166, 22, 87, 107, 121, 66, 80, 85, 109, 45, 13, 144, 63, 0, 52, 131, 122, 135, 173, 105, 98, 117, 168, 8, 123, 157, 93, 129, 37, 119, 143, 40, 59, 162, 21, 79, 102, 34, 36, 32, 41, 177, 48, 83, 94, 191, 78, 101, 155, 160, 189, 77, 57, 11, 148, 124, 65, 187, 110, 100, 114, 67, 150, 82, 156, 43, 5, 1, 126, 46, 167, 149, 72, 31, 161, 23, 113, 137, 132, 35, 76, 26, 61, 141, 15, 4, 25, 17, 182, 92, 29, 27, 73, 170, 53, 64, 127, 112, 171, 56, 106, 186, 183, 95, 165, 10, 103, 74, 84, 116, 20, 185, 6, 133, 147, 75, 62, 14, 142, 44, 181, 146, 164, 128, 9, 60, 50, 91, 88, 97, 145, 28, 7, 118, 99, 115, 39, 125, 136, 180, 179, 96, 175, 3, 47, 158, 172, 154, 138, 176, 33, 81, 134, 120, 174, 151, 49, 30, 108, 68, 38, 153, 2, 69, 111, 54, 130, 71, 24, 58, 178, 19, 42, 51, 190, 89, 16, 90, 169, 70, 18, 86, 184, 12, 188, 163, 55, 139, 104, 152, 159

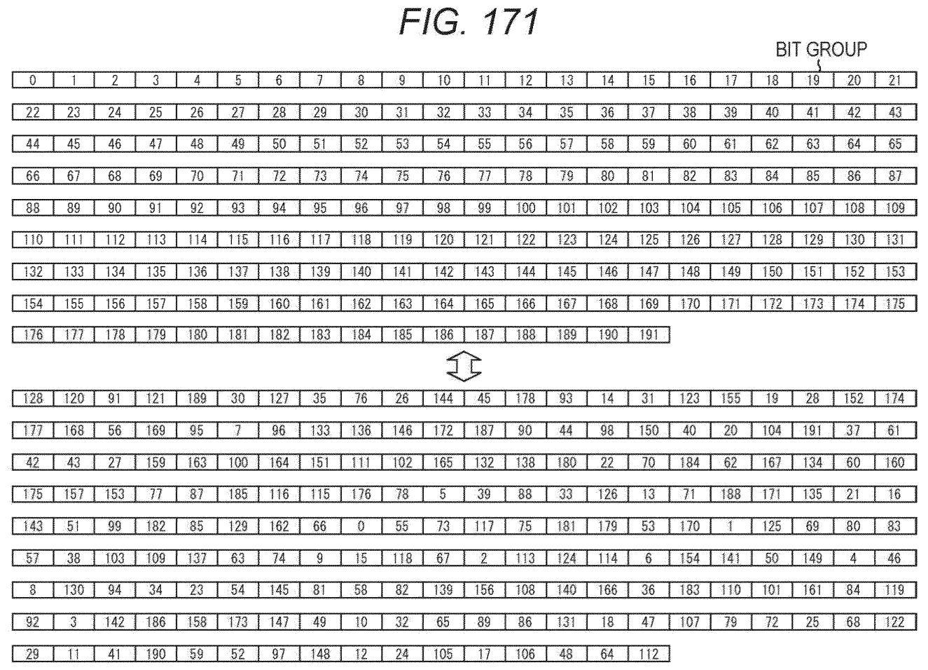

FIG. 171 is a diagram illustrating a fifty second example of the GW pattern for an LDPC code with a code length N of 69120 bits.

According to the GW pattern in FIG. 171, a sequence of bit groups 0 to 191 of the 69120 bit LDPC code is interleaved into a sequence of the following bit group.
128, 120, 91, 121, 189, 30, 127, 35, 76, 26, 144, 45, 178, 93, 14, 31, 123, 155, 19, 28, 152, 174, 177, 168, 56, 169, 95, 7, 96, 133, 136, 146, 172, 187, 90, 44, 98, 150, 40, 20, 104, 191, 37, 61, 42, 43, 27, 159, 163, 100, 164, 151, 111, 102, 165, 132, 138, 180, 22, 70, 184, 62, 167, 134, 60, 160, 175, 157, 153, 77, 87, 185, 116, 115, 176, 78, 5, 39, 88, 33, 126, 13, 71, 188, 171, 135, 21, 16, 143, 51, 99, 182, 85, 129, 162, 66, 0, 55, 73, 117, 75, 181, 179, 53, 170, 1, 125, 69, 80, 83, 57, 38, 103, 109, 137, 63, 74, 9, 15, 118, 67, 2, 113, 124, 114, 6, 154, 141, 50, 149, 4, 46, 8, 130, 94, 34, 23, 54, 145, 81, 58, 82, 139, 156, 108, 140, 166, 36, 183, 110, 101, 161, 84, 119, 92, 3, 142, 186, 158, 173, 147, 49, 10, 32, 65, 89, 86, 131, 18, 47, 107, 79, 72, 25, 68, 122, 29, 11, 41, 190, 59, 52, 97, 148, 12, 24, 105, 17, 106, 48, 64, 112

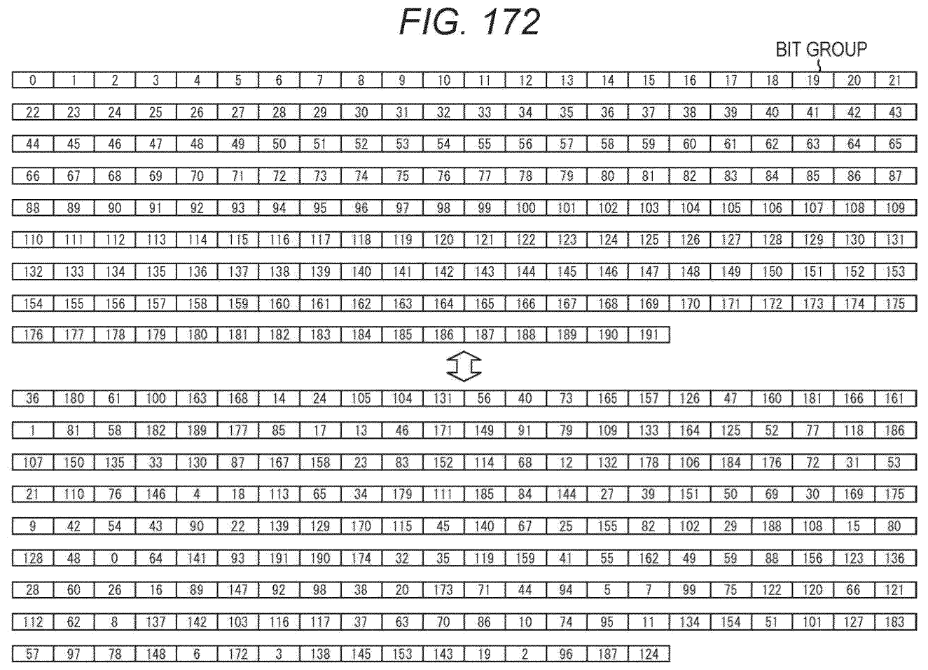

FIG. 172 is a diagram illustrating a fifty third example of the GW pattern for an LDPC code with a code length N of 69120 bits.

According to the GW pattern in FIG. 172, a sequence of bit groups 0 to 191 of the 69120 bit LDPC code is interleaved into a sequence of the following bit group.
36, 180, 61, 100, 163, 168, 14, 24, 105, 104, 131, 56, 40, 73, 165, 157, 126, 47, 160, 181, 166, 161, 1, 81, 58, 182, 189, 177, 85, 17, 13, 46, 171, 149, 91, 79, 109, 133, 164, 125, 52, 77, 118, 186, 107, 150, 135, 33, 130, 87, 167, 158, 23, 83, 152, 114, 68, 12, 132, 178, 106, 184, 176, 72, 31, 53, 21, 110, 76, 146, 4, 18, 113, 65, 34, 179, 111, 185, 84, 144, 27, 39, 151, 50, 69, 30, 169, 175, 9, 42, 54, 43, 90, 22, 139, 129, 170, 115, 45, 140, 67, 25, 155, 82, 102, 29, 188, 108, 15, 80, 128, 48, 0, 64, 141, 93, 191, 190, 174, 32, 35, 119, 159, 41, 55, 162, 49, 59, 88, 156, 123, 136, 28, 60, 26, 16, 89, 147, 92, 98, 38, 20, 173, 71, 44, 94, 5, 7, 99, 75, 122, 120, 66, 121, 112, 62, 8, 137, 142, 103, 116, 117, 37, 63, 70, 86, 10, 74, 95, 11, 134, 154, 51, 101, 127, 183, 57, 97, 78, 148, 6, 172, 3, 138, 145, 153, 143, 19, 2, 96, 187, 124

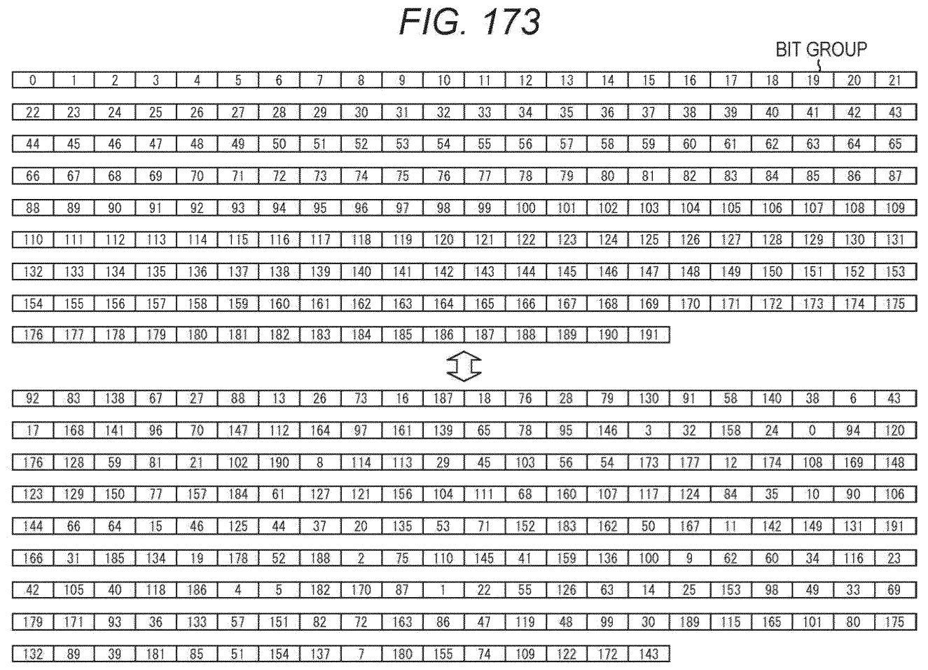

FIG. 173 is a diagram illustrating a fifty fourth example of the GW pattern for an LDPC code with a code length N of 69120 bits.

According to the GW pattern in FIG. 173, a sequence of bit groups 0 to 191 of the 69120 bit LDPC code is interleaved into a sequence of the following bit group.
92, 83, 138, 67, 27, 88, 13, 26, 73, 16, 187, 18, 76, 28, 79, 130, 91, 58, 140, 38, 6, 43, 17, 168, 141, 96, 70, 147, 112, 164, 97, 161, 139, 65, 78, 95, 146, 3, 32, 158, 24, 0, 94, 120, 176, 128, 59, 81, 21, 102, 190, 8, 114, 113, 29, 45, 103, 56, 54, 173, 177, 12, 174, 108, 169, 148, 123, 129, 150, 77, 157, 184, 61, 127, 121, 156, 104, 111, 68, 160, 107, 117, 124, 84, 35, 10, 90, 106, 144, 66, 64, 15, 46, 125, 44, 37, 20, 135, 53, 71, 152, 183, 162, 50, 167, 11, 142, 149, 131, 191, 166, 31, 185, 134, 19, 178, 52, 188, 2, 75, 110, 145, 41, 159, 136, 100, 9, 62, 60, 34, 116, 23, 42, 105, 40, 118, 186, 4, 5, 182, 170, 87, 1, 22, 55, 126, 63, 14, 25, 153, 98, 49, 33, 69, 179, 171, 93, 36, 133, 57, 151, 82, 72, 163, 86, 47, 119, 48, 99, 30, 189, 115, 165, 101, 80, 175, 132, 89, 39, 181, 85, 51, 154, 137, 7, 180, 155, 74, 109, 122, 172, 143

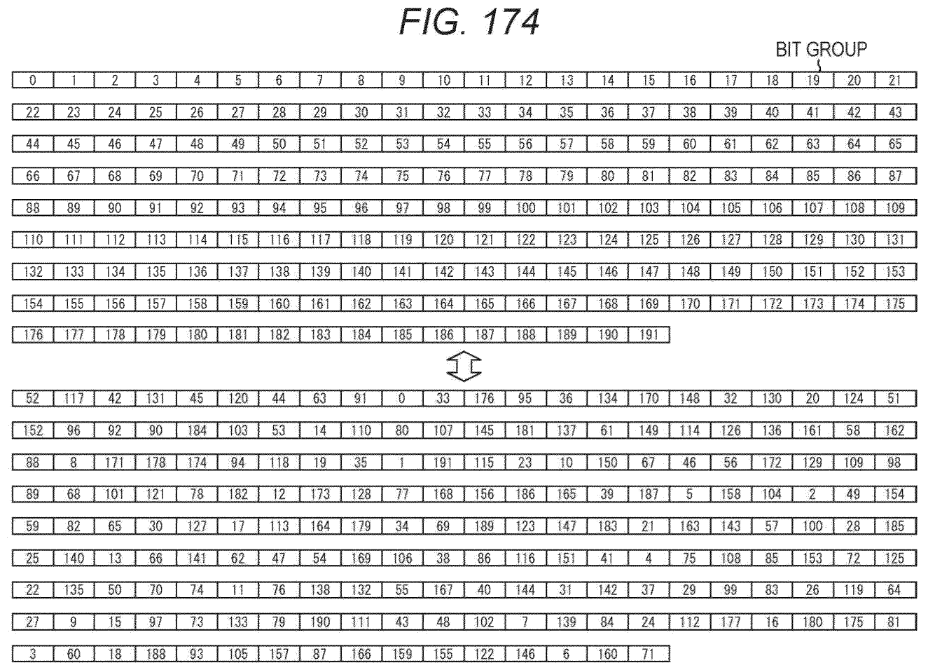

FIG. 174 is a diagram illustrating a fifty fifth example of the GW pattern for an LDPC code with a code length N of 69120 bits.

According to the GW pattern in FIG. 174, a sequence of bit groups 0 to 191 of the 69120 bit LDPC code is interleaved into a sequence of the following bit group.
52, 117, 42, 131, 45, 120, 44, 63, 91, 0, 33, 176, 95, 36, 134, 170, 148, 32, 130, 20, 124, 51, 152, 96, 92, 90, 184, 103, 53, 14, 110, 80, 107, 145, 181, 137, 61, 149, 114, 126, 136, 161, 58, 162, 88, 8, 171, 178, 174, 94, 118, 19, 35, 1, 191, 115, 23, 10, 150, 67, 46, 56, 172, 129, 109, 98, 89, 68, 101, 121, 78, 182, 12, 173, 128, 77, 168, 156, 186, 165, 39, 187, 5, 158, 104, 2, 49, 154, 59, 82, 65, 30, 127, 17, 113, 164, 179, 34, 69, 189, 123, 147, 183, 21, 163, 143, 57, 100, 28, 185, 25, 140, 13, 66, 141, 62, 47, 54, 169, 106, 38, 86, 116, 151, 41, 4, 75, 108, 85, 153, 72, 125, 22, 135, 50, 70, 74, 11, 76, 138, 132, 55, 167, 40, 144, 31, 142, 37, 29, 99, 83, 26, 119, 64, 27, 9, 15, 97, 73, 133, 79, 190, 111, 43, 48, 102, 7, 139, 84, 24, 112, 177, 16, 180, 175, 81, 3, 60, 18, 188, 93, 105, 157, 87, 166, 159, 155, 122, 146, 6, 160, 71

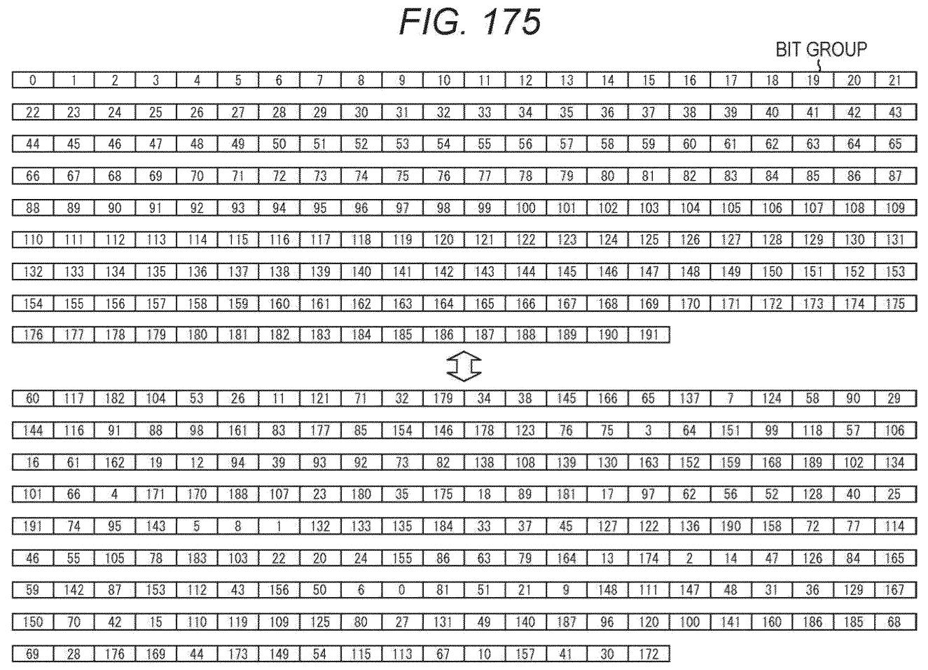

FIG. 175 is a diagram illustrating a fifty sixth example of the GW pattern for an LDPC code with a code length N of 69120 bits.

According to the GW pattern in FIG. 175, a sequence of bit groups 0 to 191 of the 69120 bit LDPC code is interleaved into a sequence of the following bit group.
60, 117, 182, 104, 53, 26, 11, 121, 71, 32, 179, 34, 38, 145, 166, 65, 137, 7, 124, 58, 90, 29, 144, 116, 91, 88, 98, 161, 83, 177, 85, 154, 146, 178, 123, 76, 75, 3, 64, 151, 99, 118, 57, 106, 16, 61, 162, 19, 12, 94, 39, 93, 92, 73, 82, 138, 108, 139, 130, 163, 152, 159, 168, 189, 102, 134, 101, 66, 4, 171, 170, 188, 107, 23, 180, 35, 175, 18, 89, 181, 17, 97, 62, 56, 52, 128, 40, 25, 191, 74, 95, 143, 5, 8, 1, 132, 133, 135, 184, 33, 37, 45, 127, 122, 136, 190, 158, 72, 77, 114, 46, 55, 105, 78, 183, 103, 22, 20, 24, 155, 86, 63, 79, 164, 13, 174, 2, 14, 47, 126, 84, 165, 59, 142, 87, 153, 112, 43, 156, 50, 6, 0, 81, 51, 21, 9, 148, 111, 147, 48, 31, 36, 129, 167, 150, 70, 42, 15, 110, 119, 109, 125, 80, 27, 131, 49, 140, 187, 96, 120, 100, 141, 160, 186, 185, 68, 69, 28, 176, 169, 44, 173, 149, 54, 115, 113, 67, 10, 157, 41, 30, 172

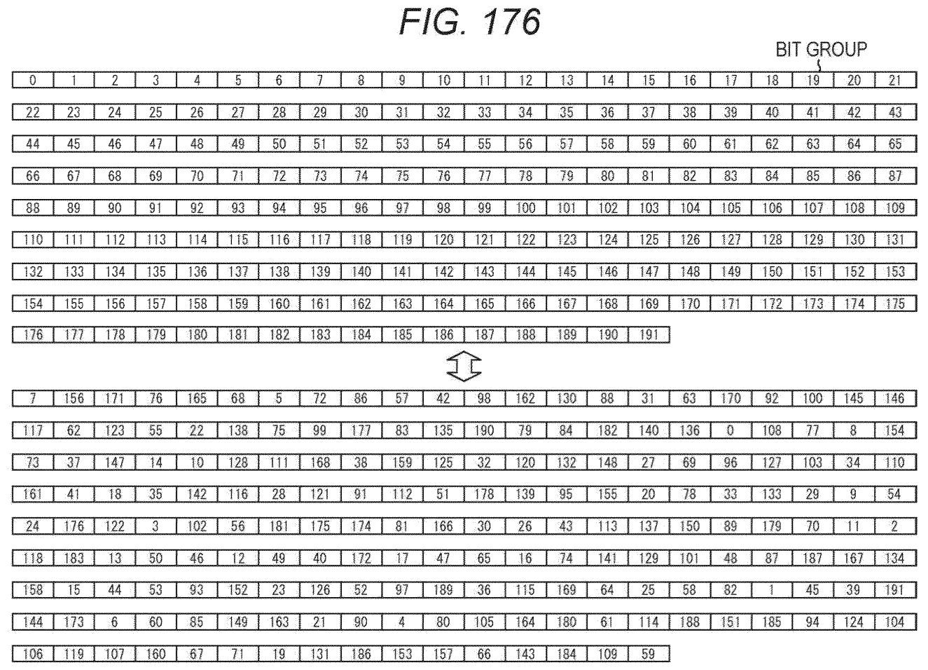

FIG. 176 is a diagram illustrating a fifty seventh example of the GW pattern for an LDPC code with a code length N of 69120 bits.

According to the GW pattern in FIG. 176, a sequence of bit groups 0 to 191 of the 69120 bit LDPC code is interleaved into a sequence of the following bit group.
7, 156, 171, 76, 165, 68, 5, 72, 86, 57, 42, 98, 162, 130, 88, 31, 63, 170, 92, 100, 145, 146, 117, 62, 123, 55, 22, 138, 75, 99, 177, 83, 135, 190, 79, 84, 182, 140, 136, 0, 108, 77, 8, 154, 73, 37, 147, 14, 10, 128, 111, 168, 38, 159, 125, 32, 120, 132, 148, 27, 69, 96, 127, 103, 34, 110, 161, 41, 18, 35, 142, 116, 28, 121, 91, 112, 51, 178, 139, 95, 155, 20, 78, 33, 133, 29, 9, 54, 24, 176, 122, 3, 102, 56, 181, 175, 174, 81, 166, 30, 26, 43, 113, 137, 150, 89, 179, 70, 11, 2, 118, 183, 13, 50, 46, 12, 49, 40, 172, 17, 47, 65, 16, 74, 141, 129, 101, 48, 87, 187, 167, 134, 158, 15, 44, 53, 93, 152, 23, 126, 52, 97, 189, 36, 115, 169, 64, 25, 58, 82, 1, 45, 39, 191, 144, 173, 6, 60, 85, 149, 163, 21, 90, 4, 80, 105, 164, 180, 61, 114, 188, 151, 185, 94, 124, 104, 106, 119, 107, 160, 67, 71, 19, 131, 186, 153, 157, 66, 143, 184, 109, 59

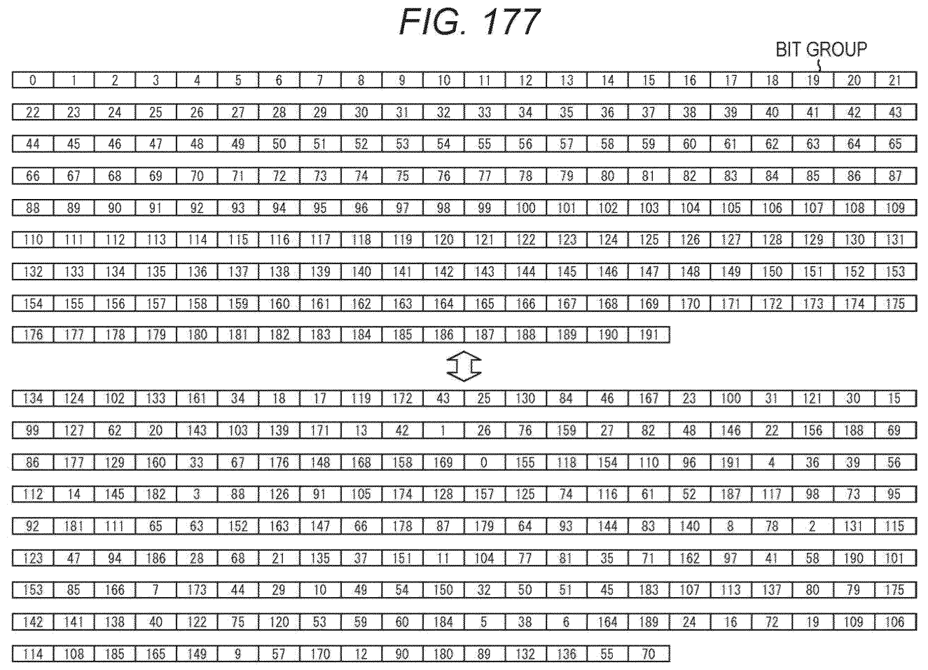

FIG. 177 is a diagram illustrating a fifty eighth example of the GW pattern for an LDPC code with a code length N of 69120 bits.

According to the GW pattern in FIG. 177, a sequence of bit groups 0 to 191 of the 69120 bit LDPC code is interleaved into a sequence of the following bit group.
134, 124, 102, 133, 161, 34, 18, 17, 119, 172, 43, 25, 130, 84, 46, 167, 23, 100, 31, 121, 30, 15, 99, 127, 62, 20, 143, 103, 139, 171, 13, 42, 1, 26, 76, 159, 27, 82, 48, 146, 22, 156, 188, 69, 86, 177, 129, 160, 33, 67, 176, 148, 168, 158, 169, 0, 155, 118, 154, 110, 96, 191, 4, 36, 39, 56, 112, 14, 145, 182, 3, 88, 126, 91, 105, 174, 128, 157, 125, 74, 116, 61, 52, 187, 117, 98, 73, 95, 92, 181, 111, 65, 63, 152, 163, 147, 66, 178, 87, 179, 64, 93, 144, 83, 140, 8, 78, 2, 131, 115, 123, 47, 94, 186, 28, 68, 21, 135, 37, 151, 11, 104, 77, 81, 35, 71, 162, 97, 41, 58, 190, 101, 153, 85, 166, 7, 173, 44, 29, 10, 49, 54, 150, 32, 50, 51, 45, 183, 107, 113, 137, 80, 79, 175, 142, 141, 138, 40, 122, 75, 120, 53, 59, 60, 184, 5, 38, 6, 164, 189, 24, 16, 72, 19, 109, 106, 114, 108, 185, 165, 149, 9, 57, 170, 12, 90, 180, 89, 132, 136, 55, 70

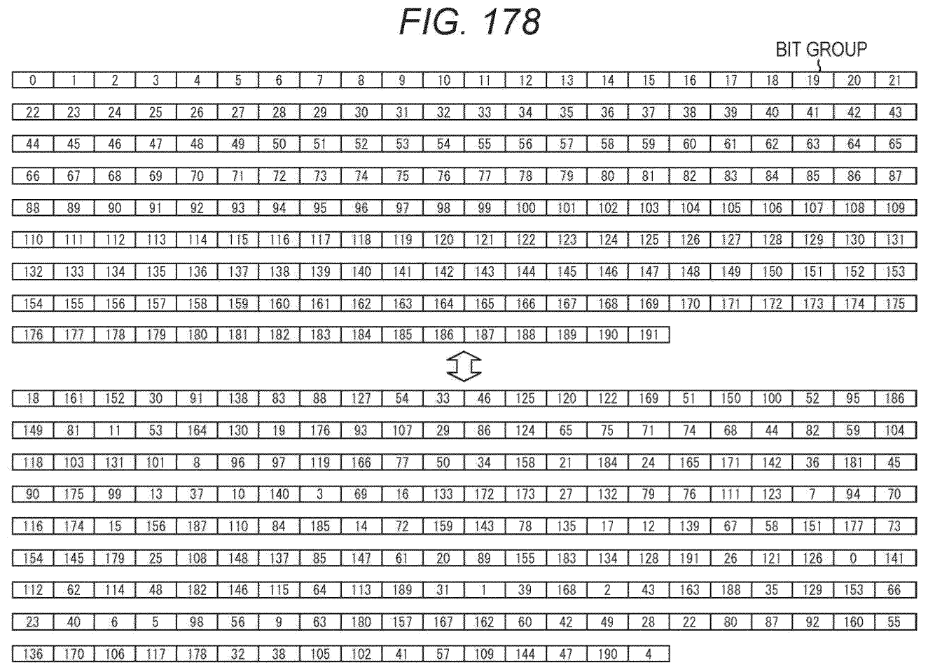

FIG. 178 is a diagram illustrating a fifty ninth example of the GW pattern for an LDPC code with a code length N of 69120 bits.

According to the GW pattern in FIG. 178, a sequence of bit groups 0 to 191 of the 69120 bit LDPC code is interleaved into a sequence of the following bit group.
18, 161, 152, 30, 91, 138, 83, 88, 127, 54, 33, 46, 125, 120, 122, 169, 51, 150, 100, 52, 95, 186, 149, 81, 11, 53, 164, 130, 19, 176, 93, 107, 29, 86, 124, 65, 75, 71, 74, 68, 44, 82, 59, 104, 118, 103, 131, 101, 8, 96, 97, 119, 166, 77, 50, 34, 158, 21, 184, 24, 165, 171, 142, 36, 181, 45, 90, 175, 99, 13, 37, 10, 140, 3, 69, 16, 133, 172, 173, 27, 132, 79, 76, 111, 123, 7, 94, 70, 116, 174, 15, 156, 187, 110, 84, 185, 14, 72, 159, 143, 78, 135, 17, 12, 139, 67, 58, 151, 177, 73, 154, 145, 179, 25, 108, 148, 137, 85, 147, 61, 20, 89, 155, 183, 134, 128, 191, 26, 121, 126, 0, 141, 112, 62, 114, 48, 182, 146, 115, 64, 113, 189, 31, 1, 39, 168, 2, 43, 163, 188, 35, 129, 153, 66, 23, 40, 6, 5, 98, 56, 9, 63, 180, 157, 167, 162, 60, 42, 49, 28, 22, 80, 87, 92, 160, 55, 136, 170, 106, 117, 178, 32, 38, 105, 102, 41, 57, 109, 144, 47, 190, 4

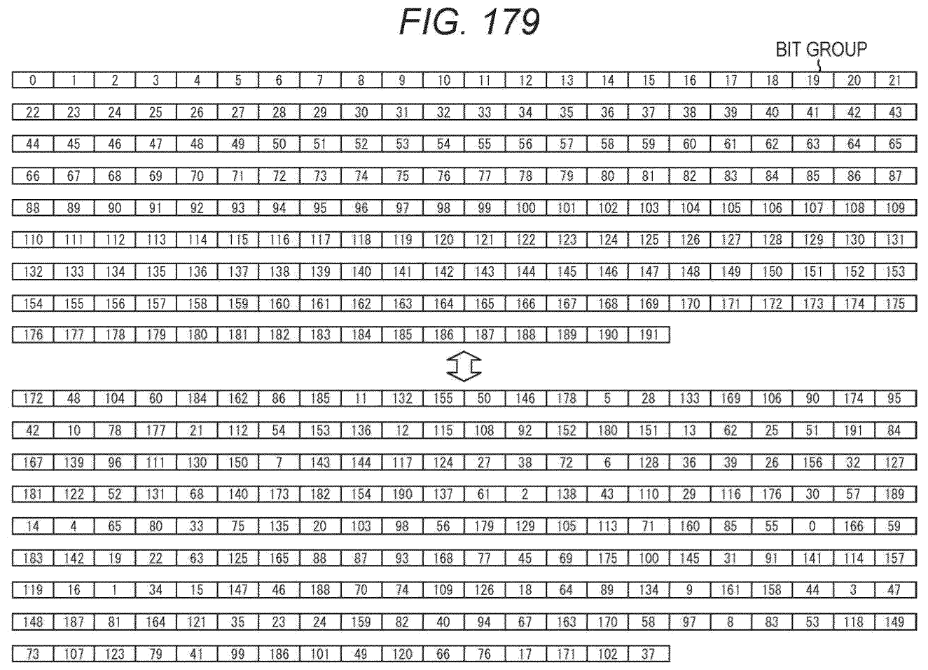

FIG. 179 is a diagram illustrating a sixtieth example of the GW pattern for an LDPC code with a code length N of 69120 bits.

According to the GW pattern in FIG. 179, a sequence of bit groups 0 to 191 of the 69120 bit LDPC code is interleaved into a sequence of the following bit group.
172, 48, 104, 60, 184, 162, 86, 185, 11, 132, 155, 50, 146, 178, 5, 28, 133, 169, 106, 90, 174, 95, 42, 10, 78, 177, 21, 112, 54, 153, 136, 12, 115, 108, 92, 152, 180, 151, 13, 62, 25, 51, 191, 84, 167, 139, 96, 111, 130, 150, 7, 143, 144, 117, 124, 27, 38, 72, 6, 128, 36, 39, 26, 156, 32, 127, 181, 122, 52, 131, 68, 140, 173, 182, 154, 190, 137, 61, 2, 138, 43, 110, 29, 116, 176, 30, 57, 189, 14, 4, 65, 80, 33, 75, 135, 20, 103, 98, 56, 179, 129, 105, 113, 71, 160, 85, 55, 0, 166, 59, 183, 142, 19, 22, 63, 125, 165, 88, 87, 93, 168, 77, 45, 69, 175, 100, 145, 31, 91, 141, 114, 157, 119, 16, 1, 34, 15, 147, 46, 188, 70, 74, 109, 126, 18, 64, 89, 134, 9, 161, 158, 44, 3, 47, 148, 187, 81, 164, 121, 35, 23, 24, 159, 82, 40, 94, 67, 163, 170, 58, 97, 8, 83, 53, 118, 149, 73, 107, 123, 79, 41, 99, 186, 101, 49, 120, 66, 76, 17, 171, 102, 37

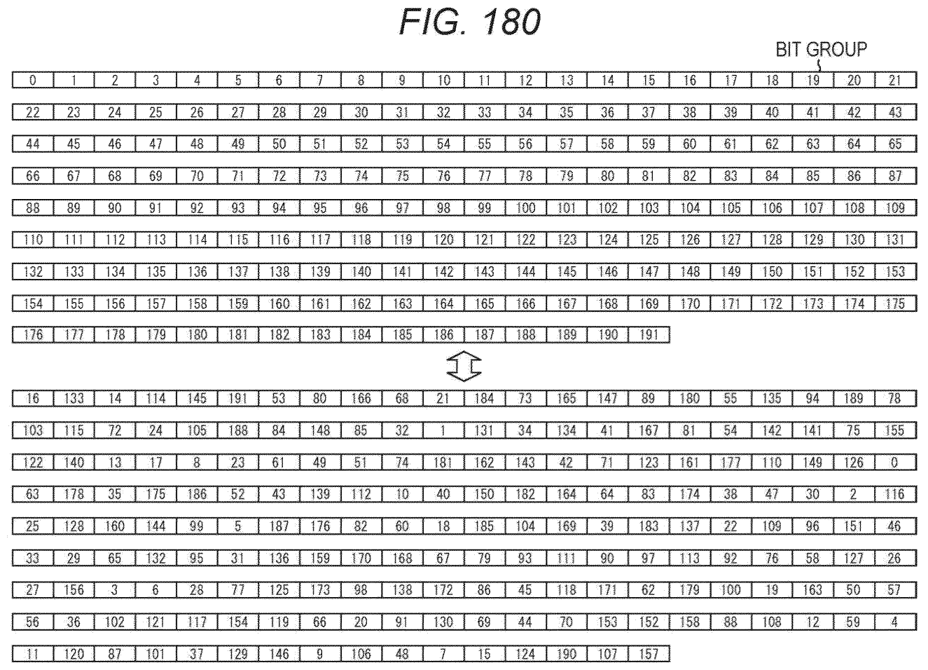

FIG. 180 is a diagram illustrating a sixty first example of the GW pattern for an LDPC code with a code length N of 69120 bits.

According to the GW pattern in FIG. 180, a sequence of bit groups 0 to 191 of the 69120 bit LDPC code is interleaved into a sequence of the following bit group.
16, 133, 14, 114, 145, 191, 53, 80, 166, 68, 21, 184, 73, 165, 147, 89, 180, 55, 135, 94, 189, 78, 103, 115, 72, 24, 105, 188, 84, 148, 85, 32, 1, 131, 34, 134, 41, 167, 81, 54, 142, 141, 75, 155, 122, 140, 13, 17, 8, 23, 61, 49, 51, 74, 181, 162, 143, 42, 71, 123, 161, 177, 110, 149, 126, 0, 63, 178, 35, 175, 186, 52, 43, 139, 112, 10, 40, 150, 182, 164, 64, 83, 174, 38, 47, 30, 2, 116, 25, 128, 160, 144, 99, 5, 187, 176, 82, 60, 18, 185, 104, 169, 39, 183, 137, 22, 109, 96, 151, 46, 33, 29, 65, 132, 95, 31, 136, 159, 170, 168, 67, 79, 93, 111, 90, 97, 113, 92, 76, 58, 127, 26, 27, 156, 3, 6, 28, 77, 125, 173, 98, 138, 172, 86, 45, 118, 171, 62, 179, 100, 19, 163, 50, 57, 56, 36, 102, 121, 117, 154, 119, 66, 20, 91, 130, 69, 44, 70, 153, 152, 158, 88, 108, 12, 59, 4, 11, 120, 87, 101, 37, 129, 146, 9, 106, 48, 7, 15, 124, 190, 107, 157

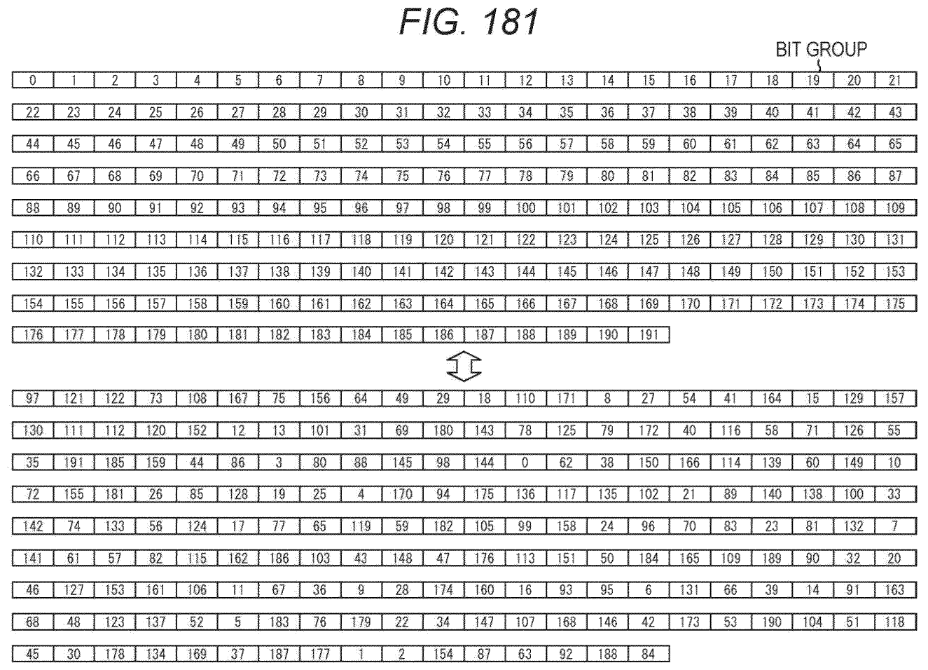

FIG. 181 is a diagram illustrating a sixty second example of the GW pattern for an LDPC code with a code length N of 69120 bits.

According to the GW pattern in FIG. 181, a sequence of bit groups 0 to 191 of the 69120 bit LDPC code is interleaved into a sequence of the following bit group.
97, 121, 122, 73, 108, 167, 75, 156, 64, 49, 29, 18, 110, 171, 8, 27, 54, 41, 164, 15, 129, 157, 130, 111, 112, 120, 152, 12, 13, 101, 31, 69, 180, 143, 78, 125, 79, 172, 40, 116, 58, 71, 126, 55, 35, 191, 185, 159, 44, 86, 3, 80, 88, 145, 98, 144, 0, 62, 38, 150, 166, 114, 139, 60, 149, 10, 72, 155, 181, 26, 85, 128, 19, 25, 4, 170, 94, 175, 136, 117, 135, 102, 21, 89, 140, 138, 100, 33, 142, 74, 133, 56, 124, 17, 77, 65, 119, 59, 182, 105, 99, 158, 24, 96, 70, 83, 23, 81, 132, 7, 141, 61, 57, 82, 115, 162, 186, 103, 43, 148, 47, 176, 113, 151, 50, 184, 165, 109, 189, 90, 32, 20, 46, 127, 153, 161, 106, 11, 67, 36, 9, 28, 174, 160, 16, 93, 95, 6, 131, 66, 39, 14, 91, 163, 68, 48, 123, 137, 52, 5, 183, 76, 179, 22, 34, 147, 107, 168, 146, 42, 173, 53, 190, 104, 51, 118, 45, 30, 178, 134, 169, 37, 187, 177, 1, 2, 154, 87, 63, 92, 188, 84

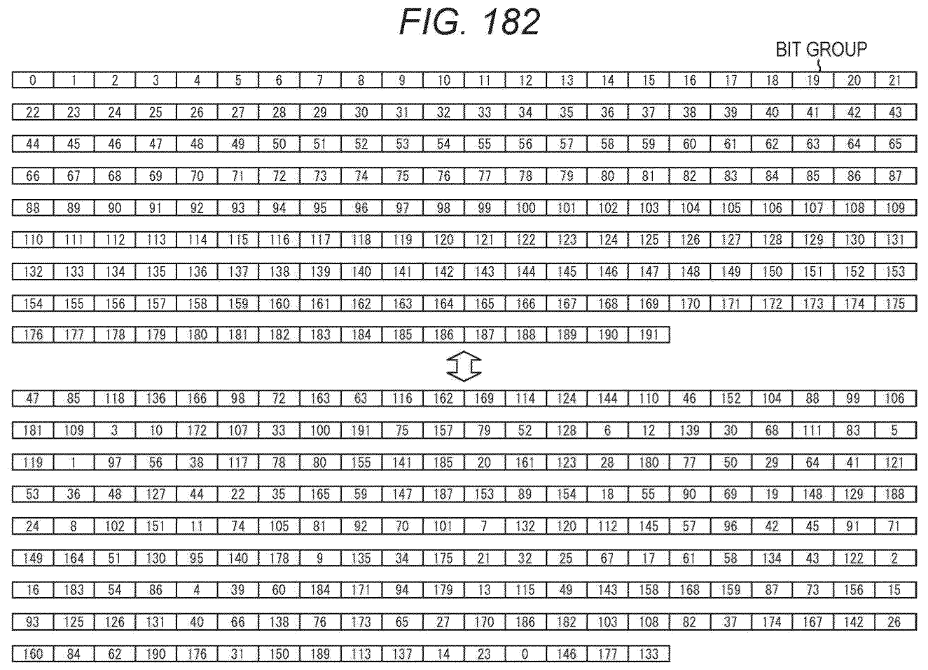

FIG. 182 is a diagram illustrating a sixty third example of the GW pattern for an LDPC code with a code length N of 69120 bits.

According to the GW pattern in FIG. 182, a sequence of bit groups 0 to 191 of the 69120 bit LDPC code is interleaved into a sequence of the following bit group.
47, 85, 118, 136, 166, 98, 72, 163, 63, 116, 162, 169, 114, 124, 144, 110, 46, 152, 104, 88, 99, 106, 181, 109, 3, 10, 172, 107, 33, 100, 191, 75, 157, 79, 52, 128, 6, 12, 139, 30, 68, 111, 83, 5, 119, 1, 97, 56, 38, 117, 78, 80, 155, 141, 185, 20, 161, 123, 28, 180, 77, 50, 29, 64, 41, 121, 53, 36, 48, 127, 44, 22, 35, 165, 59, 147, 187, 153, 89, 154, 18, 55, 90, 69, 19, 148, 129, 188, 24, 8, 102, 151, 11, 74, 105, 81, 92, 70, 101, 7, 132, 120, 112, 145, 57, 96, 42, 45, 91, 71, 149, 164, 51, 130, 95, 140, 178, 9, 135, 34, 175, 21, 32, 25, 67, 17, 61, 58, 134, 43, 122, 2, 16, 183, 54, 86, 4, 39, 60, 184, 171, 94, 179, 13, 115, 49, 143, 158, 168, 159, 87, 73, 156, 15, 93, 125, 126, 131, 40, 66, 138, 76, 173, 65, 27, 170, 186, 182, 103, 108, 82, 37, 174, 167, 142, 26, 160, 84, 62, 190, 176, 31, 150, 189, 113, 137, 14, 23, 0, 146, 177, 133

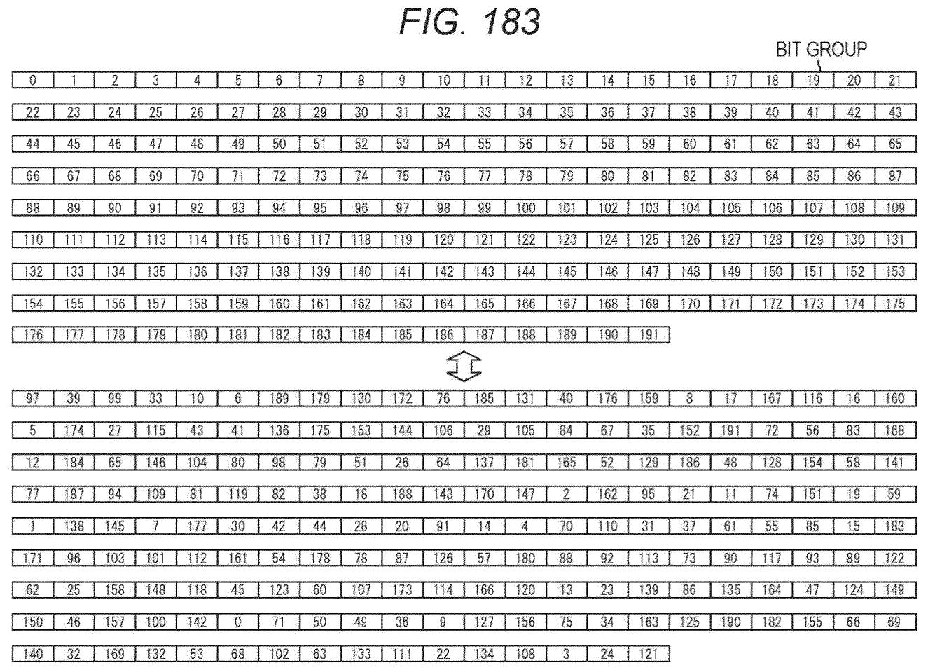

FIG. 183 is a diagram illustrating a sixty fourth example of the GW pattern for an LDPC code with a code length N of 69120 bits.

According to the GW pattern in FIG. 183, a sequence of bit groups 0 to 191 of the 69120 bit LDPC code is interleaved into a sequence of the following bit group.
97, 39, 99, 33, 10, 6, 189, 179, 130, 172, 76, 185, 131, 40, 176, 159, 8, 17, 167, 116, 16, 160, 5, 174, 27, 115, 43, 41, 136, 175, 153, 144, 106, 29, 105, 84, 67, 35, 152, 191, 72, 56, 83, 168, 12, 184, 65, 146, 104, 80, 98, 79, 51, 26, 64, 137, 181, 165, 52, 129, 186, 48, 128, 154, 58, 141, 77, 187, 94, 109, 81, 119, 82, 38, 18, 188, 143, 170, 147, 2, 162, 95, 21, 11, 74, 151, 19, 59, 1, 138, 145, 7, 177, 30, 42, 44, 28, 20, 91, 14, 4, 70, 110, 31, 37, 61, 55, 85, 15, 183, 171, 96, 103, 101, 112, 161, 54, 178, 78, 87, 126, 57, 180, 88, 92, 113, 73, 90, 117, 93, 89, 122, 62, 25, 158, 148, 118, 45, 123, 60, 107, 173, 114, 166, 120, 13, 23, 139, 86, 135, 164, 47, 124, 149, 150, 46, 157, 100, 142, 0, 71, 50, 49, 36, 9, 127, 156, 75, 34, 163, 125, 190, 182, 155, 66, 69, 140, 32, 169, 132, 53, 68, 102, 63, 133, 111, 22, 134, 108, 3, 24, 121

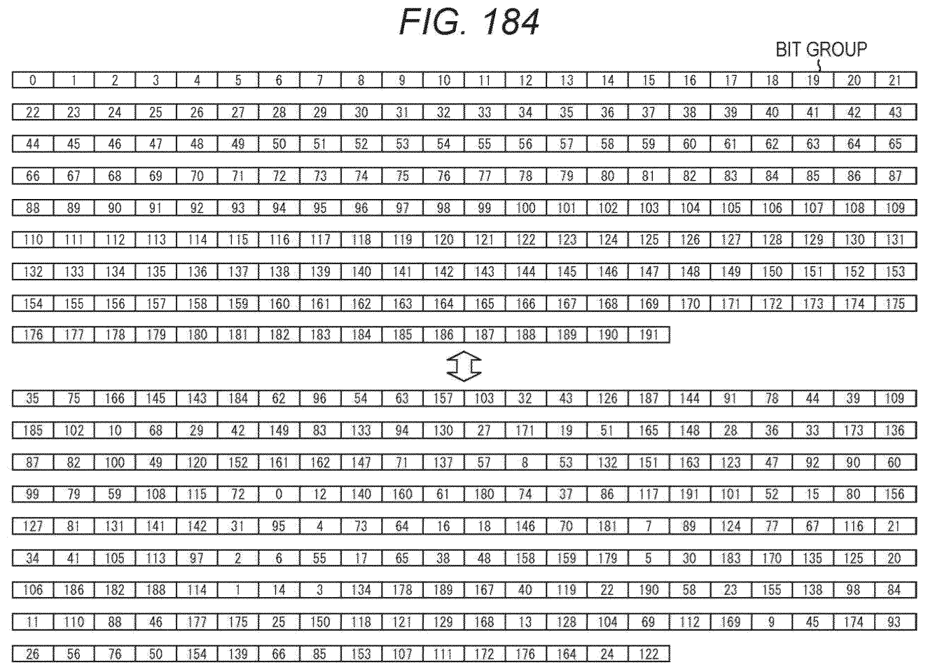

FIG. 184 is a diagram illustrating a sixty fifth example of the GW pattern for an LDPC code with a code length N of 69120 bits.

According to the GW pattern in FIG. 184, a sequence of bit groups 0 to 191 of the 69120 bit LDPC code is interleaved into a sequence of the following bit group.
35, 75, 166, 145, 143, 184, 62, 96, 54, 63, 157, 103, 32, 43, 126, 187, 144, 91, 78, 44, 39, 109, 185, 102, 10, 68, 29, 42, 149, 83, 133, 94, 130, 27, 171, 19, 51, 165, 148, 28, 36, 33, 173, 136, 87, 82, 100, 49, 120, 152, 161, 162, 147, 71, 137, 57, 8, 53, 132, 151, 163, 123, 47, 92, 90, 60, 99, 79, 59, 108, 115, 72, 0, 12, 140, 160, 61, 180, 74, 37, 86, 117, 191, 101, 52, 15, 80, 156, 127, 81, 131, 141, 142, 31, 95, 4, 73, 64, 16, 18, 146, 70, 181, 7, 89, 124, 77, 67, 116, 21, 34, 41, 105, 113, 97, 2, 6, 55, 17, 65, 38, 48, 158, 159, 179, 5, 30, 183, 170, 135, 125, 20, 106, 186, 182, 188, 114, 1, 14, 3, 134, 178, 189, 167, 40, 119, 22, 190, 58, 23, 155, 138, 98, 84, 11, 110, 88, 46, 177, 175, 25, 150, 118, 121, 129, 168, 13, 128, 104, 69, 112, 169, 9, 45, 174, 93, 26, 56, 76, 50, 154, 139, 66, 85, 153, 107, 111, 172, 176, 164, 24, 122

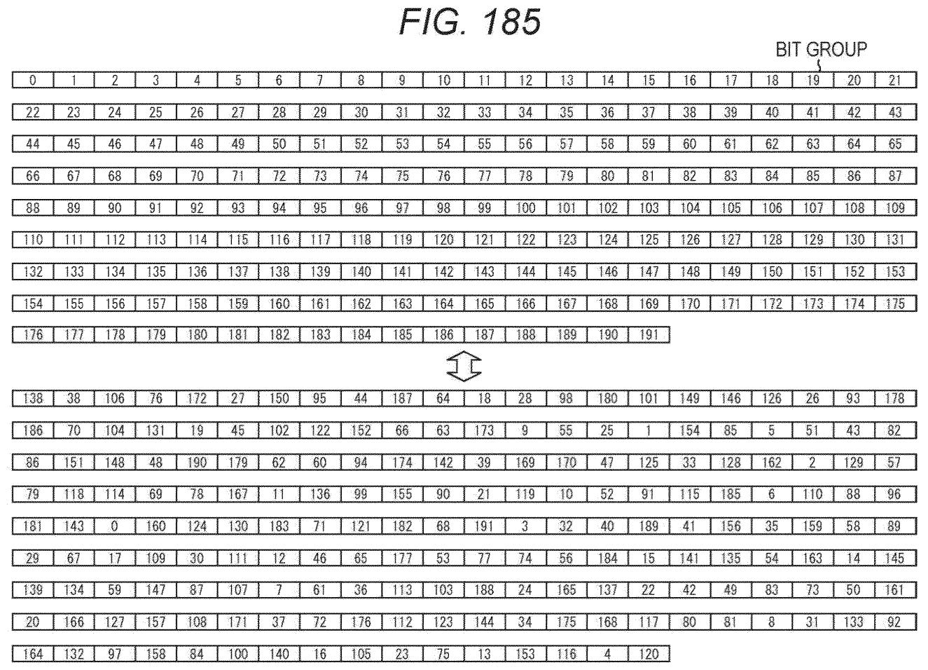

FIG. 185 is a diagram illustrating a sixty sixth example of the GW pattern for an LDPC code with a code length N of 69120 bits.

According to the GW pattern in FIG. 185, a sequence of bit groups 0 to 191 of the 69120 bit LDPC code is interleaved into a sequence of the following bit group.
138, 38, 106, 76, 172, 27, 150, 95, 44, 187, 64, 18, 28, 98, 180, 101, 149, 146, 126, 26, 93, 178, 186, 70, 104, 131, 19, 45, 102, 122, 152, 66, 63, 173, 9, 55, 25, 1, 154, 85, 5, 51, 43, 82, 86, 151, 148, 48, 190, 179, 62, 60, 94, 174, 142, 39, 169, 170, 47, 125, 33, 128, 162, 2, 129, 57, 79, 118, 114, 69, 78, 167, 11, 136, 99, 155, 90, 21, 119, 10, 52, 91, 115, 185, 6, 110, 88, 96, 181, 143, 0, 160, 124, 130, 183, 71, 121, 182, 68, 191, 3, 32, 40, 189, 41, 156, 35, 159, 58, 89, 29, 67, 17, 109, 30, 111, 12, 46, 65, 177, 53, 77, 74, 56, 184, 15, 141, 135, 54, 163, 14, 145, 139, 134, 59, 147, 87, 107, 7, 61, 36, 113, 103, 188, 24, 165, 137, 22, 42, 49, 83, 73, 50, 161, 20, 166, 127, 157, 108, 171, 37, 72, 176, 112, 123, 144, 34, 175, 168, 117, 80, 81, 8, 31, 133, 92, 164, 132, 97, 158, 84, 100, 140, 16, 105, 23, 75, 13, 153, 116, 4, 120

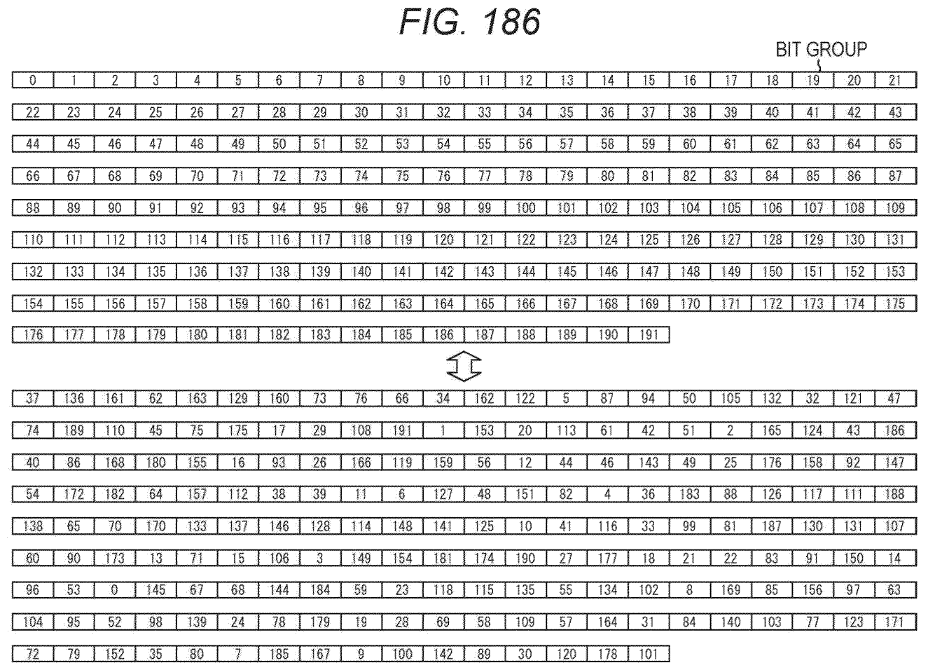

FIG. 186 is a diagram illustrating a sixty seventh example of the GW pattern for an LDPC code with a code length N of 69120 bits.

According to the GW pattern in FIG. 186, a sequence of bit groups 0 to 191 of the 69120 bit LDPC code is interleaved into a sequence of the following bit group.
37, 136, 161, 62, 163, 129, 160, 73, 76, 66, 34, 162, 122, 5, 87, 94, 50, 105, 132, 32, 121, 47, 74, 189, 110, 45, 75, 175, 17, 29, 108, 191, 1, 153, 20, 113, 61, 42, 51, 2, 165, 124, 43, 186, 40, 86, 168, 180, 155, 16, 93, 26, 166, 119, 159, 56, 12, 44, 46, 143, 49, 25, 176, 158, 92, 147, 54, 172, 182, 64, 157, 112, 38, 39, 11, 6, 127, 48, 151, 82, 4, 36, 183, 88, 126, 117, 111, 188, 138, 65, 70, 170, 133, 137, 146, 128, 114, 148, 141, 125, 10, 41, 116, 33, 99, 81, 187, 130, 131, 107, 60, 90, 173, 13, 71, 15, 106, 3, 149, 154, 181, 174, 190, 27, 177, 18, 21, 22, 83, 91, 150, 14, 96, 53, 0, 145, 67, 68, 144, 184, 59, 23, 118, 115, 135, 55, 134, 102, 8, 169, 85, 156, 97, 63, 104, 95, 52, 98, 139, 24, 78, 179, 19, 28, 69, 58, 109, 57, 164, 31, 84, 140, 103, 77, 123, 171, 72, 79, 152, 35, 80, 7, 185, 167, 9, 100, 142, 89, 30, 120, 178, 101

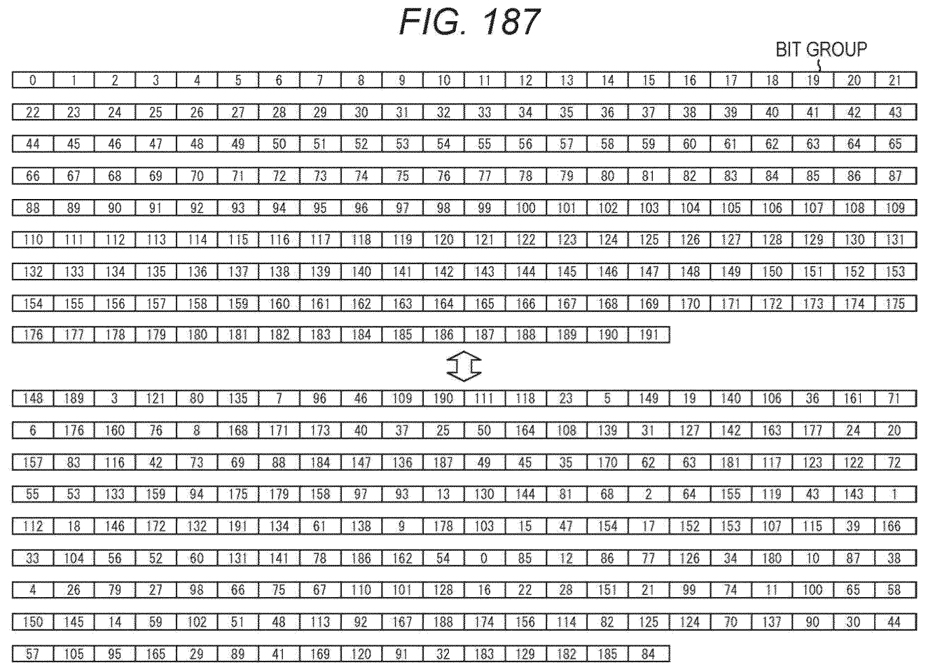

FIG. 187 is a diagram illustrating a sixty eighth example of the GW pattern for an LDPC code with a code length N of 69120 bits.

According to the GW pattern in FIG. 187, a sequence of bit groups 0 to 191 of the 69120 bit LDPC code is interleaved into a sequence of the following bit group.
148, 189, 3, 121, 80, 135, 7, 96, 46, 109, 190, 111, 118, 23, 5, 149, 19, 140, 106, 36, 161, 71, 6, 176, 160, 76, 8, 168, 171, 173, 40, 37, 25, 50, 164, 108, 139, 31, 127, 142, 163, 177, 24, 20, 157, 83, 116, 42, 73, 69, 88, 184, 147, 136, 187, 49, 45, 35, 170, 62, 63, 181, 117, 123, 122, 72, 55, 53, 133, 159, 94, 175, 179, 158, 97, 93, 13, 130, 144, 81, 68, 2, 64, 155, 119, 43, 143, 1, 112, 18, 146, 172, 132, 191, 134, 61, 138, 9, 178, 103, 15, 47, 154, 17, 152, 153, 107, 115, 39, 166, 33, 104, 56, 52, 60, 131, 141, 78, 186, 162, 54, 0, 85, 12, 86, 77, 126, 34, 180, 10, 87, 38, 4, 26, 79, 27, 98, 66, 75, 67, 110, 101, 128, 16, 22, 28, 151, 21, 99, 74, 11, 100, 65, 58, 150, 145, 14, 59, 102, 51, 48, 113, 92, 167, 188, 174, 156, 114, 82, 125, 124, 70, 137, 90, 30, 44, 57, 105, 95, 165, 29, 89, 41, 169, 120, 91, 32, 183, 129, 182, 185, 84

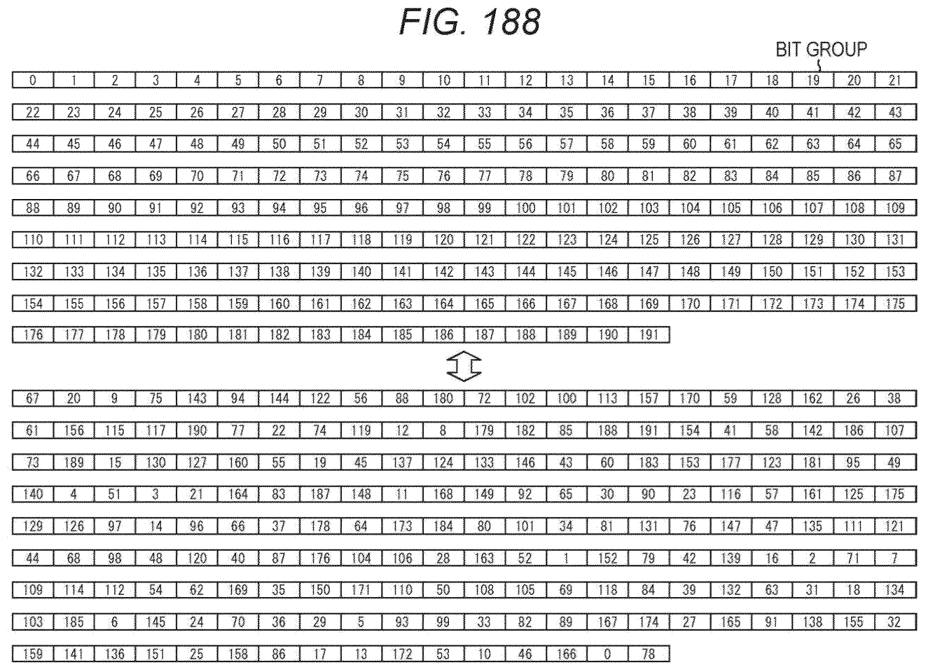

FIG. 188 is a diagram illustrating a sixty ninth example of the GW pattern for an LDPC code with a code length N of 69120 bits.

According to the GW pattern in FIG. 188, a sequence of bit groups 0 to 191 of the 69120 bit LDPC code is interleaved into a sequence of the following bit group.
67, 20, 9, 75, 143, 94, 144, 122, 56, 88, 180, 72, 102, 100, 113, 157, 170, 59, 128, 162, 26, 38, 61, 156, 115, 117, 190, 77, 22, 74, 119, 12, 8, 179, 182, 85, 188, 191, 154, 41, 58, 142, 186, 107, 73, 189, 15, 130, 127, 160, 55, 19, 45, 137, 124, 133, 146, 43, 60, 183, 153, 177, 123, 181, 95, 49, 140, 4, 51, 3, 21, 164, 83, 187, 148, 11, 168, 149, 92, 65, 30, 90, 23, 116, 57, 161, 125, 175, 129, 126, 97, 14, 96, 66, 37, 178, 64, 173, 184, 80, 101, 34, 81, 131, 76, 147, 47, 135, 111, 121, 44, 68, 98, 48, 120, 40, 87, 176, 104, 106, 28, 163, 52, 1, 152, 79, 42, 139, 16, 2, 71, 7, 109, 114, 112, 54, 62, 169, 35, 150, 171, 110, 50, 108, 105, 69, 118, 84, 39, 132, 63, 31, 18, 134, 103, 185, 6, 145, 24, 70, 36, 29, 5, 93, 99, 33, 82, 89, 167, 174, 27, 165, 91, 138, 155, 32, 159, 141, 136, 151, 25, 158, 86, 17, 13, 172, 53, 10, 46, 166, 0, 78

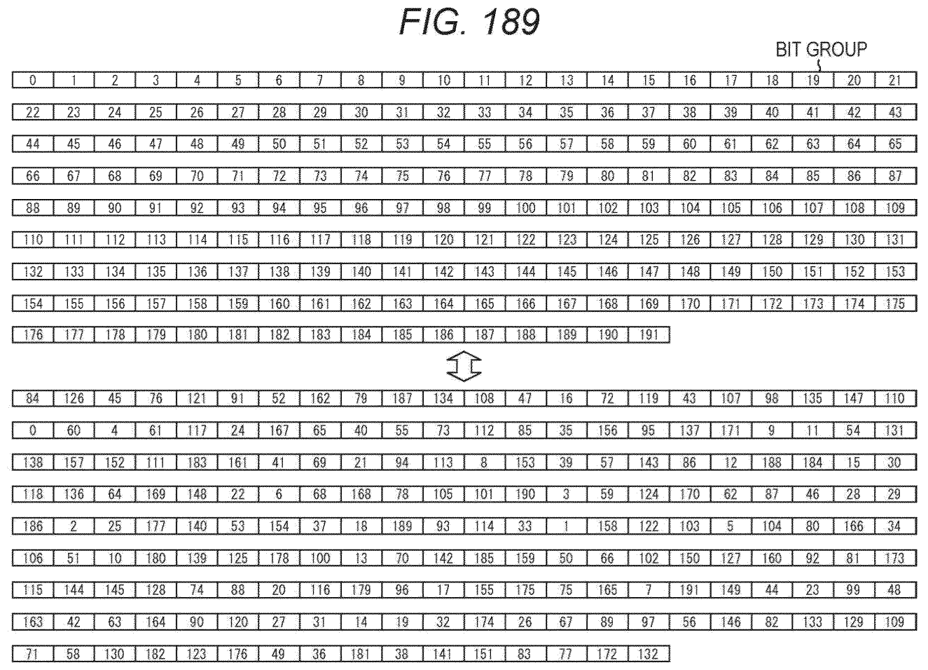

FIG. 189 is a diagram illustrating a seventieth example of the GW pattern for an LDPC code with a code length N of 69120 bits.

According to the GW pattern in FIG. 189, a sequence of bit groups 0 to 191 of the 69120 bit LDPC code is interleaved into a sequence of the following bit group.
84, 126, 45, 76, 121, 91, 52, 162, 79, 187, 134, 108, 47, 16, 72, 119, 43, 107, 98, 135, 147, 110, 0, 60, 4, 61, 117, 24, 167, 65, 40, 55, 73, 112, 85, 35, 156, 95, 137, 171, 9, 11, 54, 131, 138, 157, 152, 111, 183, 161, 41, 69, 21, 94, 113, 8, 153, 39, 57, 143, 86, 12, 188, 184, 15, 30, 118, 136, 64, 169, 148, 22, 6, 68, 168, 78, 105, 101, 190, 3, 59, 124, 170, 62, 87, 46, 28, 29, 186, 2, 25, 177, 140, 53, 154, 37, 18, 189, 93, 114, 33, 1, 158, 122, 103, 5, 104, 80, 166, 34, 106, 51, 10, 180, 139, 125, 178, 100, 13, 70, 142, 185, 159, 50, 66, 102, 150, 127, 160, 92, 81, 173, 115, 144, 145, 128, 74, 88, 20, 116, 179, 96, 17, 155, 175, 75, 165, 7, 191, 149, 44, 23, 99, 48, 163, 42, 63, 164, 90, 120, 27, 31, 14, 19, 32, 174, 26, 67, 89, 97, 56, 146, 82, 133, 129, 109, 71, 58, 130, 182, 123, 176, 49, 36, 181, 38, 141, 151, 83, 77, 172, 132

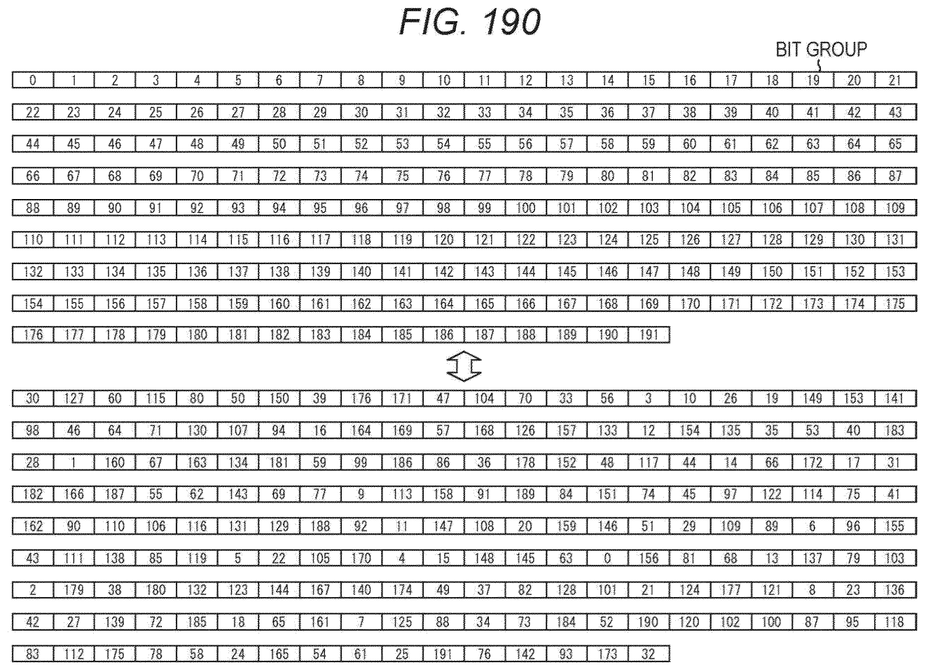

FIG. 190 is a diagram illustrating a seventy first example of the GW pattern for an LDPC code with a code length N of 69120 bits.

According to the GW pattern in FIG. 190, a sequence of bit groups 0 to 191 of the 69120 bit LDPC code is interleaved into a sequence of the following bit group.
30, 127, 60, 115, 80, 50, 150, 39, 176, 171, 47, 104, 70, 33, 56, 3, 10, 26, 19, 149, 153, 141, 98, 46, 64, 71, 130, 107, 94, 16, 164, 169, 57, 168, 126, 157, 133, 12, 154, 135, 35, 53, 40, 183, 28, 1, 160, 67, 163, 134, 181, 59, 99, 186, 86, 36, 178, 152, 48, 117, 44, 14, 66, 172, 17, 31, 182, 166, 187, 55, 62, 143, 69, 77, 9, 113, 158, 91, 189, 84, 151, 74, 45, 97, 122, 114, 75, 41, 162, 90, 110, 106, 116, 131, 129, 188, 92, 11, 147, 108, 20, 159, 146, 51, 29, 109, 89, 6, 96, 155, 43, 111, 138, 85, 119, 5, 22, 105, 170, 4, 15, 148, 145, 63, 0, 156, 81, 68, 13, 137, 79, 103, 2, 179, 38, 180, 132, 123, 144, 167, 140, 174, 49, 37, 82, 128, 101, 21, 124, 177, 121, 8, 23, 136, 42, 27, 139, 72, 185, 18, 65, 161, 7, 125, 88, 34, 73, 184, 52, 190, 120, 102, 100, 87, 95, 118, 83, 112, 175, 78, 58, 24, 165, 54, 61, 25, 191, 76, 142, 93, 173, 32

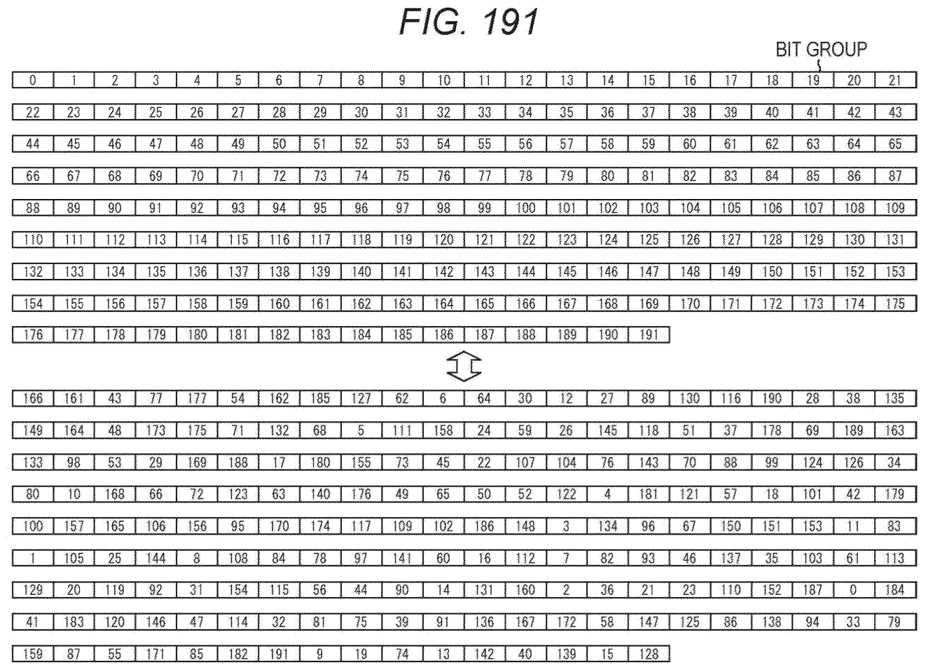

FIG. 191 is a diagram illustrating a seventy second example of the GW pattern for an LDPC code with a code length N of 69120 bits.

According to the GW pattern in FIG. 191, a sequence of bit groups 0 to 191 of the 69120 bit LDPC code is interleaved into a sequence of the following bit group.
166, 161, 43, 77, 177, 54, 162, 185, 127, 62, 6, 64, 30, 12, 27, 89, 130, 116, 190, 28, 38, 135, 149, 164, 48, 173, 175, 71, 132, 68, 5, 111, 158, 24, 59, 26, 145, 118, 51, 37, 178, 69, 189, 163, 133, 98, 53, 29, 169, 188, 17, 180, 155, 73, 45, 22, 107, 104, 76, 143, 70, 88, 99, 124, 126, 34, 80, 10, 168, 66, 72, 123, 63, 140, 176, 49, 65, 50, 52, 122, 4, 181, 121, 57, 18, 101, 42, 179, 100, 157, 165, 106, 156, 95, 170, 174, 117, 109, 102, 186, 148, 3, 134, 96, 67, 150, 151, 153, 11, 83, 1, 105, 25, 144, 8, 108, 84, 78, 97, 141, 60, 16, 112, 7, 82, 93, 46, 137, 35, 103, 61, 113, 129, 20, 119, 92, 31, 154, 115, 56, 44, 90, 14, 131, 160, 2, 36, 21, 23, 110, 152, 187, 0, 184, 41, 183, 120, 146, 47, 114, 32, 81, 75, 39, 91, 136, 167, 172, 58, 147, 125, 86, 138, 94, 33, 79, 159, 87, 55, 171, 85, 182, 191, 9, 19, 74, 13, 142, 40, 139, 15, 128

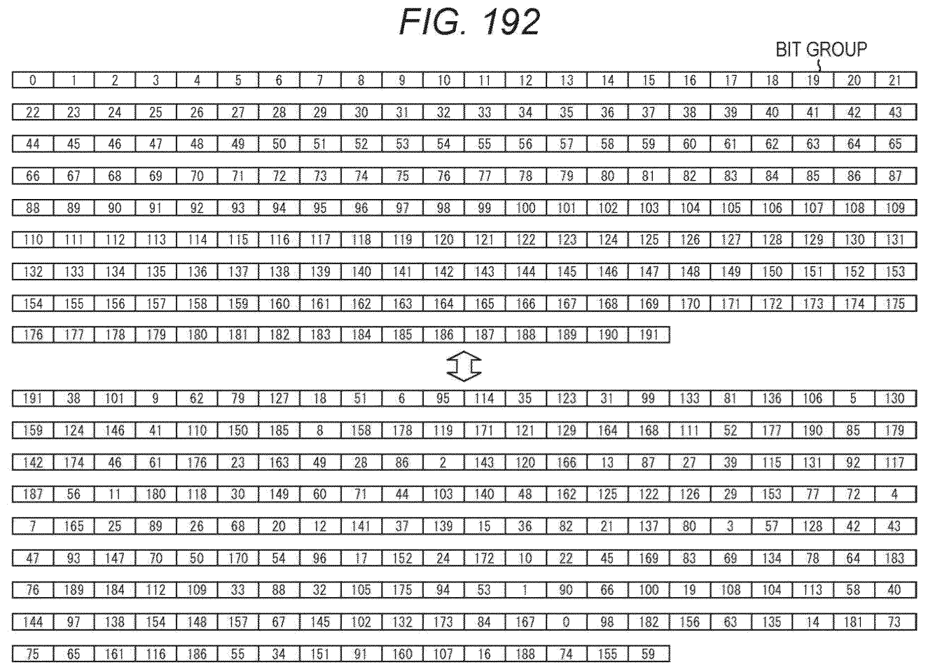

FIG. 192 is a diagram illustrating a seventy third example of the GW pattern for an LDPC code with a code length N of 69120 bits.

According to the GW pattern in FIG. 192, a sequence of bit groups 0 to 191 of the 69120 bit LDPC code is interleaved into a sequence of the following bit group.
191, 38, 101, 9, 62, 79, 127, 18, 51, 6, 95, 114, 35, 123, 31, 99, 133, 81, 136, 106, 5, 130, 159, 124, 146, 41, 110, 150, 185, 8, 158, 178, 119, 171, 121, 129, 164, 168, 111, 52, 177, 190, 85, 179, 142, 174, 46, 61, 176, 23, 163, 49, 28, 86, 2, 143, 120, 166, 13, 87, 27, 39, 115, 131, 92, 117, 187, 56, 11, 180, 118, 30, 149, 60, 71, 44, 103, 140, 48, 162, 125, 122, 126, 29, 153, 77, 72, 4, 7, 165, 25, 89, 26, 68, 20, 12, 141, 37, 139, 15, 36, 82, 21, 137, 80, 3, 57, 128, 42, 43, 47, 93, 147, 70, 50, 170, 54, 96, 17, 152, 24, 172, 10, 22, 45, 169, 83, 69, 134, 78, 64, 183, 76, 189, 184, 112, 109, 33, 88, 32, 105, 175, 94, 53, 1, 90, 66, 100, 19, 108, 104, 113, 58, 40, 144, 97, 138, 154, 148, 157, 67, 145, 102, 132, 173, 84, 167, 0, 98, 182, 156, 63, 135, 14, 181, 73, 75, 65, 161, 116, 186, 55, 34, 151, 91, 160, 107, 16, 188, 74, 155, 59

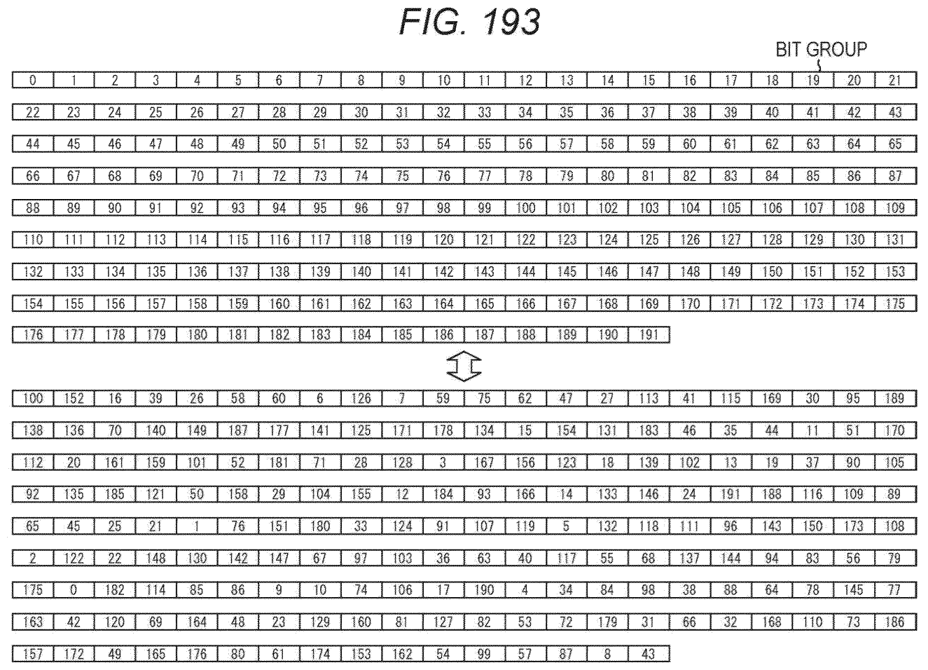

FIG. 193 is a diagram illustrating a seventy fourth example of the GW pattern for an LDPC code with a code length N of 69120 bits.

According to the GW pattern in FIG. 193, a sequence of bit groups 0 to 191 of the 69120 bit LDPC code is interleaved into a sequence of the following bit group.
100, 152, 16, 39, 26, 58, 60, 6, 126, 7, 59, 75, 62, 47, 27, 113, 41, 115, 169, 30, 95, 189, 138, 136, 70, 140, 149, 187, 177, 141, 125, 171, 178, 134, 15, 154, 131, 183, 46, 35, 44, 11, 51, 170, 112, 20, 161, 159, 101, 52, 181, 71, 28, 128, 3, 167, 156, 123, 18, 139, 102, 13, 19, 37, 90, 105, 92, 135, 185, 121, 50, 158, 29, 104, 155, 12, 184, 93, 166, 14, 133, 146, 24, 191, 188, 116, 109, 89, 65, 45, 25, 21, 1, 76, 151, 180, 33, 124, 91, 107, 119, 5, 132, 118, 111, 96, 143, 150, 173, 108, 2, 122, 22, 148, 130, 142, 147, 67, 97, 103, 36, 63, 40, 117, 55, 68, 137, 144, 94, 83, 56, 79, 175, 0, 182, 114, 85, 86, 9, 10, 74, 106, 17, 190, 4, 34, 84, 98, 38, 88, 64, 78, 145, 77, 163, 42, 120, 69, 164, 48, 23, 129, 160, 81, 127, 82, 53, 72, 179, 31, 66, 32, 168, 110, 73, 186, 157, 172, 49, 165, 176, 80, 61, 174, 153, 162, 54, 99, 57, 87, 8, 43

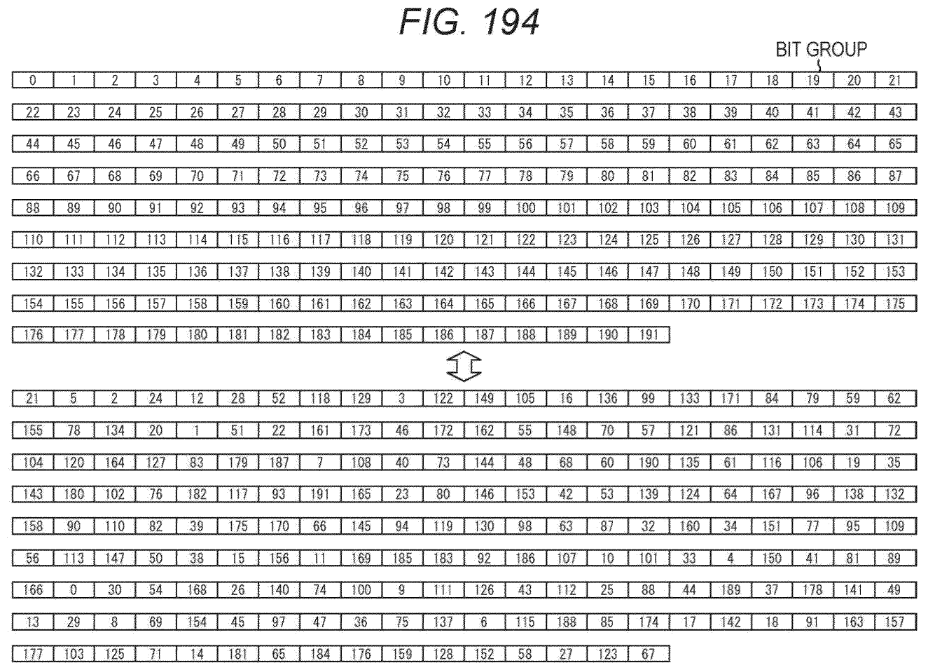

FIG. 194 is a diagram illustrating a seventy fifth example of the GW pattern for an LDPC code with a code length N of 69120 bits.

According to the GW pattern in FIG. 194, a sequence of bit groups 0 to 191 of the 69120 bit LDPC code is interleaved into a sequence of the following bit group.
21, 5, 2, 24, 12, 28, 52, 118, 129, 3, 122, 149, 105, 16, 136, 99, 133, 171, 84, 79, 59, 62, 155, 78, 134, 20, 1, 51, 22, 161, 173, 46, 172, 162, 55, 148, 70, 57, 121, 86, 131, 114, 31, 72, 104, 120, 164, 127, 83, 179, 187, 7, 108, 40, 73, 144, 48, 68, 60, 190, 135, 61, 116, 106, 19, 35, 143, 180, 102, 76, 182, 117, 93, 191, 165, 23, 80, 146, 153, 42, 53, 139, 124, 64, 167, 96, 138, 132, 158, 90, 110, 82, 39, 175, 170, 66, 145, 94, 119, 130, 98, 63, 87, 32, 160, 34, 151, 77, 95, 109, 56, 113, 147, 50, 38, 15, 156, 11, 169, 185, 183, 92, 186, 107, 10, 101, 33, 4, 150, 41, 81, 89, 166, 0, 30, 54, 168, 26, 140, 74, 100, 9, 111, 126, 43, 112, 25, 88, 44, 189, 37, 178, 141, 49, 13, 29, 8, 69, 154, 45, 97, 47, 36, 75, 137, 6, 115, 188, 85, 174, 17, 142, 18, 91, 163, 157, 177, 103, 125, 71, 14, 181, 65, 184, 176, 159, 128, 152, 58, 27, 123, 67

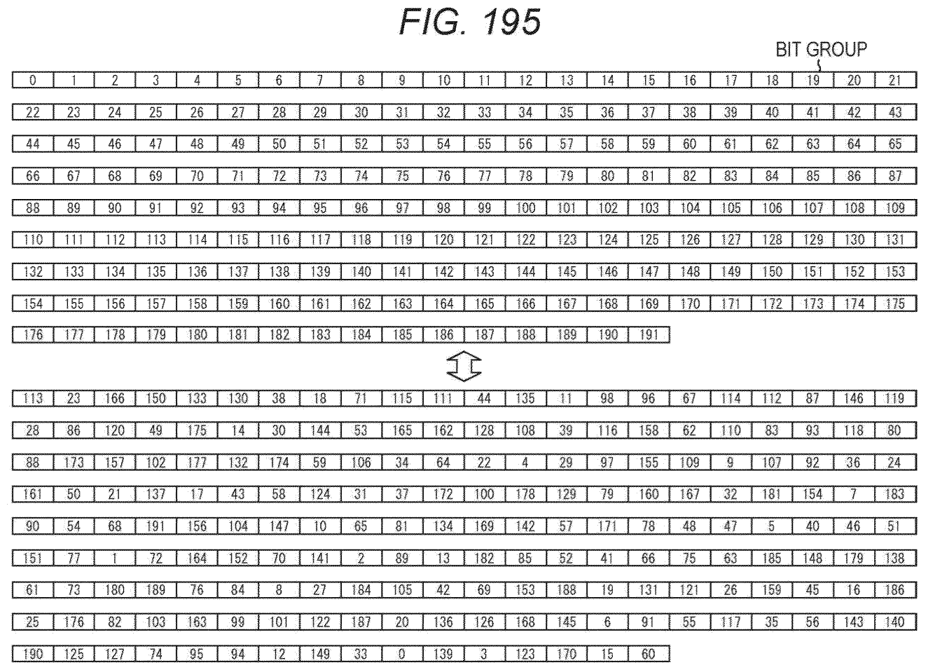

FIG. 195 is a diagram illustrating a seventy sixth example of the GW pattern for an LDPC code with a code length N of 69120 bits.

According to the GW pattern in FIG. 195, a sequence of bit groups 0 to 191 of the 69120 bit LDPC code is interleaved into a sequence of the following bit group.
113, 23, 166, 150, 133, 130, 38, 18, 71, 115, 111, 44, 135, 11, 98, 96, 67, 114, 112, 87, 146, 119, 28, 86, 120, 49, 175, 14, 30, 144, 53, 165, 162, 128, 108, 39, 116, 158, 62, 110, 83, 93, 118, 80, 88, 173, 157, 102, 177, 132, 174, 59, 106, 34, 64, 22, 4, 29, 97, 155, 109, 9, 107, 92, 36, 24, 161, 50, 21, 137, 17, 43, 58, 124, 31, 37, 172, 100, 178, 129, 79, 160, 167, 32, 181, 154, 7, 183, 90, 54, 68, 191, 156, 104, 147, 10, 65, 81, 134, 169, 142, 57, 171, 78, 48, 47, 5, 40, 46, 51, 151, 77, 1, 72, 164, 152, 70, 141, 2, 89, 13, 182, 85, 52, 41, 66, 75, 63, 185, 148, 179, 138, 61, 73, 180, 189, 76, 84, 8, 27, 184, 105, 42, 69, 153, 188, 19, 131, 121, 26, 159, 45, 16, 186, 25, 176, 82, 103, 163, 99, 101, 122, 187, 20, 136, 126, 168, 145, 6, 91, 55, 117, 35, 56, 143, 140, 190, 125, 127, 74, 95, 94, 12, 149, 33, 0, 139, 3, 123, 170, 15, 60

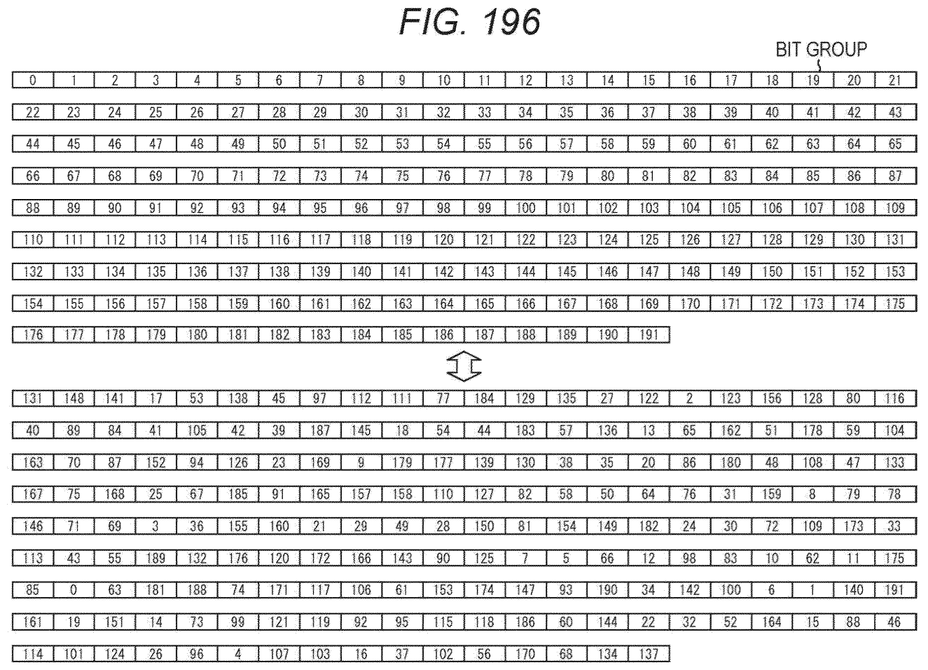

FIG. 196 is a diagram illustrating a seventy seventh example of the GW pattern for an LDPC code with a code length N of 69120 bits.

According to the GW pattern in FIG. 196, a sequence of bit groups 0 to 191 of the 69120 bit LDPC code is interleaved into a sequence of the following bit group.
131, 148, 141, 17, 53, 138, 45, 97, 112, 111, 77, 184, 129, 135, 27, 122, 2, 123, 156, 128, 80, 116, 40, 89, 84, 41, 105, 42, 39, 187, 145, 18, 54, 44, 183, 57, 136, 13, 65, 162, 51, 178, 59, 104, 163, 70, 87, 152, 94, 126, 23, 169, 9, 179, 177, 139, 130, 38, 35, 20, 86, 180, 48, 108, 47, 133, 167, 75, 168, 25, 67, 185, 91, 165, 157, 158, 110, 127, 82, 58, 50, 64, 76, 31, 159, 8, 79, 78, 146, 71, 69, 3, 36, 155, 160, 21, 29, 49, 28, 150, 81, 154, 149, 182, 24, 30, 72, 109, 173, 33, 113, 43, 55, 189, 132, 176, 120, 172, 166, 143, 90, 125, 7, 5, 66, 12, 98, 83, 10, 62, 11, 175, 85, 0, 63, 181, 188, 74, 171, 117, 106, 61, 153, 174, 147, 93, 190, 34, 142, 100, 6, 1, 140, 191, 161, 19, 151, 14, 73, 99, 121, 119, 92, 95, 115, 118, 186, 60, 144, 22, 32, 52, 164, 15, 88, 46, 114, 101, 124, 26, 96, 4, 107, 103, 16, 37, 102, 56, 170, 68, 134, 137

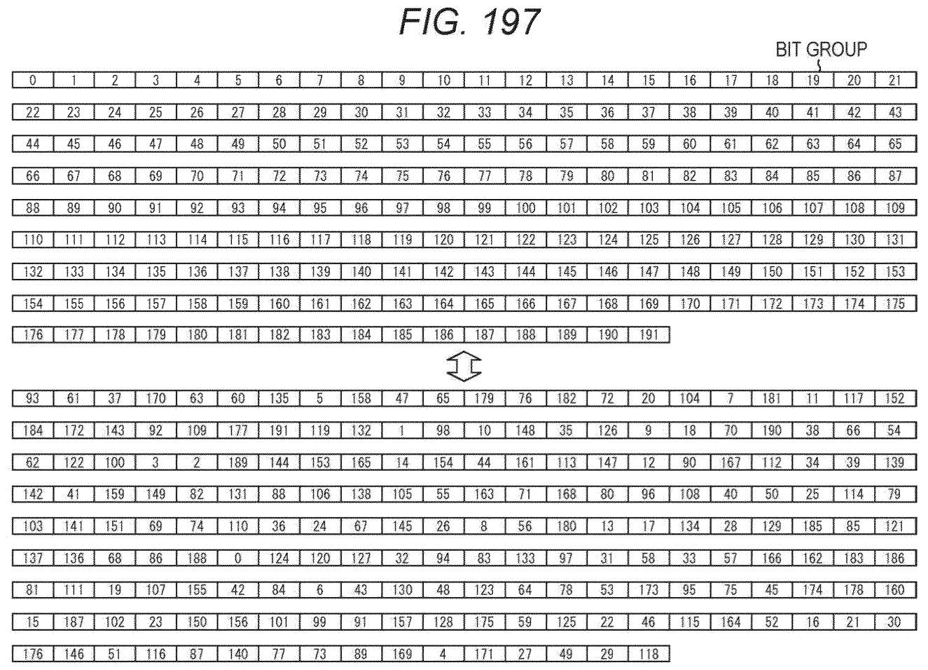

FIG. 197 is a diagram illustrating a seventy eighth example of the GW pattern for an LDPC code with a code length N of 69120 bits.

According to the GW pattern in FIG. 197, a sequence of bit groups 0 to 191 of the 69120 bit LDPC code is interleaved into a sequence of the following bit group.
93, 61, 37, 170, 63, 60, 135, 5, 158, 47, 65, 179, 76, 182, 72, 20, 104, 7, 181, 11, 117, 152, 184, 172, 143, 92, 109, 177, 191, 119, 132, 1, 98, 10, 148, 35, 126, 9, 18, 70, 190, 38, 66, 54, 62, 122, 100, 3, 2, 189, 144, 153, 165, 14, 154, 44, 161, 113, 147, 12, 90, 167, 112, 34, 39, 139, 142, 41, 159, 149, 82, 131, 88, 106, 138, 105, 55, 163, 71, 168, 80, 96, 108, 40, 50, 25, 114, 79, 103, 141, 151, 69, 74, 110, 36, 24, 67, 145, 26, 8, 56, 180, 13, 17, 134, 28, 129, 185, 85, 121, 137, 136, 68, 86, 188, 0, 124, 120, 127, 32, 94, 83, 133, 97, 31, 58, 33, 57, 166, 162, 183, 186, 81, 111, 19, 107, 155, 42, 84, 6, 43, 130, 48, 123, 64, 78, 53, 173, 95, 75, 45, 174, 178, 160, 15, 187, 102, 23, 150, 156, 101, 99, 91, 157, 128, 175, 59, 125, 22, 46, 115, 164, 52, 16, 21, 30, 176, 146, 51, 116, 87, 140, 77, 73, 89, 169, 4, 171, 27, 49, 29, 118

The first to the seventy eighth examples of the GW pattern for the LDPC code with the code length N of 69120 bits described above can be applied to any combination of an LDPC code with the code length N of 69120 bits and an arbitrary coding rate r, an arbitrary modulation method, and an arbitrary constellation.

However, in the group-wise interleaving, the error rate can be further improved for each combination by setting the GW pattern to be applied for each combination of the code length N of the LDPC code, the coding rate r of the LDPC code, the modulation method, and the constellation.

The GW pattern in FIG. 120 is applied to, for example, a combination of the LDPC code with N=69120 and r=2/16 (LDPC code with code length N of 69120 and coding rate r of 2/16) in FIG. 30 (corresponding to the parity check matrix initial value table), QPSK, and QPSK-UC in FIGS. 96 and 97, thereby achieving a particularly favorable error rate.

The GW pattern in FIG. 121 is applied to, for example, a combination of the LDPC code with N=69120 and r=3/16 in FIGS. 31 and 32, QPSK, and QPSK-UC in FIGS. 96 and 97, thereby achieving a particularly favorable error rate.

The GW pattern in FIG. 122 is applied to, for example, a combination of the LDPC code with N=69120 and r=4/16 in FIG. 33, QPSK, and QPSK-UC in FIGS. 96 and 97, thereby achieving a particularly favorable error rate.

The GW pattern in FIG. 123 is applied to, for example, a combination of the LDPC code with N=69120 and r=5/16 in FIGS. 34 and 35, QPSK, and QPSK-UC in FIGS. 96 and 97, thereby achieving a particularly favorable error rate.

The GW pattern in FIG. 124 is applied to, for example, a combination of the LDPC code with N=69120 and r=6/16 in FIGS. 36 and 37, QPSK, and QPSK-UC in FIGS. 96 and 97, thereby achieving a particularly favorable error rate.

The GW pattern in FIG. 125 is applied to, for example, a combination of the LDPC code with N=69120 and r=7/16 in FIGS. 38 and 39, QPSK, and QPSK-UC in FIGS. 96 and 97, thereby achieving a particularly favorable error rate.

The GW pattern in FIG. 126 is applied to, for example, a combination of the LDPC code with N=69120 and r=8/16 in FIGS. 46 and 47, QPSK, and QPSK-UC in FIGS. 96 and 97, thereby achieving a particularly favorable error rate.

The GW pattern in FIG. 127 is applied to, for example, a combination of the LDPC code with N=69120 and r=9/16 in FIGS. 50 to 52, QPSK, and QPSK-UC in FIGS. 96 and 97, thereby achieving a particularly favorable error rate.

The GW pattern in FIG. 128 is applied to, for example, a combination of the LDPC code with N=69120 and r=10/16 in FIGS. 56 to 58, QPSK, and QPSK-UC in FIGS. 96 and 97, thereby achieving a particularly favorable error rate.

The GW pattern in FIG. 129 is applied to, for example, a combination of the LDPC code with N=69120 and r=11/16 in FIGS. 62 to 64, QPSK, and QPSK-UC in FIGS. 96 and 97, thereby achieving a particularly favorable error rate.

The GW pattern in FIG. 130 is applied to, for example, a combination of the LDPC code with N=69120 and r=12/16 in FIGS. 68 to 70, QPSK, and QPSK-UC in FIGS. 96 and 97, thereby achieving a particularly favorable error rate.

The GW pattern in FIG. 131 is applied to, for example, a combination of the LDPC code with N=69120 and r=13/16 in FIGS. 74 to 76, QPSK, and QPSK-UC in FIGS. 96 and 97, thereby achieving a particularly favorable error rate.

The GW pattern in FIG. 132 is applied to, for example, a combination of the LDPC code with N=69120 and r=14/16 in FIGS. 80 to 82, QPSK, and QPSK-UC in FIGS. 96 and 97, thereby achieving a particularly favorable error rate.

The GW pattern in FIG. 133 is applied to, for example, a combination of the LDPC code with N=69120 and r=3/16 in FIGS. 31 and 32, 16QAM, and 16QAM-UC in FIGS. 98 and 99, thereby achieving a particularly favorable error rate.

The GW pattern in FIG. 134 is applied to, for example, a combination of the LDPC code with N=69120 and r=5/16 in FIGS. 34 and 35, 16QAM, and 16QAM-UC in FIGS. 98 and 99, thereby achieving a particularly favorable error rate.

The GW pattern in FIG. 135 is applied to, for example, a combination of the LDPC code with N=69120 and r=7/16 in FIGS. 38 and 39, 16QAM, and 16QAM-UC in FIGS. 98 and 99, thereby achieving a particularly favorable error rate.

The GW pattern in FIG. 136 is applied to, for example, a combination of the LDPC code with N=69120 and r=9/16 in FIGS. 50 to 52, 16QAM, and 16QAM-UC in FIGS. 98 and 99, thereby achieving a particularly favorable error rate.

The GW pattern in FIG. 137 is applied to, for example, a combination of the LDPC code with N=69120 and r=11/16 in FIGS. 62 to 64, 16QAM, and 16QAM-UC in FIGS. 98 and 99, thereby achieving a particularly favorable error rate.

The GW pattern in FIG. 138 is applied to, for example, a combination of the LDPC code with N=69120 and r=13/16 in FIGS. 74 to 76, 16QAM, and 16QAM-UC in FIGS. 98 and 99, thereby achieving a particularly favorable error rate.

The GW pattern in FIG. 139 is applied to, for example, a combination of the LDPC code with N=69120 and r=2/16 in FIG. 30, 64QAM, and 64QAM-UC in FIGS. 100 and 101, thereby achieving a particularly favorable error rate.

The GW pattern in FIG. 140 is applied to, for example, a combination of the LDPC code with N=69120 and r=4/16 in FIG. 33, 64QAM, and 64QAM-UC in FIGS. 100 and 101, thereby achieving a particularly favorable error rate.

The GW pattern in FIG. 141 is applied to, for example, a combination of the LDPC code with N=69120 and r=6/16 in FIGS. 36 and 37, 64QAM, and 64QAM-UC in FIGS. 100 and 101, thereby achieving a particularly favorable error rate.

The GW pattern in FIG. 142 is applied to, for example, a combination of the LDPC code with N=69120 and r=8/16 in FIGS. 46 and 47, 64QAM, and 64QAM-UC in FIGS. 100 and 101, thereby achieving a particularly favorable error rate.

The GW pattern in FIG. 143 is applied to, for example, a combination of the LDPC code with N=69120 and r=10/16 in FIGS. 56 to 58, 64QAM, and 64QAM-UC in FIGS. 100 and 101, thereby achieving a particularly favorable error rate.

The GW pattern in FIG. 144 is applied to, for example, a combination of the LDPC code with N=69120 and r=12/16 in FIGS. 68 to 70, 64QAM, and 64QAM-UC in FIGS. 100 and 101, thereby achieving a particularly favorable error rate.

The GW pattern in FIG. 145 is applied to, for example, a combination of the LDPC code with N=69120 and r=14/16 in FIGS. 80 to 82, 64QAM, and 64QAM-UC in FIGS. 100 and 101, thereby achieving a particularly favorable error rate.

The GW pattern in FIG. 146 is applied to, for example, a combination of the LDPC code with N=69120 and r=3/16 in FIGS. 31 and 32, 256QAM, and 256QAM-UC in FIGS. 102 and 103, thereby achieving a particularly favorable error rate.

The GW pattern in FIG. 147 is applied to, for example, a combination of the LDPC code with N=69120 and r=5/16 in FIGS. 34 and 35, 256QAM, and 256QAM-UC in FIGS. 102 and 103, thereby achieving a particularly favorable error rate.

The GW pattern in FIG. 148 is applied to, for example, a combination of the LDPC code with N=69120 and r=7/16 in FIGS. 38 and 39, 256QAM, and 256QAM-UC in FIGS. 102 and 103, thereby achieving a particularly favorable error rate.

The GW pattern in FIG. 149 is applied to, for example, a combination of the LDPC code with N=69120 and r=9/16 in FIGS. 50 to 52, 256QAM, and 256QAM-UC in FIGS. 102 and 103, thereby achieving a particularly favorable error rate.

The GW pattern in FIG. 150 is applied to, for example, a combination of the LDPC code with N=69120 and r=11/16 in FIGS. 62 to 64, 256QAM, and 256QAM-UC in FIGS. 102 and 103, thereby achieving a particularly favorable error rate.

The GW pattern in FIG. 151 is applied to, for example, a combination of the LDPC code with N=69120 and r=13/16 in FIGS. 74 to 76, 256QAM, and 256QAM-UC in FIGS. 102 and 103, thereby achieving a particularly favorable error rate.

The GW pattern in FIG. 152 is applied to, for example, a combination of the LDPC code with N=69120 and r=2/16 in FIG. 30, 1024QAM, and 1024QAM-UC in FIGS. 104 and 105, thereby achieving a particularly favorable error rate.

The GW pattern in FIG. 153 is applied to, for example, a combination of the LDPC code with N=69120 and r=4/16 in FIG. 33, 1024QAM, and 1024QAM-UC in FIGS. 104 and 105, thereby achieving a particularly favorable error rate.

The GW pattern in FIG. 154 is applied to, for example, a combination of the LDPC code with N=69120 and r=6/16 in FIGS. 36 and 37, 1024QAM, and 1024QAM-UC in FIGS. 104 and 105, thereby achieving a particularly favorable error rate.

The GW pattern in FIG. 155 is applied to, for example, a combination of the LDPC code with N=69120 and r=8/16 in FIGS. 46 and 47, 1024QAM, and 1024QAM-UC in FIGS. 104 and 105, thereby achieving a particularly favorable error rate.

The GW pattern in FIG. 156 is applied to, for example, a combination of the LDPC code with N=69120 and r=10/16 in FIGS. 56 to 58, 1024QAM, and 1024QAM-UC in FIGS. 104 and 105, thereby achieving a particularly favorable error rate.

The GW pattern in FIG. 157 is applied to, for example, a combination of the LDPC code with N=69120 and r=12/16 in FIGS. 68 to 70, 1024QAM, and 1024QAM-UC in FIGS. 104 and 105, thereby achieving a particularly favorable error rate.

The GW pattern in FIG. 158 is applied to, for example, a combination of the LDPC code with N=69120 and r=14/16 in FIGS. 80 to 82, 1024QAM, and 1024QAM-UC in FIGS. 104 and 105, thereby achieving a particularly favorable error rate.

The GW pattern in FIG. 159 is applied to, for example, a combination of the LDPC code with N=69120 and r=3/16 in FIGS. 31 and 32, 4096QAM, and 4096QAM-UC in FIGS. 106 and 107, thereby achieving a particularly favorable error rate.

The GW pattern in FIG. 160 is applied to, for example, a combination of the LDPC code with N=69120 and r=5/16 in FIGS. 34 and 35, 4096QAM, and 4096QAM-UC in FIGS. 106 and 107, thereby achieving a particularly favorable error rate.

The GW pattern in FIG. 161 is applied to, for example, a combination of the LDPC code with N=69120 and r=7/16 in FIGS. 38 and 39, 4096QAM, and 4096QAM-UC in FIGS. 106 and 107, thereby achieving a particularly favorable error rate.

The GW pattern in FIG. 162 is applied to, for example, a combination of the LDPC code with N=69120 and r=9/16 in FIGS. 50 to 52, 4096QAM, and 4096QAM-UC in FIGS. 106 and 107, thereby achieving a particularly favorable error rate.

The GW pattern in FIG. 163 is applied to, for example, a combination of the LDPC code with N=69120 and r=11/16 in FIGS. 62 to 64, 4096QAM, and 4096QAM-UC in FIGS. 106 and 107, thereby achieving a particularly favorable error rate.

The GW pattern in FIG. 164 is applied to, for example, a combination of the LDPC code with N=69120 and r=13/16 in FIGS. 74 to 76, 4096QAM, and 4096QAM-UC in FIGS. 106 and 107, thereby achieving a particularly favorable error rate.

The GW pattern in FIG. 165 is applied to, for example, a combination of the LDPC code with N=69120 and r=2/16 in FIG. 30, 16QAM, and 16QAM-2D-NUC in FIG. 108, thereby achieving a particularly favorable error rate.

The GW pattern in FIG. 166 is applied to, for example, a combination of the LDPC code with N=69120 and r=4/16 in FIG. 33, 16QAM, and 16QAM-2D-NUC in FIG. 108, thereby achieving a particularly favorable error rate.

The GW pattern in FIG. 167 is applied to, for example, a combination of the LDPC code with N=69120 and r=6/16 in FIGS. 36 and 37, 16QAM, and 16QAM-2D-NUC in FIG. 108, thereby achieving a particularly favorable error rate.

The GW pattern in FIG. 168 is applied to, for example, a combination of the LDPC code with N=69120 and r=8/16 in FIGS. 46 and 47, 16QAM, and 16QAM-2D-NUC in FIG. 108, thereby achieving a particularly favorable error rate.

The GW pattern in FIG. 169 is applied to, for example, a combination of the LDPC code with N=69120 and r=10/16 in FIGS. 56 to 58, 16QAM, and 16QAM-2D-NUC in FIG. 108, thereby achieving a particularly favorable error rate.

The GW pattern in FIG. 170 is applied to, for example, a combination of the LDPC code with N=69120 and r=12/16 in FIGS. 68 to 70, 16QAM, and 16QAM-2D-NUC in FIG. 108, thereby achieving a particularly favorable error rate.

The GW pattern in FIG. 171 is applied to, for example, a combination of the LDPC code with N=69120 and r=14/16 in FIGS. 80 to 82, 16QAM, and 16QAM-2D-NUC in FIG. 108, thereby achieving a particularly favorable error rate.

The GW pattern in FIG. 172 is applied to, for example, a combination of the LDPC code with N=69120 and r=3/16 in FIGS. 31 and 32, 64QAM, and 64QAM-2D-NUC in FIG. 109, thereby achieving a particularly favorable error rate.

The GW pattern in FIG. 173 is applied to, for example, a combination of the LDPC code with N=69120 and r=5/16 in FIGS. 34 and 35, 64QAM, and 64QAM-2D-NUC in FIG. 109, thereby achieving a particularly favorable error rate.

The GW pattern in FIG. 174 is applied to, for example, a combination of the LDPC code with N=69120 and r=7/16 in FIGS. 38 and 39, 64QAM, and 64QAM-2D-NUC in FIG. 109, thereby achieving a particularly favorable error rate.

The GW pattern in FIG. 175 is applied to, for example, a combination of the LDPC code with N=69120 and r=9/16 in FIGS. 50 to 52, 64QAM, and 64QAM-2D-NUC in FIG. 109, thereby achieving a particularly favorable error rate.

The GW pattern in FIG. 176 is applied to, for example, a combination of the LDPC code with N=69120 and r=11/16 in FIGS. 62 to 64, 64QAM, and 64QAM-2D-NUC in FIG. 109, thereby achieving a particularly favorable error rate.

The GW pattern in FIG. 177 is applied to, for example, a combination of the LDPC code with N=69120 and r=13/16 in FIGS. 74 to 76, 64QAM, and 64QAM-2D-NUC in FIG. 109, thereby achieving a particularly favorable error rate.

The GW pattern in FIG. 178 is applied to, for example, a combination of the LDPC code with N=69120 and r=2/16 in FIG. 30, 256QAM, and 256QAM-2D-NUC in FIGS. 110 and 111, thereby achieving a particularly favorable error rate.

The GW pattern in FIG. 179 is applied to, for example, a combination of the LDPC code with N=69120 and r=4/16 in FIG. 33, 256QAM, and 256QAM-2D-NUC in FIGS. 110 and 111, thereby achieving a particularly favorable error rate.

The GW pattern in FIG. 180 is applied to, for example, a combination of the LDPC code with N=69120 and r=6/16 in FIGS. 36 and 37, 256QAM, and 256QAM-2D-NUC in FIGS. 110 and 111, thereby achieving a particularly favorable error rate.

The GW pattern in FIG. 181 is applied to, for example, a combination of the LDPC code with N=69120 and r=8/16 in FIGS. 46 and 47, 256QAM, and 256QAM-2D-NUC in FIGS. 110 and 111, thereby achieving a particularly favorable error rate.

The GW pattern in FIG. 182 is applied to, for example, a combination of the LDPC code with N=69120 and r=10/16 in FIGS. 56 to 58, 256QAM, and 256QAM-2D-NUC in FIGS. 110 and 111, thereby achieving a particularly favorable error rate.

The GW pattern in FIG. 183 is applied to, for example, a combination of the LDPC code with N=69120 and r=12/16 in FIGS. 68 to 70, 256QAM, and 256QAM-2D-NUC in FIGS. 110 and 111, thereby achieving a particularly favorable error rate.

The GW pattern in FIG. 184 is applied to, for example, a combination of the LDPC code with N=69120 and r=14/16 in FIGS. 80 to 82, 256QAM, and 256QAM-2D-NUC in FIGS. 110 and 111, thereby achieving a particularly favorable error rate.

The GW pattern in FIG. 185 is applied to, for example, a combination of the LDPC code with N=69120 and r=3/16 in FIGS. 31 and 32, 1024QAM, and 1024QAM-1D-NUC in FIGS. 112 and 113, thereby achieving a particularly favorable error rate.

The GW pattern in FIG. 186 is applied to, for example, a combination of the LDPC code with N=69120 and r=5/16 in FIGS. 34 and 35, 1024QAM, and 1024QAM-1D-NUC in FIGS. 112 and 113, thereby achieving a particularly favorable error rate.

The GW pattern in FIG. 187 is applied to, for example, a combination of the LDPC code with N=69120 and r=7/16 in FIGS. 38 and 39, 1024QAM, and 1024QAM-1D-NUC in FIGS. 112 and 113, thereby achieving a particularly favorable error rate.

The GW pattern in FIG. 188 is applied to, for example, a combination of the LDPC code with N=69120 and r=9/16 in FIGS. 50 to 52, 1024QAM, and 1024QAM-1D-NUC in FIGS. 112 and 113, thereby achieving a particularly favorable error rate.

The GW pattern in FIG. 189 is applied to, for example, a combination of the LDPC code with N=69120 and r=11/16 in FIGS. 62 to 64, 1024QAM, and 1024QAM-1D-NUC in FIGS. 112 and 113, thereby achieving a particularly favorable error rate.

The GW pattern in FIG. 190 is applied to, for example, a combination of the LDPC code with N=69120 and r=13/16 in FIGS. 74 to 76, 1024QAM, and 1024QAM-1D-NUC in FIGS. 112 and 113, thereby achieving a particularly favorable error rate.

The GW pattern in FIG. 191 is applied to, for example, a combination of the LDPC code with N=69120 and r=2/16 in FIG. 30, 4096QAM, and 4096QAM-1D-NUC in FIGS. 114 to 116, thereby achieving a particularly favorable error rate.

The GW pattern in FIG. 192 is applied to, for example, a combination of the LDPC code with N=69120 and r=4/16 in FIG. 33, 4096QAM, and 4096QAM-1D-NUC in FIGS. 114 to 116, thereby achieving a particularly favorable error rate.

The GW pattern in FIG. 193 is applied to, for example, a combination of the LDPC code with N=69120 and r=6/16 in FIGS. 36 and 37, 4096QAM, and 4096QAM-1D-NUC in FIGS. 114 to 116, thereby achieving a particularly favorable error rate.

The GW pattern in FIG. 194 is applied to, for example, a combination of the LDPC code with N=69120 and r=8/16 in FIGS. 46 and 47, 4096QAM, and 4096QAM-1D-NUC in FIGS. 114 to 116, thereby achieving a particularly favorable error rate.

The GW pattern in FIG. 195 is applied to, for example, a combination of the LDPC code with N=69120 and r=10/16 in FIGS. 56 to 58, 4096QAM, and 4096QAM-1D-NUC in FIGS. 114 to 116, thereby achieving a particularly favorable error rate.

The GW pattern in FIG. 196 is applied to, for example, a combination of the LDPC code with N=69120 and r=12/16 in FIGS. 68 to 70, 4096QAM, and 4096QAM-1D-NUC in FIGS. 114 to 116, thereby achieving a particularly favorable error rate.

The GW pattern in FIG. 197 is applied to, for example, a combination of the LDPC code with N=69120 and r=14/16 in FIGS. 80 to 82, 4096QAM, and 4096QAM-1D-NUC in FIGS. 114 to 116, thereby achieving a particularly favorable error rate.

### <Another Example of Constellation and GW Pattern>

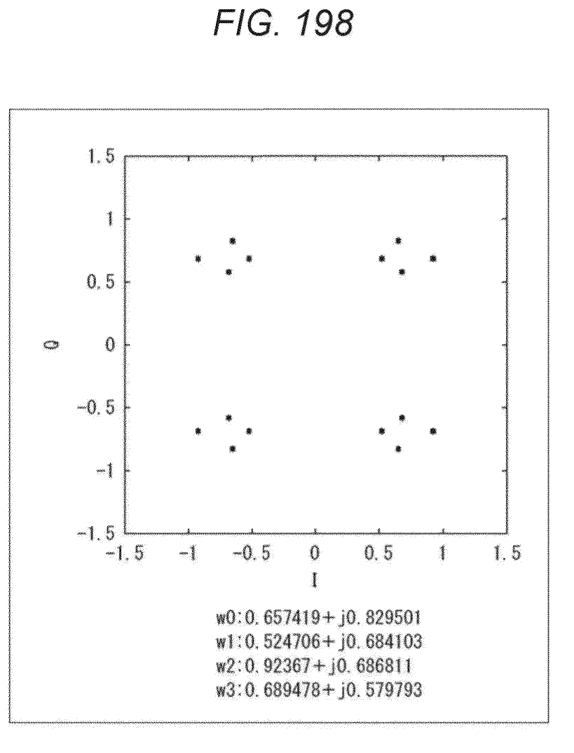

FIG. 198 is a diagram illustrating examples of coordinates of signal points of another 16QAM-2D-NUC that can be used for the new LDPC code.

In FIG. 198, the horizontal axis represents the real axis direction, and the vertical axis represents the imaginary axis direction.

FIG. 198 is a diagram illustrating examples of coordinates of signal points of another 16QAM-2D-NUC (hereinafter, also referred to as new 16QAM-2D-NUC) that can be used for the type A code with r=4/16 and the code length N of 69120 bits for example in FIG. 33, in particular.

The coordinates of a signal point of 16QAM-2D-NUC (hereinafter, also referred to as old 16QAM-2D-NUC) that can be used for the type A code with r=4/16 and the code length N of 69120 bits in FIG. 33 illustrated in FIG. 108 are coordinates represented by w0=w1=w2=w3=0.707107+j0.707107.

On the other hand, the coordinates of the signal point of the new 16QAM-2D-NUC are coordinates represented by w0=0.657419+j0.829501, w1=0.524706+j0.684103, w2=0.92367+j0.686811, and w3=0.689478+j0.579793.

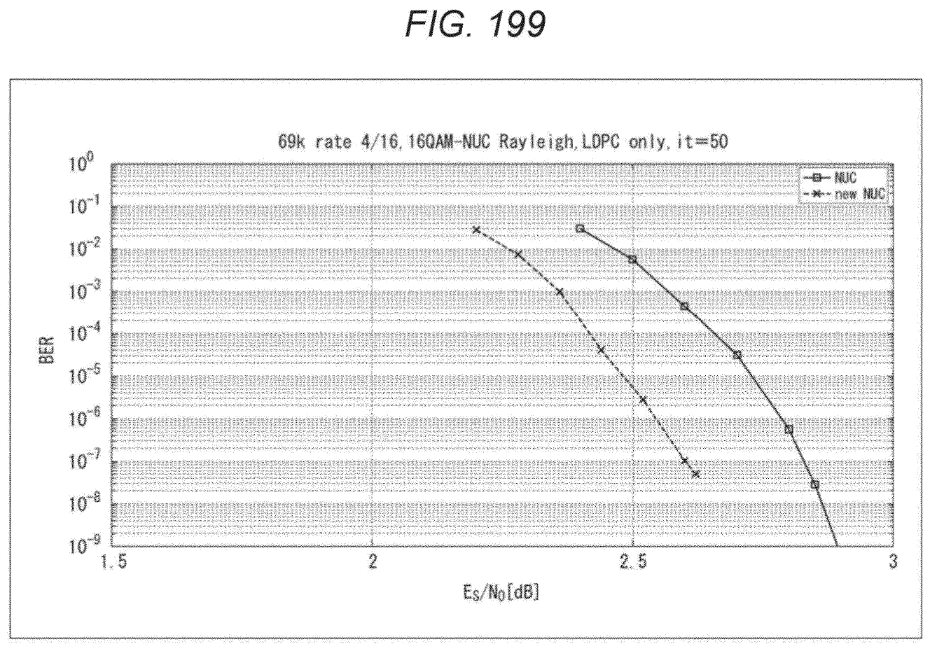

FIG. 199 is a diagram illustrating simulation results of BER in a case where old 16QAM-2D-NUC is applied to the type A code with the code length N of 69120 bits and r=4/16 in FIG. 33 and in a case where new 16QAM-2D-NUC is applied.

In FIG. 199, the horizontal axis represents Eₛ/N₀ (signal power to noise power ratio per symbol), and the vertical axis represents BER.

As described above, the GW pattern in FIG. 166 is applied to the combination of the type A code with the code length N of 69120 bits and r=4/16 in FIG. 33, 16QAM, and the old 16QAM-2D-NUC in FIG. 108, whereby a good error rate can be achieved.

Therefore, FIG. 199 illustrates simulation results of the BER (In the drawing, quadrangles are shown.) in a case where the GW pattern in FIG. 166 is adopted as the GW pattern applied to the type A code with the code length N of 69120 bits and r=4/16 in FIG. 33, and the old 16QAM-2D-NUC in FIG. 108 is applied to the 33 combination of the type A code with the code length N of 69120 bits and r=4/16, 16QAM, and the GW pattern in FIG. 166, and the BER (In the drawing, cross marks are used.) in a case where the new 16QAM-2D-NUC in FIG. 198 is applied.

In the simulation, a Rayleigh fading communication path (channel) is adopted as the communication path 13.

Because the Rayleigh fading communication path is similar to a multipath environment, improving the BER in the Rayleigh fading channel can improve the gain in a case where the transmission system of FIG. 7 is used in a multipath environment.

According to FIG. 199, it can be confirmed that a better BER is obtained in the case of applying the new 16QAM-2D-NUC than in the case of applying the old 16QAM-2D-NUC, that is, the BER becomes lower at the same Eₛ/N₀.

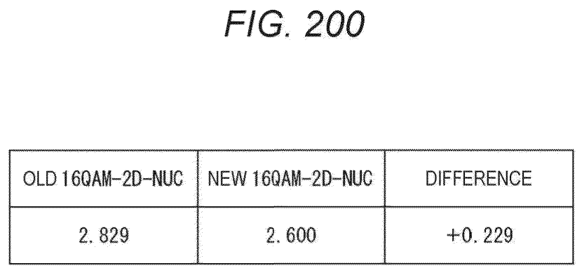

FIG. 200 is a diagram illustrating simulation results of the required carrier-to-noise ratio (CNR) of the type A code with the code length N of 69120 bits and r=4/16 in FIG. 33.

The required CNR is a minimum CNR capable of achieving a certain BER, and here, for example, is a CNR capable of achieving BER=1E−7.

FIG. 200 illustrates simulation results of the required CNR in a case where the old 16QAM-2D-NUC is applied to the 33 combination of the type A code with the code length N of 69120 bits and r=4/16, 16QAM, and the GW pattern in FIG. 166 and the required CNR in a case where the new 16QAM-2D-NUC is applied.

According to FIG. 200, the required CNR can be improved by 0.229 dB indicated by the difference in the case of applying the new 16QAM-2D-NUC compared with the case of applying the old 16QAM-2D-NUC.

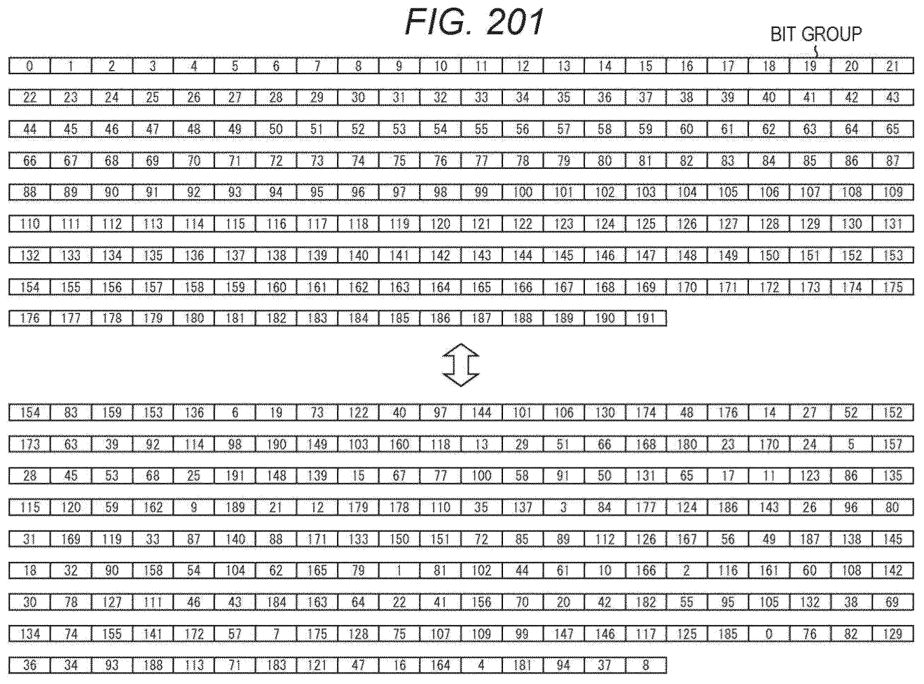

FIG. 201 is a diagram illustrating a seventy ninth example of the GW pattern for an LDPC code with a code length N of 69120 bits.

According to the GW pattern (Hereinafter, it is also referred to as a new GW pattern.) illustrated in FIG. 201, a sequence of bit groups 0 to 191 of the 69120 bit LDPC code is interleaved into a sequence of the following bit group.
154, 83, 159, 153, 136, 6, 19, 73, 122, 40, 97, 144, 101, 106, 130, 174, 48, 176, 14, 27, 52, 152, 173, 63, 39, 92, 114, 98, 190, 149, 103, 160, 118, 13, 29, 51, 66, 168, 180, 23, 170, 24, 5, 157, 28, 45, 53, 68, 25, 191, 148, 139, 15, 67, 77, 100, 58, 91, 50, 131, 65, 17, 11, 123, 86, 135, 115, 120, 59, 162, 9, 189, 21, 12, 179, 178, 110, 35, 137, 3, 84, 177, 124, 186, 143, 26, 96, 80, 31, 169, 119, 33, 87, 140, 88, 171, 133, 150, 151, 72, 85, 89, 112, 126, 167, 56, 49, 187, 138, 145, 18, 32, 90, 158, 54, 104, 62, 165, 79, 1, 81, 102, 44, 61, 10, 166, 2, 116, 161, 60, 108, 142, 30, 78, 127, 111, 46, 43, 184, 163, 64, 22, 41, 156, 70, 20, 42, 182, 55, 95, 105, 132, 38, 69, 134, 74, 155, 141, 172, 57, 7, 175, 128, 75, 107, 109, 99, 147, 146, 117, 125, 185, 0, 76, 82, 129, 36, 34, 93, 188, 113, 71, 183, 121, 47, 16, 164, 4, 181, 94, 37, 8

The new GW pattern is applied to, for example, a combination of the type A code with the code length N of 69120 bits and r=4/16 in FIG. 33, 16QAM, and the new 16QAM-2D-NUC in FIG. 198, thereby further achieving a favorable error rate.

That is, for a combination of the type A code with the code length N of 69120 bits and r=4/16 and the new 16QAM-2D-NUC, the BER in the Rayleigh fading communication path can be improved by applying the GW pattern (Hereinafter, it is also referred to as an old GW pattern.) in FIG. 166 as illustrated in FIG. 199, but the BER in the Rayleigh fading communication path can be further improved by applying the new GW pattern.

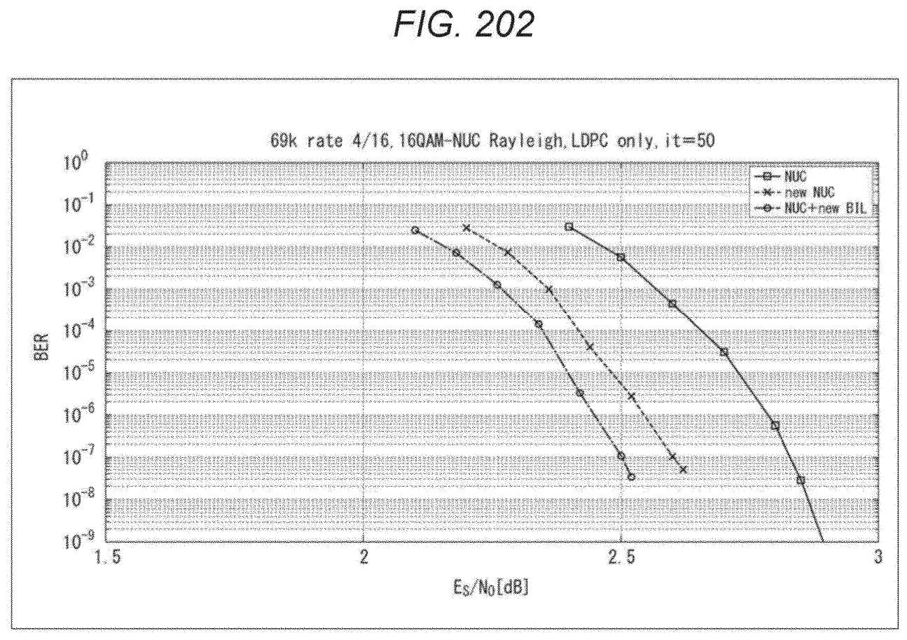

FIG. 202 is a diagram illustrating a simulation result of the BER of the combination of the type A code with the code length N of 69120 bits and r=4/16, 16QAM, new 16QAM-2D-NUC, and new GW pattern in FIG. 33.

In FIG. 202, the horizontal axis represents Eₛ/N₀, and the vertical axis represents BER.

In FIG. 202, similarly to the case of FIG. 199, a quadrangle represents the BER of the combination of the type A code with the code length N of 69120 bits and r=4/16, 16QAM, the old GW pattern, and the old 16QAM-2D-NUC, and a cross represents the BER of the combination of the type A code with the code length N of 69120 bits and r=4/16, 16QAM, the old GW pattern, and the new 16QAM-2D-NUC.

Moreover, in FIG. 202, a circle indicates the BER of the combination of the type A code with the code length N of 69120 bits and r=4/16, 16QAM, the new GW pattern, and the new 16QAM-2D-NUC.

According to FIG. 202, it can be confirmed that a better BER is obtained in a case where the new GW pattern is applied to the combination of the type A code with r=4/16 and the code length N of 69120 bits, 16QAM, and the new 16QAM-2D-NUC than a case where the old GW pattern is applied.

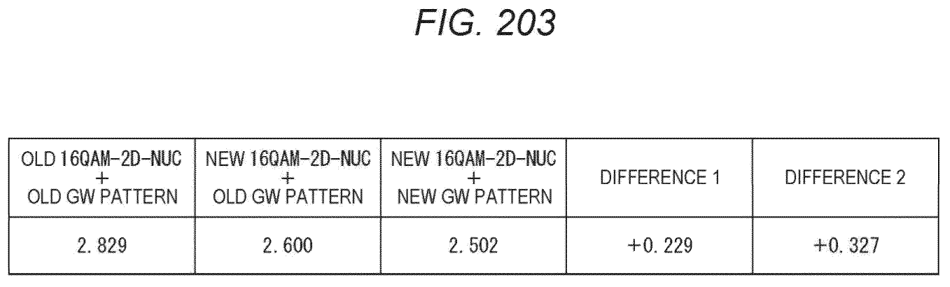

FIG. 203 is a diagram illustrating a simulation result of the required CNR of the combination of the type A code with the code length N of 69120 bits and r=4/16, 16QAM, new 16QAM-2D-NUC, and new GW pattern in FIG. 33.

In FIG. 203, the required CNR (hereinafter, it is also referred to as necessary CNR of new 16QAM-2D-NUC+new GW pattern.) of the combination of the code length N of 69120 bits and r=4/16, the type A code 16QAM, the new 16QAM-2D-NUC, and the new GW pattern, the required CNR (Hereinafter, it is also referred to as required CNR of old 16QAM-2D-NUC+old GW pattern.) of the combination of the code length N of 69120 bits and r=4/16, the type A code 16QAM, the old 16QAM-2D-NUC, and the old GW pattern, and the required CNR (Hereinafter, it is also referred to as necessary CNR of new 16QAM-2D-NUC+old GW pattern.) of the combination of the code length N of 69120 bits and r=4/16, the type A code 16QAM, the new 16QAM-2D-NUC, and the old GW pattern illustrated in FIG. 200 are also illustrated.

In FIG. 203, a difference 1 represents the difference illustrated in FIG. 200, that is, the difference between the required CNR of the new 16QAM-2D-NUC+old GW pattern and the required CNR of the old 16QAM-2D-NUC+old GW pattern. A difference 2 represents a difference between the required CNR of the new 16QAM-2D-NUC+new GW pattern and the required CNR of the old 16QAM-2D-NUC+old GW pattern.

The improvement amount of the required CNR of the new 16QAM-2D-NUC+old GW pattern with respect to the required CNR of the old 16QAM-2D-NUC+old GW pattern is 0.229 dB indicated by the difference 1, but the improvement amount of the required CNR of the new 16QAM-2D-NUC+new GW pattern is 0.326 dB indicated by the difference 2.

Therefore, by applying both the new 16QAM-2D-NUC and the new GW pattern, the required CNR can be further improved.

### <Configuration Example of Reception Device 12>

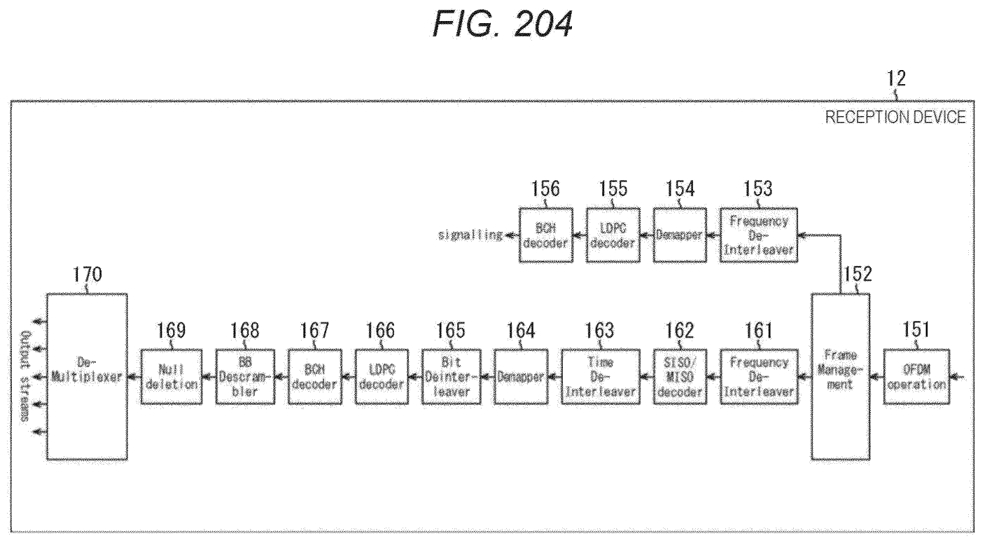

FIG. 204 is a block diagram illustrating a configuration example of the reception device 12 in FIG. 7.

An OFDM processing unit (OFDM operation) 151 receives an OFDM signal from the transmission device 11 (FIG. 7) and performs signal processing on the OFDM signal. Data obtained by the OFDM processing unit 151 performing signal processing is supplied to a frame management unit 152.

The frame management unit 152 processes (interprets) a frame including the data supplied from the OFDM processing unit 151, and supplies a signal of the target data and a signal of the control data obtained as a result to frequency deinterleavers 161 and 153, respectively.

The frequency deinterleaver 153 performs frequency deinterleaving in units of symbols for the data from the frame management unit 152, and supplies the data to a demapper 154.

The demapper 154 performs demapping (signal point arrangement decoding) and quadrature demodulation on the data (data on the constellation) from the frequency deinterleaver 153 on the basis of arrangement (constellation) of signal points determined by the quadrature modulation performed on a side of the transmission device 11, and supplies resulting data ((likelihood of) the LDPC code) to an LDPC decoder 155.

The LDPC decoder 155 performs LDPC decoding for the LDPC code from the demapper 154, and supplies resulting LDPC target data (Here, the BCH code) to a BCH decoder 156.

The BCH decoder 156 performs BCH decoding on the LDPC target data from the LDPC decoder 155, and outputs control data (signaling) obtained as a result.

On the other hand, the frequency deinterleaver 161 performs frequency deinterleaving in units of symbols for the data from the frame management unit 152, and supplies the data to an SISO/MISO decoder 162.

The SISO/MISO decoder 162 performs spatiotemporal decoding on the data from the frequency deinterleaver 161, and supplies the data to a time deinterleaver 163.

The time deinterleaver 163 performs time deinterleaving in units of symbols for the data from the SISO/MISO decoder 162, and supplies the data to a demapper 164.

The demapper 164 performs demapping (signal point arrangement decoding) and quadrature demodulation on the data (data on the constellation) from the time deinterleaver 163 on the basis of the arrangement (constellation) of the signal points determined by the quadrature modulation performed on the side of the transmission device 11, and supplies resulting data to a bit deinterleaver 165.

The bit deinterleaver 165 performs bit deinterleaving for the data from the demapper 164, and supplies (the likelihood of) the LDPC code, which is the data after the bit deinterleaving, to the LDPC decoder 166.

The LDPC decoder 166 performs LDPC decoding for the LDPC code supplied from the bit deinterleaver 165, and supplies resulting LDPC target data (here, the BCH code) to the BCH decoder 167.

The BCH decoder 167 performs BCH decoding on the LDPC target data from the LDPC decoder 155, and supplies resulting data to a BB descrambler 168.

The BB descrambler 168 descrambles the data from the BCH decoder 167, and supplies resulting data to a null deletion unit 169.

The null deletion unit 169 deletes the null inserted by the padder 112 in FIG. 8 from the data from the BB descrambler 168, and supplies the data to a demultiplexer 170.

The demultiplexer 170 separates each of one or more streams (target data) multiplexed with the data from the null deletion unit 169, performs necessary processing, and outputs the result as an output stream.

Note that the reception device 12 can be configured without providing a part of the blocks illustrated in FIG. 204. That is, for example, in a case where the transmission device 11 (FIG. 8) is configured without including the time interleaver 118, the SISO/MISO encoder 119, the frequency interleaver 120, and the frequency interleaver 124, the reception device 12 can be configured without including the time deinterleaver 163, the SISO/MISO decoder 162, the frequency deinterleaver 161, and the frequency deinterleaver 153 which are blocks respectively corresponding to the time interleaver 118, the SISO/MISO encoder 119, the frequency interleaver 120, and the frequency interleaver 124 of the transmission device 11.

### <Configuration Example of Bit Deinterleaver 165>

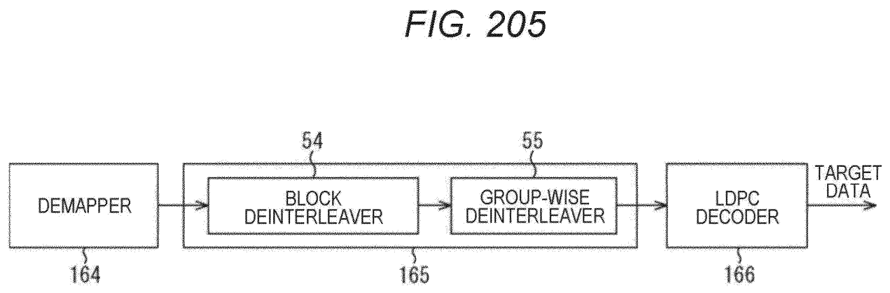

FIG. 205 is a block diagram illustrating a configuration example of the bit deinterleaver 165 in FIG. 204.

The bit deinterleaver 165 includes a block deinterleaver 54 and a group-wise deinterleaver 55, and performs (bit) deinterleaving of symbol bits of a symbol that is data from the demapper 164 (FIG. 204).

In other words, the block deinterleaver 54 performs, for the symbol bit of the symbol from demapper 164, block deinterleaving corresponding to the block interleaving performed by the block interleaver 25 in FIG. 9 (processing reverse to the block interleaving), in other words, block deinterleaving of returning the positions of (the likelihood of) the sign bits of the LDPC code rearranged by the block interleaving to the original positions, and supplies the resulting LDPC code to the group-wise deinterleaver 55.

The group-wise deinterleaver 55 performs, for the LDPC code from the block deinterleaver 54, group-wise deinterleaving corresponding to the group-wise interleaving performed by the group-wise interleaver 24 in FIG. 9 (processing reverse to the group-wise interleaving), in other words, for example, group-wise deinterleaving of rearranging, in units of bit groups, the sign bits of the LDPC code whose arrangement has been changed in units of bit groups by the group-wise interleaving described in FIG. 119 to return to the original arrangement.

Here, in a case where the parity interleaving, the group-wise interleaving, and the block interleaving have been applied to the LDPC code supplied from the demapper 164 to the bit deinterleaver 165, the bit deinterleaver 165 can perform all of the parity deinterleaving (parity deinterleaving which returns the opposite process of the parity interleaving, that is, the sign bits of the LDPC code whose arrangement has been changed by the parity interleaving to the original arrangement) corresponding to the parity interleaving, the block deinterleaving corresponding to the block interleaving, and the group-wise deinterleaving corresponding to the group-wise interleaving.

However, in the bit deinterleaver 165 in FIG. 205, the block deinterleaver 54 that performs the block deinterleaving corresponding to the block interleaving and the group-wise deinterleaver 55 that performs the group-wise deinterleaving corresponding to the group-wise interleaving are provided, but the block that performs the parity deinterleaving corresponding to the parity interleaving is not provided, and the parity deinterleaving is not performed.

Therefore, the LDPC code for which the block deinterleaving and the group-wise deinterleaving have been performed and the parity deinterleaving has not been performed is supplied from (the group-wise deinterleaver 55 of) the bit deinterleaver 165 to the LDPC decoder 166.

The LDPC decoder 166 performs LDPC decoding for the LDPC code from the bit deinterleaver 165, using a transformed parity check matrix obtained by performing at least column permutation corresponding to parity interleaving for the parity check matrix H by the type B method used for LDPC coding by the LDPC encoder 115 in FIG. 8, or a transformed parity check matrix (FIG. 29) obtained by performing row permutation for the parity check matrix (FIG. 27) by the type A method, and outputs resulting data as a decoding result of the LDPC target data.

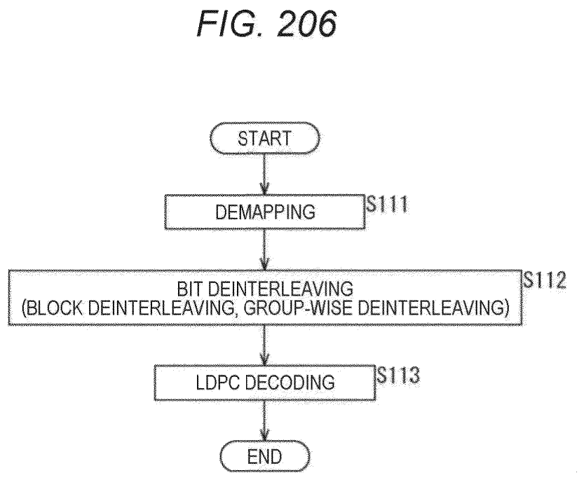

FIG. 206 is a flowchart illustrating processing performed by the demapper 164, the bit deinterleaver 165, and the LDPC decoder 166 in FIG. 205.

In step S111, the demapper 164 demaps and orthogonally demodulates the data (data on the constellation mapped to the signal point) from the time deinterleaver 163, and supplies the data to the bit deinterleaver 165, and the process proceeds to step S112.

In step S112, the bit deinterleaver 165 deinterleaves the data from the demapper 164 (bit deinterleaving), and the process proceeds to step S113.

That is, in step S112, in the bit deinterleaver 165, the block deinterleaver 54 performs block deinterleaving on the data (symbol) from the demapper 164, and supplies the sign bits of the LDPC code obtained as a result to the group-wise deinterleaver 55.

The group-wise deinterleaver 55 performs group-wise deinterleaving for the LDPC code from the block deinterleaver 54, and supplies (the likelihood of) the resulting LDPC code to the LDPC decoder 166.

In step S113, the LDPC decoder 166 performs the LDPC decoding for the LDPC code from the group-wise deinterleaver 55 by using the parity check matrix H used for the LDPC coding by the LDPC encoder 115 in FIG. 8, that is, by using, for example, the transformed parity check matrix obtained from the parity check matrix H, and outputs resulting data to the BCH decoder 167 as a decoding result of the LDPC target data.

Note that, also in FIG. 205, for convenience of description, the block deinterleaver 54 for performing block deinterleaving and the group-wise deinterleaver 55 for performing group-wise deinterleaving are separately configured similar to the case of FIG. 9, but the block deinterleaver 54 and the group-wise deinterleaver 55 can be integrally configured.

Furthermore, in a case where group-wise interleaving is not performed in the transmission device 11, the reception device 12 can be configured without providing the group-wise deinterleaver 55 that performs group-wise deinterleaving.

### <LDPC Decoding>

The LDPC decoding performed by the LDPC decoder 166 in FIG. 204 will be further described.

The LDPC decoder 166 in FIG. 204 performs the LDPC decoding for the LDPC code from the group-wise deinterleaver 55, for which the block deinterleaving and the group-wise deinterleaving have been performed and the parity deinterleaving has not been performed, using the transformed parity check matrix obtained by performing at least column permutation corresponding to the parity interleaving for the parity check matrix H by the type B method used for the LDPC coding by the LDPC encoder 115 in FIG. 8, or the transformed parity check matrix (FIG. 29) obtained by performing row permutation for the parity check matrix (FIG. 27) by the type A method.

Here, LDPC decoding that can suppress an operation frequency within a sufficiently feasible range while suppressing a circuit scale by performing LDPC decoding using a transformed parity check matrix has been previously proposed (See, for example, Japanese Patent No. 4224777).

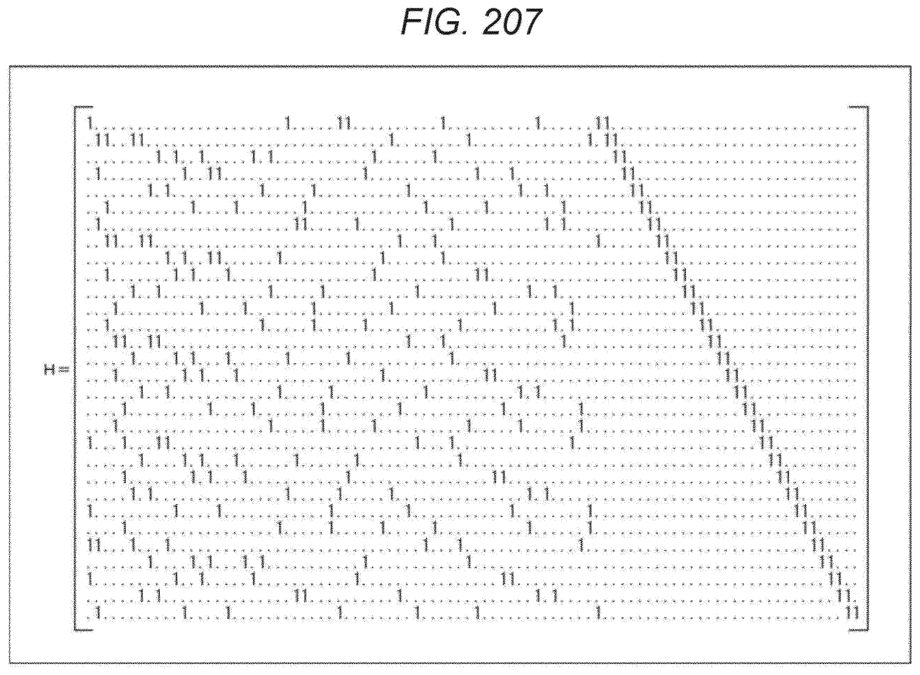

Therefore, first, the previously proposed LDPC decoding using the transformed parity check matrix will be described with reference to FIGS. 207 to 210.

FIG. 207 is a diagram illustrating an example of a parity check matrix H of an LDPC code with a code length N of 90 and a coding rate of 2/3.

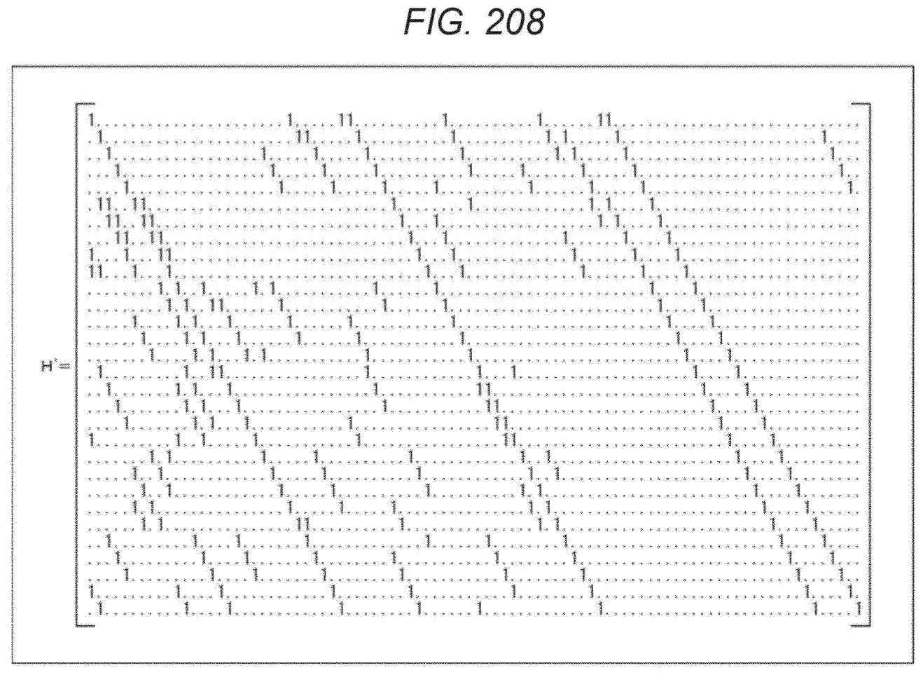

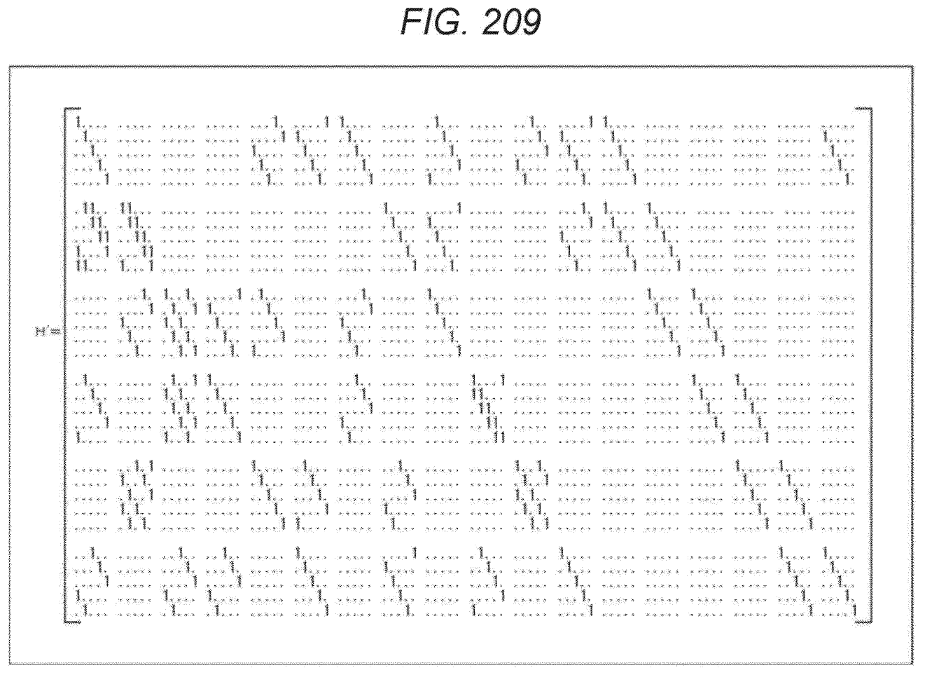

Note that, in FIG. 207 (It is similar in FIGS. 208 and 209 as described later.), 0 is expressed by a period (.).

In the parity check matrix H in FIG. 207, the parity matrix has a staircase structure.

FIG. 208 is a diagram illustrating a parity check matrix H′ obtained by applying the row permutation of Formula (11) and the column permutation of Formula (12) to the parity check matrix H in FIG. 207.

$$Row permutation : ( 6 s + t + 1 ) th row \to ( 5 t + s + 1 ) th row \qquad ( 11 )$$

$$Column permutation : ( 6 x + y + 61 ) th column \to ( 5 y + x + 61 ) th column \qquad ( 12 )$$

However, in Formulas (11) and (12), s, t, x, and y are integers in ranges of 0≤s<5, 0≤t<6, 0≤x<5, and 0≤t<6, respectively.

According to the row permutation of Formula (11), permutation is performed in such a manner that the 1st, 7th, 13, 19, and 25 rows where the remainder becomes 1 when being divided by 6 are respectively permutated to the 1st, 2nd, 3rd, 4th, and 5th rows, and the 2nd, 8th, 14, 20, and 26 rows where the remainder becomes 2 when being divided by 6 are respectively permutated to the 6th, 7th, 8th, 9, and 10 rows.

Furthermore, according to the column permutation of Formula (12), permutation is performed on the 61th and subsequent columns (parity matrix) in such a manner that the 61, 67, 73, 79, and 85th columns that have a remainder of 1 when divided by 6 are permutated to the 61, 62, 63, 64, and 65th columns, respectively, and the 62, 68, 74, 80, and 86th columns that have a remainder of 2 when divided by 6 are permutated to the 66, 67, 68, 69, and 70th columns, respectively.

A matrix obtained by performing row and column permutation for the parity check matrix H in FIG. 207 is the parity check matrix H′ in FIG. 208.

Here, the row permutation of the parity check matrix H does not affect the arrangement of the sign bits of the LDPC code.

Furthermore, the column permutation of Formula (12) corresponds to the parity interleaving of the parity interleaving of interleaving the (K+qx+y+1)th sign bit to the position of the (K+Py+x+1)th sign bit when the information length K is 60, the unit size P is 5, and the divisor q (=M/P) of the parity length M (Here, 30) is 6.

Therefore, the parity check matrix H′ in FIG. 208 is a transformed parity check matrix obtained by performing at least column permutation for permutating the (K+qx+y+1)th column with the (K+Py+x+1)th column in the parity check matrix (Hereinafter, the original check matrix is appropriately referred to as an original check matrix.) H in FIG. 207.

When multiplying the transformed parity check matrix H′ in FIG. 208 by a resultant obtained by performing the same permutation as Formula (12) for the LDPC code of the original check matrix H in FIG. 207, a 0 vector is output. That is, when a row vector obtained by applying the column permutation of Formula (12) to the row vector c as the LDPC code (one code word) of the original check matrix H is expressed as c′, Hc^{T} is a 0 vector from the nature of the parity check matrix, and thus H‘c’^{T} is also a 0 vector as a matter of course.

From the above, the transformed parity check matrix H′ in FIG. 208 is a parity check matrix of the LDPC code c′ obtained by performing the column permutation of Formula (12) for the LDPC code c of the original check matrix H.

Therefore, by performing the column permutation of Formula (12) for the LDPC code c of the original check matrix H, decoding (LDPC decoding) the LDPC code c′ after the column permutation using the transformed parity check matrix H′ in FIG. 208, and applying the inverse permutation of the column permutation of Formula (12) to the decoding result, a decoding result similar to the case of decoding the LDPC code of the original check matrix H using the parity check matrix H can be obtained.

FIG. 209 is a diagram illustrating the transformed parity check matrix H′ in FIG. 208 spaced in units of a 5×5 matrix.

In FIG. 209, the transformed parity check matrix H′ is represented by a combination of a 5×5 (=P×P) identity matrix that is the unit size P, a matrix in which one or more of 1's of the identity matrix are 0 (Hereinafter, the matrix is appropriately referred to as a quasi-identity matrix.), a matrix obtained by cyclically shifting the identity matrix or the quasi identity matrix (Hereinafter, the matrix is appropriately referred to as a shift matrix.), a sum (Hereinafter, appropriately referred to as a sum matrix.) of 2 or more of the identity matrix, the quasi identity matrix, or the shift matrix, and a 5×5 0 matrix.

It can be said that the transformed parity check matrix H′ in FIG. 209 includes a 5×5 identity matrix, a quasi identity matrix, a shift matrix, a sum matrix, and a 0 matrix. Therefore, these 5×5 matrices (identity matrix, quasi identity matrix, shift matrix, sum matrix, and zero matrix) constituting the transformed parity check matrix H′ are hereinafter appropriately referred to as configuration matrices.

An architecture that simultaneously performs P check node operations and variable node operations can be used to decode the LDPC code of the parity check matrix represented by the P×P configuration matrix.

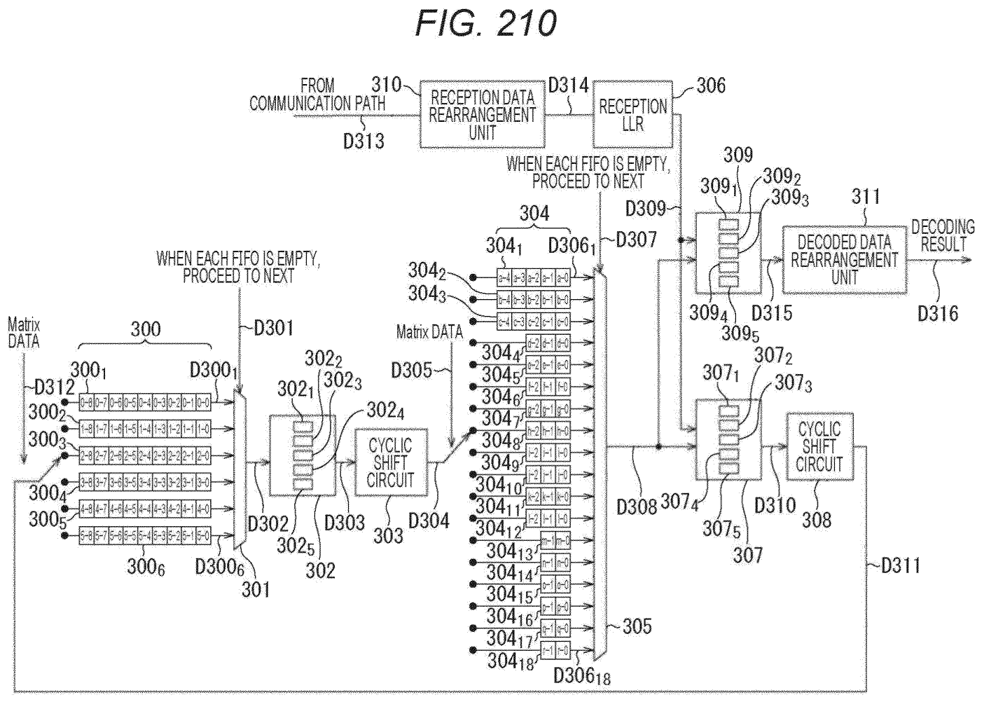

FIG. 210 is a block diagram illustrating a configuration example of a decoding device that performs such decoding.

In other words, FIG. 210 illustrates a configuration example of a decoding device that decodes the LDPC code using the transformed parity check matrix H′ in FIG. 209 obtained by performing at least the column permutation of Formula (12) for the original check matrix H in FIG. 207.

The decoding device in FIG. 210 includes an edge data storage memory 300 including six FIFOs 300₁ to 300₆, a selector 301 for selecting the FIFOs 300₁ to 300₆, a check node calculation unit 302, two cyclic shift circuits 303 and 308, an edge data storage memory 304 including 18 FIFOs 304₁ to 304₁₈, a selector 305 for selecting the FIFOs 304₁ to 304₁₈, a reception data memory 306 for storing received data, a variable node calculation unit 307, a decoded word calculation unit 309, a reception data rearrangement unit 310, and a decoded data rearrangement unit 311.

First, a method of storing data in the edge data storage memories 300 and 304 will be described.

The edge data storage memory 300 includes six FIFOs 300₁ to 300₆ which are the number obtained by dividing the number of rows 30 of the transformed parity check matrix H′ in FIG. 209 by the number of rows (unit size P) 5 of the configuration matrix. The FIFO 300_{y} (y=1, 2, . . . , 6) includes storage areas of a plurality of stages, and messages corresponding to five edges, which are the number of rows and the number of columns (unit size P) of the configuration matrix, can be simultaneously read and written for the storage areas of the respective stages. Furthermore, the number of stages of the storage areas in the FIFO 300_{y} is 9, which is the maximum number of is (Hamming weights) in the row direction of the transformed parity check matrix in FIG. 209.

In the FIFO 300₁, data (message vᵢ from the variable node) corresponding to the positions of 1 of the 1st to 5th rows of the transformed parity check matrix H′ in FIG. 209 is stored close to each other (ignoring 0) in the horizontal direction for each row. That is, if the j-th row and the i-th column are represented as (j, i), data corresponding to the positions of 1 of the 5×5 identity matrix of (1, 1) to (5, 5) of the transformed parity check matrix H′ is stored in the storage area of the first stage of the FIFO 300₁. Data corresponding to the positions of 1 of the shift matrix of (1, 21) to (5, 25) of the transformed parity check matrix H′ (the shift matrix obtained by cyclically shifting the 5×5 identity matrix rightward by three) is stored in the storage area of the second stage. Similarly, data is stored in the storage areas of the third to eighth stages in association with the transformed parity check matrix H′. Then, data corresponding to the positions of 1 of the shift matrix (1 in the first row of the 5×5 identity matrix is replaced with 0, and the shifted matrix is cyclically shifted to the left by 1.) of from (1, 86) to (5, 90) of the transformed parity check matrix H′ is stored in the storage area of the ninth stage.

Data corresponding to the positions of 1 of the 6th to 10th rows of the transformed parity check matrix H′ in FIG. 209 is stored in the FIFO 300₂. In other words, data corresponding to the positions of 1 of the first shift matrix constituting the sum matrix (a sum matrix which is a sum of a first shift matrix obtained by cyclically shifting the 5×5 identity matrix to the right by one and a second shift matrix obtained by cyclically shifting the 5×5 identity matrix to the right by two.) of (6, 1) to (10, 5) of the transformed parity check matrix H′ is stored in the storage area of the first stage of the FIFO 300₂. Furthermore, data corresponding to the positions of 1 of the second shift matrix constituting the sum matrix of (6, 1) to (10, 5) of the transformed parity check matrix H′ is stored in the storage area of the second stage.

That is, for a configuration matrix having a weight of 2 or more, when the configuration matrix is expressed in the form of a sum of some matrices of a P×P identity matrix having a weight of 1, a quasi identity matrix in which one or more of the elements of 1 of the identity matrix are 0, and a shift matrix obtained by cyclically shifting the identity matrix or the quasi identity matrix, data (Message corresponding to edge belonging to identity matrix, quasi identity matrix, or shift matrix) corresponding to the position of 1 of the identity matrix having a weight of 1, the quasi identity matrix, or the shift matrix is stored in the same address (the same FIFO among the FIFOs 300₁ to 300₆).

Hereinafter, data is stored in association with the transformed parity check matrix H′ also in the storage areas of the third to ninth stages.

Similarly, the FIFOs 300₃ to 300₆ store data in association with the transformed parity check matrix H′.

The edge data storage memory 304 includes 18 FIFOs 304₁ to 304₁₈ obtained by dividing the number of columns 90 of the transformed parity check matrix H′ by the number of columns 5 (unit size P) of the configuration matrix. The FIFO 304ₓ (x=1, 2, . . . , 18) includes storage areas of a plurality of stages, and messages corresponding to five edges, which are the number of rows and the number of columns (unit size P) of the configuration matrix, can be simultaneously read and written for the storage areas of the respective stages.

In the FIFO 304₁, data (message u from the check node) corresponding to the positions of 1 of the 1st to 5th columns of the transformed parity check matrix H′ in FIG. 209 is stored close to each other (ignoring 0) in the vertical direction for each column. That is, data corresponding to the positions of 1 of the 5×5 identity matrix of (1, 1) to (5, 5) of the transformed parity check matrix H′ is stored in the storage area of the first stage of the FIFO 304₁. Data corresponding to the positions of 1 of the first shift matrix constituting the sum matrix (A sum matrix that is a sum of a first shift matrix obtained by cyclically shifting the 5×5 identity matrix to the right by one and a second shift matrix obtained by cyclically shifting the 5×5 identity matrix to the right by two.) of (6, 1) to (10, 5) of the transformed parity check matrix H′ is stored in the storage area of the second stage. Furthermore, data corresponding to the positions of 1 of the second shift matrix constituting the sum matrix of (6, 1) to (10, 5) of the transformed parity check matrix H′ is stored in the storage area of the third stage.

That is, for a configuration matrix having a weight of 2 or more, when the configuration matrix is expressed in the form of a sum of some matrices of a P×P identity matrix having a weight of 1, a quasi identity matrix in which one or more of the elements of 1 of the identity matrix are 0, and a shift matrix obtained by cyclically shifting the identity matrix or the quasi identity matrix, data (message corresponding to edge belonging to identity matrix, quasi identity matrix, or shift matrix) corresponding to the position of 1 of the identity matrix having a weight of 1, the quasi identity matrix, or the shift matrix is stored in the same address (the same FIFO among the FIFOs 304₁ to 304₁₈).

Hereinafter, data is also stored in the storage areas of the fourth and fifth stages in association with the transformed parity check matrix H′. The number of stages of the storage areas of the FIFO 304₁ is 5, which is the maximum number of 1's (Hamming weights) in the row direction in the first to fifth columns of the transformed parity check matrix H′.

Similarly, the FIFOs 304₂ and 304₃ store data in association with the transformed parity check matrix H′, and each length (the number of stages) is 5. Similarly, the FIFOs 304₄ to 304₁₂ store data in association with the transformed parity check matrix H′, and each have a length of 3. Similarly, the FIFOs 304₁₃ to 304₁₈ store data in association with the transformed parity check matrix H′, and each have a length of 2.

Next, an operation of the decoding device in FIG. 210 will be described.

The edge data storage memory 300 includes six FIFOs 300₁ to 300₆, and selects a FIFO to store data from among the FIFOs 300₁ to 300₆ according to information (matrix data) D312 indicating to which row of the transformed parity check matrix H′ in FIG. 209 the five messages D311 supplied from the previous cyclic shift circuit 308 belong, and collectively stores the five messages D311 in the selected FIFO in order. Furthermore, when reading data, the edge data storage memory 300 sequentially reads five messages D300₁ from the FIFO 300₁ and supplies the messages to the selector 301 of the next stage. After completion of reading of the message from the FIFO 300₁, the edge data storage memory 300 sequentially reads the messages from the FIFOs 300₂ to 300₆ and supplies the messages to the selector 301.

In accordance with the select signal D301, the selector 301 selects five messages from the FIFO from which data is currently read out among the FIFOs 300₁ to 300₆, and supplies the selected messages as messages D302 to the check node calculation unit 302.

The check node calculation unit 302 includes five check node calculators 302₁ to 302₅, performs a check node operation according to Formula (7) using messages D302 (D302₁ to D302₅) (messages vᵢ in Formula (7)) supplied through the selector 301, and supplies five messages D303 (D303₁ to D303₅) (messages uⱼ in Formula (7)) obtained as a result of the check node operation to the cyclic shift circuit 303.

The cyclic shift circuit 303 cyclically shifts the five messages D303₁ to D303₅ obtained by the check node calculation unit 302 on the basis of information (matrix data) D305 indicating how many identity matrices (or quasi identity matrices), which are the basis of the transformed parity check matrix H′, have been cyclically shifted for the corresponding edge, and supplies the result as a message D304 to the edge data storage memory 304.

The edge data storage memory 304 includes 18 FIFOs 304₁ to 304₁₈, selects a FIFO to store data from among the FIFOs 304₁ to 304₁₈ according to information D305 indicating to which row of the transformed parity check matrix H′ the five messages D304 supplied from the previous cyclic shift circuit 303 belong, and collectively stores the five messages D304 in the selected FIFO in order. Furthermore, when reading data, the edge data storage memory 304 sequentially reads five messages D306₁ from the FIFO 304₁ and supplies the messages to the selector 305 of the next stage. After completion of reading data from the FIFO 304₁, the edge data storage memory 304 sequentially reads messages from the FIFOs 304₂ to 304₁₈ and supplies the messages to the selector 305.

In accordance with the select signal D307, the selector 305 selects five messages from the FIFO from which data is currently read out among the FIFOs 304₁ to 304₁₈, and supplies the selected messages as messages D308 to the variable node calculation unit 307 and the decoded word calculation unit 309.

On the other hand, the reception data rearrangement unit 310 rearranges the LDPC code D313 corresponding to the parity check matrix H in FIG. 207 received through the communication path 13 by performing the column permutation of Formula (12), and supplies the rearranged LDPC code as the received data D314 to the reception data memory 306. The reception data memory 306 calculates and stores reception LLRs (log likelihood ratios) from the received data D314 supplied from the reception data rearrangement unit 310, and supplies the five reception LLRs collectively as a reception value D309 to the variable node calculation unit 307 and the decoded word calculation unit 309.

The variable node calculation unit 307 includes five variable node calculators 307₁ to 307₅, performs a variable node operation according to Formula (1) using the messages D308 (D308₁ to D308₅) (messages uⱼ in Formula (1)) supplied through the selector 305 and the five reception values D309 (reception values u₀₁ in Formula (1)) supplied from the reception data memory 306, and supplies the messages D310 (D310₁ to D310₅) (messages vᵢ in Formula (1)) obtained as a result of the operation to the cyclic shift circuit 308.

The cyclic shift circuit 308 cyclically shifts the messages D310₁ to D310₅ calculated by the variable node calculation unit 307 on the basis of information indicating how many identity matrices (or quasi identity matrices) as the basis in the transformed parity check matrix H′ have been cyclically shifted for the corresponding edge, and supplies the result as a message D311 to the edge data storage memory 300.

By making one round of the above operation, one decoding (variable node operation and check node operation) of the LDPC code can be performed. The decoding device in FIG. 210 decodes the LDPC code a predetermined number of times, and then obtains and outputs a final decoding result in the decoded word calculation unit 309 and the decoded data rearrangement unit 311.

That is, the decoded word calculation unit 309 includes five decoded word calculators 309₁ to 309₅, calculates a decoding result (decoded word) on the basis of Formula (5) as a final stage of a plurality of times of decoding by using five messages D308 (D308₁ to D308₅) (messages uⱼ in Formula (5)) output by the selector 305 and five reception values D309 (reception values u₀₁ in Formula (5)) supplied from the reception data memory 306, and supplies decoded data D315 obtained as a result to the decoded data rearrangement unit 311.

The decoded data rearrangement unit 311 rearranges the order by performing inverse permutation of the column permutation of Formula (12) for the decoded data D315 supplied from the decoded word calculation unit 309, and outputs a final decoding result D316.

As described above, by applying one or both of the row permutation and the column permutation to the parity check matrix (original check matrix) and converting the parity check matrix into a parity check matrix (transformed parity check matrix) that can be represented by a combination of a P×P identity matrix, a quasi identity matrix in which one or more of is of the identity matrix are 0, a shift matrix obtained by cyclically shifting the identity matrix or the quasi identity matrix, a sum matrix that is a sum of a plurality of the identity matrix, the quasi identity matrix, and the shift matrix, and a P×P zero matrix, that is, a combination of configuration matrices, an architecture can be adopted in which P check node operations and variable node operations are simultaneously performed for decoding of the LDPC code, the P being a number smaller than the number of rows and the number of columns of the parity check matrix. In a case of adopting an architecture in which P node operations (check node operations and variable node operations) are simultaneously performed, the number of which is smaller than the number of rows and the number of columns of the parity check matrix, it is possible to perform a large number of iterative decoding while suppressing the operation frequency within a feasible range, as compared with a case where the node operations are simultaneously performed, the number of which is equal to the number of rows and the number of columns of the parity check matrix.

Similarly to the decoding device in FIG. 210, for example, the LDPC decoder 166 constituting the reception device 12 in FIG. 204 performs the LDPC decoding by simultaneously performing P check node operations and variable node operations.

In other words, in order to simplify the description, assuming that the parity check matrix of the LDPC code output from the LDPC encoder 115 constituting the transmission device 11 in FIG. 8 is, for example, the parity check matrix H illustrated in FIG. 207 in which the parity matrix has a staircase structure, the parity interleaver 23 of the transmission device 11 performs parity interleaving to interleave the (K+qx+y+1)th sign bit to the position of the (K+Py+x+1)th sign bit by setting the information length K to 60, the unit size P to 5, and the divisor q (=M/P) of the parity length M to 6.

Since this parity interleaving corresponds to the column permutation of Formula (12) as described above, the LDPC decoder 166 does not need to perform the column permutation of Formula (12).

Therefore, in the reception device 12 in FIG. 204, as described above, the LDPC code for which the parity deinterleaving has not been performed, that is, the LDPC code in the state where the column permutation of Formula (12) has been performed is supplied from the group-wise deinterleaver 55 to the LDPC decoder 166, and the LDPC decoder 166 performs processing similar to processing of the decoding device in FIG. 210 except that the column permutation of Formula (12) is not performed.

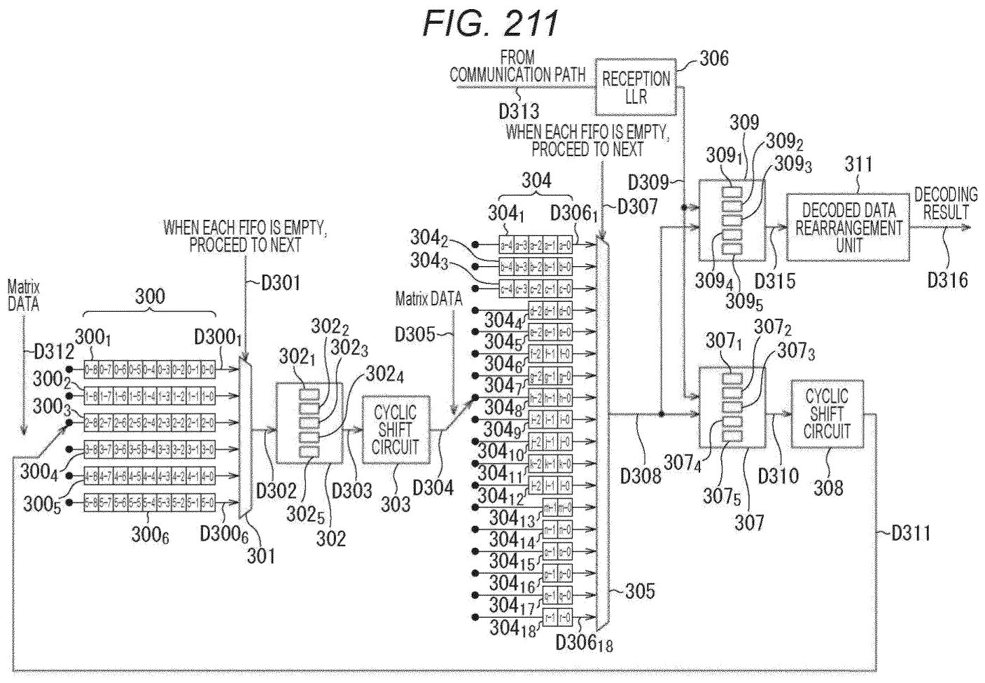

That is, FIG. 211 is a diagram illustrating a configuration example of the LDPC decoder 166 in FIG. 204.

In FIG. 211, the LDPC decoder 166 is configured similarly to the decoding device in FIG. 210 except that the reception data rearrangement unit 310 in FIG. 210 is not provided, and performs similar processing to the decoding device in FIG. 210 except that the column permutation of the equation (12) is not performed, so that the description thereof is omitted.

As described above, since the LDPC decoder 166 can be configured without the reception data rearrangement unit 310, the scale can be reduced as compared with the decoding device in FIG. 210.

Note that, in FIGS. 207 to 211, in order to simplify the description, the code length N of the LDPC code is set to 90, the information length K is set to 60, the unit size (the number of rows and the number of columns of the configuration matrix) P is set to 5, and the divisor q (=M/P) of the parity length M is set to 6. However, each of the code length N, the information length K, the unit size P, and the divisor q (=M/P) is not limited to the above-described values.

That is, in the transmission device 11 in FIG. 8, what the LDPC encoder 115 outputs is the LDPC codes with the code lengths N of 64800, 16200, 69120, and the like, the information length K of N−Pq (=N−M), the unit size P of 360, and the divisor q of M/P. However, the LDPC decoder 166 in FIG. 211 can be applied to a case of performing the LDPC decoding by performing the P check node operations and variable node operations at the same time for such LDPC codes.

Furthermore, after the LDPC code is decoded by the LDPC decoder 166, the parity part of the decoding result is unnecessary, and in a case where only the information bits of the decoding result are output, the LDPC decoder 166 can be configured without the decoded data rearrangement unit 311.

### <Configuration Example of Block Deinterleaver 54>

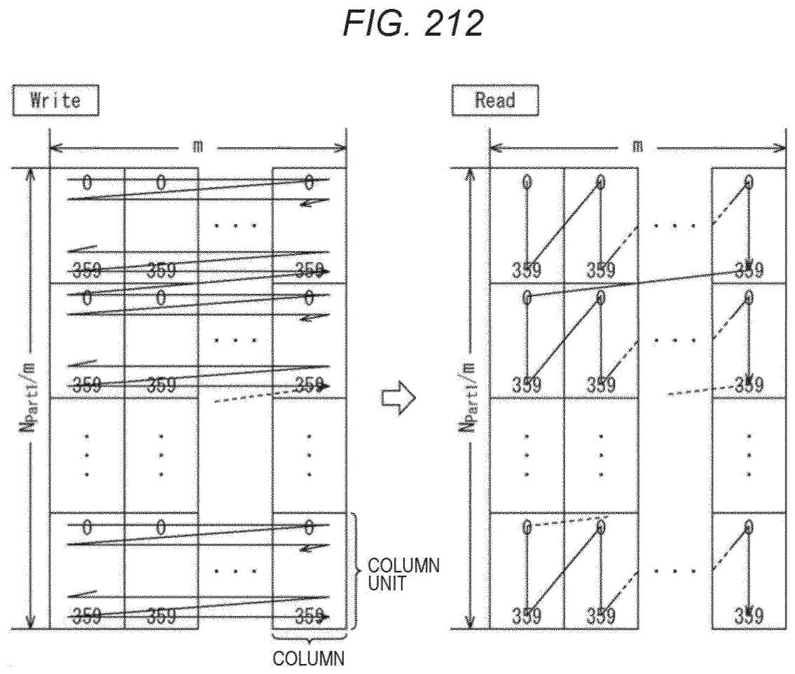

FIG. 212 is a diagram for describing block deinterleaving performed by the block deinterleaver 54 in FIG. 205.

In the block deinterleaving, reverse processing to the block interleaving by the block interleaver 25 described in FIG. 117 is performed, so that the sequence of the sign bits of the LDPC code is returned to the original sequence (restored).

That is, in the block deinterleaving, for example, similarly to the block interleaving, the sequence of the sign bits of the LDPC code is returned to the original sequence by writing and reading the LDPC code in m columns equal to the bit length m of the symbol.

However, in the block deinterleaving, the writing of the LDPC code is performed in the order of reading the LDPC code in the block interleaving. Moreover, in the block deinterleaving, the reading of the LDPC code is performed in the order of writing the LDPC code in the block interleaving.

That is, for part 1 of the LDPC code, part 1 of the LDPC code in units of m-bit symbols is written in the row direction from the first row of all the m columns as illustrated in FIG. 212. That is, the sign bits of the LDPC code, which are m-bit symbols, are written in the row direction.

Writing of part 1 in units of m bits is sequentially performed toward the lower rows of the m columns, and when the writing of part 1 is completed, reading of part 1 downward from the top of the first column unit of the column is performed toward the columns from left to right as illustrated in FIG. 212.

When the reading to the rightmost column is completed, the reading returns to the leftmost column, and reading of part 1 downward from the top of the second column unit of the column is performed in the columns from the left to right direction as illustrated in FIG. 212. Hereinafter, reading of part 1 of the LDPC code of one code word is similarly performed.

When the reading of part 1 of the LDPC code of one code word is completed, for part 2 in units of m-bit symbols, the units of m-bit symbols are sequentially concatenated after part 1, so that the LDPC code in units of symbols is returned to the sequence of sign bits of the LDPC code of the original one code word (the LDCP code before block interleaving).

### <Another Configuration Example of Bit Deinterleaver 165>

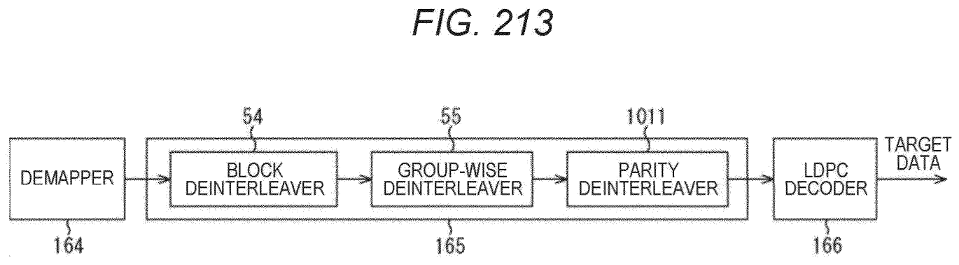

FIG. 213 is a block diagram illustrating another configuration example of the bit deinterleaver 165 in FIG. 204.

Note that, in the drawing, portions corresponding to those in the case of FIG. 205 are denoted by the same reference signs, and the description thereof will be appropriately omitted below.

That is, the bit deinterleaver 165 in FIG. 213 is configured similarly to the case in FIG. 205 except that a parity deinterleaver 1011 is newly provided.

In FIG. 213, the bit deinterleaver 165 includes the block deinterleaver 54, the group-wise deinterleaver 55, and the parity deinterleaver 1011, and performs bit deinterleaving for the sign bits of the LDPC code from the demapper 164.

In other words, the block deinterleaver 54 performs, for the LDPC code from demapper 164, block deinterleaving corresponding to the block interleaving performed by the block interleaver 25 of the transmission device 11 (processing reverse to the block interleaving), in other words, block deinterleaving of returning the positions of the sign bits rearranged by the block interleaving to the original positions, and supplies the resulting LDPC code to the group-wise deinterleaver 55.

The group-wise deinterleaver 55 performs group-wise deinterleaving corresponding to the group-wise interleaving as the rearrangement process performed by the group-wise interleaver 24 of the transmission device 11 for the LDPC code from the block deinterleaver 54.

The LDPC code obtained as a result of the group-wise deinterleaving is supplied from the group-wise deinterleaver 55 to the parity deinterleaver 1011.

The parity deinterleaver 1011 performs, for the sign bits subjected to the group-wise deinterleaving in the group-wise deinterleaver 55, parity deinterleaving corresponding to the parity interleaving performed by the parity interleaver 23 of the transmission device 11 (processing reverse to the parity interleaving), in other words, parity deinterleaving of returning the sign bits of the LDPC code changed in sequence by the parity interleaving to the original sequence.

The LDPC code obtained as a result of the parity deinterleaving is supplied from the parity deinterleaver 1011 to the LDPC decoder 166.

Therefore, in the bit deinterleaver 165 in FIG. 213, the LDPC code for which the block deinterleaving, the group-wise deinterleaving, and the parity deinterleaving have been performed, that is, the LDPC code obtained by the LDPC coding according to the parity check matrix H is supplied to the LDPC decoder 166.

The LDPC decoder 166 performs LDPC decoding for the LDPC code from the bit deinterleaver 165 using the parity check matrix H used for LDPC coding by the LDPC encoder 115 of the transmission device 11.

In other words, for the type B method, the LDPC decoder 166 performs LDPC decoding for the LDPC code from the bit deinterleaver 165, using the parity check matrix H itself (of the type B method) used for LDPC coding by the LDPC encoder 115 of the transmission device 11, or using the transformed parity check matrix obtained by performing at least column permutation corresponding to parity interleaving for the parity check matrix H. Furthermore, in the type A method, the LDPC decoder 166 performs LDPC decoding for the LDPC code from the bit deinterleaver 165, using a parity check matrix (FIG. 28) obtained by applying column permutation to a parity check matrix (FIG. 27) (of the type A method) used for LDPC coding by the LDPC encoder 115 of the transmission device 11, or a transformed parity check matrix (FIG. 29) obtained by applying row permutation to a parity check matrix (FIG. 27) used for LDPC coding.

Here, in FIG. 213, since the LDPC code obtained by the LDPC coding according to the parity check matrix H is supplied from (the parity deinterleaver 1011 of) the bit deinterleaver 165 to the LDPC decoder 166, in a case where the LDPC decoding of the LDPC code is performed using the parity check matrix H by the type B method used for the LDPC coding by the LDPC encoder 115 of the transmission device 11 or the parity check matrix (FIG. 28) obtained by applying column permutation to the parity check matrix (FIG. 27) by the type A method used for the LDPC coding, the LDPC decoder 166 may be a decoding device that performs the LDPC decoding by the full serial decoding method of sequentially performing the operation of the message (check node message, variable node message) for each node, or the like. The decoding device can be configured to perform LDPC decoding by a full parallel decoding method in which the operation of the message is performed on all the nodes at the same time (in parallel).

Furthermore, in the LDPC decoder 166, in a case where the LDPC decoding of the LDPC code is performed using the transformed parity check matrix obtained by performing at least column permutation corresponding to the parity interleaving for the parity check matrix H by the type B method used for the LDPC coding by the LDPC encoder 115 of the transmission device 11 or the transformed parity check matrix (FIG. 29) obtained by performing row permutation for the parity check matrix (FIG. 27) by the type A method used for the LDPC coding, the LDPC decoder 166 is a decoding device having an architecture that simultaneously performs the check node operation and the variable node operation for P (or a divisor other than 1 of P), and is configured to perform column permutation similar to the column permutation (parity interleaving) for obtaining the transformed parity check matrix for the LDPC code by performing the same column permutation for the LDPC code, a decoding device (FIG. 210) including the reception data rearrangement unit 310 that rearranges the sign bits of the LDPC code.

Note that, in FIG. 213, for convenience of description, the block deinterleaver 54 that performs block deinterleaving, the group-wise deinterleaver 55 that performs group-wise deinterleaving, and the parity deinterleaver 1011 that performs parity deinterleaving are separately configured. However, two or more of the block deinterleaver 54, the group-wise deinterleaver 55, and the parity deinterleaver 1011 can be integrally configured similarly to the parity interleaver 23, the group-wise interleaver 24, and the block interleaver 25 of the transmission device 11.

### <Configuration Example of Reception System>

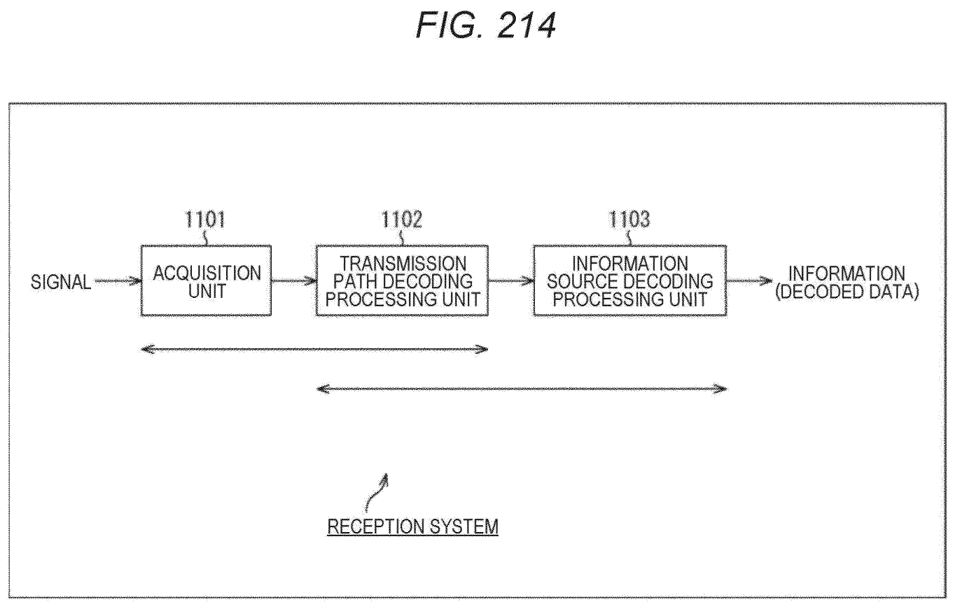

FIG. 214 is a block diagram illustrating a first configuration example of a reception system to which the reception device 12 can be applied.

In FIG. 214, the reception system includes an acquisition unit 1101, a transmission path decoding processing unit 1102, and an information source decoding processing unit 1103.

The acquisition unit 1101 acquires a signal including an LDPC code obtained by performing at least LDPC coding on LDPC target data such as image data and audio data of a program via a transmission path (communication path) (not illustrated) such as terrestrial digital broadcasting, satellite digital broadcasting, a CATV network, the Internet, or other networks, and supplies the signal to the transmission path decoding processing unit 1102.

Here, in a case where the signal acquired by the acquisition unit 1101 is broadcast from a broadcast station via terrestrial waves, satellite waves, a cable television (CATV) network, or the like, for example, the acquisition unit 1101 is configured by a tuner, a set top box (STB), or the like. Furthermore, in a case where a signal acquired by the acquisition unit 1101 is transmitted from a web server by multicast like Internet protocol television (IPTV), for example, the acquisition unit 1101 includes a network interface (I/F) such as a network interface card (NIC).

The transmission path decoding processing unit 1102 corresponds to the reception device 12. The transmission path decoding processing unit 1102 performs a transmission path decoding process including at least a process of correcting an error occurring in the transmission path on the signal acquired by the acquisition unit 1101 via the transmission path, and supplies the resultant signal to the information source decoding processing unit 1103.

That is, the signal acquired by the acquisition unit 1101 via the transmission path is a signal obtained by performing at least error correction coding for correcting an error occurring in the transmission path, and the transmission path decoding processing unit 1102 performs transmission path decoding processing such as error correction processing on such a signal.

Here, examples of the error correction coding include LDPC coding and BCH coding, for example. Here, at least LDPC coding is performed as the error correction coding.

Furthermore, the transmission path decoding process may include demodulation and the like of a modulated signal.

The information source decoding processing unit 1103 applies information source decoding processing including at least processing of decompressing compressed information into original information to the signal subjected to the transmission path decoding processing.

That is, there is a case where compression encoding for compressing information is applied to a signal acquired by the acquisition unit 1101 via the transmission path in order to reduce the amount of data such as an image and an audio as information. In this case, the information source decoding processing unit 1103 performs information source decoding processing such as processing of decompressing compressed information into original information (decompression processing) on the signal to which the transmission path decoding processing has been applied.

Note that, in a case where compression encoding is not applied to the signal acquired by the acquisition unit 1101 via the transmission path, the information source decoding processing unit 1103 does not perform processing of decompressing the compressed information into the original information.

Here, examples of the decompression processing include MPEG decoding, for example. Furthermore, the transmission path decoding process may include descrambling and the like in addition to the decompression process.

In the reception system configured as described above, in the acquisition unit 1101, for example, a signal obtained by performing compression encoding such as MPEG encoding on data such as an image and an audio and further performing error correction encoding such as LDPC encoding is acquired via a transmission path and supplied to the transmission path decoding processing unit 1102.

In the transmission path decoding processing unit 1102, for example, processing similar to the processing performed by the reception device 12 is performed on the signal from the acquisition unit 1101 as the transmission path decoding processing, and the resulting signal is supplied to the information source decoding processing unit 1103.

The information source decoding processing unit 1103 performs information source decoding processing such as MPEG decoding on the signal from the transmission path decoding processing unit 1102, and outputs an image or sound obtained as a result.

The reception system in FIG. 214 as described above can be applied to, for example, a television tuner that receives television broadcasting as digital broadcasting.

Note that each of the acquisition unit 1101, the transmission path decoding processing unit 1102, and the information source decoding processing unit 1103 can be configured as one independent device (hardware (integrated circuit (IC) or the like) or a software module).

Furthermore, regarding the acquisition unit 1101, the transmission path decoding processing unit 1102, and the information source decoding processing unit 1103, a set of the acquisition unit 1101 and the transmission path decoding processing unit 1102, a set of the transmission path decoding processing unit 1102 and the information source decoding processing unit 1103, and a set of the acquisition unit 1101, the transmission path decoding processing unit 1102, and the information source decoding processing unit 1103 can be configured as one independent device.

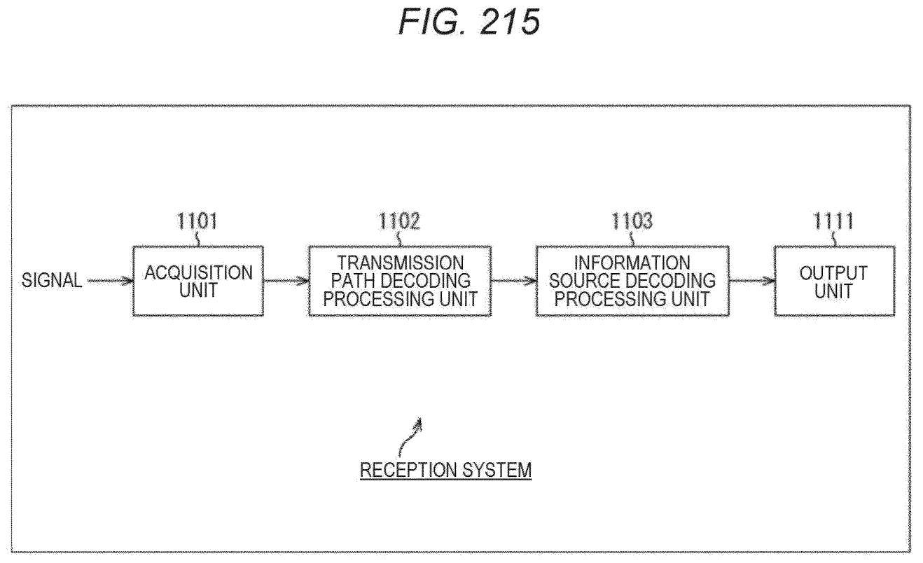

FIG. 215 is a block diagram illustrating a second configuration example of the reception system to which the reception device 12 can be applied.

Note that, in the drawing, portions corresponding to those in the case of FIG. 214 are denoted by the same reference signs, and the description thereof will be appropriately omitted below.

The reception system in FIG. 215 is common to the case in FIG. 214 in including the acquisition unit 1101, the transmission path decoding processing unit 1102, and the information source decoding processing unit 1103, and is different from the case in FIG. 214 in newly providing an output unit 1111.

The output unit 1111 is, for example, a display device that displays an image or a speaker that outputs sound, and outputs an image, sound, or the like as a signal output from the information source decoding processing unit 1103. That is, the output unit 1111 displays an image or outputs sound.

The reception system in FIG. 215 as described above can be applied to, for example, a television (TV) receiver that receives television broadcasting as digital broadcasting, a radio receiver that receives radio broadcasting, and the like.

Note that in a case where the signal acquired by the acquisition unit 1101 is not subjected to compression encoding, the signal output from the transmission path decoding processing unit 1102 is supplied to the output unit 1111.

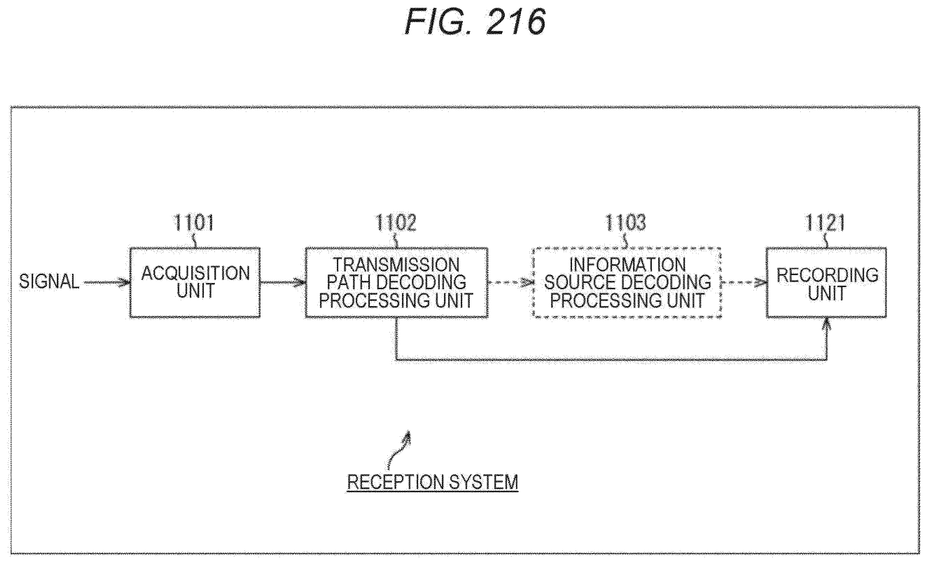

FIG. 216 is a block diagram illustrating a third configuration example of the reception system to which the reception device 12 can be applied.

Note that, in the drawing, portions corresponding to those in the case of FIG. 214 are denoted by the same reference signs, and the description thereof will be appropriately omitted below.

The reception system in FIG. 216 is common to the case in FIG. 214 in including the acquisition unit 1101 and the transmission path decoding processing unit 1102.

However, the reception system in FIG. 216 is different from the case in FIG. 214 in that the information source decoding processing unit 1103 is not provided and a recording unit 1121 is newly provided.

The recording unit 1121 records (stores) the signal (for example, a TS packet of TS of MPEG) output from the transmission path decoding processing unit 1102 in a recording (storage) medium such as an optical disk, a hard disk (magnetic disk), or a flash memory.

The reception system in FIG. 216 as described above can be applied to a recorder or the like that records television broadcasting.

Note that, in FIG. 216, the reception system includes the information source decoding processing unit 1103, and the information source decoding processing unit 1103 can record a signal subjected to the information source decoding processing, that is, an image or sound obtained by decoding, in the recording unit 1121.

### One Embodiment of Computer

Next, the series of processes described above can be performed by hardware or also performed by software. In a case where the series of the processes is performed by the software, a program constituting the software is installed on a general-purpose computer, and the like.

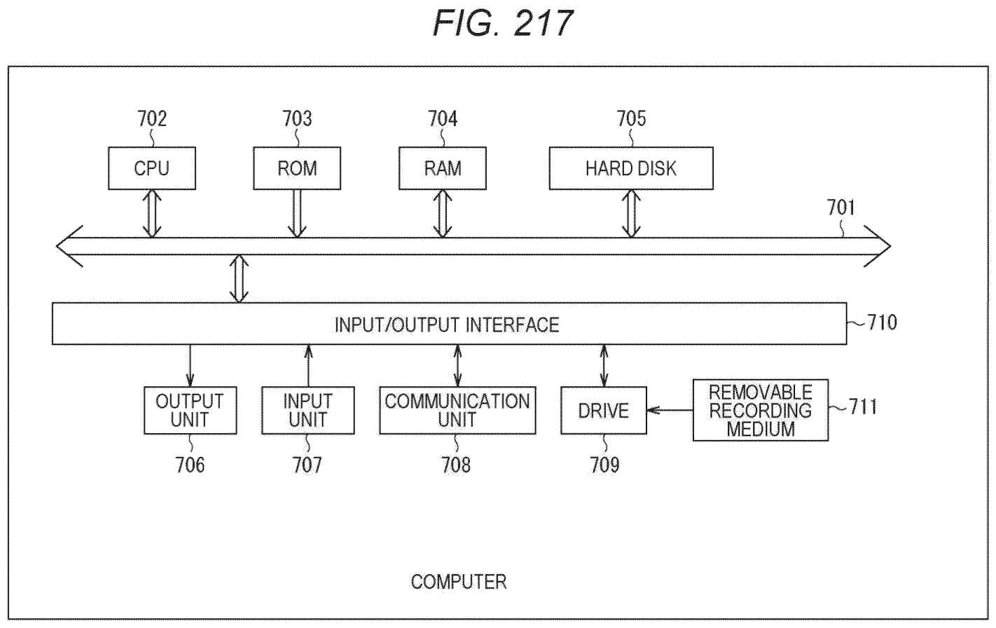

Therefore, FIG. 217 illustrates a configuration example of an embodiment of a computer in which a program for executing the series of processes described above is installed.

The program can be recorded in advance in a hard disk 705 or a ROM 703 as a recording medium built in the computer.

Alternatively, the program can be temporarily or permanently stored (recorded) in a removable recording medium 711 such as a flexible disk, a compact disc read only memory (CD-ROM), a magneto optical (MO) disk, a digital versatile disc (DVD), a magnetic disk, or a semiconductor memory. Such a removable recording medium 711 can be provided as so-called packaged software.

Note that the program can be installed from the removable recording medium 711 to the computer as described above, can be wirelessly transferred from a download site to the computer via an artificial satellite for digital satellite broadcasting, or can be transferred by wire to the computer via a network such as a local area network (LAN) or the Internet, and the program thus transferred can be received by the communication unit 708 and installed in the built-in hard disk 705 in the computer.

The computer includes a central processing unit (CPU) 702. An input/output interface 710 is connected to the CPU 702 via a bus 701, and when a command is input by the user operating an input unit 707 including a keyboard, a mouse, a microphone, and the like via the input/output interface 710, the CPU 702 executes the program stored in the read only memory (ROM) 703 according to the command. Alternatively, the CPU 702 loads a program stored in the hard disk 705, a program transferred from a satellite or a network, received by the communication unit 708, and installed in the hard disk 705, or a program read from the removable recording medium 711 attached to the drive 709 and installed in the hard disk 705 into a random access memory (RAM) 704, and executes the program. As a result, the CPU 702 performs the processing according to the above-described flowchart or the processing performed by the configuration of the above-described block diagram. Then, the CPU 702 outputs the processing result from an output unit 706 including a liquid crystal display (LCD), a speaker, or the like, or transmits the processing result from a communication unit 708, and further records the processing result in the hard disk 705 via the input/output interface 710, for example, as necessary.

Here, in the present specification, processing steps describing a program for causing a computer to perform various types of processing are not necessarily processed in time series in the order described as the flowchart, and include processing executed in parallel or individually (for example, parallel processing or processing by an object).

Furthermore, the program may be processed by one computer or may be processed in a distributed manner by a plurality of computers. Moreover, the program may be transferred to a distant computer to be executed.

Note that the embodiments of the present technology are not limited to the above-described embodiments, and various changes can be made without departing from the gist of the present technology.

For example, (the parity check matrix initial value table of) the above-described new LDPC code and GW pattern can be used for a satellite line, a terrestrial wave, a cable (wired line), and other communication paths 13 (FIG. 7). Moreover, the new LDPC code and the GW pattern can also be used for data transmission other than digital broadcasting.

Note that the effects described herein are merely examples and are not limited, and other effects may be provided.

### REFERENCE SIGNS LIST

11 Transmission device
12 Reception device
23 Parity interleaver
24 Group-wise interleaver
25 Block interleaver
54 Block deinterleaver
55 Group-wise deinterleaver
111 Mode adaptation/multiplexer
112 Padder
113 BB scrambler
114 BCH encoder
115 LDPC encoder
116 Bit interleaver
117 Mapper
118 Time interleaver
119 SISO/MISO encoder
120 Frequency interleaver
121 BCH encoder
122 LDPC encoder
123 Mapper
124 Frequency interleaver
131 Frame builder/resource allocation unit 132 OFDM generation unit
151 OFDM processing unit
152 Frame management unit
153 Frequency deinterleaver
154 Demapper
155 LDPC decoder
156 BCH decoder
161 Frequency deinterleaver
162 SISO/MISO decoder
163 Time deinterleaver
164 Demapper
165 Bit deinterleaver
166 LDPC decoder
167 BCH decoder
168 BB descrambler
169 Null deletion unit
170 Demultiplexer
300 Edge data storage memory
301 Selector
302 Check node calculation unit
303 Cyclic shift circuit
304 Edge data storage memory
305 Selector
306 Reception data memory
307 Variable node calculation unit
308 Cyclic shift circuit
309 Decoded word calculation unit
310 Reception data rearrangement unit
311 Decoded data rearrangement unit
601 Encoding processing unit
602 Storage unit
611 Coding rate setting unit
612 Initial value table reading unit
613 Parity check matrix generation unit
614 Information bit reading unit
615 Encoding parity operation unit
616 Control unit
701 Bus
702 CPU
703 ROM
704 RAM
705 Hard disk
706 Output unit
707 Input unit
708 Communication unit
709 Drive
710 Input/output interface
711 Removable recording medium
1001 Reverse exchange unit
1002 Memory
1011 Parity deinterleaver
1101 Acquisition unit
1102 Transmission path decoding processing unit
1103 Information source decoding processing unit
1111 Output unit
1121 Recording unit

1. A transmission device comprising:
an encoding unit that performs LDPC coding on a basis of a parity check matrix of an LDPC code with a code length N of 69120 bits and a coding rate r of 4/16;
a group-wise interleaving unit that performs group-wise interleaving that interleaves the LDPC code in units of bit groups of 360 bits; and
a mapping unit that maps the LDPC code to any one of 16 signal points of a 16QAM 2D-non-uniform constellation (NUC) in units of 4 bits,
wherein in the group-wise interleaving, an (i+1)th bit group from a head of the LDPC code is set as a bit group i, and a sequence of bit groups 0 to 191 of the LDPC code with the 69210 bits is interleaved into a sequence of bit groups below,
154, 83, 159, 153, 136, 6, 19, 73, 122, 40, 97, 144, 101, 106, 130, 174, 48, 176, 14, 27, 52, 152, 173, 63, 39, 92, 114, 98, 190, 149, 103, 160, 118, 13, 29, 51, 66, 168, 180, 23, 170, 24, 5, 157, 28, 45, 53, 68, 25, 191, 148, 139, 15, 67, 77, 100, 58, 91, 50, 131, 65, 17, 11, 123, 86, 135, 115, 120, 59, 162, 9, 189, 21, 12, 179, 178, 110, 35, 137, 3, 84, 177, 124, 186, 143, 26, 96, 80, 31, 169, 119, 33, 87, 140, 88, 171, 133, 150, 151, 72, 85, 89, 112, 126, 167, 56, 49, 187, 138, 145, 18, 32, 90, 158, 54, 104, 62, 165, 79, 1, 81, 102, 44, 61, 10, 166, 2, 116, 161, 60, 108, 142, 30, 78, 127, 111, 46, 43, 184, 163, 64, 22, 41, 156, 70, 20, 42, 182, 55, 95, 105, 132, 38, 69, 134, 74, 155, 141, 172, 57, 7, 175, 128, 75, 107, 109, 99, 147, 146, 117, 125, 185, 0, 76, 82, 129, 36, 34, 93, 188, 113, 71, 183, 121, 47, 16, 164, 4, 181, 94, 37, 8,
the parity check matrix includes:
an A matrix on an upper left of the parity check matrix, with M1 rows and K columns represented by a predetermined value M1 and an information length K=N×r of the LDPC code;
a B matrix of M1 rows and M1 columns, the B matrix having a staircase structure adjacent to a right side of the A matrix;
a Z matrix of M1 rows and N−K−M1 columns, the Z matrix being a zero matrix adjacent to a right side of the B matrix;
a C matrix of N−K−M1 rows and K+M1 columns, the C matrix being adjacent under the A matrix and the B matrix; and
a D matrix of N−K−M1 rows and N−K−M1 columns, the D matrix being an identity matrix adjacent to a right side of the C matrix,
the predetermined value M1 is 1800,
the A matrix and the C matrix are represented by a parity check matrix initial value table, and
the parity check matrix initial value table is a table representing positions of elements of 1 in the A matrix and the C matrix for every 360 columns, and is
561 825 1718 4745 7515 13041 13466 18039 19065 21821 32596 32708 35323 36399 36450 41124 43036 43218 43363 44875 49948
56 102 1779 2427 5381 8768 15336 26473 35717 38748 39066 45002 50720
694 1150 1533 2177 5801 6610 7601 16657 18949 33472 47746 49581 50668
90 1122 1472 2085 2593 4986 8200 9175 15502 44084 46057 48546 50487
521 619 708 6915 8978 14211 17426 23058 23463 27440 29822 33443 42871
449 912 1471 8058 9344 11928 20533 20600 20737 26557 26970 27616 33791
355 700 1528 6478 9588 10790 20992 33122 34283 41295 43439 46249 47763
997 1543 1679 5874 7973 7975 11113 28275 28812 29864 35070 36864 50676
85 326 1392 4186 10855 11005 12913 19263 22984 31733 33787 37567 48173
986 1144 1508 19864 28918 29117 33609 36452 47975 48432 48842 49274 51533
437 1190 1413 3814 6695 17541 22060 25845 28431 37453 38912 44170 49231
327 1171 1204 6952 11880 16469 25058 28956 31523 36770 40189 43422 46481
123 605 619 8118 8455 19550 20529 21762 21950 28485 30946 34755 34765
113 896 971 6400 27059 33383 34537 35827 38796 40582 42594 43098 48525
162 854 1015 2938 10659 12085 13040 32772 33023 35878 49674 51060 51333
100 452 1703 1932 4208 5127 12086 14549 16084 17890 20870 41364 48498
1569 1633 1666 12957 18611 22499 38418 38719 42135 46815 48274 50947 51387
119 691 1190 2457 3865 7468 12512 30782 31811 33508 36586 41789 47426
867 1117 1666 4376 13263 13466 33524 37440 38136 39800 41454 41620 42510
378 900 1754 16303 25369 27103 28360 30958 35316 44165 46682 47016 50004
1321 1549 1570 16276 17284 19431 23482 23920 27386 27517 46253 48617 50118
37 383 1418 15792 22551 28843 36532 36718 38805 39226 45671 47712 51769
150 787 1441 17828 19396 21576 21805 24048 31868 32891 42486 43020 45492
1095 1214 1744 2445 5773 10209 11526 29604 30121 36526 45786 47376 49366
412 448 1281 11164 14501 15538 15773 23305 31960 32721 40744 45731 50269
183 626 837 4491 12237 13705 15177 15973 21266 25374 41232 44147 50529
618 1550 1594 5474 9260 16552 18122 26061 30420 30922 32661 34390 43236
135 496 757 9327 15659 20738 24327 26688 29063 38993 46155 49532 50001
64 126 1714 5561 8921 11300 12688 14454 16857 19585 20528 24107 27252
528 687 1730 9735 11737 16396 19200 33712 34271 38241 42027 44471 45581
69 646 1447 8603 19706 22153 22398 23840 24638 27254 29107 30368 41419
673 845 1285 9100 11064 14804 15425 17357 27248 31223 32410 35444 48018
124 1531 1677 3672 3673 3786 8886 9557 10003 11053 13053 22458 25413
102 1154 1758 5721 6034 14567 17772 28670 33380 34284 35356 47480 48123
48 351 760 2078 9797 22956 26120 34119 39658 41039 45237 47861 49022
254 445 841 6835 18340 19021 20053 22874 32639 36679 42004 45696 49530
16 802 903 6218 16206 22068 23049 28201 30377 33947 44358 44739 49303
153 1542 1629 7992 29900 34931 36927 38651 39981 41085 41327 50185 51484
525 1291 1765 9425 20271 31229 37444 38996 39145 41711 43188 45203 51255
2 244 1648 12321 14991 17426 18456 20126 29915 32581 38880 39516 49013
23 452 705 9414 11862 13764 18179 35458 37892 40471 46041 46494 48746
509 1201 1328 8921 9867 10947 19476 22693 32636 34301 38356 39238 51797
246 249 1390 12438 13266 24060 33628 37130 42923 43298 43709 43721 45413
117 257 748 9419 9461 11350 12790 16724 33147 34168 34683 37884 42699
619 646 740 7468 7604 8152 16296 19120 27614 27748 40170 40289 49366
914 1360 1716 10817 17672 18919 26146 29631 40903 46716 49502 51576 51657
68 702 1552 10431 10925 12856 24516 26440 30834 31179 32277 35019 44108
588 880 1524 6641 9453 9653 13679 14488 20714 25865 42217 42637 48312
6380 12240 12558 12816 21460 24206 26129 28555
8889 16221 21629 23476 33954 40572 43494 44666 44885 49813
16938 17727 17913 18898 21754 32515 35686 36920 39898 43560
9170 11747 14681 22874 24537 24685 26989 28947 33592 34621
2427 10241 29649 30522 37700 37789 41656 44020 49801 51268.

2. A transmission method comprising:
an encoding step of performing LDPC coding on a basis of a parity check matrix of an LDPC code with a code length N of 69120 bits and a coding rate r of 4/16;
a group-wise interleaving step of performing group-wise interleaving that interleaves the LDPC code in units of bit groups of 360 bits; and
a mapping step of mapping the LDPC code to any one of 16 signal points of a 16QAM 2D-non-uniform constellation (NUC) in units of 4 bits,
wherein in the group-wise interleaving, an (i+1)th bit group from a head of the LDPC code is set as a bit group i, and a sequence of bit groups 0 to 191 of the LDPC code with the 69120 bits is interleaved into a sequence of bit groups below,
154, 83, 159, 153, 136, 6, 19, 73, 122, 40, 97, 144, 101, 106, 130, 174, 48, 176, 14, 27, 52, 152, 173, 63, 39, 92, 114, 98, 190, 149, 103, 160, 118, 13, 29, 51, 66, 168, 180, 23, 170, 24, 5, 157, 28, 45, 53, 68, 25, 191, 148, 139, 15, 67, 77, 100, 58, 91, 50, 131, 65, 17, 11, 123, 86, 135, 115, 120, 59, 162, 9, 189, 21, 12, 179, 178, 110, 35, 137, 3, 84, 177, 124, 186, 143, 26, 96, 80, 31, 169, 119, 33, 87, 140, 88, 171, 133, 150, 151, 72, 85, 89, 112, 126, 167, 56, 49, 187, 138, 145, 18, 32, 90, 158, 54, 104, 62, 165, 79, 1, 81, 102, 44, 61, 10, 166, 2, 116, 161, 60, 108, 142, 30, 78, 127, 111, 46, 43, 184, 163, 64, 22, 41, 156, 70, 20, 42, 182, 55, 95, 105, 132, 38, 69, 134, 74, 155, 141, 172, 57, 7, 175, 128, 75, 107, 109, 99, 147, 146, 117, 125, 185, 0, 76, 82, 129, 36, 34, 93, 188, 113, 71, 183, 121, 47, 16, 164, 4, 181, 94, 37, 8,
the parity check matrix includes:
an A matrix on an upper left of the parity check matrix, with M1 rows and K columns represented by a predetermined value M1 and an information length K=N×r of the LDPC code;
a B matrix of M1 rows and M1 columns, the B matrix having a staircase structure adjacent to a right side of the A matrix;
a Z matrix of M1 rows and N−K−M1 columns, the Z matrix being a zero matrix adjacent to a right side of the B matrix;
a C matrix of N−K−M1 rows and K+M1 columns, the C matrix being adjacent under the A matrix and the B matrix; and
a D matrix of N−K−M1 rows and N−K−M1 columns, the D matrix being an identity matrix adjacent to a right side of the C matrix,
the predetermined value M1 is 1800,
the A matrix and the C matrix are represented by a parity check matrix initial value table, and
the parity check matrix initial value table is a table representing positions of elements of 1 in the A matrix and the C matrix for every 360 columns, and is
561 825 1718 4745 7515 13041 13466 18039 19065 21821 32596 32708 35323 36399 36450 41124 43036 43218 43363 44875 49948
56 102 1779 2427 5381 8768 15336 26473 35717 38748 39066 45002 50720
694 1150 1533 2177 5801 6610 7601 16657 18949 33472 47746 49581 50668
90 1122 1472 2085 2593 4986 8200 9175 15502 44084 46057 48546 50487
521 619 708 6915 8978 14211 17426 23058 23463 27440 29822 33443 42871
449 912 1471 8058 9344 11928 20533 20600 20737 26557 26970 27616 33791
355 700 1528 6478 9588 10790 20992 33122 34283 41295 43439 46249 47763
997 1543 1679 5874 7973 7975 11113 28275 28812 29864 35070 36864 50676
85 326 1392 4186 10855 11005 12913 19263 22984 31733 33787 37567 48173
986 1144 1508 19864 28918 29117 33609 36452 47975 48432 48842 49274 51533
437 1190 1413 3814 6695 17541 22060 25845 28431 37453 38912 44170 49231
327 1171 1204 6952 11880 16469 25058 28956 31523 36770 40189 43422 46481
123 605 619 8118 8455 19550 20529 21762 21950 28485 30946 34755 34765
113 896 971 6400 27059 33383 34537 35827 38796 40582 42594 43098 48525
162 854 1015 2938 10659 12085 13040 32772 33023 35878 49674 51060 51333
100 452 1703 1932 4208 5127 12086 14549 16084 17890 20870 41364 48498
1569 1633 1666 12957 18611 22499 38418 38719 42135 46815 48274 50947 51387
119 691 1190 2457 3865 7468 12512 30782 31811 33508 36586 41789 47426
867 1117 1666 4376 13263 13466 33524 37440 38136 39800 41454 41620 42510
378 900 1754 16303 25369 27103 28360 30958 35316 44165 46682 47016 50004
1321 1549 1570 16276 17284 19431 23482 23920 27386 27517 46253 48617 50118
37 383 1418 15792 22551 28843 36532 36718 38805 39226 45671 47712 51769
150 787 1441 17828 19396 21576 21805 24048 31868 32891 42486 43020 45492
1095 1214 1744 2445 5773 10209 11526 29604 30121 36526 45786 47376 49366
412 448 1281 11164 14501 15538 15773 23305 31960 32721 40744 45731 50269
183 626 837 4491 12237 13705 15177 15973 21266 25374 41232 44147 50529
618 1550 1594 5474 9260 16552 18122 26061 30420 30922 32661 34390 43236
135 496 757 9327 15659 20738 24327 26688 29063 38993 46155 49532 50001
64 126 1714 5561 8921 11300 12688 14454 16857 19585 20528 24107 27252
528 687 1730 9735 11737 16396 19200 33712 34271 38241 42027 44471 45581
69 646 1447 8603 19706 22153 22398 23840 24638 27254 29107 30368 41419
673 845 1285 9100 11064 14804 15425 17357 27248 31223 32410 35444 48018
124 1531 1677 3672 3673 3786 8886 9557 10003 11053 13053 22458 25413
102 1154 1758 5721 6034 14567 17772 28670 33380 34284 35356 47480 48123
48 351 760 2078 9797 22956 26120 34119 39658 41039 45237 47861 49022
254 445 841 6835 18340 19021 20053 22874 32639 36679 42004 45696 49530
16 802 903 6218 16206 22068 23049 28201 30377 33947 44358 44739 49303
153 1542 1629 7992 29900 34931 36927 38651 39981 41085 41327 50185 51484
525 1291 1765 9425 20271 31229 37444 38996 39145 41711 43188 45203 51255
2 244 1648 12321 14991 17426 18456 20126 29915 32581 38880 39516 49013
23 452 705 9414 11862 13764 18179 35458 37892 40471 46041 46494 48746
509 1201 1328 8921 9867 10947 19476 22693 32636 34301 38356 39238 51797
246 249 1390 12438 13266 24060 33628 37130 42923 43298 43709 43721 45413
117 257 748 9419 9461 11350 12790 16724 33147 34168 34683 37884 42699
619 646 740 7468 7604 8152 16296 19120 27614 27748 40170 40289 49366
914 1360 1716 10817 17672 18919 26146 29631 40903 46716 49502 51576 51657
68 702 1552 10431 10925 12856 24516 26440 30834 31179 32277 35019 44108
588 880 1524 6641 9453 9653 13679 14488 20714 25865 42217 42637 48312
6380 12240 12558 12816 21460 24206 26129 28555 41616 51767
8889 16221 21629 23476 33954 40572 43494 44666 44885 49813
16938 17727 17913 18898 21754 32515 35686 36920 39898 43560
9170 11747 14681 22874 24537 24685 26989 28947 33592 34621
2427 10241 29649 30522 37700 37789 41656 44020 49801 51268.

3. A reception device comprising
a group-wise deinterleaving unit that returns a sequence of an LDPC code after group-wise interleaving to an original sequence, the sequence of the LDPC code after group-wise interleaving being obtained from data transmitted by a transmission method including:
an encoding step of performing LDPC coding on a basis of a parity check matrix of an LDPC code with a code length N of 69120 bits and a coding rate r of 4/16;
a group-wise interleaving step of performing group-wise interleaving that interleaves the LDPC code in units of bit groups of 360 bits; and
a mapping step of mapping the LDPC code to any one of 16 signal points of a 16QAM 2D-non-uniform constellation (NUC) in units of 4 bits,
wherein in the group-wise interleaving, an (i+1)th bit group from a head of the LDPC code is set as a bit group i, and a sequence of bit groups 0 to 191 of the LDPC code with the 69120 bits is interleaved into a sequence of bit groups below,
154, 83, 159, 153, 136, 6, 19, 73, 122, 40, 97, 144, 101, 106, 130, 174, 48, 176, 14, 27, 52, 152, 173, 63, 39, 92, 114, 98, 190, 149, 103, 160, 118, 13, 29, 51, 66, 168, 180, 23, 170, 24, 5, 157, 28, 45, 53, 68, 25, 191, 148, 139, 15, 67, 77, 100, 58, 91, 50, 131, 65, 17, 11, 123, 86, 135, 115, 120, 59, 162, 9, 189, 21, 12, 179, 178, 110, 35, 137, 3, 84, 177, 124, 186, 143, 26, 96, 80, 31, 169, 119, 33, 87, 140, 88, 171, 133, 150, 151, 72, 85, 89, 112, 126, 167, 56, 49, 187, 138, 145, 18, 32, 90, 158, 54, 104, 62, 165, 79, 1, 81, 102, 44, 61, 10, 166, 2, 116, 161, 60, 108, 142, 30, 78, 127, 111, 46, 43, 184, 163, 64, 22, 41, 156, 70, 20, 42, 182, 55, 95, 105, 132, 38, 69, 134, 74, 155, 141, 172, 57, 7, 175, 128, 75, 107, 109, 99, 147, 146, 117, 125, 185, 0, 76, 82, 129, 36, 34, 93, 188, 113, 71, 183, 121, 47, 16, 164, 4, 181, 94, 37, 8,
the parity check matrix includes:
an A matrix on an upper left of the parity check matrix, with M1 rows and K columns represented by a predetermined value M1 and an information length K=N×r of the LDPC code;
a B matrix of M1 rows and M1 columns, the B matrix having a staircase structure adjacent to a right side of the A matrix;
a Z matrix of M1 rows and N−K−M1 columns, the Z matrix being a zero matrix adjacent to a right side of the B matrix;
a C matrix of N−K−M1 rows and K+M1 columns, the C matrix being adjacent under the A matrix and the B matrix; and
a D matrix of N−K−M1 rows and N−K−M1 columns, the D matrix being an identity matrix adjacent to a right side of the C matrix,
the predetermined value M1 is 1800,
the A matrix and the C matrix are represented by a parity check matrix initial value table, and
the parity check matrix initial value table is a table representing positions of elements of 1 in the A matrix and the C matrix for every 360 columns, and is
561 825 1718 4745 7515 13041 13466 18039 19065 21821 32596 32708 35323 36399 36450 41124 43036 43218 43363 44875 49948
56 102 1779 2427 5381 8768 15336 26473 35717 38748 39066 45002 50720
694 1150 1533 2177 5801 6610 7601 16657 18949 33472 47746 49581 50668
90 1122 1472 2085 2593 4986 8200 9175 15502 44084 46057 48546 50487
521 619 708 6915 8978 14211 17426 23058 23463 27440 29822 33443 42871
449 912 1471 8058 9344 11928 20533 20600 20737 26557 26970 27616 33791
355 700 1528 6478 9588 10790 20992 33122 34283 41295 43439 46249 47763
997 1543 1679 5874 7973 7975 11113 28275 28812 29864 35070 36864 50676
85 326 1392 4186 10855 11005 12913 19263 22984 31733 33787 37567 48173
986 1144 1508 19864 28918 29117 33609 36452 47975 48432 48842 49274 51533
437 1190 1413 3814 6695 17541 22060 25845 28431 37453 38912 44170 49231
327 1171 1204 6952 11880 16469 25058 28956 31523 36770 40189 43422 46481
123 605 619 8118 8455 19550 20529 21762 21950 28485 30946 34755 34765
113 896 971 6400 27059 33383 34537 35827 38796 40582 42594 43098 48525
162 854 1015 2938 10659 12085 13040 32772 33023 35878 49674 51060 51333
100 452 1703 1932 4208 5127 12086 14549 16084 17890 20870 41364 48498
1569 1633 1666 12957 18611 22499 38418 38719 42135 46815 48274 50947 51387
119 691 1190 2457 3865 7468 12512 30782 31811 33508 36586 41789 47426
867 1117 1666 4376 13263 13466 33524 37440 38136 39800 41454 41620 42510
378 900 1754 16303 25369 27103 28360 30958 35316 44165 46682 47016 50004
1321 1549 1570 16276 17284 19431 23482 23920 27386 27517 46253 48617 50118
37 383 1418 15792 22551 28843 36532 36718 38805 39226 45671 47712 51769
150 787 1441 17828 19396 21576 21805 24048 31868 32891 42486 43020 45492
1095 1214 1744 2445 5773 10209 11526 29604 30121 36526 45786 47376 49366
412 448 1281 11164 14501 15538 15773 23305 31960 32721 40744 45731 50269
183 626 837 4491 12237 13705 15177 15973 21266 25374 41232 44147 50529
618 1550 1594 5474 9260 16552 18122 26061 30420 30922 32661 34390 43236
135 496 757 9327 15659 20738 24327 26688 29063 38993 46155 49532 50001
64 126 1714 5561 8921 11300 12688 14454 16857 19585 20528 24107 27252
528 687 1730 9735 11737 16396 19200 33712 34271 38241 42027 44471 45581
69 646 1447 8603 19706 22153 22398 23840 24638 27254 29107 30368 41419
673 845 1285 9100 11064 14804 15425 17357 27248 31223 32410 35444 48018
124 1531 1677 3672 3673 3786 8886 9557 10003 11053 13053 22458 25413
102 1154 1758 5721 6034 14567 17772 28670 33380 34284 35356 47480 48123
48 351 760 2078 9797 22956 26120 34119 39658 41039 45237 47861 49022
254 445 841 6835 18340 19021 20053 22874 32639 36679 42004 45696 49530
16 802 903 6218 16206 22068 23049 28201 30377 33947 44358 44739 49303
153 1542 1629 7992 29900 34931 36927 38651 39981 41085 41327 50185 51484
525 1291 1765 9425 20271 31229 37444 38996 39145 41711 43188 45203 51255
2 244 1648 12321 14991 17426 18456 20126 29915 32581 38880 39516 49013
23 452 705 9414 11862 13764 18179 35458 37892 40471 46041 46494 48746
509 1201 1328 8921 9867 10947 19476 22693 32636 34301 38356 39238 51797
246 249 1390 12438 13266 24060 33628 37130 42923 43298 43709 43721 45413
117 257 748 9419 9461 11350 12790 16724 33147 34168 34683 37884 42699
619 646 740 7468 7604 8152 16296 19120 27614 27748 40170 40289 49366
914 1360 1716 10817 17672 18919 26146 29631 40903 46716 49502 51576 51657
68 702 1552 10431 10925 12856 24516 26440 30834 31179 32277 35019 44108
588 880 1524 6641 9453 9653 13679 14488 20714 25865 42217 42637 48312
6380 12240 12558 12816 21460 24206 26129 28555 41616 51767
8889 16221 21629 23476 33954 40572 43494 44666 44885 49813
16938 17727 17913 18898 21754 32515 35686 36920 39898 43560
9170 11747 14681 22874 24537 24685 26989 28947 33592 34621
2427 10241 29649 30522 37700 37789 41656 44020 49801 51268.

4. A reception method comprising
a group-wise deinterleaving step of returning a sequence of an LDPC code after group-wise interleaving to an original sequence, the sequence of the LDPC code after group-wise interleaving being obtained from data transmitted by a transmission method including:
an encoding step of performing LDPC coding on a basis of a parity check matrix of an LDPC code with a code length N of 69120 bits and a coding rate r of 4/16;
a group-wise interleaving step of performing group-wise interleaving that interleaves the LDPC code in units of bit groups of 360 bits; and
a mapping step of mapping the LDPC code to any one of 16 signal points of a 16QAM 2D-non-uniform constellation (NUC) in units of 4 bits,
wherein in the group-wise interleaving, an (i+1)th bit group from a head of the LDPC code is set as a bit group i, and a sequence of bit groups 0 to 191 of the LDPC code with the 69120 bits is interleaved into a sequence of bit groups below,
154, 83, 159, 153, 136, 6, 19, 73, 122, 40, 97, 144, 101, 106, 130, 174, 48, 176, 14, 27, 52, 152, 173, 63, 39, 92, 114, 98, 190, 149, 103, 160, 118, 13, 29, 51, 66, 168, 180, 23, 170, 24, 5, 157, 28, 45, 53, 68, 25, 191, 148, 139, 15, 67, 77, 100, 58, 91, 50, 131, 65, 17, 11, 123, 86, 135, 115, 120, 59, 162, 9, 189, 21, 12, 179, 178, 110, 35, 137, 3, 84, 177, 124, 186, 143, 26, 96, 80, 31, 169, 119, 33, 87, 140, 88, 171, 133, 150, 151, 72, 85, 89, 112, 126, 167, 56, 49, 187, 138, 145, 18, 32, 90, 158, 54, 104, 62, 165, 79, 1, 81, 102, 44, 61, 10, 166, 2, 116, 161, 60, 108, 142, 30, 78, 127, 111, 46, 43, 184, 163, 64, 22, 41, 156, 70, 20, 42, 182, 55, 95, 105, 132, 38, 69, 134, 74, 155, 141, 172, 57, 7, 175, 128, 75, 107, 109, 99, 147, 146, 117, 125, 185, 0, 76, 82, 129, 36, 34, 93, 188, 113, 71, 183, 121, 47, 16, 164, 4, 181, 94, 37, 8,
the parity check matrix includes:
an A matrix on an upper left of the parity check matrix, with M1 rows and K columns represented by a predetermined value M1 and an information length K=N×r of the LDPC code;
a B matrix of M1 rows and M1 columns, the B matrix having a staircase structure adjacent to a right side of the A matrix;
a Z matrix of M1 rows and N−K−M1 columns, the Z matrix being a zero matrix adjacent to a right side of the B matrix;
a C matrix of N−K−M1 rows and K+M1 columns, the C matrix being adjacent under the A matrix and the B matrix; and
a D matrix of N−K−M1 rows and N−K−M1 columns, the D matrix being an identity matrix adjacent to a right side of the C matrix,
the predetermined value M1 is 1800,
the A matrix and the C matrix are represented by a parity check matrix initial value table, and
the parity check matrix initial value table is a table representing positions of elements of 1 in the A matrix and the C matrix for every 360 columns, and is
561 825 1718 4745 7515 13041 13466 18039 19065 21821 32596 32708 35323 36399 36450 41124 43036 43218 43363 44875 49948
56 102 1779 2427 5381 8768 15336 26473 35717 38748 39066 45002 50720
694 1150 1533 2177 5801 6610 7601 16657 18949 33472 47746 49581 50668
90 1122 1472 2085 2593 4986 8200 9175 15502 44084 46057 48546 50487
521 619 708 6915 8978 14211 17426 23058 23463 27440 29822 33443 42871
449 912 1471 8058 9344 11928 20533 20600 20737 26557 26970 27616 33791
355 700 1528 6478 9588 10790 20992 33122 34283 41295 43439 46249 47763
997 1543 1679 5874 7973 7975 11113 28275 28812 29864 35070 36864 50676
85 326 1392 4186 10855 11005 12913 19263 22984 31733 33787 37567 48173
986 1144 1508 19864 28918 29117 33609 36452 47975 48432 48842 49274 51533
437 1190 1413 3814 6695 17541 22060 25845 28431 37453 38912 44170 49231
327 1171 1204 6952 11880 16469 25058 28956 31523 36770 40189 43422 46481
123 605 619 8118 8455 19550 20529 21762 21950 28485 30946 34755 34765
113 896 971 6400 27059 33383 34537 35827 38796 40582 42594 43098 48525
162 854 1015 2938 10659 12085 13040 32772 33023 35878 49674 51060 51333
100 452 1703 1932 4208 5127 12086 14549 16084 17890 20870 41364 48498
1569 1633 1666 12957 18611 22499 38418 38719 42135 46815 48274 50947 51387
119 691 1190 2457 3865 7468 12512 30782 31811 33508 36586 41789 47426
867 1117 1666 4376 13263 13466 33524 37440 38136 39800 41454 41620 42510
378 900 1754 16303 25369 27103 28360 30958 35316 44165 46682 47016 50004
1321 1549 1570 16276 17284 19431 23482 23920 27386 27517 46253 48617 50118
37 383 1418 15792 22551 28843 36532 36718 38805 39226 45671 47712 51769
150 787 1441 17828 19396 21576 21805 24048 31868 32891 42486 43020 45492
1095 1214 1744 2445 5773 10209 11526 29604 30121 36526 45786 47376 49366
412 448 1281 11164 14501 15538 15773 23305 31960 32721 40744 45731 50269
183 626 837 4491 12237 13705 15177 15973 21266 25374 41232 44147 50529
618 1550 1594 5474 9260 16552 18122 26061 30420 30922 32661 34390 43236
135 496 757 9327 15659 20738 24327 26688 29063 38993 46155 49532 50001
64 126 1714 5561 8921 11300 12688 14454 16857 19585 20528 24107 27252
528 687 1730 9735 11737 16396 19200 33712 34271 38241 42027 44471 45581
69 646 1447 8603 19706 22153 22398 23840 24638 27254 29107 30368 41419
673 845 1285 9100 11064 14804 15425 17357 27248 31223 32410 35444 48018
124 1531 1677 3672 3673 3786 8886 9557 10003 11053 13053 22458 25413
102 1154 1758 5721 6034 14567 17772 28670 33380 34284 35356 47480 48123
48 351 760 2078 9797 22956 26120 34119 39658 41039 45237 47861 49022
254 445 841 6835 18340 19021 20053 22874 32639 36679 42004 45696 49530
16 802 903 6218 16206 22068 23049 28201 30377 33947 44358 44739 49303
153 1542 1629 7992 29900 34931 36927 38651 39981 41085 41327 50185 51484
525 1291 1765 9425 20271 31229 37444 38996 39145 41711 43188 45203 51255
2 244 1648 12321 14991 17426 18456 20126 29915 32581 38880 39516 49013
23 452 705 9414 11862 13764 18179 35458 37892 40471 46041 46494 48746
509 1201 1328 8921 9867 10947 19476 22693 32636 34301 38356 39238 51797
246 249 1390 12438 13266 24060 33628 37130 42923 43298 43709 43721 45413
117 257 748 9419 9461 11350 12790 16724 33147 34168 34683 37884 42699
619 646 740 7468 7604 8152 16296 19120 27614 27748 40170 40289 49366
914 1360 1716 10817 17672 18919 26146 29631 40903 46716 49502 51576 51657
68 702 1552 10431 10925 12856 24516 26440 30834 31179 32277 35019 44108
588 880 1524 6641 9453 9653 13679 14488 20714 25865 42217 42637 48312
6380 12240 12558 12816 21460 24206 26129 28555
8889 16221 21629 23476 33954 40572 43494 44666 44885 49813
16938 17727 17913 18898 21754 32515 35686 36920 39898 43560
9170 11747 14681 22874 24537 24685 26989 28947 33592 34621
2427 10241 29649 30522 37700 37789 41656 44020 49801 51268.
